(19) United States
(12) Patent Application Publication
(10) Pub. No.: US 2025/0081737 A1
(43) Pub. Date: Mar. 6, 2025

(54) DISPLAY DEVICE, DISPLAY MODULE, ELECTRONIC DEVICE, AND METHOD OF MANUFACTURING DISPLAY DEVICE

(71) Applicant: SEMICONDUCTOR ENERGY LABORATORY CO., LTD., Atsugi-shi, Kanagawa-ken (JP)

(72) Inventors: Shunpei YAMAZAKI, Setagaya, Tokyo (JP); Ryota HODO, Atsugi, Kanagawa (JP); Yasuhiro JINBO, Isehara, Kanagawa (JP); Yasunori SASAMURA, Hiratsuka, Kanagawa (JP); Hiromi SAWAI, Atsugi, Kanagawa (JP)

(21) Appl. No.: 18/293,193

(22) PCT Filed: Jul. 26, 2022
(86) PCT No.: PCT/IB2022/056861

§ 371 Date: Jan. 29, 2024

(30) Foreign Application Priority Data
Aug. 5, 2021 (JP) 2021-129028
Aug. 5, 2021 (JP) 2021-129038
Sep. 17, 2021 (JP) 2021-152258
Sep. 22, 2021 (JP) 2021-154716
Sep. 29, 2021 (JP) 2021-158983
Oct. 15, 2021 (JP) 2021-169569

(51) Int. Cl. H10K 59/122; H10K 59/12; H10K 59/80

(52) U.S. Cl. CPC H10K 59/122; H10K 59/1201; H10K 59/80518; H10K 59/878

(57) ABSTRACT

A highly reliable display device is provided. The display device includes a first light-emitting element, a second light-emitting element adjacent to the first light-emitting element, a first insulating layer provided between the first light-emitting element and the second light-emitting element, and a second insulating layer over the first insulating layer. The first light-emitting element includes a first conductive layer, a second conductive layer covering an upper surface and a side surface of the first conductive layer, a first EL layer covering an upper surface and a side surface of the second conductive layer, and a common electrode over the first EL layer. The second light-emitting element includes a third conductive layer, a fourth conductive layer covering an upper surface and a side surface of the third conductive layer, a second EL layer covering an upper surface and a side surface of the fourth conductive layer, and the common electrode over the second EL layer. The common electrode is provided over the second insulating layer. The visible light reflectance of the first conductive layer is higher than the visible light reflectance of the second conductive layer. The visible light reflectance of the third conductive layer is higher than the visible light reflectance of the fourth conductive layer.

### TECHNICAL FIELD

One embodiment of the present invention relates to a display device, a display module, and an electronic device. One embodiment of the present invention relates to a method of manufacturing a display device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), a method for driving any of them, and a method of manufacturing any of them.

### BACKGROUND ART

Recent display devices have been expected to be applied to a variety of uses. Usage examples of large-sized display devices include a television device for home use (also referred to as TV or television receiver), digital signage, and a PID (Public Information Display). In addition, a smartphone and a tablet terminal each including a touch panel, and the like, are being developed as portable information terminals.

Furthermore, higher-resolution display devices have been required. As devices requiring high-resolution display devices, for example, devices for virtual reality (VR), augmented reality (AR), substitutional reality (SR), or mixed reality (MR) have been actively developed.

Light-emitting apparatuses including light-emitting elements (also referred to as light-emitting devices) have been developed as display devices, for example. Light-emitting devices (also referred to as EL elements or organic EL elements) utilizing electroluminescence (EL) have features such as ease of reduction in thickness and weight, high-speed response to input signals, and driving with a constant DC voltage power source, and have been used in display devices.

Patent Document 1 discloses a display device using an organic EL element (also referred to as an organic EL device) for VR.

Non-Patent Document 1 discloses a method of manufacturing an organic optoelectronic device using standard UV photolithography.

### References

### Patent Document

[Patent Document 1] PCT International Publication No. 2018/087625

### Non-Patent Document

[Non-Patent Document 1] B. Lamprecht et al., “Organic optoelectronic device fabrication using standard UV photolithography” phys. stat. sol. (RRL) 2, No. 1, pp. 16-18 (2008)

### SUMMARY OF THE INVENTION

### Problems to be Solved by the Invention

An organic EL element can have a structure in which a layer containing an organic compound is interposed between a pair of electrodes, for example. Here, in the case of having a stacked-layer structure of a plurality of layers containing different materials, an electrode might change in quality as a result of, for example, a reaction occurring between the plurality of layers. This degrades the reliability of the display device in some cases.

In view of the above, an object of one embodiment of the present invention is to provide a highly reliable display device. Another object of one embodiment of the present invention is to provide a display device including a light-emitting element with high emission efficiency. Another object of one embodiment of the present invention is to provide a display device having low power consumption. Another object of one embodiment of the present invention is to provide a display device with high light extraction efficiency. Another object of one embodiment of the present invention is to provide an inexpensive display device. Another object of one embodiment of the present invention is to provide a display device with high display quality. Another object of one embodiment of the present invention is to provide a high-resolution display device. Another object of one embodiment of the present invention is to provide a high-definition display device. Another object of one embodiment of the present invention is to provide a novel display device.

Another object of one embodiment of the present invention is to provide a method of manufacturing a display device with high yield. An object of one embodiment of the present invention is to provide a method of manufacturing a highly reliable display device. Another object of one embodiment of the present invention is to provide a method of manufacturing a display device including a light-emitting element with high light extraction efficiency. Another object of one embodiment of the present invention is to provide a method of manufacturing a display device with low power consumption. Another object of one embodiment of the present invention is to provide a method of manufacturing a display device with high light extraction efficiency. An object of one embodiment of the present invention is to provide a method of manufacturing a display device with high display quality. Another object of one embodiment of the present invention is to provide a method of manufacturing a high-resolution display device. Another object of one embodiment of the present invention is to provide a method of manufacturing a high-definition display device. Another object of one embodiment of the present invention is to provide a method of manufacturing a novel display device.

Note that the description of these objects does not preclude the existence of other objects. One embodiment of the present invention does not need to achieve all of these objects. Other objects can be derived from the description of the specification, the drawings, and the claims.

### Means for Solving the Problems

One embodiment of the present invention is a display device including a first light-emitting element, a second light-emitting element adjacent to the first light-emitting element, a first insulating layer provided between the first light-emitting element and the second light-emitting element, and a second insulating layer over the first insulating layer. The first light-emitting element includes a first conductive layer, a second conductive layer covering an upper surface and a side surface of the first conductive layer, a first EL layer over the second conductive layer, and a common electrode over the first EL layer. The second light-emitting element includes a third conductive layer, a fourth conductive layer covering an upper surface and a side surface of the third conductive layer, a second EL layer over the fourth conductive layer, and the common electrode over the second EL layer. The common electrode is provided over the second insulating layer. The visible light reflectance of the first conductive layer is higher than the visible light reflectance of the second conductive layer. The visible light reflectance of the third conductive layer is higher than the visible light reflectance of the fourth conductive layer.

Alternatively, in the above embodiment, the first EL layer may include a first functional layer including a region in contact with the second conductive layer and a first light-emitting layer over the first functional layer. The second EL layer may include a second functional layer including a region in contact with the fourth conductive layer and a second light-emitting layer over the second functional layer.

Alternatively, in the above embodiment, the first functional layer and the second functional layer may include at least one of a hole-injection layer and a hole-transport layer. The work function of the second conductive layer may be higher than the work function of the first conductive layer. The work function of the fourth conductive layer may be higher than the work function of the third conductive layer.

Alternatively, in the above embodiment, the first light-emitting element may include a common layer between the first EL layer and the common electrode. The second light-emitting element may include the common layer between the second EL layer and the common electrode. The common layer may be positioned between the second insulating layer and the common electrode. The common layer may include at least one of an electron-injection layer and an electron-transport layer.

Alternatively, in the above embodiment, the first functional layer and the second functional layer may include at least one of an electron-injection layer and an electron-transport layer. The work function of the second conductive layer may be lower than the work function of the first conductive layer. The work function of the fourth conductive layer may be lower than the work function of the third conductive layer.

Alternatively, in the above embodiment, the first light-emitting element may include a common layer between the first EL layer and the common electrode. The second light-emitting element may include the common layer between the second EL layer and the common electrode. The common layer may be positioned between the second insulating layer and the common electrode. The common layer may include at least one of a hole-injection layer and a hole-transport layer.

Alternatively, in the above embodiment, the second conductive layer and the fourth conductive layer may include any one or more selected from indium, tin, zinc, gallium, titanium, aluminum, and silicon.

Alternatively, in the above embodiment, the first insulating layer may include a region in contact with a side surface of the first EL layer and a side surface of the second EL layer and covers part of an upper surface of the first EL layer and part of an upper surface of the second EL layer. An end portion of the second insulating layer may have a tapered shape with a taper angle less than 90° in a cross-sectional view. The second insulating layer may cover at least part of a side surface of the first insulating layer.

Alternatively, in the above embodiment, an end portion of the first insulating layer may have a tapered shape with a taper angle less than 90° in a cross-sectional view.

Alternatively, in the above embodiment, the first insulating layer may be an inorganic insulating layer and the second insulating layer may be an organic insulating layer.

Alternatively, in the above embodiment, the first insulating layer may include aluminum oxide and the second insulating layer includes an acrylic resin.

A display module including the display device of one embodiment of the present invention and at least one of a connector and an integrated circuit is also one embodiment of the present invention.

An electronic device that includes the above display module and at least one of a housing, a battery, a camera, a speaker, and a microphone is also one embodiment of the present invention.

Another embodiment of the present invention is a method of manufacturing a display device, which includes: forming a first conductive layer: forming a second conductive layer that covers an upper surface and a side surface of the first conductive layer and has lower visible light reflectance than the first conductive layer: forming an EL film over the second conductive layer: forming a mask film over the EL film; and forming an EL layer over the second conductive layer and a mask layer over the EL layer by processing the EL film and the mask film.

Alternatively, in the above embodiment, hydrophobization treatment for the second conductive layer may be performed after the formation of the second conductive layer but before the formation of the EL film.

Alternatively, in the above embodiment, the hydrophobization treatment may be performed by fluorination of the second conductive layer.

Another embodiment of the present invention is a method of manufacturing a display device, which includes: forming a first conductive layer and a second conductive layer: forming a third conductive layer that covers an upper surface and a side surface of the first conductive layer and has lower visible light reflectance than the first conductive layer and a fourth conductive layer that covers an upper surface and a side surface of the second conductive layer and has lower visible light reflectance than the second conductive layer: forming a first EL film over the third conductive layer and over the fourth conductive layer: forming a first mask film over the first EL film: forming a first EL layer over the third conductive layer and a first mask layer over the first EL layer and exposing the fourth conductive layer by processing the first EL film and the first mask film: forming a second EL film over the first mask layer and over the fourth conductive layer: forming a second mask film over the second EL film: forming a second EL layer over the fourth conductive layer and a second mask layer over the second EL layer and exposing the first mask layer by processing the second EL film and the second mask film, forming an insulating film using a photosensitive material over the first mask layer and over the second mask layer: forming an insulating layer between the first EL layer and the second EL layer by processing the insulating film: exposing an upper surface of the first EL layer and an upper surface of the second EL layer by etching treatment using the insulating layer as a mask; and forming a common electrode over the first EL layer, over the second EL layer, and over the insulating layer.

Alternatively, in the above embodiment, hydrophobization treatment for the third conductive layer and the fourth conductive layer may be performed after the formation of the third conductive layer and the fourth conductive layer but before the formation of the first EL film.

Alternatively, in the above embodiment, the hydrophobization treatment may be performed by fluorination of the third conductive layer and the fourth conductive layer.

Alternatively, in the above embodiment, the etching treatment may be performed by wet etching.

### Effect of the Invention

An embodiment of the present invention can provide a highly reliable display device. Another embodiment of the present invention can provide a display device including a light-emitting element with high emission efficiency. Another embodiment of the present invention can provide a display device having low power consumption. Another embodiment of the present invention can provide a display device with high light extraction efficiency. Another embodiment of the present invention can provide an inexpensive display device. Another embodiment of the present invention can provide a display device with high display quality. Another embodiment of the present invention can provide a high-resolution display device. Another embodiment of the present invention can provide a high-definition display device. Another embodiment of the present invention can provide a novel display device.

Another embodiment of the present invention can provide a method of manufacturing a display device with high yield. An embodiment of the present invention can provide a method of manufacturing a highly reliable display device. Another embodiment of the present invention can provide a method of manufacturing a display device including a light-emitting element with high light extraction efficiency. Another embodiment of the present invention can provide a method of manufacturing a display device with low power consumption. Another embodiment of the present invention can provide a method of manufacturing a display device with high light extraction efficiency. An embodiment of the present invention can provide a method of manufacturing a display device with high display quality. Another embodiment of the present invention can provide a method of manufacturing a high-resolution display device. Another embodiment of the present invention can provide a method of manufacturing a high-definition display device. Another embodiment of the present invention can provide a method of manufacturing a novel display device.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1 is a plan view illustrating a structure example of a display device.

FIG. 2A is a cross-sectional view illustrating a structure example of a display device. FIG. 2B1 and FIG. 2B2 are cross-sectional views illustrating structure examples of a pixel electrode.

FIG. 3A and FIG. 3B are cross-sectional views illustrating structure examples of a pixel electrode.

FIG. 4A to FIG. 4C are cross-sectional views illustrating structure examples of a pixel electrode.

FIG. 5A and FIG. 5B are cross-sectional views illustrating a structure example of a display device.

FIG. 6A and FIG. 6B are cross-sectional views illustrating a structure example of a display device.

FIG. 7A and FIG. 7B are cross-sectional views illustrating a structure example of a display device.

FIG. 8A and FIG. 8B are cross-sectional views illustrating a structure example of a display device.

FIG. 9A and FIG. 9B are cross-sectional views illustrating structure examples of a display device.

FIG. 10 is a cross-sectional view illustrating a structure example of a display device.

FIG. 11A and FIG. 11B are cross-sectional views illustrating structure examples of a display device.

FIG. 12A and FIG. 12B are cross-sectional views illustrating structure examples of a display device.

FIG. 13A and FIG. 13B are cross-sectional views illustrating structure examples of a display device.

FIG. 14 is a cross-sectional view illustrating a structure example of a display device.

FIG. 15A and FIG. 15B are cross-sectional views illustrating structure examples of a display device.

FIG. 16A and FIG. 16B are cross-sectional views illustrating structure examples of a display device.

FIG. 17A and FIG. 17B are cross-sectional views illustrating structure examples of a display device.

FIG. 18A to FIG. 18F are cross-sectional views illustrating structure examples of a display device.

FIG. 19A and FIG. 19B are cross-sectional views illustrating a structure example of a display device.

FIG. 20A and FIG. 20B are cross-sectional views illustrating structure examples of a display device.

FIG. 21A and FIG. 21B are cross-sectional views illustrating a structure example of a display device.

FIG. 22A and FIG. 22B are cross-sectional views illustrating structure examples of a display device.

FIG. 23 is a cross-sectional view illustrating a structure example of a display device.

FIG. 24A to FIG. 24D are cross-sectional views illustrating an example of a method of manufacturing a display device.

FIG. 25A to FIG. 25D are cross-sectional views illustrating an example of a method of manufacturing a display device.

FIG. 26A to FIG. 26D are cross-sectional views illustrating an example of a method of manufacturing a display device.

FIG. 27A, FIG. 27B1, and FIG. 27B2 are cross-sectional views illustrating an example of a method of manufacturing a display device.

FIG. 28A and FIG. 28B are cross-sectional views illustrating an example of a method of manufacturing a display device.

FIG. 29A and FIG. 29B are cross-sectional views illustrating an example of a method of manufacturing a display device.

FIG. 30A and FIG. 30B are cross-sectional views illustrating an example of a method of manufacturing a display device.

FIG. 31A and FIG. 31B are cross-sectional views illustrating an example of a method of manufacturing a display device.

FIG. 32A, FIG. 32B, FIG. 32C, FIG. 32D1, and FIG. 32D2 are cross-sectional views illustrating examples of a method of manufacturing a display device.

FIG. 33A to FIG. 33D are cross-sectional views illustrating an example of a method of manufacturing a display device.

FIG. 34A to FIG. 34C are cross-sectional views illustrating an example of a method of manufacturing a display device.

FIG. 35A to FIG. 35C are cross-sectional views illustrating an example of a method of manufacturing a display device.

FIG. 36A to FIG. 36D are cross-sectional views illustrating an example of a method of manufacturing a display device.

FIG. 37A and FIG. 37B are cross-sectional views illustrating an example of a method of manufacturing a display device.

FIG. 38A to FIG. 38D are cross-sectional views illustrating an example of a method of manufacturing a display device.

FIG. 39A to FIG. 39D are cross-sectional views illustrating an example of a method of manufacturing a display device.

FIG. 40A to FIG. 40C are cross-sectional views illustrating an example of a method of manufacturing a display device.

FIG. 41A and FIG. 41B are cross-sectional views illustrating an example of a method of manufacturing a display device.

FIG. 42A and FIG. 42B are cross-sectional views illustrating an example of a method of manufacturing a display device.

FIG. 43A to FIG. 43E are cross-sectional views illustrating an example of a method of manufacturing a display device.

FIG. 44A to FIG. 44D are cross-sectional views illustrating an example of a method of manufacturing a display device.

FIG. 45A to FIG. 45C are cross-sectional views illustrating an example of a method of manufacturing a display device.

FIG. 46A and FIG. 46B are cross-sectional views illustrating structure examples of a display device.

FIG. 47A and FIG. 47B are cross-sectional views illustrating structure examples of a display device.

FIG. 48A to FIG. 48G are plan views illustrating structure examples of pixels.

FIG. 49A to FIG. 49I are plan views illustrating structure examples of pixels.

FIG. 50A and FIG. 50B are perspective views illustrating a structure example of a display module.

FIG. 51A and FIG. 51B are cross-sectional views illustrating structure examples of a display device.

FIG. 52A and FIG. 52B are cross-sectional views illustrating structure examples of a display device.

FIG. 53 is a cross-sectional view illustrating a structure example of a display device.

FIG. 54 is a cross-sectional view illustrating a structure example of a display device.

FIG. 55 is a cross-sectional view illustrating a structure example of a display device.

FIG. 56 is a cross-sectional view illustrating a structure example of a display device.

FIG. 57 is a cross-sectional view illustrating a structure example of a display device.

FIG. 58 is a cross-sectional view illustrating a structure example of a display device.

FIG. 59 is a cross-sectional view illustrating a structure example of a display device.

FIG. 60 is a cross-sectional view illustrating a structure example of a display device.

FIG. 61 is a cross-sectional view illustrating a structure example of a display device.

FIG. 62 is a cross-sectional view illustrating a structure example of a display device.

FIG. 63 is a cross-sectional view illustrating a structure example of a display device.

FIG. 64 is a cross-sectional view illustrating a structure example of a display device.

FIG. 65 is a cross-sectional view illustrating a structure example of a display device.

FIG. 66 is a cross-sectional view illustrating a structure example of a display device.

FIG. 67 is a cross-sectional view illustrating a structure example of a display device.

FIG. 68 is a cross-sectional view illustrating a structure example of a display device.

FIG. 69 is a perspective view illustrating a structure example of a display device.

FIG. 70A is a cross-sectional view of a structure example of a display device. FIG. 70B1 and

FIG. 70B2 are cross-sectional views illustrating structure examples of a display device.

FIG. 71 is a cross-sectional view illustrating a structure example of a display device.

FIG. 72 is a perspective view illustrating a structure example of a display device.

FIG. 73A to FIG. 73B3 are cross-sectional views illustrating structure examples of a display device.

FIG. 74A to FIG. 74B3 are cross-sectional views illustrating structure examples of a display device.

FIG. 75A to FIG. 75C are cross-sectional views illustrating structure examples of a display device.

FIG. 76A to FIG. 76F are cross-sectional views each illustrating structure example of a light-emitting element.

FIG. 77A to FIG. 77C are cross-sectional views each illustrating structure example of a light-emitting element.

FIG. 78A to FIG. 78D are diagrams illustrating examples of electronic devices.

FIG. 79A to FIG. 79F are diagrams illustrating examples of electronic devices.

FIG. 80A to FIG. 80G are diagrams illustrating examples of electronic devices.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same reference numerals are commonly used for the same portions or portions having similar functions in different drawings, and a repeated description thereof is omitted. The same hatching pattern is applied to portions having similar functions, and the portions are not especially denoted by reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in drawings.

Note that the term “film” and the term “layer” can be interchanged with each other depending on the case or circumstances. For example, the term “conductive layer” can be changed into the term “conductive film” in some cases. For example, the term “insulating film” can be changed into the term “insulating layer” in some cases.

In this specification and the like, terms for describing positioning, such as “over,” “under,” “above,” and “below,” are sometimes used for convenience to describe the positional relation between components with reference to drawings. The positional relationship between components is changed as appropriate in accordance with a direction in which each component is described. Thus, the positional relation is not limited to the terms described in this specification and the like, and can be described with another term as appropriate depending on the situation. For example, the expression “an insulating layer positioned over (on) an upper surface of a conductive layer” can be replaced with the expression “an insulating layer positioned under (on) a lower surface of a conductive layer” when the direction of a drawing illustrating these components is rotated by 180°.

In this specification and the like, a device fabricated using a metal mask or an FMM (fine metal mask) is sometimes referred to as a device having an MM (metal mask) structure. In this specification and the like, a device fabricated without using a metal mask or an FMM is sometimes referred to as a device having an MML (metal maskless) structure.

In this specification and the like, a hole or an electron is sometimes referred to as a “carrier.” Specifically, a hole-injection layer or an electron-injection layer may be referred to as a “carrier-injection layer,” a hole-transport layer or an electron-transport layer may be referred to as a “carrier-transport layer,” and a hole-blocking layer or an electron-blocking layer may be referred to as a “carrier-blocking layer.” Note that the above-described carrier-injection layer, carrier-transport layer, and carrier-blocking layer cannot be distinguished from each other on the basis of the cross-sectional shape, properties, or the like in some cases. Furthermore, one layer may have two or three functions of the carrier-injection layer, the carrier-transport layer, and the carrier-blocking layer in some cases.

In this specification and the like, the light-emitting element includes an EL layer between a pair of electrodes. The EL layer includes at least a light-emitting layer. Examples of a layer included in the EL layer include a light-emitting layer, a carrier-injection layer, a carrier-transport layer, and a carrier-blocking layer.

In this specification and the like, the carrier-injection layer refers to one or both of a hole-injection layer and an electron-injection layer. The carrier-transport layer refers to one or both of a hole-transport layer and an electron-transport layer. The carrier-blocking layer refers to one or both of a hole-blocking layer and an electron-blocking layer.

Note that in this specification and the like, a tapered shape refers to a shape such that at least part of a side surface of a component is inclined with respect to a substrate surface. For example, a tapered shape indicates a shape including a region where the angle formed by the inclined side surface and the substrate surface (such an angle is also referred to as a taper angle) is less than 90°. Note that the side surface of the component and the substrate surface are not necessarily completely flat and may be substantially flat with a slight curvature or substantially flat with slight unevenness.

### Embodiment 1

In this embodiment, a display device of one embodiment of the present invention and a manufacturing method thereof are described.

The display device of one embodiment of the present invention is capable of full-color display. For example, EL layers including at least light-emitting layers are separately formed for the respective colors, whereby the display device capable of full-color display can be manufactured. Alternatively, for example, a coloring layer (also referred to as a color filter) is provided over an EL layer that emits white light, whereby the display device capable of full-color display can be manufactured.

A structure where light-emitting layers in light-emitting elements of different colors (e.g., blue (B), green (G), and red (R)) are separately formed or separately patterned is sometimes referred to as an SBS (Side By Side) structure. A light-emitting element capable of emitting white light may be referred to as a white-light-emitting element.

In the case where a display device including a plurality of light-emitting elements emitting light of different colors, the light-emitting layers emitting light of different colors each need to be formed into an island shape. Also in the case where a display device including a white light-emitting element is manufactured, the light-emitting layer is preferably formed into an island shape so that leakage current that would be generated between adjacent light-emitting elements through the light-emitting layer can be reduced.

Note that in this specification and the like, the term island shape refers to a state where two or more layers formed using the same material in the same step are physically separated from each other. For example, the term island-shaped light-emitting layer refers to a state where the light-emitting layer and its adjacent light-emitting layer are physically separated from each other.

For example, an island-shaped light-emitting layer can be formed by a vacuum evaporation method using a metal mask. However, this method causes a deviation from the designed shape and position of an island-shaped light-emitting layer due to various influences such as a low accuracy of the metal mask, positional deviation between the metal mask and a substrate, a warp of the metal mask, and expansion of the outline of a formed film, for example. Consequently, increasing the definition and aperture ratio of a display device is difficult. In addition, the outline of the layer may blur during vapor deposition, whereby the thickness of an end portion may be reduced. That is, the thickness of the island-shaped light-emitting layer may vary from area to area. In the case of manufacturing a display device with a large size, high definition, or high resolution, the manufacturing yield might be reduced because of low dimensional accuracy of the metal mask and deformation due to heat or the like.

In view of this, in manufacturing the display device of one embodiment of the present invention, patterning of light-emitting layers is performed by a photolithography method without a shadow mask such as a metal mask. Specifically, pixel electrodes are formed for the respective subpixels, and then a light-emitting layer is formed across the pixel electrodes. After that, the light-emitting layer is processed by a photolithography method, for example, so that one island-shaped light-emitting layer is formed per pixel electrode. Thus, the light-emitting layer can be divided into island-shaped light-emitting layers for respective subpixels.

In the case of processing the light-emitting layer into an island shape, a structure is possible where processing is performed by a photolithography method directly on the light-emitting layer. In the structure, damage to the light-emitting layer, e.g., processing damage, might significantly degrade the reliability. In view of the above, in manufacturing the display device of one embodiment of the present invention, as the EL layer, in addition to the light-emitting layer, a mask layer or the like is preferably formed over a functional layer positioned above the light-emitting layer, such as a carrier-blocking layer, a carrier-transport layer, or a carrier-injection layer, or more specifically, a hole-blocking layer, an electron-transport layer, or an electron-injection layer, or the like, followed by the processing of the light-emitting layer and the functional layer into an island shape. Such a method can provide a highly reliable display device. The functional layer between the light-emitting layer and the mask layer can inhibit the light-emitting layer from being exposed on the outermost surface during the manufacturing process of the display device and can reduce damage to the light-emitting layer.

In this specification and the like, a mask film and a mask layer refer to, respectively, a film and a layer that are positioned above at least the light-emitting layer, specifically, a layer processed into an island shape among the layers included in the EL layer, and have a function of protecting the light-emitting layer in the manufacturing process. The mask film can be referred to as a sacrificial film or a protective film, and the mask layer can also be referred to as a sacrificial layer or a protective layer.

The EL layer can include a functional layer below as well as above the light-emitting layer. In the case where the above light-emitting layer is processed into an island shape, a layer positioned below the light-emitting layer (e.g., a carrier-injection layer, a carrier-transport layer, or a carrier-blocking layer, and specifically, a hole-injection layer, a hole-transport layer, or an electron-blocking layer) is preferably processed into an island shape with the same pattern as the light-emitting layer. When the layer positioned below the light-emitting layer is processed into an island shape with the same pattern as the light-emitting layer, a leakage current that would be generated between adjacent subpixels (sometimes referred to as a horizontal-direction leakage current, a horizontal leakage current, or a lateral leakage current) can be reduced. For example, in the case where a hole-injection layer is shared by adjacent subpixels, a horizontal leakage current would be generated because of the hole-injection layer. In the display device of one embodiment of the present invention, the hole-injection layer can be processed into an island shape with the same pattern as the light-emitting layer: hence, a horizontal leakage current between adjacent subpixels is not substantially generated or a horizontal leakage current can be extremely small.

Here, the EL layer is preferably provided to cover an upper surface and a side surface of a pixel electrode. Such a structure can easily increase the aperture ratio compared with the structure in which an end portion of the island-shaped EL layer is positioned on the inner side of an end portion of the pixel electrode.

The pixel electrode preferably has a stacked-layer structure of a plurality of layers containing different materials. For example, in the case where the display device has a top-emission structure and the pixel electrode has a stacked-layer structure of two layers, the first conductive layer and the second conductive layer over the first conductive layer, the first conductive layer can be a layer having higher visible light reflectance than the second conductive layer. In the case where a functional layer positioned below the light-emitting layer includes at least one of a hole-injection layer and a hole-transport layer, for example, and the second conductive layer is in contact with the functional layer, the second conductive layer can be a layer that has a higher work function than the first conductive layer. That is, in the case where the pixel electrode functions as an anode, the second conductive layer can be a layer that has a higher work function than the first conductive layer. Thus, the light-emitting element can have high light extraction efficiency and low driving voltage.

In this specification and the like, visible light refers to light at a wavelength longer than or equal to 400 nm and shorter than 750 nm. The visible light reflectance refers to the reflectance with respect to the light in a predetermined range of wavelengths longer than or equal to 400 nm and shorter than 750 nm. For example, the visible light reflectance may refer to the average or maximum reflectance with respect to the light at all the wavelengths longer than or equal to 400 nm and shorter than 750 nm. The visible light reflectance may refer to the reflectance with respect to light at a specific wavelength that is longer than or equal to 400 nm and shorter than 750 nm.

By contrast, in the case of having a stacked-layer structure of a plurality of layers using different materials, the pixel electrode might change in quality as a result of a reaction occurring between the plurality of layers, for example. In a method of manufacturing the display device of one embodiment of the present invention, for example, in the case where a film formed after formation of the pixel electrode is removed by a wet etching method, a chemical solution sometimes comes into contact with the pixel electrode. The contact of the plurality of layers with the chemical solution might cause galvanic corrosion in the case of the pixel electrode having a stacked-layer structure of the plurality of layers. As a result, at least one layer included in the pixel electrode sometimes changes in quality. This might decrease the yield of the display device and might degrade the reliability of the display device.

In view of the above, in one embodiment of the present invention, the second conductive layer is formed to cover an upper surface and a side surface of the first conductive layer. This can inhibit the chemical solution from coming into contact with the first conductive layer even in the case where a film that is formed after formation of the pixel electrode including the first conductive layer and the second conductive layer is removed by a wet etching method, for example. Accordingly, the occurrence of galvanic corrosion in the pixel electrode can be inhibited, for example. As described above, the display device of one embodiment of the present invention can be manufactured by a high-yield method. In addition, generation of a defect in the display device of one embodiment of the present invention can be inhibited, which makes the display device highly reliable.

Note that it is not necessary to form all layers included in EL layers separately between light-emitting elements that emit light of different colors, and some layers of the EL layers can be formed in the same step. In the method of manufacturing a display device of one embodiment of the present invention, after some layers included in the EL layers are formed into an island shape separately for the respective colors, the mask layer is removed at least partly, and then the other layers (also referred to as a common layer in some cases) included in the EL layers and a common electrode (also referred to as an upper electrode) are formed so as to be shared by the light-emitting elements of different colors, i.e., formed as a single film. For example, a carrier-injection layer and the common electrode can be formed so as to be shared by the light-emitting elements of different colors.

Meanwhile, the carrier-injection layer is often a layer having relatively high conductivity in the EL layer. Accordingly, when the carrier-injection layer is in contact with a side surface of any layer of the EL layers formed into an island shape or a side surface of the pixel electrode, the light-emitting element might be short-circuited. Note that also in the case where the carrier-injection layer is formed into an island shape and the common electrode is formed to be shared by the light-emitting elements of the different colors, the contact between the common electrode and the side surface of the EL layer or the side surface of the pixel electrode might cause the light-emitting element to be short-circuited.

Thus, the display device of one embodiment of the present invention includes an insulating layer covering at least a side surface of the island-shaped light-emitting layer. The insulating layer preferably covers part of an upper surface of the island-shaped light-emitting layer.

Accordingly, the contact of the carrier-injection layer and the common electrode with at least some layer of the island-shaped EL layers and the pixel electrode can be inhibited. Thus, a short circuit in the light-emitting element can be inhibited, leading to an increase in the reliability of the light-emitting element.

In a cross-sectional view; an end portion of the insulating layer preferably has a tapered shape with a taper angle less than 90°. Thus, step disconnection of the common layer and the common electrode provided over the insulating layer can be inhibited. This can inhibit a connection defect due to the step disconnection. In addition, local thinning of the common electrode due to a step can be inhibited from increasing electrical resistance.

In this specification and the like, step disconnection refers to a phenomenon in which a layer, a film, or an electrode is split because of the shape of the formation surface such as a step or a phenomenon in which a locally thinned portion is formed.

As described above, in the method of manufacturing a display device of one embodiment of the present invention, the island-shaped light-emitting layers are formed not by using a fine metal mask but by processing a light-emitting layer formed over the entire surface. Accordingly, a high-resolution display device or a display device with a high aperture ratio, which has been difficult to achieve, can be achieved. Moreover, light-emitting layers can be formed separately for each color, enabling the display device to perform extremely clear display with high contrast and high display quality. In addition, a mask layer provided over a light-emitting layer can reduce damage to the light-emitting layer in the manufacturing process of the display device, increasing the reliability of the light-emitting element.

A formation method using a fine metal mask, for example, does not easily shorten the distance between adjacent light-emitting elements to less than 10 μm: meanwhile, the method employing a photolithography method according to one embodiment of the present invention can shorten the distance between adjacent light-emitting elements, the distance between adjacent EL layers, or the distance between adjacent pixel electrodes to less than 10 μm, 5 μm or less, 3 μm or less, 2 μm or less, 1.5 μm or less, 1 μm or less, or even 0.5 μm or less in a process over a glass substrate. Using a light exposure apparatus for LSI can further shorten the distance between adjacent light-emitting elements, the distance between adjacent EL layers, or the distance between adjacent pixel electrodes to 500 nm or less, 200 nm or less, 100 nm or less, or even 50 nm or less, for example, in a process over a silicon wafer. Accordingly, the area of a non-light-emitting region that may exist between two light-emitting elements can be significantly reduced, and the aperture ratio can be close to 100%. For example, the display device of one embodiment of the present invention can achieve an aperture ratio higher than or equal to 40%, higher than or equal to 50%, higher than or equal to 60%, higher than or equal to 70%, higher than or equal to 80%, or higher than or equal to 90% and lower than 100%.

Increasing the aperture ratio of the display device can improve the reliability of the display device. Specifically, with reference to the lifetime of a display device including an organic EL element and having an aperture ratio of 10%, a display device having an aperture ratio of 20% (i.e., having an aperture ratio two times the reference) has a lifetime approximately 3.25 times the reference, and a display device having an aperture ratio of 40% (i.e., having an aperture ratio four times the reference) has a lifetime approximately 10.6 times the reference. Thus, the density of current flowing to the organic EL element can be reduced with the increasing aperture ratio, and accordingly the lifetime of the display device can be increased. The display device of one embodiment of the present invention can have a higher aperture ratio and thus can have higher display quality. Furthermore, the display device has excellent effect that the reliability (especially the lifetime) can be significantly improved with increasing aperture ratio.

In addition, a pattern of the light-emitting layer itself can be made much smaller than that in the case of using a fine metal mask. For example, in the case of using a metal mask for forming light-emitting layers separately, the thickness varies between the center and the edge of the pattern, which causes a reduction in an effective area that can be used for a light-emitting region with respect to the entire pattern area. By contrast, according to the above manufacturing method, a film formed to a uniform thickness is processed and accordingly island-shaped light-emitting layers can be formed to a uniform thickness: thus, even with a fine pattern, almost the entire area can be used as a light-emitting region. Consequently, a display device having both a high resolution and a high aperture ratio can be manufactured. Furthermore, the display device can be reduced in size and weight.

Specifically, for example, the display device of one embodiment of the present invention can have a definition higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

### Structure Example 1

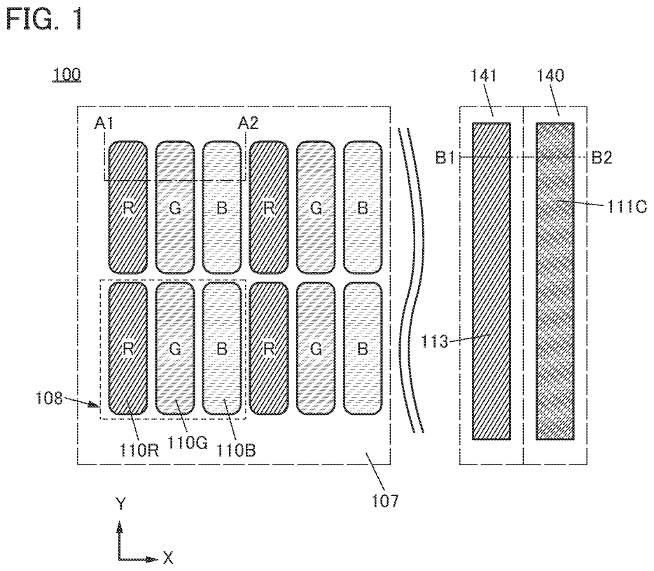

FIG. 1 is a plan view illustrating a structure example of a display device 100. The display device 100 includes a pixel portion 107 in which a plurality of pixels 108 are arranged in a matrix. The pixel 108 includes a subpixel 110R, a subpixel 110G, and a subpixel 110B. FIG. 1 illustrates subpixels 110 arranged in two rows and six columns, which form pixels 108 in two rows and two columns.

In this specification and the like, for example, matters common to the subpixel 110R, the subpixel 110G, and the subpixel 110B are sometimes described using the collective term “subpixel 110.” In the same manner, in the description common to other components that are distinguished by alphabets, reference numerals without alphabets are sometimes used.

The subpixel 110R emits red light, the subpixel 110G emits green light, and the subpixel 110B emits blue light. Accordingly, an image can be displayed on the pixel portion 107. Thus, the pixel portion 107 can be referred to as a display portion. Note that in this embodiment, subpixels of three colors of red (R), green (G), and blue (B) are given as examples: however, subpixels of three colors of yellow (Y), cyan (C), and magenta (M) may be used, for example. The number of kinds of subpixels is not limited to three, and four or more kinds of subpixels may be used. The four subpixels can be of four colors of R, G, B, and white (W), of four colors of R, G, B, and Y, or of four colors of R, G, B, and infrared light (IR), for example.

It also can be said that stripe arrangement is employed for the pixels 108 illustrated in FIG. 1. Note that the arrangement method that can be employed for the pixels 108 is not limited thereto: another arrangement method such as stripe arrangement, S stripe arrangement, delta arrangement, Bayer arrangement, or zigzag arrangement may be used, or PenTile arrangement, diamond arrangement, or the like can be used.

In this specification and the like, the row direction is referred to as X direction and the column direction is referred to as Y direction in some cases. The X direction and the Y direction intersect with each other and are perpendicular to each other, for example.

FIG. 1 illustrates an example where subpixels of different colors are arranged in the X direction and subpixels of the same color are arranged in the Y direction. Note that subpixels of different colors may be arranged in the Y direction, and subpixels of the same color may be arranged in the X direction.

A region 141 and a connection portion 140 are provided outside the pixel portion 107, and the region 141 is positioned between the pixel portion 107 and the connection portion 140. An EL layer 113 is provided in the region 141. A conductive layer 111C is provided in the connection portion 140.

Although FIG. 1 illustrates an example where the region 141 and the connection portion 140 are positioned on the right side of the pixel portion 107 in the plan view, the position of the region 141 and the connection portion 140 is not particularly limited. The region 141 and the connection portion 140 are provided on at least one of the upper side, the right side, the left side, and the lower side of the pixel portion 107 in the plan view, and may be provided to surround the four sides of the pixel portion 107. The top surface shapes of the region 141 and the connection portion 140 can be a belt-like shape, an L shape, a U shape, a frame-like shape, or the like. In addition, the numbers of the regions 141 and the connection portions 140 can be one or more.

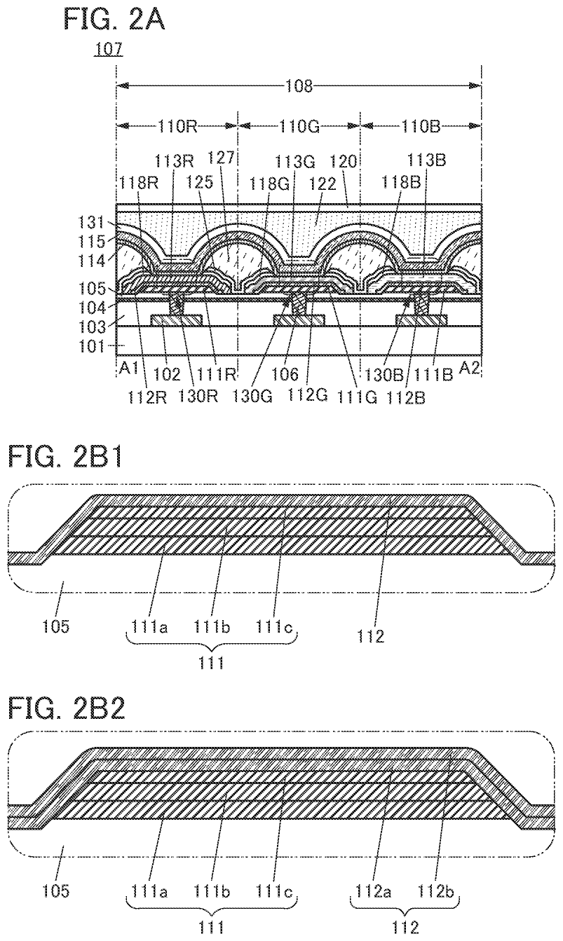

FIG. 2A is a cross-sectional view along the dashed-dotted line A1-A2 in FIG. 1 and illustrates a structure example of the pixel 108 provided in the pixel portion 107. As illustrated in FIG. 2A, the display device 100 includes an insulating layer 101, a conductive layer 102 over the insulating layer 101, an insulating layer 103 over the insulating layer 101 and over the conductive layer 102, an insulating layer 104 over the insulating layer 103, and an insulating layer 105 over the insulating layer 104. The insulating layer 101 is provided over a substrate (not illustrated). An opening reaching the conductive layer 102 is provided in the insulating layer 105, the insulating layer 104, and the insulating layer 103, and a plug 106 is provided so as to fill the opening.

In the pixel portion 107, a light-emitting element 130 is provided over the insulating layer 105 and over the plug 106. A protective layer 131 is provided to cover the light-emitting element 130. The substrate 120 is bonded to the protective layer 131 with the resin layer 122. In a region between adjacent light-emitting elements 130, an insulating layer 125 and an insulating layer 127 over the insulating layer 125 are provided.

Although FIG. 2A illustrates a plurality of cross sections of the insulating layer 125 and the insulating layer 127, the insulating layer 125 and the insulating layer 127 are each a continuous layer in the plan view of the display device 100. In other words, the display device 100 can have a structure including one insulating layer 125 and one insulating layer 127, for example. Note that the display device 100 may include a plurality of insulating layers 125 which are separated from each other and a plurality of insulating layers 127 which are separated from each other.

In FIG. 2A, a light-emitting element 130R, a light-emitting element 130G, and a light-emitting element 130B are shown as the light-emitting element 130. The light-emitting element 130R, the light-emitting element 130G, and the light-emitting element 130B emit light of different colors. For example, the light-emitting element 130R can emit red light, the light-emitting element 130G can emit green light, and the light-emitting element 130B can emit blue light. The light-emitting element 130R, the light-emitting element 130G, or the light-emitting element 130B may emit light of cyan, magenta, yellow, or white or light such as infrared light.

The display device of one embodiment of the present invention is a top-emission display device where light is emitted in the direction opposite to a substrate over which the light-emitting elements are formed.

As the light-emitting element 130, an OLED (Organic Light Emitting Diode) or a QLED (Quantum-dot Light Emitting Diode) is preferably used, for example. Examples of a light-emitting substance contained in the light-emitting element 130 include a substance exhibiting fluorescence (a fluorescent material), a substance exhibiting phosphorescence (a phosphorescent material), an inorganic compound (e.g., a quantum dot material), and a substance exhibiting thermally activated delayed fluorescence (a TADF material). An LED such as a micro-LED (Light Emitting Diode) can be used as the light-emitting element 130.

The light-emitting element 130R includes a conductive layer 111R over the plug 106 and the insulating layer 105, a conductive layer 112R covering the upper surface and the side surface of the conductive layer 111R, an EL layer 113R covering the upper surface and the side surface of the conductive layer 112R, a common layer 114 over the EL layer 113R, and a common electrode 115 over the common layer 114. Here, the conductive layer 111R and the conductive layer 112R form a pixel electrode of the light-emitting element 130R. Note that in the light-emitting element 130R, the EL layer 113R and the common layer 114 can be collectively referred to as an EL layer.

The light-emitting element 130G includes a conductive layer 111G over the plug 106 and the insulating layer 105, a conductive layer 112G covering the upper surface and the side surface of the conductive layer 111G, an EL layer 113G covering the upper surface and the side surface of the conductive layer 112G, the common layer 114 over the EL layer 113G, and the common electrode 115 over the common layer 114. Here, the conductive layer 111G and the conductive layer 112G form a pixel electrode of the light-emitting element 130G. Note that in the light-emitting element 130G, the EL layer 113G and the common layer 114 can be collectively referred to as an EL layer.

The light-emitting element 130B includes a conductive layer 111B over the plug 106 and the insulating layer 105, a conductive layer 112B covering the upper surface and the side surface of the conductive layer 111B, an EL layer 113B covering the upper surface and the side surface of the conductive layer 112B, the common layer 114 over the EL layer 113B, and the common electrode 115 over the common layer 114. Here, the conductive layer 111B and the conductive layer 112B form a pixel electrode of the light-emitting element 130B. Note that in the light-emitting element 130B, the EL layer 113B and the common layer 114 can be collectively referred to as an EL layer.

One of the pixel electrode and the common electrode of the light-emitting element functions as an anode, and the other thereof functions as a cathode. Hereinafter, the pixel electrode may function as the anode and the common electrode may function as the cathode unless otherwise specified.

Each of the EL layer 113R, the EL layer 113G, and the EL layer 113B includes at least a light-emitting layer. For example, the EL layer 113R, the EL layer 113G, and the EL layer 113B can respectively include a light-emitting layer that emits red light, a light-emitting layer that emits green light, and a light-emitting layer that emits blue light. The EL layer 113R, the EL layer 113G, or the EL layer 113B may emit cyan light, magenta light, yellow light, white light, infrared light, or the like.

The EL layer 113R, the EL layer 113G, and the EL layer 113B are separated from each other. Providing the island-shaped EL layer 113 in each of the light-emitting elements 130 can inhibit a leakage current between the adjacent light-emitting elements 130. This can inhibit crosstalk due to unintended light emission, so that the display device can achieve extremely high contrast. The display device can achieve high current efficiency at low luminance, in particular.

The island-shaped EL layer 113 can be formed by forming an EL film and processing the EL film by a photolithography method, for example. For example, the EL layer 113R can be formed by forming and processing an EL film to be the EL layer 113R, the EL layer 113G can be formed by forming and processing an EL film to be the EL layer 113G, and the EL layer 113B can be formed by forming and processing an EL film to be the EL layer 113B.

The EL layer 113 is provided to cover an upper surface and a side surface of the pixel electrode of the light-emitting element 130. In this structure, the aperture ratio of the display device 100 can be easily increased as compared to the structure where an end portion of the EL layer 113 is positioned more inside than the end portion of the pixel electrode. Covering the side surface of the pixel electrode of the light-emitting element 130 with the EL layer 113 inhibits contact between the pixel electrode and the common electrode 115, thereby inhibiting a short circuit in the light-emitting element 130. Furthermore, the distance between the end portion of the EL layer 113 and the light-emitting region in the EL layer 113, i.e., the region overlapping with the pixel electrode, the EL layer 113, and the common electrode 115, can be increased. Since the end portion of the EL layer 113 might be damaged by processing, the use of a region away from the end portion of the EL layer 113 as the light-emitting region can improve the reliability of the light-emitting element 130 in some cases.

In the display device of one embodiment of the present invention, the pixel electrode of the light-emitting element has a stacked-layer structure of a plurality of layers. For example, in the example illustrated in FIG. 2A, the pixel electrode of the light-emitting element 130 is a stack of the conductive layer 111 and the conductive layer 112. In the case where the display device 100 has a top-emission structure and the pixel electrode of the light-emitting element 130 functions as an anode, for example, the conductive layer 111 can have higher visible light reflectance than the conductive layer 112, and the conductive layer 112 can have a higher work function than the conductive layer 111. As the pixel electrode has higher visible light reflectance, for example, transmission of light emitted from the EL layer 113 through the pixel electrode can be more inhibited, which leads to the increased efficiency of extraction of the light emitted from the EL layer 113 in the case of the display device 100 having a top-emission structure. Moreover, as the pixel electrode has a higher work function, hole injection into the EL layer 113 is easier and accordingly the driving voltage of the light-emitting element can be lower in the case where the pixel electrode functions as an anode. Thus, when the pixel electrode of the light-emitting element 130 has a stacked-layer structure of the conductive layer 111 with high visible light reflectance and the conductive layer 112 with a high work function, the light-emitting element 130 can have high light extraction efficiency and a low driving voltage.

In the case where the conductive layer 111 has higher visible light reflectance than the conductive layer 112, the visible light reflectance of the conductive layer 111 is preferably higher than or equal to 40% and lower than or equal to 100%, further preferably higher than or equal to 70% and lower than or equal to 100%, for example. The conductive layer 112 can be an electrode having a property of transmitting visible light (also referred to as a transparent electrode).

In this specification and the like, a transparent electrode refers to an electrode whose transmittance to visible light is higher than or equal to 40%.

The conductive layer 111 of the light-emitting element 130 has high reflectance with respect to the light emitted from the EL layer 113. For example, in the case where the EL layer 113 emits infrared light, the conductive layer 111 can have high reflectance with respect to infrared light. In the case where the pixel electrode of the light-emitting element 130 functions as a cathode, the conductive layer 112 preferably has a lower work function than the conductive layer 111, for example.

By contrast, in the case of having a stacked-layer structure of a plurality of layers, the pixel electrode might change in quality as a result of a reaction occurring between the plurality of layers, for example. In the manufacture of the display device 100, for example, in the case where a film formed after formation of the pixel electrode is removed by a wet etching method, a chemical solution sometimes comes into contact with the pixel electrode, although the details are described later. The contact of the plurality of layers with the chemical solution might cause galvanic corrosion in the case of the pixel electrode having a stacked-layer structure of the plurality of layers. As a result, at least one layer included in the pixel electrode sometimes changes in quality. This might decrease the yield of the display device and might degrade the reliability of the display device.

In view of the above, the conductive layer 112 is formed to cover the upper surface and the side surface of the conductive layer 111 in the display device 100. This can inhibit the chemical solution from coming into contact with the conductive layer 111 even in the case where a film that is formed after formation of the pixel electrode including the conductive layer 111 and the conductive layer 112 is removed by a wet etching method, for example. Accordingly, the occurrence of galvanic corrosion in the pixel electrode can be inhibited, for example. As described above, the display device 100 can be manufactured by a high-yield method. In addition, generation of a defect in the display device 100 can be inhibited, which makes the display device 100 highly reliable.

A metal material can be used for the conductive layer 111, for example. For example, a metal such as aluminum (Al), magnesium (Mg), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals can be used. As an alloy material, for example, an alloy containing aluminum (an aluminum alloy), such as an alloy of aluminum, nickel, and lanthanum (Al—Ni—La) or an alloy containing silver, such as an alloy of silver and magnesium and an alloy of silver, palladium, and copper (also referred to as Ag—Pd—Cu or APC) can be used.

For the conductive layer 112, an oxide containing one or more selected from indium, tin, zinc, gallium, titanium, aluminum, and silicon can be used. For example, it is preferable to use a conductive oxide containing one or more of indium oxide, indium tin oxide, indium zinc oxide, zinc oxide, zinc oxide containing gallium, titanium oxide, indium titanium oxide, zinc titanate, aluminum zinc oxide, indium zinc oxide containing gallium, indium zinc oxide containing aluminum, indium tin oxide containing silicon, indium zinc oxide containing silicon, and the like. In particular, in the case where the pixel electrode functions as an anode, indium tin oxide containing silicon can be suitably used for the conductive layer 112 because of having a high work function, for example, a work function higher than or equal to 4.0 eV.

The conductive layer 111 may have a stacked-layer structure of a plurality of layers containing different materials and the conductive layer 112 may have a stacked-layer structure of a plurality of layers containing different materials, though the details are described later. In that case, the conductive layer 111 may include a layer formed using a material that can be used for the conductive layer 112, such as a conductive oxide. The conductive layer 112 may include a layer formed using a material that can be used for the conductive layer 111, such as a metal material. In the case where the conductive layer 112 has a stacked-layer structure of two or more layers, for example, a layer in contact with the conductive layer 111 can be formed using a material that can be used for the conductive layer 111, such as a metal material.

An end portion of the conductive layer 111 preferably has a tapered shape. Specifically, the end portion of the conductive layer 111 preferably has a tapered shape with a taper angle less than 90°. In that case, the conductive layer 112 provided along the side surface of the conductive layer 111 also has a tapered shape. Accordingly, the EL layer 113 provided along the side surface of the conductive layer 112 also has a tapered shape. When the side surface of the conductive layer 112 has a tapered shape, coverage with the EL layer 113 provided along the side surface of the conductive layer 112 can be improved.

In FIG. 2A, an insulating layer (also referred to as a bank or a structure body) that covers an upper end portion of the conductive layer 112R is not provided between the conductive layer 112R and the EL layer 113R. An insulating layer that covers an upper end portion of the conductive layer 112G is not provided between the conductive layer 112G and the EL layer 113G. An insulating layer that covers an upper end portion of the conductive layer 112B is not provided between the conductive layer 112B and the EL layer 113B. Thus, the distance between adjacent light-emitting elements 130 can be extremely small. Accordingly, the display device can have high resolution or high definition. In addition, a mask for forming the insulating layer is not needed, which leads to a reduction in manufacturing cost of the display device.

Furthermore, light emitted from the EL layer 113 can be extracted efficiently with the structure where an insulating layer covering the end portion of the conductive layer 112 is not provided between the conductive layer 112 and the EL layer 113. Therefore, the display device 100 can significantly reduce the viewing angle dependence. A reduction in the viewing angle dependence leads to an increase in visibility of an image on the display device 100. For example, in the display device 100, the viewing angle (the maximum angle with a certain contrast ratio maintained when the screen is seen from an oblique direction) can be greater than or equal to 100° and less than 180°, preferably greater than or equal to 150° and less than or equal to 170°. Note that the above viewing angle refers to that in both the vertical direction and the horizontal direction.

The insulating layer 101, the insulating layer 103, and the insulating layer 105 function as interlayer insulating layers. As the insulating layer 101, the insulating layer 103, and the insulating layer 105, a variety of inorganic insulating films such as an oxide insulating film, a nitride insulating film, an oxynitride insulating film, and a nitride oxide insulating film can be suitably used: specifically, a silicon oxide film, a silicon oxynitride film, an aluminum oxide film, a silicon nitride film, or a silicon nitride oxide film can be used, for example.

Note that in this specification and the like, oxynitride refers to a material that contains more oxygen than nitrogen, and nitride oxide refers to a material that contains more nitrogen than oxygen. For example, in the case where silicon oxynitride is described, it refers to a material that contains more oxygen than nitrogen in its composition. In the case where silicon nitride oxide is described, it refers to a material that contains more nitrogen than oxygen in its composition.

The insulating layer 104 functions as a barrier layer that inhibits entry of impurities such as water into, for example, the light-emitting element 130. As the insulating layer 104, it is possible to use, for example, a film in which hydrogen or oxygen is less likely to be diffused than in a silicon oxide film, such as a silicon nitride film, an aluminum oxide film, or a hafnium oxide film.

Specifically, the thickness of the insulating layer 105 in a region not overlapping with the conductive layer 111 is sometimes smaller than that of the insulating layer 105 in a region overlapping with the conductive layer 111. That is, the insulating layer 105 may have a depressed portion in the region that does not overlap with the conductive layer 111. The depressed portion is formed because of the step of forming the conductive layer 111, for example.

The conductive layer 102 functions as a wiring. The conductive layer 102 is electrically connected to the light-emitting element 130 through the plug 106.

For the conductive layer 102 and the plug 106, it is possible to use a variety of conductive materials, for example, a metal such as aluminum (Al), magnesium (Mg), titanium (Ti), chromium (Cr), nickel (Ni), copper (Cu), yttrium (Y), zirconium (Zr), tin (Sn), zinc (Zn), silver (Ag), platinum (Pt), gold (Au), molybdenum (Mo), tantalum (Ta), or tungsten (W) or an alloy containing the metal as its main component (e.g., APC). For the conductive layer 102 and the plug 106, an oxide such as tin oxide or zinc oxide may be used.

For the light-emitting element 130, a single structure (a structure including only one light-emitting unit) can be employed.

As described above, each of the EL layer 113R, the EL layer 113G, and the EL layer 113B includes at least a light-emitting layer. For example, the EL layer 113R, the EL layer 113G, and the EL layer 113B can respectively include a light-emitting layer that emits red light, a light-emitting layer that emits green light, and a light-emitting layer that emits blue light.

The EL layer 113R, the EL layer 113G, and the EL layer 113B may each include one or more of a hole-injection layer, a hole-transport layer, a hole-blocking layer, a charge-generation layer (also referred to as an intermediate layer), an electron-blocking layer, an electron-transport layer, and an electron-injection layer.

In this specification and the like, a functional layer refers to a layer that is included in the EL layer and is other than the light-emitting layer.

In the case where the pixel electrode of the light-emitting element 130 functions as an anode and the common electrode 115 functions as a cathode, for example, the EL layer 113R, the EL layer 113G, and the EL layer 113B may each include a hole-injection layer, a hole-transport layer, a light-emitting layer, and an electron-transport layer in this order. In other words, the EL layer 113 can have a structure in which, for example, a first functional layer including a hole-injection layer and a hole-transport layer, a light-emitting layer, and a second functional layer including an electron-transport layer are stacked in order from the bottom. The EL layer 113 may include an electron-blocking layer between the hole-transport layer and the light-emitting layer. The EL layer 113 may include a hole-blocking layer between the electron-transport layer and the light-emitting layer. The EL layer 113 may include an electron-injection layer over the electron-transport layer. Note that the first functional layer may be configured to include one of the hole-injection layer and the hole-transport layer and not to include the other. The second functional layer may include the electron-injection layer and does not necessarily include the electron-transport layer.

In the case where the pixel electrode of the light-emitting element 130 functions as a cathode and the common electrode 115 functions as an anode, for example, the EL layer 113R, the EL layer 113G, and the EL layer 113B may each include an electron-injection layer, an electron-transport layer, a light-emitting layer, and a hole-transport layer in this order. In other words, the EL layer 113 can have a structure in which, for example, a first functional layer including an electron-injection layer and an electron-transport layer, a light-emitting layer, and a second functional layer including a hole-transport layer are stacked in order from the bottom. The EL layer 113 may include a hole-blocking layer between the electron-transport layer and the light-emitting layer. The EL layer 113 may include an electron-blocking layer between the hole-transport layer and the light-emitting layer. The EL layer 113 may include a hole-injection layer over the hole-transport layer. Note that the first functional layer may be configured to include one of the electron-injection layer and the electron-transport layer and not to include the other. The second functional layer may include the hole-injection layer and does not necessarily include the hole-transport layer.

As described above, the EL layer 113R, the EL layer 113G, and the EL layer 113B each preferably include a light-emitting layer and a carrier-transport layer over the light-emitting layer. The EL layer 113R, the EL layer 113G, and the EL layer 113B each preferably include a light-emitting layer and a carrier-blocking layer over the light-emitting layer. Alternatively, the EL layer 113R, the EL layer 113G, and the EL layer 113B each preferably include a light-emitting layer, a carrier-blocking layer over the light-emitting layer, and a carrier-transport layer over the carrier-blocking layer. Since the surfaces of the EL layer 113R, the EL layer 113G, and the EL layer 113B are exposed in the manufacturing process of the display device, providing one or both of the carrier-transport layer and the carrier-blocking layer over the light-emitting layer inhibits the light-emitting layer from being exposed on the outermost surface, so that damage to the light-emitting layer can be reduced. As a result, the reliability of the light-emitting element can be increased.

The upper temperature limit of the compounds included in the EL layer 113R, the EL layer 113G, and the EL layer 113B is preferably higher than or equal to 100° C., and lower than or equal to 180° C., further preferably higher than or equal to 120° C., and lower than or equal to 180° C., still further preferably higher than or equal to 140° C., and lower than or equal to 180° C. For example, the glass transition temperature (Tg) of these compounds is preferably higher than or equal to 100° C., and lower than or equal to 180° C., further preferably higher than or equal to 120° C., and lower than or equal to 180° C., still further preferably higher than or equal to 140° C., and lower than or equal to 180° C.

In particular, the upper temperature limit of the functional layer provided over the light-emitting layer is preferably high. It is further preferable that the upper temperature limit of the functional layer provided on and in contact with the light-emitting layer be high. When such a functional layer has high heat resistance, the light-emitting layer can be effectively protected, resulting in less damage to the light-emitting layer.

The functional layer provided over the light-emitting layer preferably contains an organic compound that includes a heteroaromatic ring skeleton including one selected from a pyridine ring, a diazine ring, and a triazine ring and a bicarbazole skeleton or an organic compound that includes a fused heteroaromatic ring skeleton including a pyridine ring or a diazine ring and a bicarbazole skeleton, and the organic compound preferably has Tg higher than or equal to 100° C., and lower than or equal to 180° C., preferably higher than or equal to 120° C., and lower than or equal to 180° C., further preferably higher than or equal to 140° C., and lower than or equal to 180° C. The functional layer using such an organic compound can have one or both of a function of a hole-blocking layer and a function of an electron-transport layer. Note that the functional layer using such an organic compound is not necessarily positioned above (on the upper electrode side) of the light-emitting layer and may be provided below the light-emitting layer (on the lower electrode side).

Specific examples of the organic compound include 2-{3-[3-(9-phenyl-9H-carbazol-3-yl)-9H-carbazol-9-yl]phenyl}dibenzo[f,h]quinoxaline (abbreviation: 2mPCCzPDBq), 2-{3-[2-(9-phenyl-9H-carbazol-3-yl)-9H-carbazol-9-yl]phenyl}dibenzo[f.h]quinoxaline (abbreviation: 2mPCCzPDBq-02), 9-[3-(4,6-diphenyl-1,3,5-triazin-2-yl)phenyl]-9′-phenyl-3,3′-bi-9H-carbazole (abbreviation: mPCCzPT/n), 9-[3-(4,6-diphenyl-1,3,5-triazin-2-yl)phenyl]-9′-phenyl-2,3′-bi-9H-carbazole (abbreviation: mPCC/PTzn-02), 9-[4-(4,6-diphenyl-1,3,5-triazin-2-yl)phenyl]-9)′-phenyl-3,3′-bi-9H-carbazole (abbreviation: PCCzPTzn), 9-(4,6-diphenyl-1,3,5-triazin-2-yl)-9′-phenyl-3,3′-bi-9H-carbazole (abbreviation: PCCzTzn), 9-13-(4,6-diphenyl-pyrimidin-2-yl)phenyl]-9′-phenyl-3,3′-bi-9H-carbazole (abbreviation: 2PCCzPPm), 9-(4,6-diphenyl-pyrimidin-2-yl)-9′-phenyl-2,3′-bi-9H-carbazole (abbreviation: 2PCCzPm), 9-(4,6-diphenylpirimidin-2-yl)-9′-phenyl-3,3′-bi-9H-carbazole (abbreviation: 2PCCzPm-02), 4-(9′-phenyl[2,3′-bi-9H-carbazol]-9-yl) benzofuro]3,2-d]pyrimidine (abbreviation: 4PCCzBfpm-02), and 4-{3-[3-(9-phenyl-9H-carbazol-3-yl)-9H-carbazol-9-yl]phenyl}benzo[h]quinazoline.

The upper temperature limit of the light-emitting layer is preferably high. In this case, the light-emitting layer can be inhibited from being damaged by heating and being decreased in emission efficiency and lifetime.

The EL layer 113R, the EL layer 113G, and the EL layer 113B can each include a first light-emitting unit, a charge-generation layer, and a second light-emitting unit, for example.

The second light-emitting unit preferably includes a light-emitting layer and a carrier-transport layer over the light-emitting layer. Alternatively, the second light-emitting unit preferably includes a light-emitting layer and a carrier-blocking layer over the light-emitting layer. Alternatively, the second light-emitting unit preferably includes a light-emitting layer, a carrier-blocking layer over the light-emitting layer, and a carrier-transport layer over the carrier-blocking layer. Since the surface of the second light-emitting unit is exposed in the manufacturing process of the display device, providing one or both of the carrier-transport layer and the carrier-blocking layer over the light-emitting layer inhibits the light-emitting layer from being exposed on the outermost surface, so that damage to the light-emitting layer can be reduced. Accordingly, the reliability of the light-emitting element can be improved. Note that in the case where three or more light-emitting units are provided, the uppermost light-emitting unit preferably includes a light-emitting layer and one or both of a carrier-transport layer and a carrier-blocking layer over the light-emitting layer.

In the case where the pixel electrode of the light-emitting element 130 functions as the anode and the common electrode 115 functions as the cathode, the common layer 114 includes at least one of an electron-injection layer and an electron-transport layer and, for example, includes an electron-injection layer. Alternatively, the common layer 114 may include a stack of an electron-transport layer and an electron-injection layer. Meanwhile, in the case where the pixel electrode of the light-emitting element 130 functions as the cathode and the common electrode 115 functions as the anode, the common layer 114 includes at least one of a hole-injection layer and a hole-transport layer and, for example, includes a hole-injection layer. Alternatively, the common layer 114 may include a stack of a hole-transport layer and a hole-injection layer. The common layer 114 is shared by the light-emitting element 130R, the light-emitting element 130G, and the light-emitting element 130B.

Like the common layer 114, the common electrode 115 is shared by the light-emitting element 130R, the light-emitting element 130G, and the light-emitting element 130B.

The common electrode 115 can be formed successively without a process such as etching between formations of the common layer 114 and the common electrode 115. For example, after the common layer 114 is formed in a vacuum, the common electrode 115 can be formed in a vacuum without exposing the substrate to the air. In other words, the common layer 114 and the common electrode 115 can be successively formed in a vacuum. Accordingly, the lower surface of the common electrode 115 can be a clean surface, as compared to the case where the common layer 114 is not provided in the display device 100. Thus, the light-emitting element 130 can have high reliability and favorable characteristics.

In the example illustrated in FIG. 2A, a mask layer 118R is provided over the EL layer 113R included in the light-emitting element 130R, a mask layer 118G is provided over the EL layer 113G included in the light-emitting element 130G, and a mask layer 118B is provided over the EL layer 113B included in the light-emitting element 130B. The mask layer 118R is a remaining portion of the mask layer provided over the EL layer 113R when the EL layer 113R is processed. Similarly, the mask layer 118G is a remaining portion of the mask layer provided at the time of forming the EL layer 113G, and the mask layer 118B is a remaining portion of the mask layer provided at the time of forming the EL layer 113B. In the display device 100, the mask layer used to protect the EL layer at the time of forming the display device 100 may partly remain in this manner. Two or all of the mask layer 118R, the mask layer 118G, and the mask layer 118B may be formed using the same material, or they may be formed using different materials. Note that hereinafter the mask layer 118R, the mask layer 118G, and the mask layer 118B may be collectively referred to as the mask layer 118.

In FIG. 2A, one end portion of the mask layer 118R is aligned or substantially aligned with the end portion of the EL layer 113R, and the other end portion of the mask layer 118R is positioned over the EL layer 113R. Here, the other end portion of the mask layer 118R preferably overlaps with the conductive layer 111R. In that case, the other end portion of the mask layer 118R is likely to be formed on a substantially flat surface of the EL layer 113R. The same applies to the mask layer 118G and the mask layer 118B. The mask layer 118 remains between the upper surface of the EL layer 113 processed into an island shape and the insulating layer 125, for example.

In the case where end portions are aligned or substantially aligned with each other and the case where top surface shapes are the same or substantially the same, it can be said that at least part of outlines of stacked layers overlap with each other in a plan view. The case where at least part of outlines of the upper layer and the lower layer overlap with each other includes the case where the layers are processed with the use of the same mask pattern or mask patterns that are partly the same, for example. However, in some cases, the outlines do not completely overlap with each other and the upper layer is positioned on the inner side of the lower layer or the upper layer is positioned on the outer side of the lower layer: such a case is also represented as “end portions are substantially aligned with each other” or “top surface shapes are substantially the same.”

The side surfaces of the EL layer 113R, the EL layer 113G, and the EL layer 113B are covered with the insulating layer 125. The insulating layer 127 overlaps with the side surfaces of the EL layer 113R, the EL layer 113G, and the EL layer 113B with the insulating layer 125 therebetween.

The upper surfaces of the EL layer 113R, the EL layer 113G, and the EL layer 113B are partly covered with the mask layer 118. The insulating layer 125 and the insulating layer 127 overlap with part of the upper surfaces of the EL layer 113R, the EL layer 113G, and the EL layer 113B with the mask layer 118 therebetween.

Covering the side surfaces and part of the upper surfaces of the EL layer 113R, the EL layer 113G, and the EL layer 113B with at least one of the insulating layer 125, the insulating layer 127, and the mask layer 118 can inhibit the common layer 114 and the common electrode 115 from being in contact with the side surfaces of the EL layer 113R, the EL layer 113G, and the EL layer 113B and thus inhibit a short circuit of the light-emitting element 130. Thus, the reliability of the light-emitting element 130 can be increased.

The thicknesses of the EL layer 113R, the EL layer 113G, and the EL layer 113B can be different from each other. For example, the thicknesses of the EL layer 113R, the EL layer 113G, and the EL layer 113B are preferably set to match an optical path length that intensifies light emitted from each EL layer. Thus, a microcavity structure is achieved, and the color purity of light emitted from the subpixels 110 can be improved.

The insulating layer 125 is preferably in contact with the side surfaces of the EL layer 113R, the EL layer 113G, and the EL layer 113B. In that case, peeling of the EL layer 113R, the EL layer 113G, and the EL layer 113B can be inhibited. When the insulating layer 125 is closely attached to the EL layer 113R, the EL layer 113G, or the EL layer 113B, the effect of fixing or bonding the adjacent EL layers 113 by the insulating layer 125 is obtained. Thus, the reliability of the light-emitting element 130 can be increased. In addition, the yield of the light-emitting element can be increased.

The insulating layer 125 and the insulating layer 127 cover both the side surfaces and part of the upper surfaces of the EL layer 113R, the EL layer 113G, and the EL layer 113B, as illustrated in FIG. 2A, whereby peeling of the EL layers 113 can be more favorably inhibited and the reliability of the light-emitting element 130 can be more favorably increased. In addition, the yield of the light-emitting element 130 can be more favorably increased.

In the example in FIG. 2A, the EL layer 113R, the mask layer 118R, the insulating layer 125, and the insulating layer 127 are stacked in the position over the end portion of the conductive layer 112R. Similarly, the EL layer 113G, the mask layer 118G, the insulating layer 125, and the insulating layer 127 are stacked over the end portion of the conductive layer 112G; and the EL layer 113B, the mask layer 118B, the insulating layer 125, and the insulating layer 127 are stacked over the end portion of the conductive layer 112B.

In FIG. 2A, the end portion of the conductive layer 112R is covered with the EL layer 113R, and the insulating layer 125 includes a region in contact with the side surface of the EL layer 113R. Similarly, the end portion of the conductive layer 112G is covered with the EL layer 113G, the end portion of the conductive layer 112B is covered with the EL layer 113B, and the insulating layer 125 includes regions in contact with the side surface of the EL layer 113G and the side surface of the EL layer 113B.

The insulating layer 127 is provided over the insulating layer 125 to fill a depressed portion formed in the insulating layer 125. The insulating layer 127 can overlap with the side surfaces and part of the upper surfaces of the EL layer 113R, the EL layer 113G, and the EL layer 113B, with the insulating layer 125 therebetween. The insulating layer 127 preferably covers at least part of the side surface of the insulating layer 125.

The insulating layer 125 and the insulating layer 127 can fill a gap between adjacent island-shaped layers. Accordingly, extreme unevenness of the formation surface of the layers, or more specifically, the common layer 114, the common electrode 115, and the like provided over the island-shaped layers can be reduced, and the formation surface can be made flatter. This can further improve the coverage with the common layer 114, the common electrode 115, and the like can be improved.

The common layer 114 and the common electrode 115 are provided over the EL layer 113R, the EL layer 113G, the EL layer 113B, the mask layer 118, the insulating layer 125, and the insulating layer 127. Before the insulating layer 125 and the insulating layer 127 are provided, there is a step due to a region where the pixel electrode and the island-shaped EL layer 113 are provided and a region where neither the pixel electrode nor the island-shaped EL layer 113 is provided (a region between the light-emitting elements 130). In the display device 100, the step can be eliminated with the insulating layer 125 and the insulating layer 127, and the coverage with the common layer 114 and the common electrode 115 can be improved. This can inhibit a connection defect due to the step disconnection. In addition, local thinning of the common electrode 115 due to a step can be inhibited from increasing electrical resistance.

The upper surface of the insulating layer 127 preferably has a shape with higher flatness and may have a protruding portion, a convex surface, a concave surface, or a depressed portion. For example, the upper surface of the insulating layer 127 preferably has a smooth convex shape with high planarity.

Note that in the display device 100, the insulating layer 127 is provided over the insulating layer 125 to fill the depressed portion formed in the insulating layer 125. Moreover, the insulating layer 127 is provided between the island-shaped EL layers 113. In other words, the display device 100 employs a process in which an island-shaped EL layer 113 is formed and then the insulating layer 127 is provided to overlap with an end portion of the island-shaped EL layer 113 (hereinafter referred to as a process 1). As a process different from the process 1, there is a process in which a pixel electrode is formed to have an island shape, an insulating layer that covers an end portion of the pixel electrode is formed, and then an island-shaped EL layer 113 is formed over the pixel electrode and the insulating layer (hereinafter referred to as a process 2).

The above process 1 is preferable to the above process 2 because of having a wider margin. Specifically, the above process 1 has a wider margin with respect to alignment accuracy between different patterning steps than the above process 2 and can provide display devices with few characteristics variations. The method of manufacturing the display device 100 is based on the above process 1 and thus, display devices with few variations and high display quality can be provided.

Next, examples of materials of the insulating layer 125 and the insulating layer 127 are described.

The insulating layer 125 can be formed using an inorganic material. As the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium-gallium-zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, aluminum oxide is preferably used because it has high selectivity with respect to the EL layer 113 in etching and has a function of protecting the EL layer 113 when the insulating layer 127 to be described later is formed. In particular, when an inorganic insulating film such as an aluminum oxide film, a hafnium oxide film, or a silicon oxide film that is formed by an atomic layer deposition (ALD) method is used for the insulating layer 125, it is possible to form the insulating layer 125 that has few pinholes and an excellent function of protecting the EL layer 113. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

The insulating layer 125 preferably has a function of a barrier insulating layer against at least one of water and oxygen. Alternatively, the insulating layer 125 preferably has a function of inhibiting diffusion of at least one of water and oxygen. Alternatively, the insulating layer 125 preferably has a function of capturing or fixing (also referred to as gettering) at least one of water and oxygen.

Note that in this specification and the like, a barrier insulating layer refers to an insulating layer having a barrier property. A barrier property in this specification and the like refers to a function of inhibiting diffusion of a particular substance (also referred to as having low permeability). Alternatively, a barrier property refers to a function of capturing or fixing a particular substance.

When the insulating layer 125 has a function of a barrier insulating layer or a gettering function, entry of impurities, typically, at least one of water and oxygen, which might diffuse into the light-emitting elements 130 from the outside can be inhibited. With this structure, a highly reliable light-emitting element and a highly reliable display device can be provided.

The insulating layer 125 preferably has a low impurity concentration. In this case, deterioration of the EL layer 113 due to entry of impurities from the insulating layer 125 into the EL layer 113 can be inhibited. In addition, when the impurity concentration is reduced in the insulating layer 125, a barrier property against at least one of water and oxygen can be increased. For example, the insulating layer 125 preferably has one of a sufficiently low hydrogen concentration and a sufficiently low carbon concentration, desirably has both of them.

Note that the same material can be used for the insulating layer 125, the mask layer 118R, the mask layer 118G, and the mask layer 118B. In this case, the boundary between the insulating layer 125 and any of the mask layer 118R, the mask layer 118G, and the mask layer 118B and thus the layers cannot be distinguished from each other in some cases. Thus, the insulating layer 125 and any of the mask layer 118R, the mask layer 118G, and the mask layer 118B are observed as one layer in some cases. In other words, it sometimes appears that one layer is provided in contact with the side surfaces and part of the upper surfaces of the EL layer 113R, the EL layer 113G, and the EL layer 113B, and the insulating layer 127 covers at least part of the side surface of the one layer.

The insulating layer 127 provided over the insulating layer 125 has a planarization function for the extreme unevenness of the insulating layer 125, which is formed between adjacent light-emitting elements 130. In other words, the insulating layer 127 has an effect of improving the planarity of the surface where the common electrode 115 is formed.

As the insulating layer 127, an insulating layer containing an organic material can be suitably used. As the organic material, a photosensitive material, for example, a photosensitive organic resin is preferably used, and a photosensitive resin composition containing an acrylic resin is preferably used. Note that in this specification and the like, an acrylic resin refers to not only a polymethacrylic acid ester or a methacrylic resin, but also all the acrylic polymer in a broad sense in some cases.

For the insulating layer 127, an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like may be used. For the insulating layer 127, an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin may be used. A photoresist may be used for the photosensitive resin. As the photosensitive organic resin, either a positive-type material or a negative-type material may be used.

A material absorbing visible light may be used for the insulating layer 127. When the insulating layer 127 absorbs light emitted from the light-emitting element 130, leakage of light from the light-emitting element 130 to the adjacent light-emitting element 130 through the insulating layer 127 (stray light) can be inhibited. Thus, the display quality of the display device can be improved. Since the display quality of the display device can be improved without using a polarizing plate, the weight and thickness of the display device can be reduced.

Examples of the material absorbing visible light include materials containing pigment of black or the like, materials containing dye, light-absorbing resin materials such as polyimide, and a resin material that can be used for coloring layers. Using a resin material obtained by stacking or mixing color filter materials of two or three or more colors is particularly preferred to enhance the effect of blocking visible light. In particular, mixing color filter materials of three or more colors enables the formation of a black or nearly black resin layer.

The material used for the insulating layer 127 preferably has a low volume shrinkage rate. In this case, the insulating layer 127 can be easily formed into a desired shape. In addition, the insulating layer 127 preferably has a low volume shrinkage rate after being cured. In this case, the shape of the insulating layer 127 can be easily maintained in a variety of steps after formation of the insulating layer 127. Specifically, the volume shrinkage rate of the insulating layer 127 after thermal curing, after light curing, or after light curing and thermal curing is preferably lower than or equal to 10%, further preferably lower than or equal to 5%, still further preferably lower than or equal to 1%. Here, as the volume shrinkage rate, one of the rate of volume shrinkage by light irradiation and the rate of volume shrinkage by heating, or the sum of these rates can be used.

Providing the protective layer 131 over the light-emitting elements 130 can improve the reliability of the light-emitting elements 130. The protective layer 131 may have a single-layer structure or a stacked-layer structure of two or more layers.

There is no limitation on the conductivity of the protective layer 131. As the protective layer 131, at least one of an insulating film, a semiconductor film, and a conductive film can be used.

As the protective layer 131, an inorganic insulating film such as an oxide insulating film, a nitride insulating film, an oxynitride insulating film, or a nitride oxide insulating film can be used, for example. Specific examples of these inorganic films are as listed in the description of the insulating layer 125. In particular, the protective layer 131 preferably includes a nitride insulating film or a nitride oxide insulating film, and further preferably includes a nitride insulating film.

As the protective layer 131, an inorganic film containing In—Sn oxide (also referred to as ITO), In—Zn oxide, Ga—Zn oxide, Al—Zn oxide, indium gallium zinc oxide (In—Ga—Zn oxide, also referred to as IGZO), or the like can also be used. The inorganic film preferably has high resistance, specifically, higher resistance than the common electrode 115. The inorganic film may further contain nitrogen.

By including the inorganic film, the protective layer 131 can inhibit oxidation of the common electrode 115. Moreover, by including the inorganic film, the protective layer 131 can inhibit entry of impurities such as water and oxygen into the light-emitting element 130. Accordingly, since the light-emitting element 130 can be a light-emitting element that is unlikely to deteriorate, the display device 100 can be a highly reliable display device.

When light emitted from the light-emitting element 130 is extracted through the protective layer 131, the protective layer 131 preferably has a high visible-light-transmitting property. For example, ITO, IGZO, and aluminum oxide are preferable because they are inorganic materials having a high visible-light-transmitting property.

The protective layer 131 can employ, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities such as water and oxygen into the EL layer 113 side.

Furthermore, the protective layer 131 may include an organic film. For example, the protective layer 131 may include both an organic film and an inorganic film. Examples of an organic material that can be used for the protective layer 131 include organic insulating materials that can be used for the insulating layer 127.

The protective layer 131 may have a stacked-layer structure of two layers which are formed by different film formation methods. Specifically, the first layer of the protective layer 131 may be formed by an ALD method, and the second layer of the protective layer 131 may be formed by a sputtering method.

A light-blocking layer may be provided on a surface of the substrate 120 on the resin layer 122 side. Moreover, a variety of optical members can be provided on the outer surface of the substrate 120. Examples of the optical members include a polarizing plate, a retardation plate, a light diffusion layer such as a diffusion film, an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer surface of the substrate 120. For example, a glass layer or a silica layer (SiOₓ layer) is preferably provided as the surface protective layer to inhibit the surface contamination and generation of a scratch. The surface protective layer may be formed using DLC (diamond like carbon), aluminum oxide (AlOₓ), a polyester-based material, a polycarbonate-based material, or the like. For the surface protective layer, a material having high visible-light transmittance is preferably used. The surface protective layer is preferably formed using a material with high hardness.

For the substrate 120, glass, quartz, ceramic, sapphire, a resin, a metal, an alloy, a semiconductor, or the like can be used. The substrate on the side from which light from the light-emitting element is extracted is formed using a material that transmits the light. When the substrate 120 is formed using a flexible material, the flexibility of the display device can be increased. Furthermore, a polarizing plate may be used as the substrate 120.

For the substrate 120, any of the following can be used: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used for the substrate 120.

In the case where a circularly polarizing plate overlaps with the display device, a highly optically isotropic substrate is preferably used as the substrate included in the display device. A highly optically isotropic substrate has a low birefringence, or more specifically a small amount of birefringence.

The absolute value of a retardation (phase difference) of a highly optically isotropic substrate is preferably less than or equal to 30 nm, further preferably less than or equal to 20 nm, still further preferably less than or equal to 10 nm.

Examples of the film having high optical isotropy include a triacetyl cellulose (TAC, also referred to as cellulose triacetate) film, a cycloolefin polymer (COP) film, a cycloolefin copolymer (COC) film, and an acrylic film.

When a film is used for the substrate and the film absorbs water, the shape of the display device might be changed, e.g., creases are generated. Thus, for the substrate, a film with a low water absorption rate is preferably used. For example, a film with a water absorption rate lower than or equal to 1% is preferably used, a film with a water absorption rate lower than or equal to 0.1% is further preferably used, and a film with a water absorption rate lower than or equal to 0.01% is still further preferably used.

As the resin layer 122, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. A two-component-mixture-type resin may be used. An adhesive sheet may be used, for example.

FIG. 2B1 is a cross-sectional view illustrating a structure example of the conductive layer 111 and the conductive layer 112. Note that FIG. 2B1 also illustrates the insulating layer 105. The same applies to other views illustrating a structure example of the conductive layer 111 and the conductive layer 112.

As illustrated in FIG. 2B1, the conductive layer 111 can be configured to include a conductive layer 111a over the insulating layer 105, a conductive layer 111b over the conductive layer 111a, and a conductive layer 111c over the conductive layer 111b. The conductive layer 112 is provided to cover an upper surface of the conductive layer 111c, a side surface of the conductive layer 111c, a side surface of the conductive layer 111b, and a side surface of the conductive layer 111a.

In the example illustrated in FIG. 2B1, the conductive layer 111b is interposed between the conductive layer 111a and the conductive layer 111c. A material that is less likely to change in quality than the conductive layer 111b is preferably used for the conductive layer 111a and the conductive layer 111c. For example, a material that is less likely to cause migration due to contact with the insulating layer 105 than the conductive layer 111b can be used for the conductive layer 111a. For the conductive layer 111c, a material which is less likely to be oxidized than the conductive layer 111b and an oxide of which has lower electrical resistance than an oxide of the material used for the conductive layer 111b can be used.

In this specification and the like, migration refers to one or both of stress migration and electromigration. Stress migration refers to a phenomenon in which, in heat treatment, a stress occurs in the conductive layer due to a difference in thermal expansion coefficient between a conductive layer and a layer such as an insulating layer in contact with the conductive layer to cause atoms included in the conductive layer to migrate. Electromigration refers to a phenomenon in which an electric field causes atoms included in the conductive layer to migrate. Migration might form hillocks which are bulges or voids which are cavities on a surface of the conductive layer. The hillock formation might cause a short circuit between the conductive layer and another conductive layer, and the void formation might break the conductive layer.

In this manner, the structure in which the conductive layer 111b is interposed between the conductive layer 111a and the conductive layer 111c can expand the range of choices for the material for the conductive layer 111b. The conductive layer 111b, for example, can thus have higher visible light reflectance than at least one of the conductive layer 111a and the conductive layer 111c. For example, aluminum can be used for the conductive layer 111b. Note that an alloy containing aluminum may be used for the conductive layer 111b. For the conductive layer 111a, titanium, a material which has lower visible light reflectance than aluminum and is less likely to cause migration even at the time of contact with the insulating layer 105 than aluminum, can be used. For the conductive layer 111c, titanium, a material which has lower visible light reflectance than aluminum and is less likely to be oxidized than aluminum and whose oxide has lower electrical resistivity than aluminum oxide, can be used.

The conductive layer 111 having a stacked-layer structure of a plurality of layers as described above can improve the characteristics of the display device. For example, the display device 100 can have high light extraction efficiency and high reliability.

FIG. 2B2 illustrates a modification example of the structure in FIG. 2B1. In this example, the conductive layer 112 includes a conductive layer 112a, which covers the upper surface of the conductive layer 111c, the side surface of the conductive layer 111c, the side surface of the conductive layer 111b, and the side surface of the conductive layer 111a, and a conductive layer 112b over the conductive layer 112a.

For the conductive layer 112a, a material similar to the material that can be used for the conductive layer 111c can be used. For the conductive layer 112b, a material similar to the material that can be used for the conductive layer 112 illustrated in FIG. 2B1 can be used. In other words, for example, a metal material such as titanium can be used for the conductive layer 112a, and for example, a conductive oxide such as indium tin oxide can be used for the conductive layer 112b.

The conductive layer 112 that has the structure illustrated in FIG. 2B2 can hinder the conductive layer 112b, for which a conductive oxide such as indium tin oxide can be used, from being in contact with the side surface of the conductive layer 111b, for which aluminum can be used, for example. Consequently, a change in the quality of the conductive layer 111b can be suitably inhibited, and the reliability of the display device 100 can be increased. Note that the conductive layer 111c is preferably provided even in the case where the conductive layer 112 has the structure illustrated in FIG. 2B2. This can inhibit oxygen in the atmosphere from oxidizing, for example, the upper surface of the conductive layer 111b having higher visible light reflectance than the conductive layer 111a after the formation of the conductive layer 111 but before the formation of the conductive layer 112. Thus, a reduction in the visible light reflectance of the conductive layer 111 can be inhibited. Consequently, the display device 100 can be a display device having high light extraction efficiency.

In the case where the conductive layer 112 has a stacked-layer structure of the conductive layer 112a and the conductive layer 112b, as illustrated in FIG. 2B2, for example, a conductive oxide such as indium tin oxide may be used for the conductive layer 112a and a mixed material in which molybdenum oxide and an organic material are mixed may be used for the conductive layer 112b.

In the case where the conductive layer 111 has the structure illustrated in FIG. 2B1 and FIG. 2B2, for example, an end portion of the conductive layer 111b might be positioned more inside than an end portion of the conductive layer 111c in a cross-sectional view. In other words, the conductive layer 111c includes a region projecting from the conductive layer 111b in a cross-sectional view in some cases. In this case, when the conductive layer 112 is formed by a film formation method providing low coverage, the above projecting region might cause step disconnection of the conductive layer 112. The conductive layer 112 might be locally thinned to have increased electrical resistance.

Thus, when the conductive layer 112 is formed by a film formation method providing high coverage, it is possible to inhibit the occurrence of a connection defect due to the step disconnection of the conductive layer 112 and an increase in electrical resistance due to the local thinning of the conductive layer 112. For example, when the conductive layer 112 is formed by an ALD method, even with the conductive layer 111c including a region projecting from the conductive layer 111b, the occurrence of a connection defect due to the step disconnection of the conductive layer 112 and an increase in electrical resistance due to the local thinning of the conductive layer 112 can be suitably inhibited.

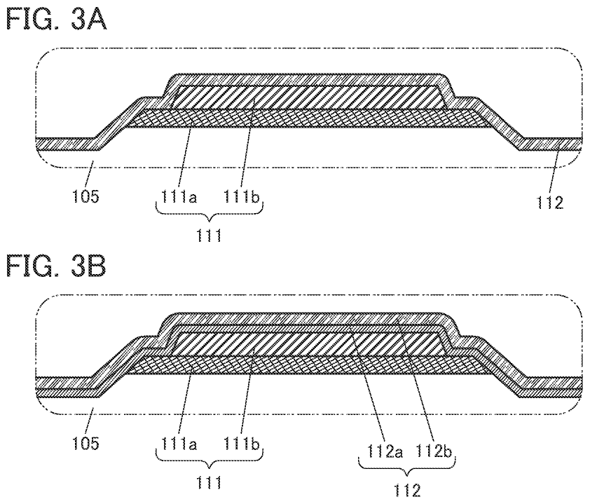

FIG. 3A is a cross-sectional view of a structure example of the conductive layer 111 and the conductive layer 112, which is different from the structures in FIG. 2B1 and FIG. 2B2. As illustrated in FIG. 3A, the conductive layer 111 can be configured to include the conductive layer 111a over the insulating layer 105 and the conductive layer 111b over the conductive layer 111a. In other words, the conductive layer 111 illustrated in FIG. 3A has a stacked-layer structure of two layers. In the case where the conductive layer 111 has a stacked-layer structure of a plurality of layers as described above, the visible light reflectance of at least one of the layers included in the conductive layer 111 is higher than that of the conductive layer 112. The conductive layer 112 is provided to cover the side surfaces and upper surfaces of the conductive layer 111a and the conductive layer 111b.

As already described above, the conductive layer 111 preferably has a side surface with a tapered shape. Specifically, the side surface of the conductive layer 111 preferably has a tapered shape with a taper angle of less than 90°. For example, in the conductive layer 111 illustrated in FIG. 3A, the side surface of at least one of the conductive layer 111a and the conductive layer 111b preferably has a tapered shape. For example, the conductive layer 111a preferably has a side surface with a tapered shape. Alternatively, each of the side surface of the conductive layer 111a and the side surface of the conductive layer 111b preferably has a tapered shape.

FIG. 3B illustrates a modification example of the structure in FIG. 3A, and in this example, the conductive layer 112 has a two-layer structure in which the conductive layer 112a and the conductive layer 112b over the conductive layer 112a are stacked. For the conductive layer 112a, a material similar to the material that can be used for the conductive layer 111 can be used. For the conductive layer 112b, a material similar to the material that can be used for the conductive layer 112 illustrated in FIG. 3A can be used, for example.

For the conductive layer 112a, silver or an alloy containing silver can be used, for example. Silver and an alloy containing silver have higher visible light reflectance than that of titanium. In addition, silver is less likely to be oxidized than aluminum, which can be used for the conductive layer 111b, and silver oxide has lower electrical resistance than aluminum oxide, for example. Thus, the use of silver or an alloy containing silver for the conductive layer 112a can suitably increase the visible light reflectance of the pixel electrode and inhibit an increase in the electrical resistance of the pixel electrode due to oxidation of the conductive layer 112a. Accordingly, the display device 100 can have high light extraction efficiency and high reliability. In particular, in the case where the light-emitting element 130 has a microcavity structure, silver or an alloy containing silver, which is a material having high visible light reflectance, is preferably used for the conductive layer 112a. This can suitably increase the light extraction efficiency of the display device 100.

Titanium may be used for the conductive layer 112a. Since titanium has better processability in etching than silver, the use of titanium for the conductive layer 112a facilitates the formation of the conductive layer 112a.

Note that the conductive layer 111 does not necessarily include the conductive layer 111b. That is, the conductive layer 111 can have a single-layer structure of the conductive layer 111a. For example, titanium which can be used for the conductive layer 111a is less likely to be oxidized which aluminum that can be used for the conductive layer 111b, and the electrical resistivity of titanium oxide is lower than the electrical resistivity of aluminum oxide. This indicates that, when the conductive layer 111 does not include the conductive layer 111b, the electrical resistance at the contact interface between the conductive layer 111 and the conductive layer 112 can be reduced.

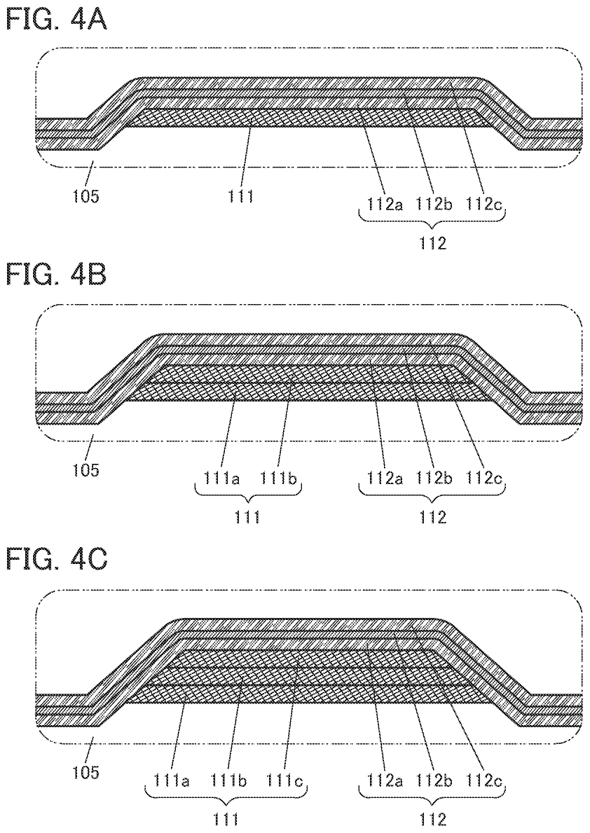

FIG. 4A is a cross-sectional view of a structure example of the conductive layer 111 and the conductive layer 112, which is different from the structures in FIG. 2B1, FIG. 2B2, FIG. 3A, and FIG. 3B. In the example illustrated in FIG. 4A, the conductive layer 111 has a single-layer structure. The conductive layer 112 has a stacked-layer of three layers, the conductive layer 112a, the conductive layer 112b over the conductive layer 112a, and a conductive layer 112c over the conductive layer 112b.

For the conductive layer 111 illustrated in FIG. 4A, for example, a material that is hardly oxidized when being in contact with the conductive layer 112a and has electrical resistivity unlikely to increase significantly even when being oxidized is used. For example, the conductive layer 111 can be formed using an alloy containing titanium. Thus, any change in the quality of the conductive layer 111 can be inhibited and the display device 100 can be a highly reliable display device.

The conductive layer 112a illustrated in FIG. 4A has higher adhesion to the conductive layer 112b than the insulating layer 105 does, for example. For the conductive layer 112a, a conductive oxide can be used, and an oxide containing one or more selected from indium, tin, zinc, gallium, titanium, aluminum, and silicon, for example, can be used. Specifically, indium tin oxide or indium tin oxide containing silicon, for example, can be used for the conductive layer 112a. This can inhibit peeling of the conductive layer 112b, so that the display device 100 can be a highly reliable display device. The structure can be employed in which the conductive layer 112a is in contact with the insulating layer 105 and the conductive layer 112b is not in contact with the insulating layer 105, as illustrated in FIG. 4A.

The conductive layer 112b illustrated in FIG. 4A is a layer having higher visible light reflectance than the conductive layer 111, the conductive layer 112a, and the conductive layer 112c. The visible light reflectance of the conductive layer 112b can be, for example, higher than or equal to 70% and lower than or equal to 100%, and is preferably higher than or equal to 80% and lower than or equal to 100%, further preferably higher than or equal to 90% and lower than or equal to 100%. For the conductive layer 112b, silver or an alloy containing silver can be used, for example. An example of the alloy containing silver is APC. Consequently, the display device 100 can be a display device with high light extraction efficiency.

In the case where the conductive layer 111 and the conductive layer 112 function as the anode, a layer having a high work function is used as the conductive layer 112c. The conductive layer 112c has a higher work function than the conductive layer 112b, for example. Accordingly, the driving voltage of the light-emitting element 130 can be reduced. For the conductive layer 112c, a material similar to the material that can be used for the conductive layer 112a can be used, for example. For example, the conductive layer 112a and the conductive layer 112c can be formed using the same kind of material. For example, in the case where indium tin oxide is used for the conductive layer 112a, indium tin oxide can also be used for the conductive layer 112c.

In the case where the conductive layer 111 and the conductive layer 112 function as the cathode, a layer having a low work function is used as the conductive layer 112c. The conductive layer 112c has a lower work function than the conductive layer 112b, for example. Accordingly, the driving voltage of the light-emitting element 130 can be reduced.

The conductive layer 112c is preferably a layer having high visible light transmittance. For example, the visible light transmittance of the conductive layer 112c is preferably higher than those of the conductive layer 111 and the conductive layer 112b. The visible light transmittance of the conductive layer 112c can be, for example, greater than or equal to 60% and less than or equal to 100%, and is preferably higher than or equal to 70% and lower than or equal to 100%, further preferably higher than or equal to 80% and lower than or equal to 100%. Accordingly, the amount of light absorbed by the conductive layer 112c among light emitted from the EL layer 113 can be reduced. As described above, the conductive layer 112b under the conductive layer 112c can be a layer having high visible light reflectance. Thus, the display device 100 can have high light extraction efficiency.

Note that the conductive layer 112b illustrated in FIG. 4A is a layer having high reflectance with respect to light emitted from the EL layer 113, and the conductive layer 112c is a layer having high transmittance with respect to light emitted from the EL layer 113. For example, in the case where the EL layer 113 emits infrared light, the conductive layer 112b is a layer having high reflectance with respect to infrared light, and the conductive layer 112c is a layer having high transmittance with respect to infrared light. For example, in the case where the EL layer 113 emits infrared light, “visible light” in the above description of the conductive layer 112b and the conductive layer 112c illustrated in FIG. 4A can be replaced with “infrared light.”

Thus, the display device 100 can have high reliability and high light extraction efficiency. In addition, the display device 100 can include a light-emitting element with high emission efficiency.

FIG. 4B and FIG. 4C are each a cross-sectional view of a structure example of the conductive layer 111 and the conductive layer 112, which is different from the structure in FIG. 4A. In the example illustrated in FIG. 4B, the conductive layer 111 has a stacked-layer of two layers, the conductive layer 111a and the conductive layer 111b over the conductive layer 111a. In the example illustrated in FIG. 4C, the conductive layer 111 has a stacked-layer of three layers, the conductive layer 111a, the conductive layer 111b over the conductive layer 111a, and the conductive layer 111c over the conductive layer 111b.

The conductive layer 111a and the conductive layer 111c can be formed using a material similar to that for the conductive layer 111 illustrated in FIG. 4A, for example, titanium or an alloy containing titanium. The conductive layer 111b can be a layer having higher visible light reflectance than the conductive layer 111a, for example. Moreover, the conductive layer 111b can be a layer that is more easily processed by etching than the conductive layer 112b, for example. In the above manner, the thickness of the conductive layer 112b that can contain silver or an alloy containing silver, for example, can be reduced while the visible light reflectance of the pixel electrode increases. Hence, the display device 100 can have high light extraction efficiency and be easily manufactured. For the conductive layer 111b, aluminum or an aluminum alloy can be used, for example.

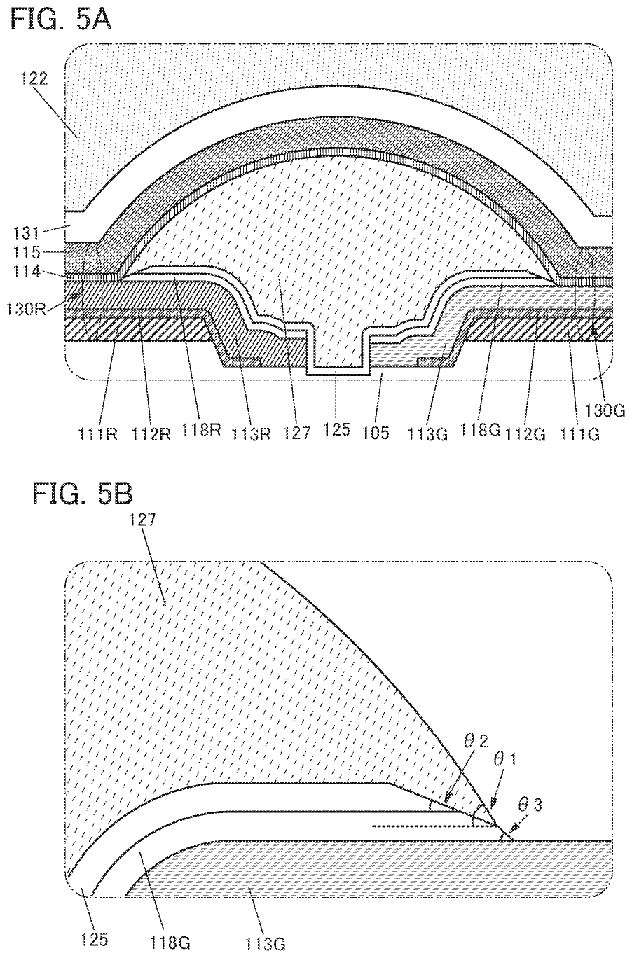

Next, a structure of the insulating layer 127 and the vicinity thereof will be described with reference to FIG. 5A and FIG. 5B. FIG. 5A is a cross-sectional enlarged view of a region including the insulating layer 127 between the EL layer 113R and the EL layer 113G and the vicinity thereof. The description is made below using the insulating layer 127 between the EL layer 113R and the EL layer 113G as an example: the same applies to the insulating layer 127 between the EL layer 113G and the EL layer 113B and the insulating layer 127 between the EL layer 113B and the EL layer 113R, for example. FIG. 5B is an enlarged view of the vicinity of the end portion of the insulating layer 127 over the EL layer 113G illustrated in FIG. 5A. Although the description is sometimes made below using the end portion of the insulating layer 127 over the EL layer 113G as an example, the same applies to the end portion of the insulating layer 127 over the EL layer 113R and the end portion of the insulating layer 127 over the EL layer 113B, for example.

As illustrated in FIG. 5A, the EL layer 113R is provided to cover the conductive layer 112R, and the EL layer 113G is provided to cover the conductive layer 112G. The mask layer 118R is provided in contact with part of the upper surface of the EL layer 113R, and the mask layer 118G is provided in contact with part of the upper surface of the EL layer 113G. The insulating layer 125 is provided to include a region in contact with the upper surface and the side surface of the mask layer 118R, the side surface of the EL layer 113R, the upper surface of the insulating layer 105, the upper surface and the side surface of the mask layer 118G, and the side surface of the EL layer 113G. The insulating layer 127 is provided in contact with the upper surface of the insulating layer 125. The insulating layer 127 overlaps with the side surface and part of the upper surface of the EL layer 113R and the side surface and part of the upper surface of the EL layer 113G with the insulating layer 125 therebetween, and is in contact with at least part of the side surface and the upper surface of the insulating layer 125. The common layer 114 is provided to cover the EL layer 113R, the mask layer 118R, the EL layer 113G, the mask layer 118G, the insulating layer 125, and the insulating layer 127. The common electrode 115 is provided over the common layer 114.

As illustrated in FIG. 5A, the thickness of the insulating layer 105 in a region that does not overlap with the EL layer 113 may be smaller than that of the insulating layer 105 in a region overlapping with the EL layer 113. That is, the insulating layer 105 may have a depressed portion in the region that does not overlap with the EL layer 113. The depressed portion is formed because of the step of forming the EL layer 113, for example.

The insulating layer 127 is formed in a region between the two island-shaped EL layers 113 (e.g., a region between the EL layer 113R and the EL layer 113G in FIG. 5A). In this case, at least part of the insulating layer 127 is positioned between a side end portion of one of the EL layers 113 (e.g., the EL layer 113R in FIG. 5A) and a side end portion of the other EL layer 113 (e.g., the EL layer 113G in FIG. 5A). Providing the insulating layer 127 in such a manner can inhibit formation of a disconnected portion and a locally thinned portion in the common layer 114 and the common electrode 115 that are formed over the island-shaped EL layers 113 and over the insulating layer 127.

As illustrated in FIG. 5B, the end portion of the insulating layer 127 preferably has a tapered shape with a taper angle θ1 in the cross-sectional view of the display device 100. The taper angle θ1 is an angle formed by the side surface of the insulating layer 127 and the substrate surface. Note that the taper angle θ1 may be an angle formed by the side surface of the insulating layer 127 and, instead of the substrate surface, the upper surface of the flat portion of the EL layer 113G or the upper surface of the flat portion of the conductive layer 112G.

The taper angle θ1 of the insulating layer 127 is less than 90°, preferably less than or equal to 60°, further preferably less than or equal to 45°, still further preferably less than or equal to 20°. When the end portion of the insulating layer 127 has such a forward tapered shape, the common layer 114 and the common electrode 115 that are provided over the insulating layer 127 can be formed with favorable coverage, thereby inhibiting step disconnection, local thinning, or the like. Accordingly, the in-place uniformity of the common layer 114 and the common electrode 115 can be improved, leading to higher display quality of the display device.

As illustrated in FIG. 5A, the upper surface of the insulating layer 127 preferably has a convex shape in the cross-sectional view of the display device 100. The convex shape of the upper surface of the insulating layer 127 is preferably a shape gently bulging toward the center. The insulating layer 127 preferably has a shape such that the convex portion at the center portion of the upper surface is connected smoothly to the tapered portion of the end portion. When the insulating layer 127 has such a shape, the common layer 114 and the common electrode 115 can be formed with good coverage over the whole insulating layer 127.

As illustrated in FIG. 5B, the end portion of the insulating layer 127 is preferably positioned on the outer side of the end portion of the insulating layer 125. In that case, unevenness of the surface where the common layer 114 and the common electrode 115 are formed is favorably reduced, and coverage with the common layer 114 and the common electrode 115 can be improved.

As illustrated in FIG. 5B, the end portion of the insulating layer 125 preferably has a tapered shape with a taper angle θ2 in the cross-sectional view of the display device 100. The taper angle θ2 is an angle formed by the side surface of the insulating layer 125 and the substrate surface. Note that the taper angle θ2 may be an angle formed by the side surface of the insulating layer 125 and, instead of the substrate surface, the upper surface of the flat portion of the EL layer 113G or the upper surface of the flat portion of the conductive layer 112G.

The taper angle θ2 of the insulating layer 125 is less than 90°, preferably less than or equal to 60°, further preferably less than or equal to 45°, still further preferably less than or equal to 20°.

As illustrated in FIG. 5B, the end portion of the mask layer 118G preferably has a tapered shape with a taper angle θ3 in the cross-sectional view of the display device 100. The taper angle θ3 is an angle formed by the side surface of the mask layer 118G and the substrate surface. Note that the taper angle θ3 may be an angle formed by the side surface of the mask layer 118G and, instead of the substrate surface, the upper surface of the flat portion of the EL layer 113G or the upper surface of the flat portion of the conductive layer 112G.

The taper angle θ3 of the mask layer 118G is less than 90°, preferably less than or equal to 60°, further preferably less than or equal to 45°, still further preferably less than or equal to 20°. When the end portion of the mask layer 118G has such a forward tapered shape, the common layer 114 and the common electrode 115 that are provided over the mask layer 118G can be formed with favorable coverage.

The end portion of the mask layer 118R and the end portion of the mask layer 118G are preferably positioned on the outer side of the end portion of the insulating layer 125. In that case, unevenness of the surface where the common layer 114 and the common electrode 115 are formed is reduced, and coverage with the common layer 114 and the common electrode 115 can be improved.

Although the details will be described later, when the insulating layer 125 and the mask layer 118 are etched at once, the insulating layer 125 and the mask layer 118 under the end portion of the insulating layer 127 are eliminated by side etching and accordingly a cavity is formed in some cases. The cavity causes unevenness in the formation surface of the common layer 114 and the common electrode 115, so that step disconnection is likely to occur in the common layer 114 and the common electrode 115. Thus, when etching treatment is divided into two steps and heat treatment is performed between the two etching steps, even if a cavity is formed by the first etching treatment, the shape of the insulating layer 127 is changed by the heat treatment to fill the cavity. Since the second etching treatment is for etching a thinner film, the amount of side etching decreases, a cavity is less likely to be formed, and even if a cavity is formed, it can be extremely small. Thus, generation of unevenness in the formation surface of the common layer 114 and the common electrode 115 can be inhibited and accordingly step disconnection of the common layer 114 and the common electrode 115 can be inhibited. Since the etching treatment is performed twice, the taper angle θ2 and the taper angle θ3 are different from each other in some cases. The taper angle θ2 and the taper angle θ3 may be the same. The taper angle θ2 and the taper angle θ3 may each be smaller than the taper angle θ1.

The insulating layer 127 may cover at least part of the side surface of the mask layer 118R and at least part of the side surface of the mask layer 118G. For example, FIG. 5B illustrates an example in which the insulating layer 127 touches and covers an inclined surface that is formed by the first etching treatment and positioned at the end portion of the mask layer 118G, and an inclined surface that is formed by the second etching treatment and positioned at the end portion of the mask layer 118G is exposed. These two inclined surfaces can sometimes be distinguished from each other because of different taper angles. In some cases, they cannot be distinguished from each other because the taper angles on the side surface formed by the two etching treatments are almost the same.

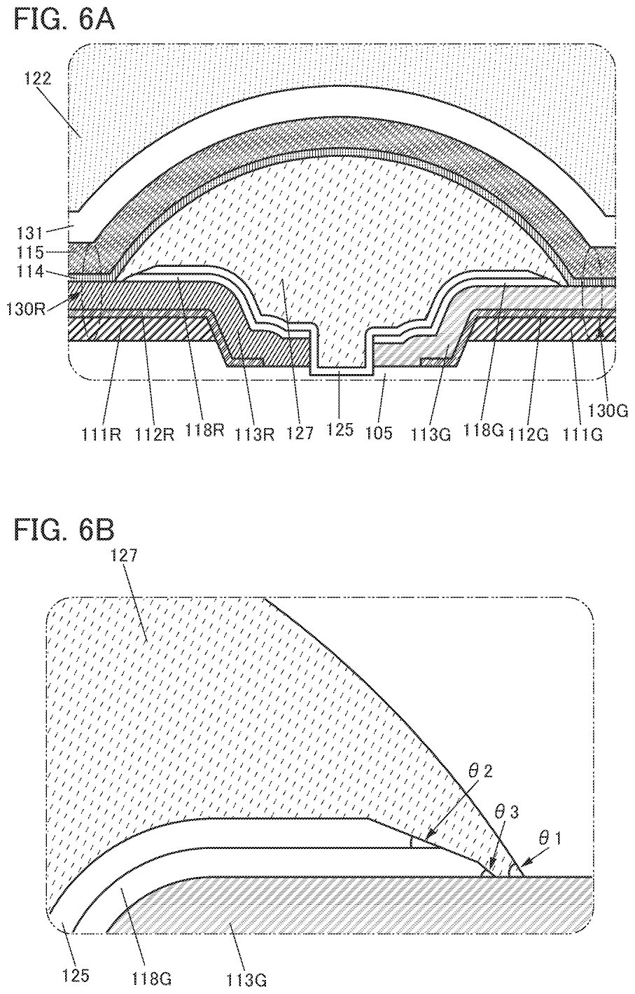

FIG. 6A and FIG. 6B illustrate a modification example of the structure in FIG. 5A and FIG. 5B, and in this example, the insulating layer 127 covers the entire side surface of the mask layer 118R and the entire side surface of the mask layer 118G. Specifically, in FIG. 6B, the insulating layer 127 covers and is in contact with both of the two inclined surfaces. This is preferable because unevenness of the formation surface of the common layer 114 and the common electrode 115 can be further reduced. FIG. 6B illustrates an example where the end portion of the insulating layer 127 is positioned on the outer side of the end portion of the mask layer 118G. As illustrated in FIG. 6B, the end portion of the insulating layer 127 may be positioned on the inner side of the end portion of the mask layer 118G, or may be aligned or substantially aligned with the end portion of the mask layer 118G. As illustrated in FIG. 6B, the insulating layer 127 is in contact with the EL layer 113G in some cases.

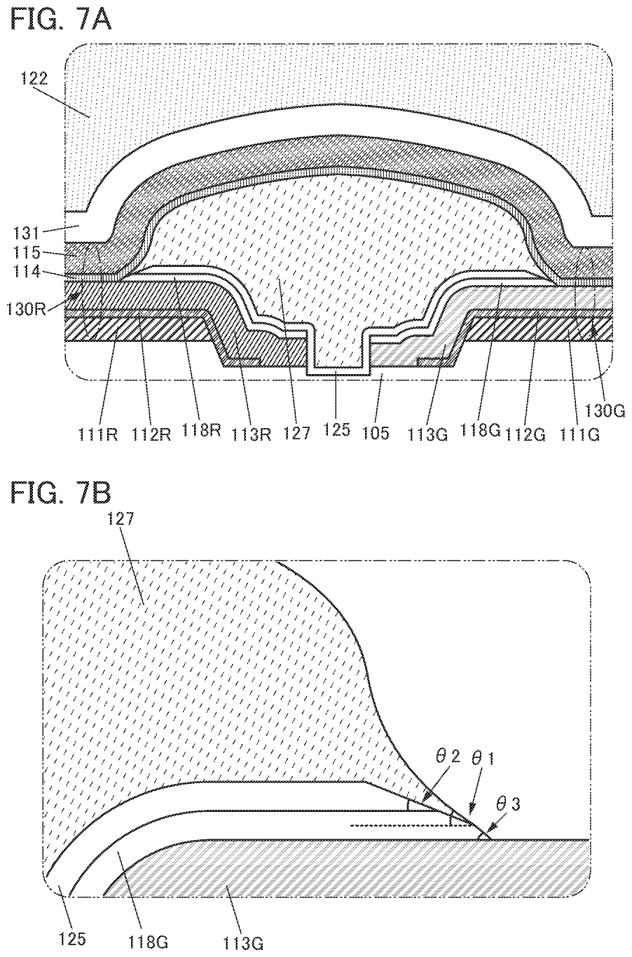

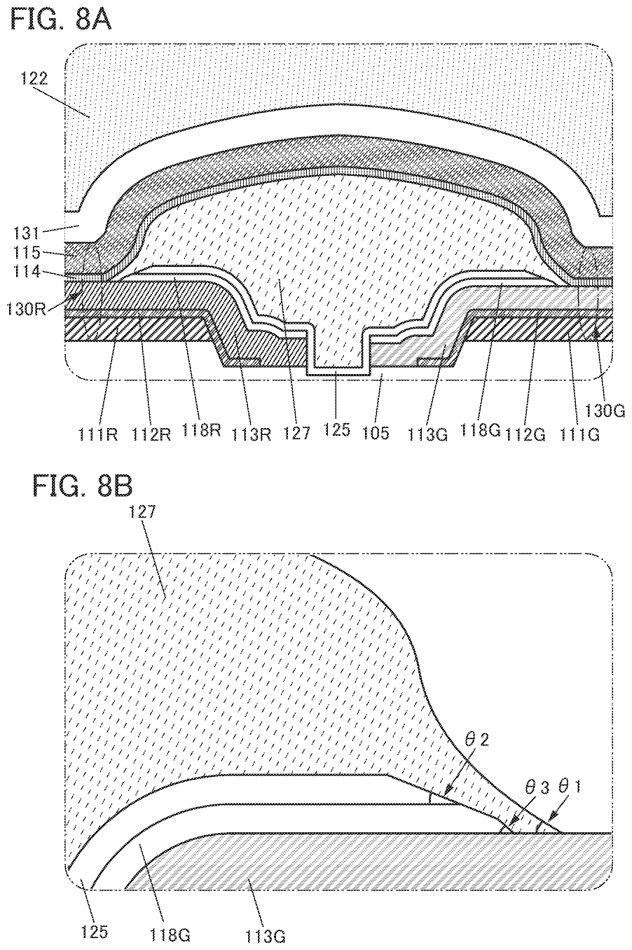

FIG. 7A and FIG. 8A illustrate modification examples of the structure illustrated in FIG. 5A, and FIG. 7B and FIG. 8B illustrate modification examples of the structure illustrated in FIG. 5B. FIG. 7A, FIG. 7B, FIG. 8A, and FIG. 8B illustrate examples where the side surface of the insulating layer 127 has a concave shape (also referred to as a narrowed portion, a depressed portion, a dent, a hollow, or the like). In some cases, the side surface of the insulating layer 127 has a concave shape depending on the material and formation conditions (e.g., heating temperature, heating time, and heating atmosphere) of the insulating layer 127.

FIG. 7A and FIG. 7B illustrate an example in which the insulating layer 127 covers part of the side surface of the mask layer 118G and the other part of the side surface of the mask layer 118G is exposed. FIG. 8A and FIG. 8B illustrate an example where the insulating layer 127 covers and is in contact with the entire side surface of the mask layer 118G.

Also in the structures illustrated in FIG. 6B, FIG. 7B, and FIG. 8B, the taper angle θ1 to the taper angle θ3 are preferably within the above range.

As illustrated in FIG. 5A, FIG. 6A, FIG. 7A, and FIG. 8A, one end portion of the insulating layer 127 preferably overlaps with the upper surface of the conductive layer 111R and the other end portion of the insulating layer 127 preferably overlaps with the upper surface of the conductive layer 111G. With such a structure, the end portions of the insulating layer 127 can be formed over substantially flat regions of the EL layer 113R and the EL layer 113G. This makes it relatively easy to form a tapered shape in each of the insulating layer 127, the insulating layer 125, and the mask layer 118. Furthermore, peeling of the conductive layer 111R, the conductive layer 111G, the conductive layer 112R, the conductive layer 112G, the EL layer 113R, and the EL layer 113G can be inhibited. Meanwhile, a portion where the upper surface of the pixel electrode and the insulating layer 127 overlap with each other is preferably smaller because the light-emitting region of the light-emitting element can be wider and the aperture ratio can be higher.

As described above, in each of the structures illustrated in FIG. 5 to FIG. 8, the insulating layer 127, the insulating layer 125, the mask layer 118R, and the mask layer 118G are provided and thus, the common layer 114 and the common electrode 115 can be formed with favorable coverage from the flat or substantially flat region of the EL layer 113R to the flat or substantially flat region of the EL layer 113G. Moreover, formation of a step disconnection portion and a local thinning portion can be inhibited in the common layer 114 and the common electrode 115. This can inhibit the common layer 114 and the common electrode 115 between light-emitting elements 130 from having connection defects due to the disconnected portion and an increased electrical resistance due to the locally thinned portion. Accordingly: the display device 100 can be a display 20) device with high display quality.

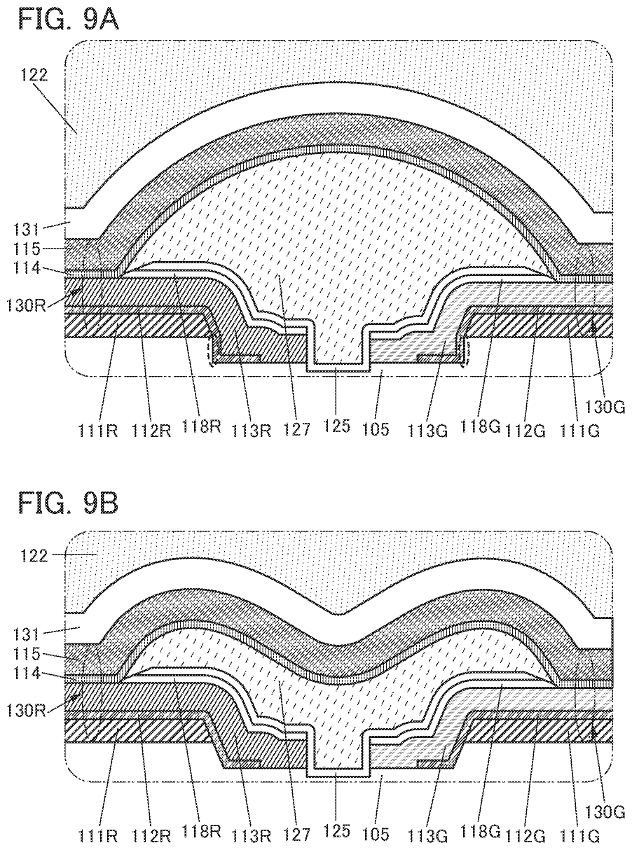

FIG. 9A and FIG. 9B illustrate modification examples of the structure illustrated in FIG. 5A. In the example illustrated in FIG. 9A, a side surface of the insulating layer 105 (a portion surrounded by the dashed line in FIG. 9A) is vertical: specifically, the side surface of the insulating layer 105 at the boundary between a region overlapping with the conductive layer 111 and a region not overlapping with the conductive layer 111 is vertical. In the example illustrated in FIG. 9B, the upper surface of the insulating layer 127 has a depressed portion in the center and its vicinity. i.e., has a concave surface in the cross-sectional view. With the structure where the center portion of the insulating layer 127 has a concave surface, as illustrated in FIG. 9B, stress on the insulating layer 127 can be relieved. Specifically, with the structure where the center portion of the insulating layer 127 has a concave surface, local stress applied to the end portion of the insulating layer 127 can be relieved, thereby inhibiting any one or more of peeling between the EL layer 113R and the mask layer 118R and between the EL layer 113G and the mask layer 118G, peeling between the EL layer 118R and the insulating layer 125 and between the EL layer 118G and the insulating layer 125, and peeling between the insulating layer 125 and the insulating layer 127.

In order to form the structure where the center portion of the insulating layer 127 has a concave surface as illustrated in FIG. 9B, light exposure using a multi-tone mask, typically, a half-tone mask or a gray-tone mask, can be performed. Note that a multi-tone mask is a mask capable of light exposure of three levels to provide an exposed portion, a half-exposed portion, and an unexposed portion, and is a light-exposure mask through which light is transmitted to have a plurality of intensities. The insulating layer 127 including regions with a plurality of (typically two kinds of) thicknesses can be formed with one photomask (one-time light exposure and development process). Alternatively, in order to form the structure where the center portion of the insulating layer 127 has a concave surface, the line width of the mask positioned on the concave surface is made smaller than the line width of the exposed portion, whereby the insulating layer 127 including regions with a plurality of thicknesses can be formed.

Note that a method of forming the structure where the center portion of the insulating layer 127 has a concave surface is not limited to the above. For example, an exposed portion and a half-exposed portion may be formed separately with the use of two photomasks. Alternatively, the viscosity of the resin material used for the insulating layer 127 may be adjusted, specifically to less than or equal to 10 cP, preferably greater than or equal to 1 cP and less than or equal to 5 cP.

Although not illustrated in FIG. 9B, the concave surface in the center portion of the insulating layer 127 is not necessarily continuous and may be disconnected between adjacent light-emitting elements. This leads to the structure where, in the center portion of the insulating layer 127 illustrated in FIG. 9B, part of the insulating layer 127 is eliminated to expose the surface of the insulating layer 125. In the case of the structure, the insulating layer 127 can be shaped so as to be covered with the common layer 114 and the common electrode 115.

### Structure Example 2

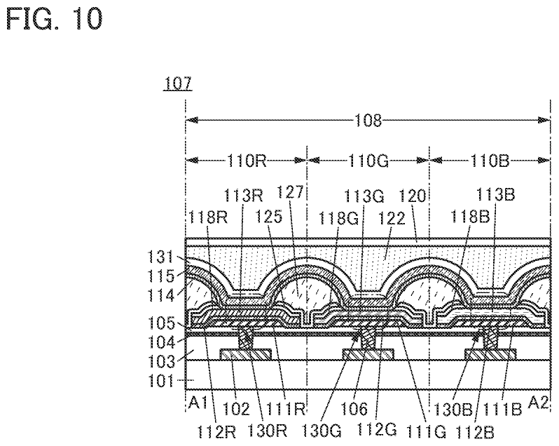

FIG. 10 is a modification example of the structure illustrated in FIG. 2A: in this example, the end portion of the mask layer 118R is aligned or substantially aligned with the end portion of the conductive layer 112R in addition to the end portion of the EL layer 113R. That is, FIG. 10 illustrates an example in which the end portion of the conductive layer 112R is aligned or substantially aligned with the end portion of the EL layer 113R. Similarly, in the example illustrated in FIG. 10, the end portion of the mask layer 118G is aligned or substantially aligned with the end portion of the conductive layer 112G in addition to the end portion of the EL layer 113G, and the end portion of the mask layer 118B is aligned or substantially aligned with the end portion of the conductive layer 112B in addition to the end portion of the EL layer 113B. That is, in the example illustrated in FIG. 10, the end portion of the conductive layer 112G is aligned or substantially aligned with the end portion of the EL layer 113G, and the end portion of the conductive layer 112B is aligned or substantially aligned with the end portion of the EL layer 113B. In the example illustrated in FIG. 10, the insulating layer 125 includes regions in contact with the side surface of the conductive layer 112R, the side surface of the conductive layer 112G, and the side surface of the conductive layer 112B, in addition to the side surface of the EL layer 113R, the side surface of the EL layer 113G, and the side surface of the EL layer 113B.

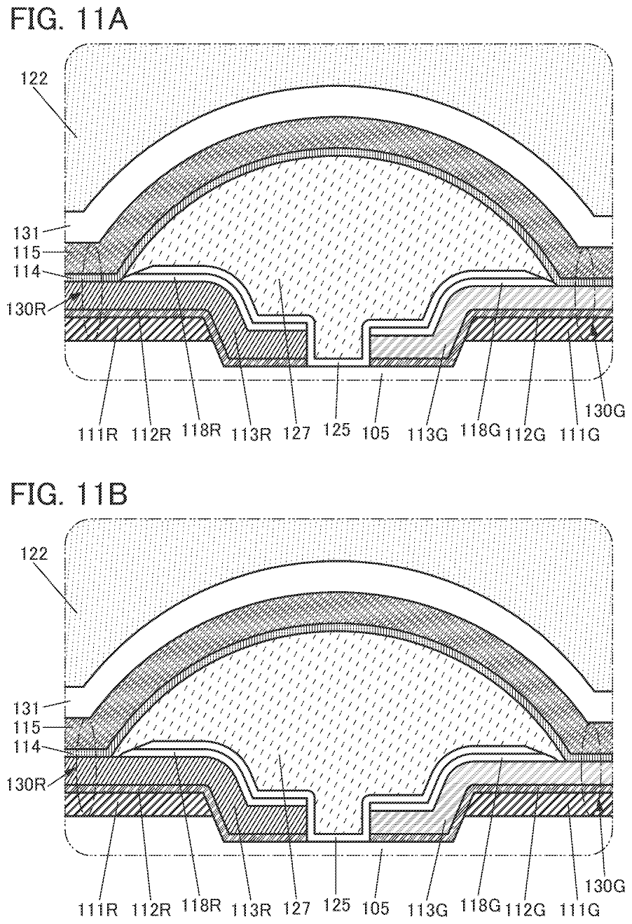

FIG. 11A is an enlarged cross-sectional view of a region of the insulating layer 127 between the EL layer 113R and the EL layer 113G and its periphery in the structure illustrated in FIG. 10, which is a modification example of the structure illustrated in FIG. 5A. In the example illustrated in FIG. 11A, the EL layer 113R is provided over the conductive layer 112R, and the EL layer 113G is provided over the conductive layer 112G.

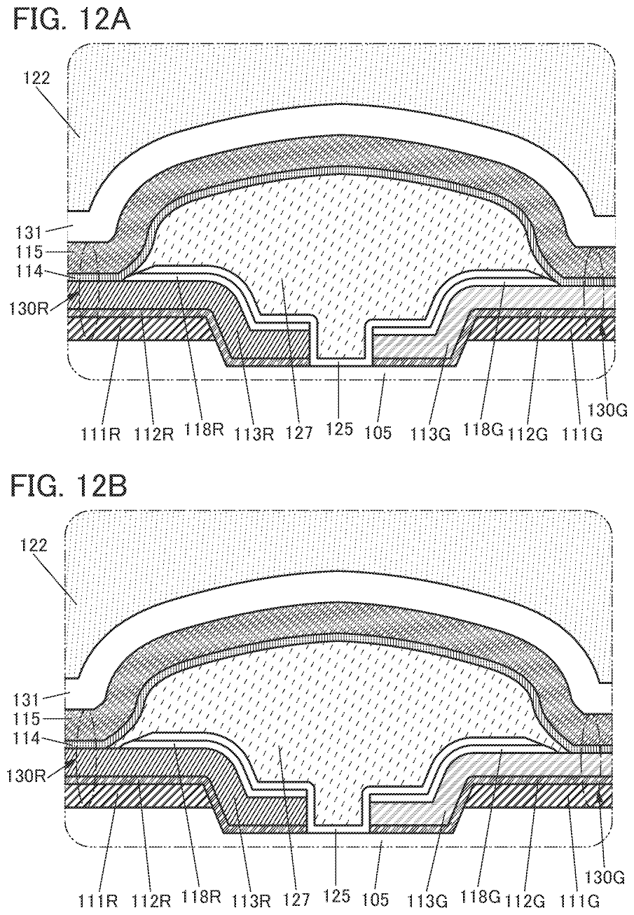

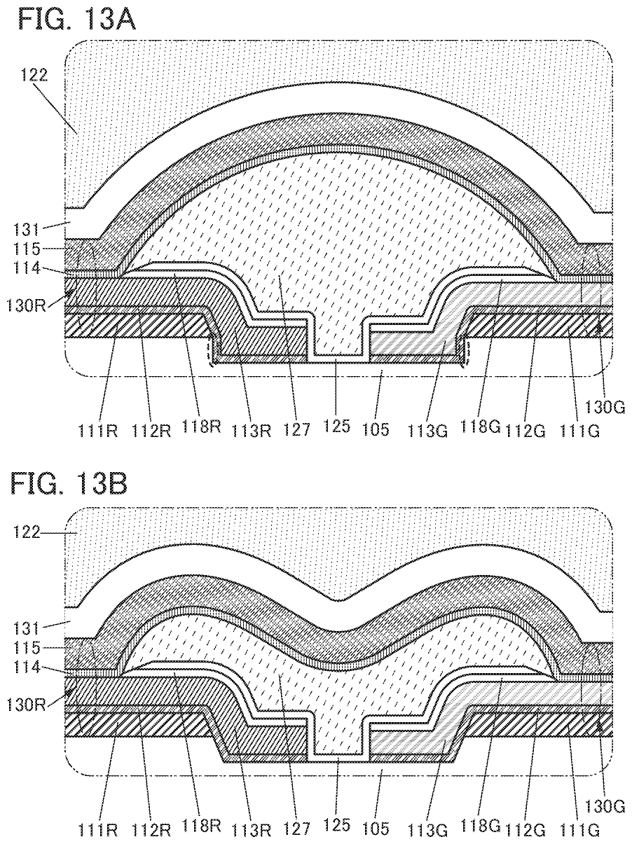

FIG. 11B, FIG. 12A, FIG. 12B, FIG. 13A, and FIG. 13B illustrate modification examples of the structures illustrated in FIG. 6A, FIG. 7A, FIG. 8A, FIG. 9A, and FIG. 9B, respectively, and each employ the structure illustrated in FIG. 10.

### Structure Example 3

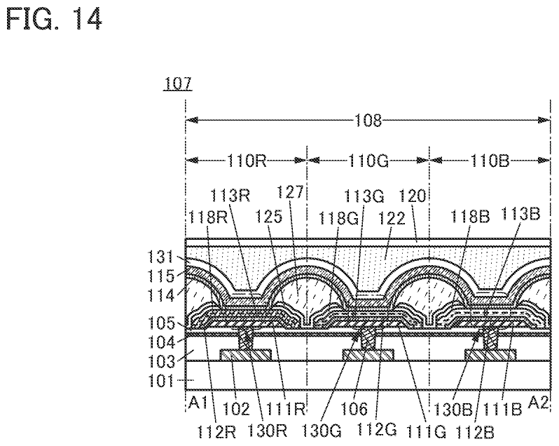

FIG. 14 is a modification example of the structure illustrated in FIG. 2A: in this example, the light-emitting element 130 employs a tandem structure (a structure including a plurality of light-emitting units). The light-emitting unit includes at least one light-emitting layer. A charge-generation layer is preferably provided between light-emitting units.

FIG. 14 illustrates a structure example of the light-emitting element 130 employing a two-unit tandem structure in which two light-emitting units are stacked. In FIG. 14, the dashed line in the EL layer 113 indicates the charge-generation layer. Note that also in the following diagrams, the charge-generation layer included in the EL layer 113 is sometimes indicated by a dashed line.

In the example illustrated in FIG. 14, the EL layer 113 includes a first light-emitting unit below the charge-generation layer and a second light-emitting unit above the charge-generation layer. When the light-emitting element 130 has a tandem structure, the current efficiency for light emission can be increased, so that the light emission efficiency of the light-emitting element 130 can be increased. Alternatively, the density of current flowing through the light-emitting element 130 can be reduced at the same luminance; thus, power consumption of the display device 100 including the light-emitting element 130 can be reduced. When the light-emitting element 130 has a tandem structure, the reliability of the light-emitting element 130 can be increased. Note that the light-emitting element 130 may employ a tandem structure with three units or more. For example, in the case where the light-emitting element 130 has a three-unit tandem structure, the EL layer 113 can have a structure in which a first light-emitting unit, a first charge-generation layer, a second light-emitting unit, a second charge-generation layer, and a third light-emitting unit are stacked in this order from the bottom.

As described above, each of the EL layer 113R, the EL layer 113G, and the EL layer 113B includes at least a light-emitting layer. For example, the first light-emitting unit and the second light-emitting unit included in the EL layer 113R each include a light-emitting layer that emits red light. The first light-emitting unit and the second light-emitting unit included in the EL layer 113G each include a light-emitting layer that emits green light. For example, the first light-emitting unit and the second light-emitting unit included in the EL layer 113B each include a light-emitting layer that emits blue light.

The light-emitting units included in the EL layer 113R, the EL layer 113G, and the EL layer 113B may each include one or more of a hole-injection layer, a hole-transport layer, a hole-blocking layer, an electron-blocking laver, an electron-transport layer, and an electron-injection layer.

In the pixel 108 illustrated in FIG. 14, in the case where the pixel electrode of the light-emitting element 130 functions as an anode and the common electrode 115 functions as a cathode, for example, the first light-emitting unit included in each of the EL layer 113R, the EL layer 113G, and the EL layer 113B may include a hole-injection layer, a hole-transport layer, a light-emitting layer, and an electron-transport layer in this order. In other words, the first light-emitting unit included in the EL layer 113 can have a structure in which, for example, a first functional layer including a hole-injection layer and a hole-transport layer, a light-emitting layer, and a second functional layer including an electron-transport layer are stacked in order from the bottom. The second light-emitting unit included in each of the EL layer 113R, the EL layer 113G, and the EL layer 113B may include the hole-transport layer, the light-emitting layer, and the electron-transport layer in this order. In other words, the second light-emitting unit included in the EL layer 113 can have a structure in which, for example, a third functional layer including a hole-transport layer, a light-emitting layer, and a fourth functional layer including an electron-transport layer are stacked in order from the bottom.

Here, the first light-emitting unit and the second light-emitting unit may each include the electron-blocking layer between the hole-transport layer and the light-emitting layer. The hole-blocking layer may be provided between the electron-transport layer and the light-emitting layer. The second light-emitting unit may include the electron-injection layer over the electron-transport layer. Note that the first functional layer may be configured to include one of the hole-injection layer and the hole-transport layer and not to include the other.

In the case where the pixel electrode of the light-emitting element 130 functions as a cathode and the common electrode 115 functions as an anode, for example, the first light-emitting unit included in each of the EL layer 113R, the EL layer 113G, and the EL layer 113B may include an electron-injection layer, an electron-transport layer, a light-emitting layer, and a hole-transport layer in this order. In other words, the first light-emitting unit included in the EL layer 113 can have a structure in which, for example, a first functional layer including an electron-injection layer and an electron-transport layer, a light-emitting layer, and a second functional layer including a hole-transport layer are stacked in order from the bottom. The second light-emitting unit included in each of the EL layer 113R, the EL layer 113G, and the EL layer 113B may include the electron-transport layer, the light-emitting layer, and the hole-transport layer in this order. In other words, the second light-emitting unit included in the EL layer 113 can have a structure in which, for example, a third functional layer including an electron-transport layer, a light-emitting layer, and a fourth functional layer including a hole-transport layer are stacked in order from the bottom.

Here, the first light-emitting unit and the second light-emitting unit may each include the hole-blocking layer between the electron-transport layer and the light-emitting layer. The electron-blocking layer may be provided between the hole-transport layer and the light-emitting layer. The second light-emitting unit may include the hole-injection layer over the hole-transport layer. Note that the first functional layer may be configured to include one of the electron-injection layer and the electron-transport layer and not to include the other.

In each of the case where the pixel electrode of the light-emitting element 130 functions as an anode and the case where the pixel electrode of the light-emitting element 130 functions as a cathode, the first light-emitting unit does not necessarily include the second functional layer. Furthermore, the second light-emitting unit does not necessarily include at least one of the third functional layer and the fourth functional layer.

The second light-emitting unit preferably includes a light-emitting layer and a carrier-transport layer over the light-emitting layer. Alternatively, the second light-emitting unit preferably includes a light-emitting layer and a carrier-blocking layer over the light-emitting layer. Alternatively, the second light-emitting unit preferably includes a light-emitting layer, a carrier-blocking layer over the light-emitting layer, and a carrier-transport layer over the carrier-blocking layer. Since the surface of the second light-emitting unit is exposed in the manufacturing process of the display device, providing one or both of the carrier-transport layer and the carrier-blocking layer over the light-emitting layer inhibits the light-emitting layer from being exposed on the outermost surface, so that damage to the light-emitting layer can be reduced. Accordingly, the reliability of the light-emitting element can be improved. Note that in the case where three or more light-emitting units are provided, the uppermost light-emitting unit preferably includes a light-emitting layer and one or both of a carrier-transport layer and a carrier-blocking layer over the light-emitting layer.

As described above, the light-emitting element 130 can have a tandem structure. Embodiment 2 can be referred to for the detailed structure of the light-emitting element 130 having a tandem structure. Furthermore, even when the light-emitting element 130 has either a single structure or a tandem structure, Embodiment 5 can be referred to for the structure and the material of the light-emitting element 130.

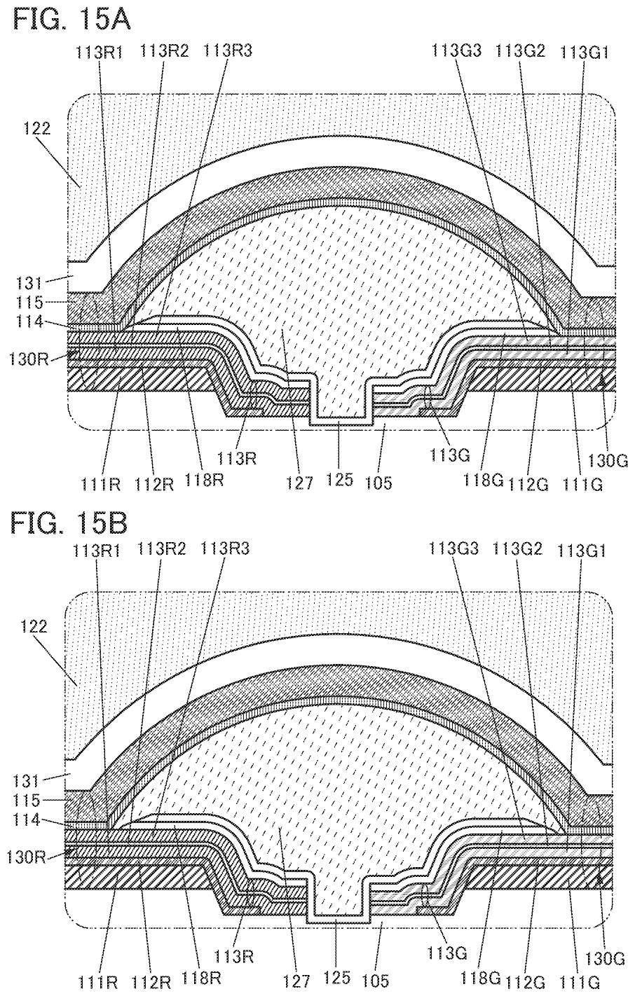

FIG. 15A is an enlarged cross-sectional view of a region of the insulating layer 127 between the EL layer 113R and the EL layer 113G and its periphery in the structure illustrated in FIG. 14, which is a modification example of the structure illustrated in FIG. 5A.

In the example illustrated in FIG. 15A, the EL layer 113R includes a light-emitting unit 113R1, a charge-generation layer 113R2 over the light-emitting unit 113R1, and a light-emitting unit 113R3 over the charge-generation layer 113R2, for example. The EL layer 113G includes a light-emitting unit 113G1, a charge-generation layer 113G2 over the light-emitting unit 113G1, and a light-emitting unit 113G3 over the charge-generation layer 113G2, for example. Here, in FIG. 14, a layer indicated by the dashed line in the EL layer 113R corresponds to the charge-generation layer 113R2 and a layer indicated by the dashed line in the EL layer 113G corresponds to the charge-generation layer 113G2.

In the case where a two-unit tandem structure is employed for the light-emitting element 130R and the light-emitting element 130G, the light-emitting unit 113R1 and the light-emitting unit 113G1 can each be the first light-emitting unit described with reference to FIG. 14, and the light-emitting unit 113R3 and the light-emitting unit 113G3 can each be the second light-emitting unit described with reference to FIG. 14.

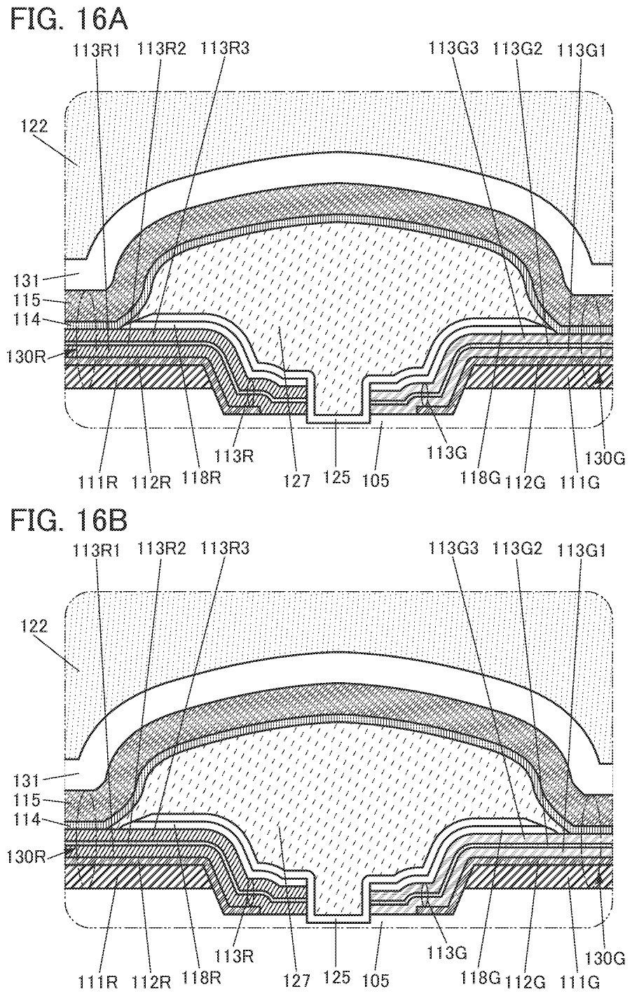

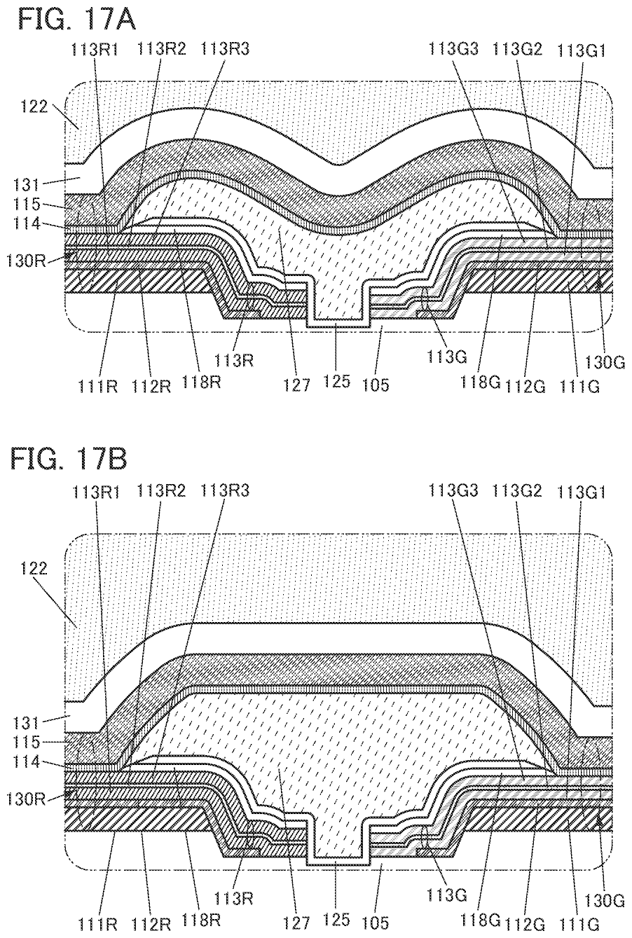

FIG. 15B, FIG. 16A, FIG. 16B, and FIG. 17A illustrate modification examples of the structures illustrated in FIG. 6A, FIG. 7A, FIG. 8A, and FIG. 9B, respectively, and each employ the structure illustrated in FIG. 14. FIG. 17B illustrates a modification example of the structure illustrated in FIG. 15A, and in this example, the upper surface of the insulating layer 127 includes a flat portion in a cross-sectional view.

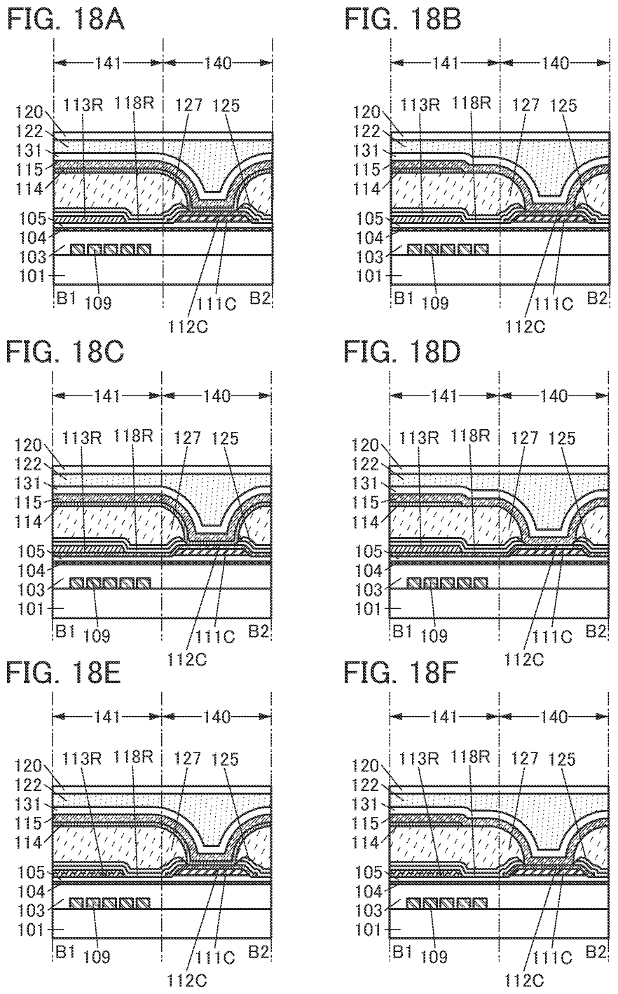

FIG. 18A is a cross-sectional view illustrating a structure example of the region 141 and the connection portion 140. In the region 141, the conductive layer 109 is provided over the insulating layer 101, and the insulating layer 103 is provided over the insulating layer 101 and over the conductive layer 109. The conductive layer 109 can be formed in the same step as the conductive layer 102 illustrated in FIG. 2A and contain the same material as the conductive layer 102.

In the region 141, the EL layer 113R over the insulating layer 105, the mask layer 118R over the insulating layer 105 and over the EL layer 113R, the insulating layer 125 over the mask layer 118R, the insulating layer 127 over the insulating layer 125, the common layer 114 over the insulating layer 127, the common electrode 115 over the common layer 114, the protective layer 131 over the common electrode 115, the resin layer 122 over the protective layer 131, and the substrate 120 over the resin layer 122 are provided. In the region 141, the mask layer 118R is provided so as to cover the end portion of the EL layer 113R, for example. Note that in some cases, depending on the manufacturing process of the display device 100, for example, the EL layer 113G or the EL layer 113B is provided in the region 141 instead of the EL layer 113R. In some cases, the mask layer 118G or the mask layer 118B is provided in the region 141 instead of the mask layer 118R.

The EL layer 113R provided in the region 141 is not electrically connected to the common electrode 115. Accordingly, a structure can be employed in which a voltage is not applied to the EL layer 113R provided in the region 141, which offers a structure in which the EL layer 113R provided in the region 141 does not emit light.

In the display device in which the EL layer 113R and the mask layer 118R are provided in the region 141, it is possible to inhibit the insulating layer 105, the insulating layer 104, and the insulating layer 103 from being partly removed by etching or the like during the manufacturing process of the display device and thus inhibit the conductive layer 109 from being exposed. Hence, the conductive layer 109 can be inhibited from being unintentionally in contact with other electrodes, layers, or the like. For example, a short circuit between the conductive layer 109 and the common electrode 115 can be inhibited. Consequently, the display device 100 can be a highly reliable display device. Moreover, the display device 100 can be manufactured by a method with a high yield.

The connection portion 140 includes the conductive layer 111C over the insulating layer 105, a conductive layer 112C covering the upper surface and the side surface of the conductive layer 111C, the common layer 114 over the conductive layer 112C, the common electrode 115 over the common layer 114, the protective layer 131 over the common electrode 115, the resin layer 122 over the protective layer 131, and the substrate 120 over the resin layer 122. The mask layer 118R is provided so as to cover an end portion of the conductive layer 112C: the insulating layer 125, the insulating layer 127, the common layer 114, the common electrode 115, and the protective layer 131 are stacked in this order over the mask layer 118R. In the case where the mask layer 118G or the mask layer 118B is provided in the region 141 instead of the mask layer 118R, the mask layer 118G or the mask layer 118B is also provided in the connection portion 140 instead of the mask layer 118R.

In the connection portion 140, the conductive layer 111C and the conductive layer 112C are electrically connected to the common electrode 115. The conductive layer 111C and the conductive layer 112C are electrically connected to, for example, an FPC (Flexible Printed Circuit) (not illustrated). Thus, by supplying a power supply potential to the FPC, for example, the common electrode 115 can be supplied with the power supply potential through the conductive layer 111C and the conductive layer 112C.

Here, in the case where the electrical resistance of the common layer 114 in the thickness direction is small enough to be negligible, electrical continuity between the conductive layer 111C, the conductive layer 112C, and the common electrode 115 can be maintained even when the common layer 114 is provided between the conductive layer 112C and the common electrode 115. When the common layer 114 is provided not only in the pixel portion 107 but also in the region 141 and the connection portion 140, the common layer 114 can be formed, for example, without using a metal mask such as a mask for specifying a deposition area (also referred to as an area mask, a rough metal mask, or the like to be distinguished from a fine metal mask). Thus, the manufacturing process of the display device 100 can be simplified.

FIG. 18B illustrates a modification example of the structure illustrated in FIG. 18A, and in this example, the common layer 114 is not provided in the connection portion 140. In the example illustrated in FIG. 18B, the conductive layer 112C and the common electrode 115 can be in contact with each other. Thus, electrical resistance between the conductive layer 112C and the common electrode 115 can be decreased. Although FIG. 18B illustrates a structure where in the region 141, the common layer 114 is provided in a region overlapping with the EL layer 113R and the common layer 114 is not provided in a region not overlapping with the EL layer 113R, one embodiment of the present invention is not limited thereto. For example, in the region 141, it is acceptable that the common layer 114 is not provided in the region overlapping with the EL layer 113R, or the common layer 114 is provided in the region not overlapping with the EL layer 113R.

FIG. 18C and FIG. 18D illustrate modification examples of the structures illustrated in FIG. 18A and FIG. 18B, and in the examples, the conductive layer 112C is provided not only in the connection portion 140 but also in the region 141. In the examples illustrated in FIG. 18C and FIG. 18D, in the region 141, the conductive layer 112C is provided over the insulating layer 105, the EL layer 113R is provided over the conductive layer 112C, and the mask layer 118R is provided over the conductive layer 112C and the EL layer 113R. In the connection portion 140, the mask layer 118R is provided over the conductive layer 112C.

FIG. 18E and FIG. 18F illustrate modification examples of the structures illustrated in FIG. 18A and FIG. 18B, respectively, and in the examples, the EL layer 113R employs a tandem structure.

### Structure Example 4

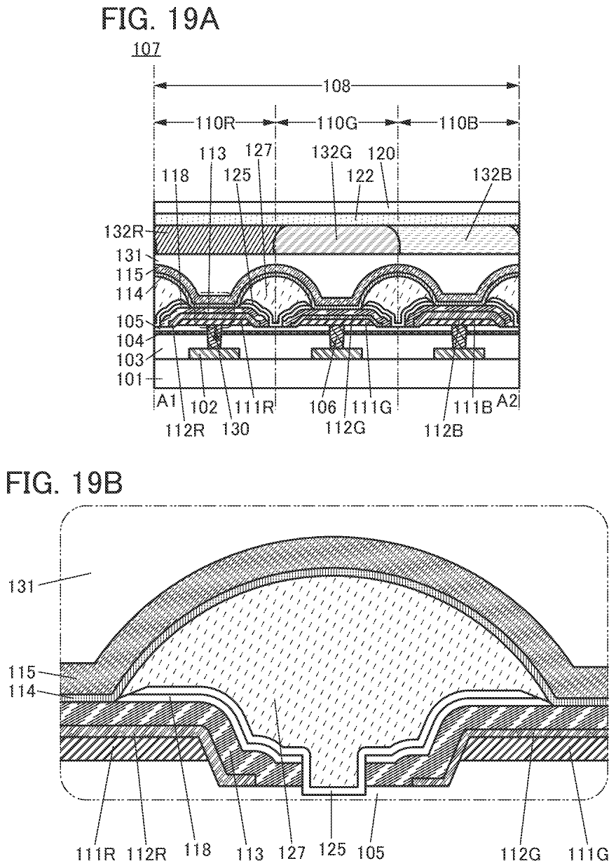

FIG. 19A illustrates a modification example of the structure illustrated in FIG. 2A, and in this example, the subpixel 110R includes a coloring layer 132R, the subpixel 110G includes a coloring layer 132G, and the subpixel 110B includes a coloring layer 132B.

As illustrated in FIG. 19A, the coloring layer 132R, the coloring layer 132G, and the coloring layer 132B can be provided over the protective layer 131. In this case, the protective layer 131 is preferably planarized but is not necessarily planarized.

In the example illustrated in FIG. 19A, the light-emitting element 130 included in the subpixel 110R, the light-emitting element 130 included in the subpixel 110G, and the light-emitting element 130 included in the subpixel 110B can emit light of the same color, e.g., white light. In this case, for example, when the coloring layer 132R transmits red light, the coloring layer 132G transmits green light, and the coloring layer 132B transmits blue light, the display device 100 having the structure illustrated in FIG. 19A can perform full-color display. Note that the coloring layer 132R, the coloring layer 132G, or the coloring layer 132B may have a function of transmitting cyan light, magenta light, yellow light, white light, infrared light, or the like. The light-emitting element 130 may emit infrared light, for example.

Since the EL layers 113 do not have to be formed separately for different emission colors in the display device 100 having the structure illustrated in FIG. 19A, the manufacturing process of the display device 100 can be simplified. Consequently, the manufacturing cost of the display device 100 can be reduced, whereby the display device 100 can be an inexpensive display device.

The adjacent coloring layers 132 include an overlap region over the insulating layer 127. For example, in the cross section illustrated in FIG. 19A, one end portion of the coloring layer 132G overlaps with the coloring layer 132R, and the other end portion of the coloring layer 132G overlaps with the coloring layer 132B. This can inhibit leakage of light from the light-emitting element 130 to the adjacent subpixels 110. Thus, for example, light emitted from the light-emitting element 130 provided in the subpixel 110G can be inhibited from entering the coloring layer 132R and the coloring layer 132B. Consequently, the display device 100 can be a display device with high display quality.

FIG. 19B is a cross-sectional enlarged view of a region including the insulating layer 127 between the two EL layer 113 in FIG. 19A and the vicinity thereof. Note that FIG. 19B illustrates the conductive layer 112R and the conductive layer 112G as the conductive layer 112. The shapes of the mask layer 118, the insulating layer 125, the insulating layer 127, and the like illustrated in FIG. 19B are similar to those in FIG. 5A.

As illustrated in FIG. 19A and FIG. 19B, the conductive layer 112R, the conductive layer 112G, and the conductive layer 1112B can differ from each other in thickness. For example, the thickness is preferably set in accordance with the optical path length that intensifies light of the color transmitted through the coloring layer 132. For example, in the case where the coloring layer 132R transmits red light, the thickness of the conductive layer 112R is preferably set to intensify red light: in the case where the coloring layer 132G transmits green light, the thickness of the conductive layer 112G is preferably set to intensify green light: in the case where the coloring layer 132B transmits blue light, the thickness of the conductive layer 112B is preferably set to intensify blue light. Thus, a microcavity structure is achieved, and the color purity of light emitted from the subpixels 110 can be increased. Note that the conductive layer 112R, the conductive layer 112G, and the conductive layer 1112B may differ from each other in thickness also in the structure illustrated in FIG. 2A, for example. In that case, a microcavity structure can be achieved even when the EL layer 113R, the EL layer 113G, and the EL layer 113B have the same thickness.

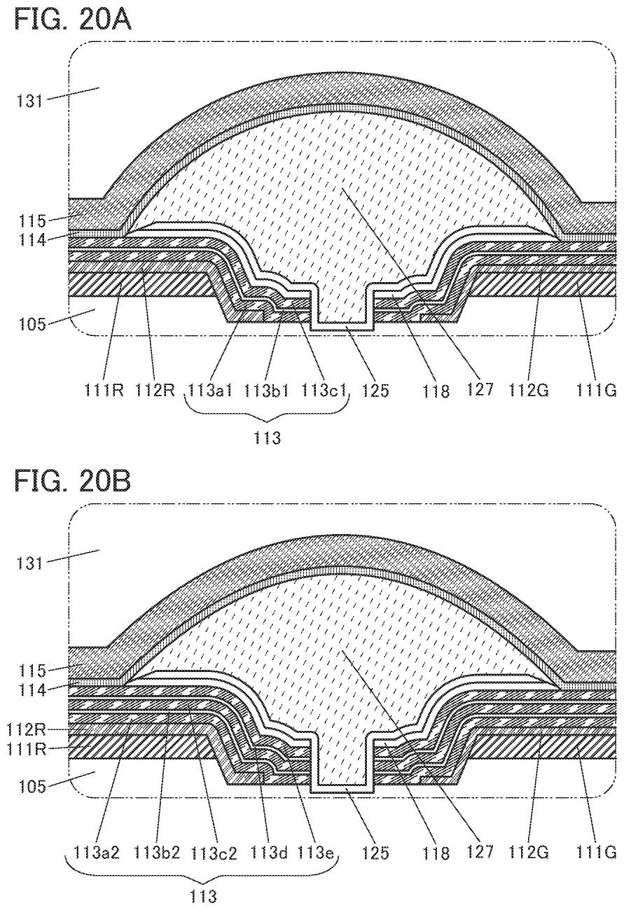

Although the light-emitting element 130 has a single structure in FIG. 19B, the light-emitting element 130 may have a tandem structure. FIG. 20A illustrates an example in which the EL layer 113 includes a light-emitting unit 113al, a charge-generation layer 113b1 over the light-emitting unit 113al, and a light-emitting unit 113c1 over the charge-generation layer 113bl. The light-emitting element 130 including the EL layer 113 illustrated in FIG. 20A has a two-unit tandem structure. When the light-emitting element 130 has a tandem structure, the current efficiency for light emission can be increased, so that the light emission efficiency of the light-emitting element 130 can be increased. Alternatively, the density of current flowing through the light-emitting element 130 can be reduced at the same luminance: thus, power consumption of the display device 100 including the light-emitting element 130 can be reduced. When the light-emitting element 130 has a tandem structure, the reliability of the light-emitting element 130 can be increased.

The light-emitting unit 113a1 and the light-emitting unit 113c1 each include at least one light-emitting layer. The color of light emitted from the light-emitting unit 113a1 can be different from the color of light emitted from the light-emitting unit 113cl.

In this specification and the like, light emitted from a light-emitting layer included in a light-emitting unit is referred to as light emitted from the light-emitting unit.

The color of light emitted from the light-emitting layer included in the light-emitting unit 113a1 and the color of light emitted from the light-emitting layer included in the light-emitting unit 113c1 can be complementary colors, for example. For example, one of the light-emitting unit 113a1 and the light-emitting unit 113c1 can emit blue light and the other of the light-emitting unit 113a1 and the light-emitting unit 113c1 can emit yellow light. For example, one of the light-emitting unit 113a1 and the light-emitting unit 113c1 can be emit blue light and the other of the light-emitting unit 113a1 and the light-emitting unit 113c1 can emit red light and green light. For example, when the pixel electrode of the light-emitting element 130 functions as the anode and the common electrode 115 functions as the cathode, the light-emitting unit 113a1 can emit blue light. In that case, the light-emitting element 130 as a whole can emit white light.

The light-emitting unit 113a1 and the light-emitting unit 113c1 may each include one or more of a hole-injection layer, a hole-transport layer, a hole-blocking layer, an electron-blocking layer, an electron-transport layer, and an electron-injection layer in addition to the light-emitting layer. That is, the light-emitting unit 113a1 and the light-emitting unit 113c1 may each include a functional layer. A structure similar to the above can be employed for a light-emitting unit other than the light-emitting unit 113a1 and the light-emitting unit 113c1.

For example, in the case where the pixel electrode of the light-emitting element 130 functions as an anode and the common electrode 115 functions as a cathode, the light-emitting unit 113a1 can have a structure in which the first functional layer including the hole-injection layer and the hole-transport layer, the light-emitting layer, and the second functional layer including the electron-transport layer are stacked in this order from the bottom. Furthermore, the light-emitting unit 113c1 may include a hole-transport layer, the light-emitting layer, and an electron-transport layer in this order. In other words, the light-emitting unit 113c1 can have a structure in which, for example, the third functional layer including the hole-transport layer, the light-emitting layer, and the fourth functional layer including the electron-transport layer are stacked in order from the bottom.

Here, the light-emitting unit 113a1 and the light-emitting unit 113c1 may each include the electron-blocking layer between the hole-transport layer and the light-emitting layer. In addition, the hole-blocking layer may be provided between the electron-transport layer and the light-emitting layer. The light-emitting unit 113c1 may include the electron-injection layer between the electron-transport layer and the common electrode 115. Note that the first functional layer may be configured to include one of the hole-injection layer and the hole-transport layer and not to include the other.

For example, in the case where the pixel electrode of the light-emitting element 130 functions as a cathode and the common electrode 115 functions as an anode, the light-emitting unit 113a1 can have a structure in which the first functional layer including the electron-injection layer and the electron-transport layer, the light-emitting layer, and the second functional layer including the hole-transport layer are stacked in this order from the bottom. Furthermore, the light-emitting unit 113c1 may include an electron-transport layer, the light-emitting layer, and a hole-transport layer in this order. In other words, the light-emitting unit 113c1 can have a structure in which, for example, the third functional layer including the electron-transport layer, the light-emitting laver, and the fourth functional layer including the hole-transport layer are stacked in order from the bottom.

Here, the light-emitting unit 113a1 and the light-emitting unit 113c1 may each include the hole-blocking layer between the electron-transport layer and the light-emitting layer. In addition, the electron-blocking layer may be provided between the hole-transport layer and the light-emitting layer. The light-emitting unit 113c1 may include the hole-injection layer between the hole-transport layer and the common electrode 115. Note that the first functional layer may be configured to include one of the electron-injection layer and the electron-transport layer and not to include the other.

In each of the case where the pixel electrode of the light-emitting element 130 functions as an anode and the case where the pixel electrode of the light-emitting element 130 functions as a cathode, the light-emitting unit 113a1 does not necessarily include the second functional layer. Furthermore, the light-emitting unit 113c1 does not necessarily include at least one of the third functional layer and the fourth functional layer.

The charge-generation layer 113b1 includes at least a charge-generation region. The charge-generation layer 113b1 has a function of injecting electrons into one of the light-emitting unit 113a1 and the light-emitting unit 113c1 and a function of injecting holes into the other of the light-emitting unit 113a1 and the light-emitting unit 113c1 when voltage is applied between the pixel electrode of the light-emitting element 130 and the common electrode 115.

FIG. 20B illustrates an example in which the EL layer 113 includes a light-emitting unit 113a2, a charge-generation layer 113b2 over the light-emitting unit 113a2, a light-emitting unit 113c2 over the charge-generation layer 113b2, a charge-generation layer 113d over the light-emitting unit 113c2, and a light-emitting unit 113e over the charge-generation layer 113d. The light-emitting element 130 including the EL layer 113 illustrated in FIG. 20B has a three-unit tandem structure. By increasing the number of units in the tandem structure, the current efficiency of the light-emitting element 130 for light emission can be favorably increased, so that the light emission efficiency of the light-emitting element 130 can be favorably increased. Alternatively, the density of current flowing through the light-emitting element 130 can be favorably reduced at the same luminance: thus, power consumption of the display device 100 including the light-emitting element 130 can be favorably reduced. Thus, the reliability of the light-emitting element 130 can be suitably increased. Note that the light-emitting element 130 may have a tandem structure with four or more units.

The light-emitting unit 113a2, the light-emitting unit 113c2, and the light-emitting unit 113e each include at least one light-emitting layer. The color of light emitted from at least one of the light-emitting unit 113a2, the light-emitting unit 113c2, and the light-emitting unit 113e can differ from the color(s) of light emitted from the other light-emitting unit(s). For example, the color of light emitted from at least one of the light-emitting unit 113a2, the light-emitting unit 113c2, and the light-emitting unit 113e can be complementary to the color of light emitted from the other light-emitting unit(s).

For example, the light-emitting unit 113a2 and the light-emitting unit 113e can emit blue light, and the light-emitting unit 113c2 can emit yellow, yellow green, or green light. As another example, the light-emitting unit 113a2 and the light-emitting unit 113e can emit blue light, and the light-emitting unit 113c2 can emit red light, green light, and yellow green light. Thus, the light-emitting element 130 as a whole can emit white light.

The charge-generation layer 113b2 and the charge-generation layer 113d each include at least a charge-generation region. The charge-generation layer 113b2 has a function of injecting electrons into one of the light-emitting unit 113a2 and the light-emitting unit 113c2 and a function of injecting holes into the other of the light-emitting unit 113a2 and the light-emitting unit 113c2 when voltage is applied between the pixel electrode of the light-emitting element 130 and the common electrode 115. The charge-generation layer 113d has a function of injecting electrons into one of the light-emitting unit 113c2 and the light-emitting unit 113e and a function of injecting holes into the other of the light-emitting unit 113c2 and the light-emitting unit 113e when voltage is applied between the pixel electrode of the light-emitting element 130 and the common electrode 115.

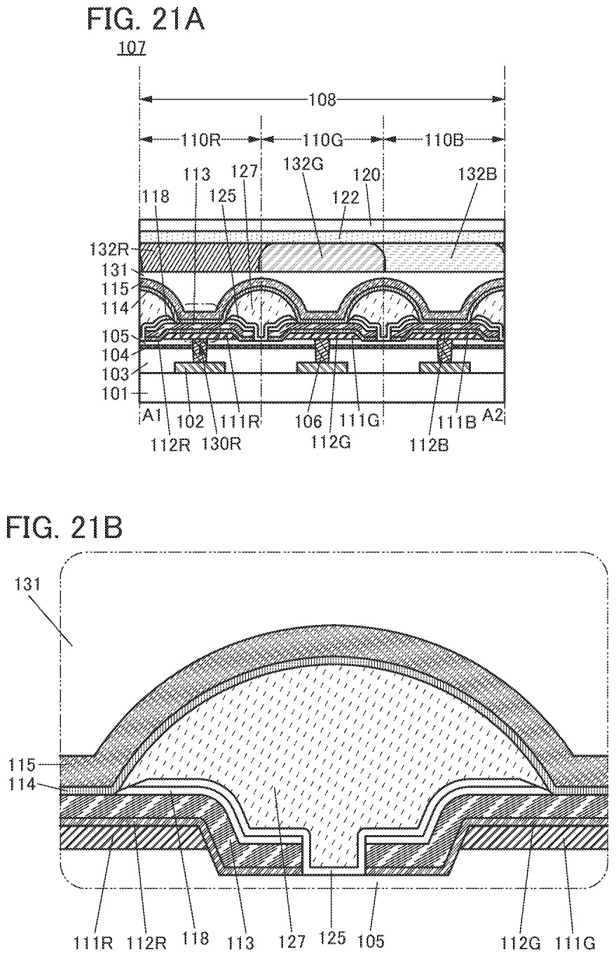

FIG. 21A illustrates a modification example of the structure illustrated in FIG. 10, and in this example, the subpixel 110R includes the coloring layer 132R, the subpixel 110G includes the coloring layer 132G, and the subpixel 110B includes the coloring layer 132B. That is, FIG. 21A illustrates an example in which the structure example illustrated in FIG. 10 and the structure example illustrated in FIG. 19A are combined.

FIG. 21B is a cross-sectional enlarged view of a region including the insulating layer 127 between the two EL layer 113 in FIG. 21A and the vicinity thereof. Note that FIG. 21B illustrates the conductive layer 112R and the conductive layer 112G as the conductive layer 112. The shapes of the mask layer 118, the insulating layer 125, the insulating layer 127, and the like illustrated in FIG. 21B are similar to those in FIG. 11A.

In the display device of one embodiment of the present invention, the island-shaped EL layer is provided in each light-emitting element, whereby generation of lateral leakage current between the subpixels can be inhibited. This can inhibit crosstalk due to unintended light emission, so that a display device with extremely high contrast can be obtained. The insulating layer that has an end portion with a tapered shape and is provided between adjacent island-shaped EL layers can inhibit formation of step disconnection and a locally thinned portion in the common electrode at the time of forming the common electrode. This can inhibit the common layer and the common electrode from having connection defects due to the disconnected portion and an increased electrical resistance due to the locally thinned portion. Consequently, the display device of one embodiment of the present invention achieves both high resolution and high display quality.

Next, the light-emitting region of the display device of one embodiment of the present invention is described with reference to drawings.

### Structure Example 5

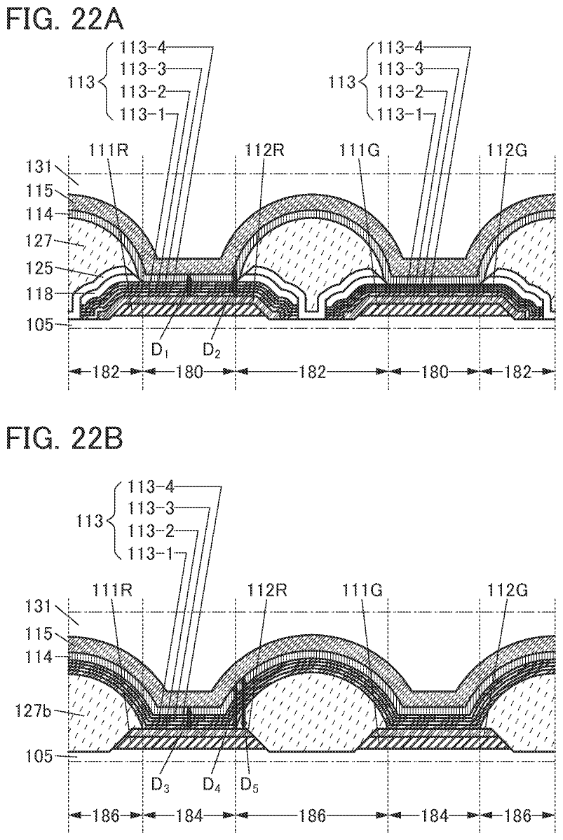

FIG. 22A illustrates a modification example of the structure illustrated in FIG. 19A. Note that FIG. 22A is a cross-sectional view in which, for example, the microcavity structure described above is omitted and the vicinity of the subpixel 110R and the subpixel 110G illustrated in FIG. 19A is enlarged. FIG. 22B is a reference view of a cross-section illustrating the light-emitting region of the display device. Note that in FIG. 22A and FIG. 22B, the coloring layer 132, the plug 106, and the like are not illustrated.

FIG. 22A illustrates a region 180 and a region 182 in addition to the structure described with reference to FIG. 19A, in order to explain the light-emitting region of the display device. The region 180 functions as the light-emitting region of the display device, and the region 182 functions as a non-light-emitting region of the display device.

In the light-emitting region of the display device, the EL layer is provided between a pair of electrodes (also referred to as between upper and lower electrodes or between an anode and a cathode). The EL layer includes the common layer 114 in addition to the island-shaped EL layer 113. In the structure illustrated as an example in FIG. 22A, the EL layer 113 includes a hole-injection layer 113-1, a hole-transport layer 113-2, a light-emitting layer 113-3, and an electron-transport layer 113-4. In FIG. 22A, the common layer 114 functions as the electron-injection layer.

FIG. 22B is a cross-sectional view illustrating one embodiment of the display device. The display device illustrated in FIG. 22B includes the insulating layer 105, the conductive layer 111R over the insulating layer 105, the conductive layer 111G over the insulating layer 105, the conductive layer 112R over the conductive layer 111R, the conductive layer 112G over the conductive layer 111G, an insulating layer 127b in contact with the insulating layer 105, the conductive layer 111R, the conductive layer 111G, the conductive layer 112R, and the conductive layer 112G, the EL layer 113 in contact with the insulating layer 127b, the conductive layer 112R, and the conductive layer 112G, the common layer 114 over the EL layer 113, the common electrode 115 over the common layer 114, and the protective layer 131 over the common electrode 115.

In the light-emitting region of the display device illustrated in FIG. 22B, the EL layer 113 and the common layer 114 are provided as the EL layer between the pair of electrodes. Unlike in FIG. 22A, the EL layer 113 illustrated in FIG. 22B is a continuous film shared by a plurality of light-emitting elements. In the structure illustrated as an example in FIG. 22B, the EL layer 113 includes the hole-injection layer 113-1, the hole-transport layer 113-2, the light-emitting layer 113-3, and the electron-transport layer 113-4. In FIG. 22B, the common layer 114 functions as the electron-injection layer.

In FIG. 22B, the insulating layer 127b is provided to cover the side surface of the conductive layer 111R, the side surface of the conductive layer 111G, the side surface and part of the upper surface of the conductive layer 112R, and the side surface and part of the upper surface of the conductive layer 112G. In this manner, the insulating layer 127b functions as a structure body (also referred to as a bank) that covers the side surface of the conductive layer and part of the upper surface of the conductive layer. That is, the insulating layer 127b is provided to include a region in contact with the conductive layer 111R, the conductive layer 111G, the conductive layer 112R, and the conductive layer 112G.

FIG. 22B illustrates a region 184 and a region 186. The region 184 functions as the light-emitting region of the display device, and the region 186 functions as the non-light-emitting region of the display device.

As illustrated in FIG. 22A, in the display device of one embodiment of the present invention, the island-shaped EL layer 113 (here, the hole-injection layer 113-1, the hole-transport layer 113-2, the light-emitting layer 113-3, and the electron-transport layer 113-4) is provided for each light-emitting element, whereby generation of lateral leakage current between the subpixels can be inhibited. In particular, the island-shaped hole-injection layer 113-1 in the EL layer 113 can suitably reduce lateral leakage current between the subpixels. Since the hole-injection layer 113-1 has higher conductivity than the other layers in the EL layer 113, at least the hole-injection layer 113-1 is preferably divided between adjacent subpixels as illustrated in FIG. 22A.

In the region 180 functioning as the light-emitting region in FIG. 22A, the difference between the distance (denoted as D₁) between the pair of electrodes in the center portion of the EL layer (the EL layer 113 and the common layer 114) and the distance (denoted as D₂) between the pair of electrodes in the end portion of the EL layer (the EL layer 113 and the common layer 114) is preferably small. Specifically, the distance (D₂) between the pair of electrodes in the end portion of the EL layer is preferably less than ±10%, further preferably less than ±3%, of the distance (D₁) between the pair of electrodes in the center portion of the EL layer. Light emission from the light-emitting region can be uniform when the difference between the distance (D₁) between the pair of electrodes in the center portion of the EL layer and the distance (D₂) between the pair of electrodes in the end portion of the EL layer is made small or eliminated.

Meanwhile, in the case where the EL layer 113 is shared by adjacent subpixels, particularly the hole-injection layer 113-1 is shared by adjacent subpixels, as illustrated in FIG. 22B, the region 186 functioning as a non-light-emitting region might partly or wholly emit light. In other words, lateral leakage current might be generated between the adjacent subpixels. Moreover, in the region 184 functioning as a light-emitting region in FIG. 22B, the difference between the distance (denoted as D₃) between the pair of electrodes in the center portion of the EL layer (the EL layer 113 and the common layer 114) and the distance (denoted as D₄) between the pair of electrodes in the end portion of the EL layer (the EL layer 113 and the common layer 114) is larger than the difference between D₁ and D₂ described above.

In FIG. 22B, the distance (denoted as D₅) between the pair of electrodes in the region 186 functioning as a non-light-emitting region is larger than the distance (D₄) between the pair of electrodes in the end portion of the EL layer. Note that the distance (D₅) between the pair of electrodes in the region 186 is the value of the sum of the thickness of the EL layer 113, the thickness of the common layer 114, and the thickness of the end portion of the insulating layer 127b. For example, in the case where the region 186 functioning as a non-light-emitting region partly emits light, light resonates in the distance (D₅) between the pair of electrodes in the region 186, and therefore the distance is different from the distance in which light resonates in the region 184 functioning as a light-emitting region. Thus, in the case where the region 186 emits light, the distance in which light resonates is varied from that in the region 184, and accordingly the region 186 and the region 184 differ in one or more of luminance, chromaticity, and the direction of light emission. In the case where light emission from the region 184 functioning as a light-emitting region and the region 186 functioning as a non-light-emitting region is mixed, the emission spectrum might be broad or have a shape with a plurality of peaks. By contrast, in the structure illustrated in FIG. 22A, the emission spectrum can be inhibited from being broad or from having a shape with a plurality of peaks because of the structure in which light emission from the non-light-emitting region is reduced.

The display device preferably has a structure in which the chromaticity is constant either at high luminance (e.g., 10000 cd/m²) or low luminance (e.g., 100 cd/m²). To achieve this, the structure illustrated in FIG. 22A is more suitable than the structure illustrated in FIG. 22B.

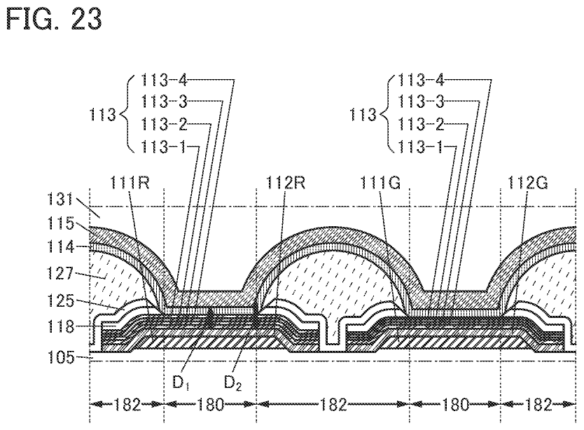

FIG. 23 illustrates a modification example of the structure illustrated in FIG. 21A. Note that FIG. 23 is a cross-sectional view in which, for example, the microcavity structure described above is omitted and the vicinity of the subpixel 110R and the subpixel 110G illustrated in FIG. 21A is enlarged. That is, FIG. 23 illustrates an example in which the structure illustrated in FIG. 21A and the structure illustrated in FIG. 22A are combined.

### Manufacturing Method Example 1

A manufacturing method example of the display device 100 having the structure illustrated in FIG. 2A and the structure illustrated in FIG. 18A will be described below with reference to drawings.

Thin films included in the display device (insulating films, semiconductor films, conductive films, and the like) can be formed by a sputtering method, a chemical vapor deposition (CVD) method, a vacuum evaporation method, a pulsed laser deposition (PLD) method, an ALD method, or the like. Examples of the CVD method include a plasma-enhanced chemical vapor deposition (PECVD) method and a thermal CVD method. As an example of the thermal CVD method, a metal organic chemical vapor deposition (MOCVD) method can be given.

The thin films included in the display device (insulating films, semiconductor films, conductive films, and the like) can be formed by a wet film formation method such as spin coating, dipping, spray coating, inkjetting, dispensing, screen printing, offset printing, a doctor knife method, slit coating, roll coating, curtain coating, or knife coating.

For fabrication of the light-emitting elements, a vacuum process such as an evaporation method or a solution process such as a spin coating method or an inkjet method can be especially used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). In particular, the EL layer can be formed by an evaporation method (e.g., a vacuum evaporation method), a coating method (a dip coating method, a die coating method, a bar coating method, a spin coating method, a spray coating method, or the like), a printing method (an inkjet method, a screen printing (stencil) method, an offset printing (planography) method, a flexography (relief printing) method, a gravure printing method, a micro-contact printing method, or the like), or the like.

Thin films that form the display device can be processed by, for example, a photolithography method. Alternatively, the thin films may be processed by a nanoimprinting method, a sandblasting method, a lift-off method, or the like. An island-shaped thin film may be directly formed by a film formation method using a shielding mask such as a metal mask.

There are the following two typical methods of a photolithography method. In one of the methods, a resist mask is formed over a thin film that is to be processed, the thin film is processed by, for example, etching, and then the resist mask is removed. In the other method, after a photosensitive thin film is formed, light exposure and development are performed, so that the thin film is processed into a desired shape.

For light exposure in a photolithography method, for example, an i-line (with a wavelength of 365 nm), a g-line (with a wavelength of 436 nm), an h-line (with a wavelength of 405 nm), or light in which these lines are mixed can be used. Besides, ultraviolet light, KrF laser light, ArF laser light, or the like can be used. In addition, light exposure may be performed by liquid immersion exposure technique. The light exposure may be performed with the use of extreme ultraviolet (EUV) light or X-rays. Instead of the light used for the light exposure, an electron beam can also be used. It is preferable to use extreme ultraviolet light, X-rays, or an electron beam because extremely minute processing is possible. Note that when light exposure is performed by scanning of a beam such as an electron beam, a photomask is not needed.

For etching of the thin films, a dry etching method, a wet etching method, a sandblasting method, or the like can be used.

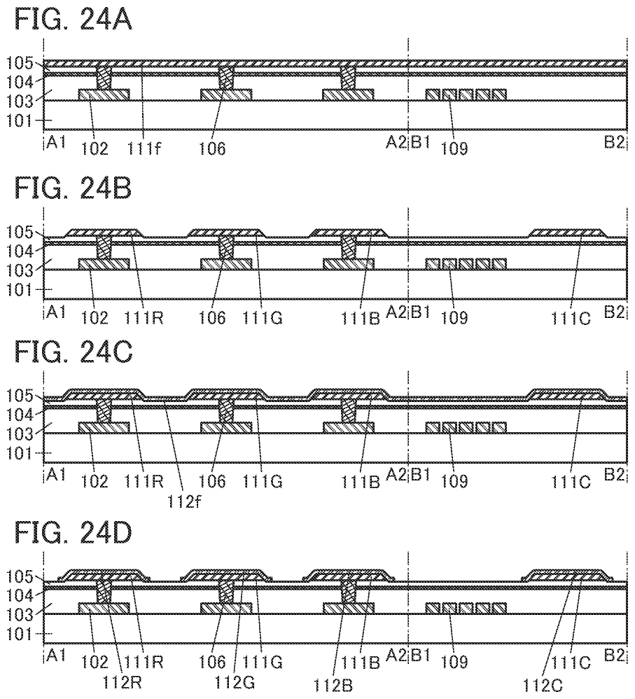

To manufacture the display device 100 having the structure illustrated in FIG. 2A and the structure illustrated in FIG. 18A, first, the insulating layer 101 is formed over a substrate (not illustrated), as illustrated in FIG. 24A. Next, the conductive layer 102 and the conductive layer 109 are formed over the insulating layer 101, and the insulating layer 103 is formed over the insulating layer 101 so as to cover the conductive layer 102 and the conductive layer 109. Then, the insulating layer 104 is formed over the insulating layer 103, and the insulating layer 105 is formed over the insulating layer 104.

As the substrate, a substrate having at least heat resistance high enough to withstand heat treatment performed later can be used. In the case where an insulating substrate is used as the substrate, a glass substrate, a quartz substrate, a sapphire substrate, a ceramic substrate, an organic resin substrate, or the like can be used. Alternatively, it is possible to use a semiconductor substrate such as a single crystal semiconductor substrate or a polycrystalline semiconductor substrate of silicon, silicon carbide, or the like, a compound semiconductor substrate of silicon germanium or the like, or an SOI substrate.

Note that FIG. 24A illustrates a cross-sectional view along the line A1-A2 and a cross-sectional view along the line B1-B2 side by side. The same applies to the diagrams illustrating the manufacturing method example of the display device in the following description.

Next, openings reaching the conductive layer 102 are formed in the insulating layer 105, the insulating layer 104, and the insulating layer 103, as illustrated in FIG. 24A. Then, the plugs 106 are formed to fill the openings.

Next, a conductive film 111f to be the conductive layer 111R, the conductive layer 111G, the conductive layer 111B, and the conductive layer 111C later is formed over the plugs 106 and over the insulating layer 105, as illustrated in FIG. 24A. For formation of the conductive film 111f, a sputtering method or a vacuum evaporation method can be used, for example. A metal material can be used for the conductive film 111f, for example.

The conductive film 111f can have a three-layer structure in which a film to be the conductive layer 111a later, a film to be the conductive layer 111b later, and a film to be the conductive layer 111c later are stacked in this order from the bottom. Alternatively, the conductive film 111f can have a two-layer structure in which the film to be the conductive layer 111a later and the film to be the conductive layer 111b later are stacked in this order from the bottom. For example, titanium can be used for the film to be the conductive layer 111a, aluminum can be used for the film to be the conductive layer 111b, and titanium can be used for the film to be the conductive layer 111c. Alternatively, the conductive film 111f can have a single-layer structure.

Then, as illustrated in FIG. 24B, the conductive film 111f is processed by a photolithography method, for example, so that the conductive layer 111R, the conductive layer 111G, the conductive layer 111B, and the conductive layer 111C are formed. Specifically, the conductive film 111f is partly removed by an etching method after a resist mask is formed, for example. In the case where a metal material is used for the conductive film 111f, the conductive film 111f can be removed by a dry etching method, for example. Here, in the case where part of the conductive film 111f is removed by a dry etching method, for example, a depressed portion may be formed in a region of the insulating layer 105 that does not overlap with the conductive layer 111.

As illustrated in FIG. 2B1, FIG. 2B2, and FIG. 4C, the conductive layer 111R, the conductive layer 111G, the conductive layer 111B, and the conductive layer 111C can each have a three-layer structure in which the conductive layer 111a, the conductive layer 111b over the conductive layer 111a, and the conductive layer 111c over the conductive layer 111b are stacked. As illustrated in FIG. 3A, FIG. 3B, and FIG. 4B, the conductive layer 111R, the conductive layer 111G, the conductive layer 111B, and the conductive layer 111C can each have a two-layer structure in which the conductive layer 111a and the conductive layer 111b over the conductive layer 111a are stacked. As illustrated in FIG. 4A, the conductive layer 111R, the conductive layer 111G, the conductive layer 111B, and the conductive layer 111C can each have a single-layer structure.

Next, as illustrated in FIG. 24C, a conductive film 112f to be the conductive layer 112R, the conductive layer 112G, the conductive layer 112B, and the conductive layer 112C later is formed over the conductive layer 111R, over the conductive layer 111G, over the conductive layer 111B, over the conductive layer 111C, and over the insulating layer 105. The conductive film 112f can be formed by a sputtering method or a vacuum evaporation method, for example.

In the case where the conductive layer 112 having the structure illustrated in FIG. 2B1 and FIG. 3A is formed, a conductive oxide, for example, can be used for the conductive film 112f. In the case where the conductive layer 112 having the structure illustrated in FIG. 2B2 and FIG. 3B is formed, the conductive film 112f can have a two-layer structure in which a film to be the conductive layer 112a later and a film to be the conductive layer 112b later are stacked in this order from the bottom. A metal material such as titanium, silver, or an alloy containing silver can be used for the film to be the conductive layer 112a and a conductive oxide can be used for the film to be the conductive layer 112b, for example. In the case where the conductive layer 112 having the structure illustrated in FIG. 4A, FIG. 4B, and FIG. 4C is formed, the conductive film 112f can have a three-layer structure in which the film to be the conductive layer 112a later, the film to be the conductive layer 112b later, and a film to be the conductive layer 112c later are stacked in this order from the bottom. A conductive oxide can be used for the film to be the conductive layer 112a, silver or an alloy containing silver can be used for the film to be the conductive layer 112b, and a conductive oxide can be used for the film to be the conductive layer 112c, for example.

The conductive film 112f can be formed by an ALD method. For the conductive film 112f, an oxide containing one or more selected from indium, tin, zinc, gallium, titanium, aluminum, and silicon can be used. In this case, the conductive film 112f can be formed by repeating a cycle of introduction of a precursor (generally referred to as a metal precursor or the like in some cases), purge of the precursor, introduction of an oxidizer (generally referred to as a reactant, a non-metal precursor, or the like in some cases), and purge of the oxidizer. Here, in the case where an oxide film containing a plurality of kinds of metals, such as an indium tin oxide film, is formed as the conductive film 112f, the composition of the metals can be controlled by varying the number of cycles for different kinds of precursors.

For example, in the case where an indium tin oxide film is formed as the conductive film 112f, after a precursor containing indium is introduced, the precursor is purged, and an oxidizer is introduced to form an In—O film, and then a precursor containing tin is introduced, the precursor is purged, and an oxidizer is introduced to form a Sn—O film. Here, when the number of cycles of forming an In—O film is larger than the number of cycles of forming a Sn—O film, the number of In atoms contained in the conductive film 112f can be larger than the number of Sn atoms contained therein.

For example, to form a zinc oxide film as the conductive film 112f, a Zn—O film is formed in the above procedure. For example, to form an aluminum zinc oxide film as the conductive film 112f, a Zn—O film and an Al—O film are formed in the above procedure. For example, to form a titanium oxide film as the conductive film 112f, a Ti—O film is formed in the above procedure. For example, to form an indium tin oxide film containing silicon as the conductive film 112f, an In—O film, a Sn—O film, and a Si—O film are formed in the above procedure. For example, to form a zinc oxide film containing gallium as the conductive film 112f, a Ga—O film and a Zn—O film are formed in the above procedure.

As a precursor containing indium, it is possible to use, for example, triethylindium, trimethylindium, or [1,1,1-trimethyl-N-(trimethylsilyl)amide]-indium. As a precursor containing tin, it is possible to use, for example, tin chloride or tetrakis(dimethylamido) tin. As a precursor containing zinc, it is possible to use, for example, diethylzinc or dimethylzinc. As a precursor containing gallium, it is possible to use, for example, triethylgallium. As a precursor containing titanium, it is possible to use, for example, titanium chloride, tetrakis(dimethylamido) titanium, or tetraisopropyl titanate. As a precursor containing aluminum, it is possible to use, for example, aluminum chloride or trimethylaluminum. As a precursor containing silicon, it is possible to use, for example, trisilylamine, bis(diethylamino) silane, tris(dimethylamino) silane, bis(tert-butylamino) silane, or bis(ethylmethylamino) silane. As the oxidizer, water vapor, oxygen plasma, or an ozone gas can be used.

Here, a surface of the conductive layer 111 might be oxidized after the formation of the conductive layer 111 but before the formation of the conductive film 112f, for example. For example, exposure to the air after the formation of the conductive layer 111 might allow oxygen contained in the air to oxidize a surface of the conductive layer 111. Here, in the case where a metal whose electrical resistance would be increased by oxidation is used for the uppermost layer of the conductive layer 111, the electric resistance at the contact interface between the conductive layer 111 and the conductive layer 112 might be increased as compared with the case where the surface of the conductive layer 111 is not oxidized. Consequently, defects might be generated in the manufactured display device to reduce the reliability of the display device.

Thus, an oxide on a surface of the conductive layer 111 is preferably remover after the formation of the conductive layer 111 but before the formation of the conductive film 112f. It is preferable that the formation of the conductive film 112f follow the removal of the oxide without exposure to the air. In this case, the electrical resistance at the contact interface between the conductive layer 111 and the conductive layer 112 can be made low. Accordingly, generation of a defect in the display device 100 can be inhibited, which makes the display device 100 highly reliable. The oxide on a surface of the conductive layer 111 can be removed by a reverse sputtering method, for example.

A reverse sputtering method refers to a method in which property modification of a surface to be processed is caused by collision of ions with the surface to be processed, in contrast to collision of ions with a sputtering target in normal sputtering. An example of a method of making ions collide with a surface to be processed is a method in which high-frequency voltage is applied to the side of the surface to be processed in a gas atmosphere containing a Group 18 element such as argon so that plasma is generated near the surface to be processed. Note that an atmosphere containing nitrogen, oxygen, or the like may be used instead of the gas atmosphere containing a Group 18 element. An apparatus used for the reverse sputtering method is not limited to a sputtering apparatus, and the same treatment can also be performed with a plasma CVD apparatus, a dry etching apparatus, or the like.

Then, as illustrated in FIG. 24D, the conductive film 112f is processed by a photolithography method, for example, so that the conductive layer 112R, the conductive layer 112G, the conductive layer 112B, and the conductive layer 112C are formed. Specifically, the conductive film 112f is partly removed by an etching method after a resist mask is formed, for example. In the case where a conductive oxide is used for the conductive film 112f, the conductive film 112f can be removed by a wet etching method, for example. The conductive layer 112 is formed to cover the upper surface and the side surface of the conductive layer 111. In the case where the conductive layer 112 has the structure illustrated in FIG. 2B2, a metal material is used for the conductive layer 112a, and a conductive oxide is used for the conductive layer 112b, for example, a conductive film to be the conductive layer 112a can be partly removed by a dry etching method after a conductive film to be the conductive layer 112b is partly removed by a wet etching method. Note that the conductive film to be the conductive layer 112a may be partly removed by a wet etching method and the conductive film to be the conductive layer 112b may be partly removed by a dry etching method.

Here, in the case where the conductive layer 112 is a stacked-layer structure of the conductive layer 112a and the conductive layer 112b as illustrated in FIG. 2B2 and FIG. 3B, a film to be the conductive layer 112a, which is included in the conductive film 112f, can be formed using a metal material such as titanium, silver, or an alloy containing silver. A film to be the conductive layer 112b, which is included in the conductive film 112f, can be formed using a conductive oxide such as indium tin oxide, for example. As described above, using silver or an alloy containing silver for the conductive layer 112a enables the pixel electrode to have high visible light reflectance as described above. Meanwhile, using titanium for the film to be the conductive layer 112a facilitates processing of the film to form the conductive layer 112a because titanium has better processability in etching than silver, as described above.

Then, the conductive layer 112 is preferably subjected to hydrophobic treatment. The hydrophobic treatment can change the property of the surface of a processing target from hydrophilic to hydrophobic, or can improve the hydrophobic property of the surface of the processing target. The hydrophobic treatment for the conductive layer 112 can increase the adhesion between the conductive layer 112 and the EL layer 113 formed in a later step and inhibits peeling. Note that the hydrophobization treatment is not necessarily performed.

The hydrophobic treatment can be performed by fluorine modification of the conductive layer 112, for example. The fluorine modification can be performed by, for example, treatment or heat treatment using a fluorine-containing gas, plasma treatment in an atmosphere of a fluorine-containing gas, or the like. As the fluorine-containing gas, a fluorine gas such as a fluorocarbon gas can be used, for example. As a fluorocarbon gas, a low carbon fluoride gas such as a carbon tetrafluoride (CF₄) gas, a C₄F₆ gas, a C₂F₆ gas, a C₄F₈ gas, or a CsF& gas can be used, for example. Moreover, as the fluorine-containing gas, a SF₆ gas, a NF₃ gas, a CHF: gas, or the like can be used, for example. A helium gas, an argon gas, a hydrogen gas, a hydrogen gas, an oxygen gas, or the like can be added to these gases as appropriate.

In addition, treatment using a silylation agent is performed on the surface of the conductive layer 112 after plasma treatment is performed in a gas atmosphere containing a Group 18 element such as argon, so that the surface of the conductive layer 112 can become hydrophobic. As the silylation agent, hexamethyldisilazane (HMDS), N-trimethylsilylimidazole (TMSI), or the like can be used. Alternatively, treatment using a silane coupling agent is performed on the surface of the conductive layer 112 after plasma treatment is performed in a gas atmosphere containing a Group 18 element such as argon, so that the surface of the conductive layer 112 can become hydrophobic.

Plasma treatment in a gas atmosphere containing a Group 18 element such as argon is performed on the surface of the conductive layer 112, whereby the surface of the conductive layer 112 can be damaged. Accordingly, a methyl group included in the silylation agent such as HMDS is likely to bond to the surface of the conductive layer 112. Moreover, silane coupling due to the silane coupling agent is likely to occur. As described above, treatment using a silylation agent or a silane coupling agent performed on the surface of the conductive layer 112 after plasma treatment in a gas atmosphere containing a Group 18 element such as argon enables the surface of the conductive layer 112 to become hydrophobic.

The treatment using the silylation agent, the silane coupling agent, or the like can be performed by application of the silylation agent, the silane coupling agent, or the like by a spin coating method or a dipping method, for example. The treatment using the silylation agent, the silane coupling agent, or the like can also be performed by forming a film containing the silylation agent, a film containing the silane coupling agent, or the like over the conductive layer 112 and the like by a gas phase method, for example. In a gas phase method, first, a material containing the silylation agent, a material containing the silane coupling agent, or the like is volatilized so that the silylation agent, the silane coupling agent, or the like is included in the atmosphere. Then, the substrate where the conductive layer 112, for example, is formed is put in the atmosphere. Thus, a film containing the silylation agent, the silane coupling agent, or the like can be formed over the conductive layer 112, and the surface of the conductive layer 112 can be made hydrophobic.

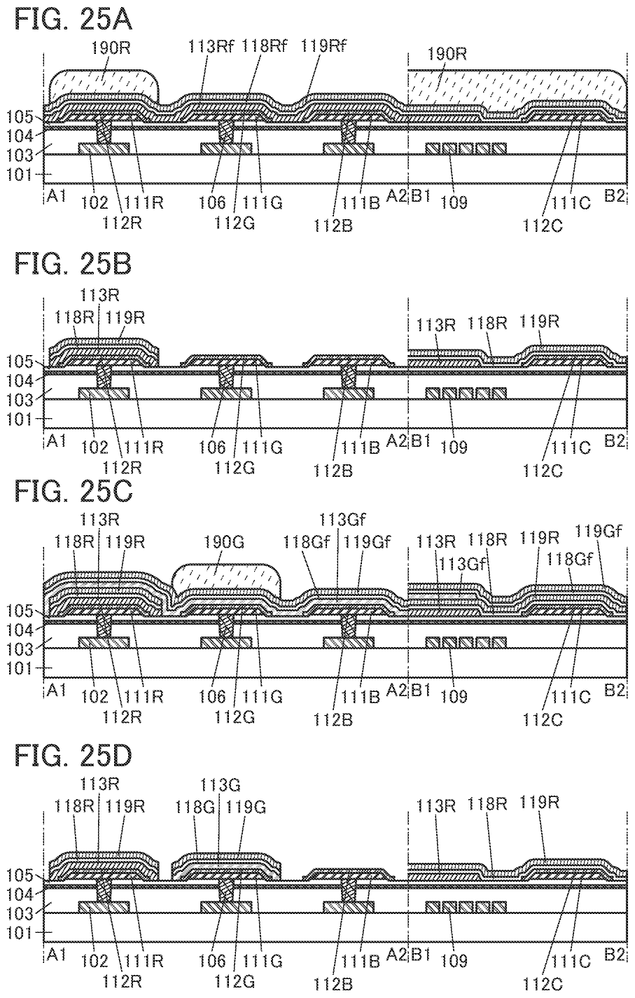

Next, as illustrated in FIG. 25A, an EL film 113Rf to be the EL layer 113R later is formed over the conductive layer 112R, over the conductive layer 112G, over the conductive layer 112B, and over the insulating layer 105.

As illustrated in FIG. 25A, the EL film 113Rf is not formed over the conductive layer 112C. The EL film 113Rf can be formed only in an intended region by using an area mask, for example. Employing a film formation step using an area mask and a processing step using a resist mask enables a light-emitting element to be manufactured by a relatively easy process.

The EL film 113Rf can be formed by an evaporation method, specifically a vacuum evaporation method, for example. The EL film 113Rf may be formed by a transfer method, a printing method, an inkjet method, a coating method, or the like.

Next, as illustrated in FIG. 25A, the mask film 118Rf to be the mask layer 118R later and the mask film 119Rf to be the mask layer 119R later are sequentially formed over the EL film 113Rf, over the conductive layer 112C, and over the insulating layer 105.

Although this embodiment describes an example in which the mask film is formed with a two-layer structure of the mask film 118Rf and the mask film 119Rf, the mask film may have a single-layer structure or a stacked-layer structure of three or more layers.

The mask layer provided over the EL film 113Rf can reduce damage to the EL film 113Rf in the manufacturing process of the display device, increasing the reliability of the light-emitting element.

As the mask film 118Rf, a film that is highly resistant to the processing conditions for the EL film 113Rf, specifically, a film having high etching selectivity with the EL film 113Rf is used. As the mask film 119Rf, a film having high etching selectivity with the mask film 118Rf is used.

The mask film 118Rf and the mask film 119Rf are formed at a temperature lower than the upper temperature limit of the EL film 113Rf. The typical substrate temperatures in formation of the mask film 118Rf and the mask film 119Rf are each lower than or equal to 200° C., preferably lower than or equal to 150° C., further preferably lower than or equal to 120° C., still further preferably lower than or equal to 100° C., yet still further preferably lower than or equal to 80° C.

As the mask film 118Rf and the mask film 119Rf, it is preferable to use a film that can be removed by a wet etching method. Using a wet etching method can reduce damage to the EL film 113Rf in processing the mask film 118Rf and the mask film 119Rf, as compared to the case of using a dry etching method.

The mask film 118Rf and the mask film 119Rf can be formed by a sputtering method, an ALD method (a thermal ALD method or a PEALD method), a CVD method, or a vacuum evaporation method, for example. Alternatively, the aforementioned wet film formation method may be used for the formation.

Note that the mask film 118Rf, which is formed over and in contact with the EL film 113Rf, is preferably formed by a formation method that causes less damage to the EL film 113Rf than a formation method for the mask film 119Rf. For example, the mask film 118Rf is preferably formed by an ALD method or a vacuum evaporation method rather than a sputtering method.

As the mask film 118Rf and the mask film 119Rf, it is possible to use one or more of a metal film, an alloy film, a metal oxide film, a semiconductor film, an organic insulating film, and an inorganic insulating film, for example.

For the mask film 118Rf and the mask film 119Rf, it is possible to use a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials, for example. It is particularly preferable to use a low-melting-point material such as aluminum or silver. The use of a metal material capable of blocking ultraviolet rays for one or both of the mask film 118Rf and the mask film 119Rf is preferable, in which case the EL film 113Rf can be inhibited from being irradiated with ultraviolet light and deteriorating.

For each of the mask film 118Rf and the mask film 119Rf, it is possible to use a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

Note that an element M (M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used instead of gallium described above. Specifically, M is preferably one or more kinds selected from gallium, aluminum, and yttrium.

As the mask film, a film containing a material having a light-blocking property, particularly with respect to ultraviolet rays, can be used. For example, a film having a property of reflecting ultraviolet rays or a film absorbing ultraviolet rays can be used. Although a variety of materials such as a metal, an insulator, a semiconductor, and a metalloid that have a property of blocking ultraviolet rays can be used as the material having a light-blocking property, the mask film is preferably a film capable of being processed by etching and is particularly preferably a film having good processability because part or the whole of the mask film is removed in a later step.

Examples of a material with an affinity for a semiconductor manufacturing process include semiconductor materials such as silicon and germanium. Other examples include oxides and nitrides of the above semiconductor materials. Other examples include non-metallic (metalloid) materials such as carbon and compounds thereof. Other examples include metals such as titanium, tantalum, tungsten, chromium, aluminum, and alloys containing one or more of these metals. Other examples include oxides containing the above metal such as titanium oxide and chromium oxide, and nitrides such as titanium nitride, chromium nitride, and tantalum nitride.

The use of a film containing a material having a light-blocking property with respect to ultraviolet rays can inhibit the EL layer from being irradiated with ultraviolet rays in a light exposure step, for example. The EL layer is inhibited from being damaged by ultraviolet rays, so that the reliability of the light-emitting element can be improved.

Note that the film containing a material having a light-blocking property with respect to ultraviolet ray's can have the same effect even when used as an insulating film 125f to be described later.

As the mask film 118Rf and the mask film 119Rf, a variety of inorganic insulating films that can be used as the protective layer 131 can be used. In particular, an oxide insulating film is preferable because its adhesion to the EL film 113Rf is higher than that of a nitride insulating film. For example, an inorganic insulating material such as aluminum oxide, hafnium oxide, or silicon oxide can be used for the mask film 118Rf and the mask film 119Rf. As the mask film 118Rf or the mask film 119Rf, an aluminum oxide film can be formed by an ALD method, for example. The use of an ALD method is preferable, in which case damage to a base (in particular, the EL layer) can be reduced.

For example, an inorganic insulating film (e.g., an aluminum oxide film) formed by an ALD method can be used as the mask film 118Rf, and an inorganic film (e.g., an In—Ga—Zn oxide film, an aluminum film, or a tungsten film) formed by a sputtering method can be used as the mask film 119Rf.

Note that the same inorganic insulating film can be used for both the mask film 118Rf and the insulating layer 125 that is to be formed later. For example, an aluminum oxide film formed by an ALD method can be used for both the mask film 118Rf and the insulating layer 125. Here, for the mask film 118Rf and the insulating layer 125, the same film formation condition may be used or different film formation conditions may be used. For example, when the mask film 118Rf is formed under conditions similar to those of the insulating layer 125, the mask film 118Rf can be an insulating film having a high barrier property against at least one of water and oxygen. Meanwhile, the mask film 118Rf is a layer most or all of which is to be removed in a later step, and thus is preferably easy to process. Therefore, the mask film 118Rf is preferably formed with a substrate temperature lower than that for formation of the insulating layer 125.

An organic material may be used for one or both of the mask film 118Rf and the mask film 119Rf. For example, as the organic material, a material that can be dissolved in a solvent chemically stable may be used. Specifically, a material that will be dissolved in water or alcohol can be suitably used. In film formation of a film of such a material, it is preferable to apply the material dissolved in a solvent such as water or alcohol by a wet film formation method and then perform heat treatment for evaporating the solvent. At this time, the heat treatment is preferably performed in a reduced-pressure atmosphere, in which case the solvent can be removed at a low temperature in a short time and thermal damage to the EL film 113Rf can be reduced accordingly.

For each of the mask film 118Rf and the mask film 119Rf, an organic resin such as polyvinyl alcohol (PVA), polyvinyl butyral, polyvinylpyrrolidone, polyethylene glycol, polyglycerin, pullulan, water-soluble cellulose, an alcohol-soluble polyamide resin, or a fluororesin such as perfluoropolymer may be used.

For example, an organic film (e.g., a PVA film) formed by an evaporation method or the above wet film formation method can be used as the mask film 118Rf, and an inorganic film (e.g., a silicon nitride film) formed by a sputtering method can be used as the mask film 119Rf.

Note that in the display device of one embodiment of the present invention, part of the mask film remains as the mask layer in some cases.

Then, a resist mask 190R is formed over the mask film 119Rf, as illustrated in FIG. 25A. The resist mask 190R can be formed by application of a photosensitive material (photoresist), exposure, and development.

Either a positive resist material or a negative resist material may be used to form the resist mask 190R.

The resist mask 190R is provided at a position overlapping with the conductive layer 112R. Note that the resist mask 190R is preferably provided also at a position overlapping with the conductive layer 112C. This can inhibit the conductive layer 112C from being damaged during the manufacturing process of the display device. Note that the resist mask 190R is not necessarily provided over the conductive layer 112C. The resist mask 190R is preferably provided to cover the area from the end portion of the EL film 113Rf to the end portion of the conductive layer 112C (the end portion closer to the EL film 113Rf), as illustrated in the cross-sectional view along the line B1-B2 in FIG. 25A.

Subsequently, as illustrated in FIG. 25A and FIG. 25B, part of the mask film 119Rf is removed using the resist mask 190R, whereby the mask layer 119R is formed. The mask layer 119R remains over the conductive layer 112R and over the conductive layer 112C. After that, the resist mask 190R is removed. Next, part of the mask film 118Rf is removed using the mask layer 119R as a mask (also referred to as a hard mask), whereby the mask layer 118R is formed.

The mask film 118Rf and the mask film 119Rf can be processed by a wet etching method or a dry etching method. The mask film 118Rf and the mask film 119Rf are preferably processed by anisotropic etching.

Using a wet etching method can reduce damage to the EL film 113Rf in processing the mask film 118Rf and the mask film 119Rf, as compared to the case of using a dry etching method. In the case of using a wet etching method, it is preferable to use a developer, a tetramethylammonium hydroxide aqueous solution (TMAH), dilute hydrofluoric acid, oxalic acid, phosphoric acid, acetic acid, nitric acid, or a chemical solution containing a mixed solution of any of these acids, for example.

Since the EL film 113Rf is not exposed in processing the mask film 119Rf, the range of choices of the processing method is wider than that for processing the mask film 118Rf. Specifically, even in the case where a gas containing oxygen is used as the etching gas in the processing of the mask film 119Rf, deterioration of the EL film 113Rf can be inhibited as compared to the case where a gas containing oxygen is used as the etching gas in the processing of the mask film 118Rf.

In the case of using a dry etching method for processing the mask film 118Rf, deterioration of the EL film 113Rf can be inhibited by not using a gas containing oxygen as the etching gas. In the case of using a dry etching method, it is preferable to use a gas containing CF₄, C₄F₈, SF₆, CHF₃, Cl₂, H₂O, BCl₃, or a Group 18 element, for example, as the etching gas. He can be used as the Group 18 element, for example.

For example, in the case where an aluminum oxide film formed by an ALD method is used as the mask film 118Rf, part of the mask film 118Rf can be removed by a dry etching method using a combination of CHF₃ and He or a combination of CHF₃, He, and CH₄. In the case where an In—Ga—Zn oxide film formed by a sputtering method is used as the mask film 119Rf, part of the mask film 119Rf can be removed by a wet etching method using a diluted phosphoric acid.

Alternatively, part of the mask film 119Rf may be removed by a dry etching method using CH₄ and Ar. Alternatively, part of the mask film 119Rf can be removed by a wet etching method using diluted phosphoric acid. In the case where a tungsten film formed by a sputtering method is used as the mask film 119Rf, part of the mask film 119Rf can be removed by a dry etching method using SF₆, a combination of CF₄ and O₂, or a combination of CF₄, Cl₂, and O₂.

The resist mask 190R can be removed by ashing using oxygen plasma, for example. Alternatively, an oxygen gas and CF₄, C₄F₈, SF₆, CHF₃, Cl₂, H₂O, BCl₃, or a Group 18 element may be used. He can be used as the Group 18 element, for example. Alternatively, the resist mask 190R may be removed by wet etching. At this time, the mask film 118Rf is positioned on the outermost surface and the EL film 113Rf is not exposed; thus, the EL film 113Rf can be inhibited from being damaged in the step of removing the resist mask 190R. In addition, the range of choices of the method for removing the resist mask 190R can be widened.

Next, as illustrated in FIG. 25A and FIG. 25B, the EL film 113Rf is processed, so that the EL layer 113R is formed. For example, part of the EL film 113Rf is removed using the mask layer 119R and the mask layer 118R as a mask to form the EL layer 113R.

Accordingly, as illustrated in FIG. 25B, a stacked-layer structure of the EL layer 113R, the mask layer 118R, and the mask layer 119R remains over the conductive layer 112R. The conductive layer 112G and the conductive layer 112B are exposed.

FIG. 25B illustrates an example in which the end portion of the EL layer 113R is positioned on the outer side of the end portion of the conductive layer 112R. Such a structure can increase the aperture ratio of the pixel. Although not illustrated in FIG. 25B, by the above etching treatment, a depressed portion may be formed in the insulating layer 105 in a region that does not overlap with the EL layer 113R.

The EL layer 113R covers the upper surface and the side surface of the conductive layer 112R and thus, the subsequent steps can be performed without exposure of the conductive layer 112R. When the end portion of the conductive layer 112R is exposed, corrosion might occur in the etching step, for example. A product generated by corrosion of the conductive layer 112R may be unstable, and for example, might be dissolved in a solution when wet etching is performed and might be scattered in an atmosphere when dry etching is performed. The product dissolved in a solution or scattered in an atmosphere might be attached to a surface to be processed, the side surface of the EL layer 113R, and the like, which adversely affects the characteristics of the light-emitting element or forms a leakage path between the light-emitting elements in some cases. In a region where the end portion of the conductive layer 112R is exposed, adhesion between layers in contact with each other might be lowered, which might be likely to cause peeling of the EL layer 113R or the conductive layer 112R.

Thus, the structure where the EL layer 113R covers the upper surface and the side surface of the conductive layer 112R can improve the yield and characteristics of the light-emitting element, for example.

As described above, the resist mask 190R is preferably provided to cover the area from the end portion of the EL layer 113R to the end portion of the conductive layer 112C (the end portion closer to the EL layer 113R) in the cross section B1-B2. Thus, as illustrated in FIG. 25B, the mask layer 118R and mask layer 119R are provided to cover the area from the end portion of the EL layer 113R to the end portion of the conductive layer 112C (the end portion closer to the EL layer 113R) in the cross section B1-B2. Hence, the insulating layer 105 can be inhibited from being exposed in the cross section B1-B2, for example. This can inhibit the insulating layer 105, the insulating layer 104, and the insulating layer 103 from being partly removed by etching, for example, and thus inhibit the conductive layer 109 from being exposed. Thus, unintentional electrical connection between the conductive layer 109 and another conductive layer can be inhibited. For example, a short circuit between the conductive layer 109 and the common electrode 115 formed in a later step can be inhibited.

The EL film 113Rf is preferably processed by anisotropic etching. In particular, anisotropic dry etching is preferable. Alternatively, wet etching may be used.

In the case of using a dry etching method, deterioration of the EL film 113Rf can be inhibited by not using a gas containing oxygen as the etching gas.

A gas containing oxygen may be used as the etching gas. When the etching gas contains oxygen, the etching rate can be increased. Therefore the etching can be performed under a low-power condition while an adequately high etching rate is maintained. Thus, damage to the EL film 113Rf can be inhibited. Furthermore, a defect such as attachment of a reaction product generated at the etching can be inhibited.

In the case of using a dry etching method, it is preferable to use a gas containing at least one of H₂, CF₄, C₄F₈, SF₆, CHF₃, Cl₂, H₂O, BCl₃, and a Group 18 element such as He or Ar as the etching gas, for example. Alternatively, a gas containing oxygen and at least one kind of the above is preferably used as the etching gas. Alternatively, an oxygen gas may be used as the etching gas. Specifically, for example, a gas containing H₂ and Ar or a gas containing CF₄ and He can be used as the etching gas. For example, a gas containing CF₄, He, and oxygen can be used as the etching gas. For example, a gas containing H₂ and Ar and a gas containing oxygen can be used as the etching gas.

As described above, in one embodiment of the present invention, the mask layer 119R is formed in the following manner: the resist mask 190R is formed over the mask film 119Rf, and part of the mask film 119Rf is removed using the resist mask 190R. After that, part of the EL film 113Rf is removed using the mask layer 119R as a mask, so that the EL layer 113R is formed. In other words, the EL layer 113R can be formed by processing the EL film 113Rf by a photolithography method. Note that part of the EL film 113Rf may be removed using the resist mask 190R. Then, the resist mask 190R may be removed.

Next, hydrophobic treatment for the conductive layer 112G, for example, is preferably performed. At the time of processing the EL film 113Rf, the surface of the conductive layer 112G changes to have hydrophilic properties in some cases, for example. The hydrophobization treatment for the conductive layer 112G, for example, can increase the adhesion between the conductive layer 112G and a layer to be formed in a later step (which is the EL layer 113G here) and inhibit peeling. Note that the hydrophobization treatment is not necessarily performed.

Next, as illustrated in FIG. 25C, an EL film 113Gf to be the EL layer 113G later is formed over the conductive layer 112G, over the conductive layer 112B, over the mask layer 119R, and over the insulating layer 105.

The EL film 113Gf can be formed by a method similar to a method that can be employed to form the EL film 113Rf.

Then, as illustrated in FIG. 25C, a mask film 118Gf to be the mask layer 118G later and a mask film 119Gf to be a mask layer 119G later are sequentially formed over the EL film 113Gf and over the mask layer 119R. After that, a resist mask 190G is formed. The materials and the formation methods of the mask film 118Gf and the mask film 119Gf are similar to conditions applicable to the mask film 118Rf and the mask film 119Rf. The materials and the formation method of the resist mask 190G are similar to conditions applicable to the resist mask 190R.

The resist mask 190G is provided at a position overlapping with the conductive layer 112G.

Subsequently, as illustrated in FIG. 25C and FIG. 25D, part of the mask film 119Gf is removed using the resist mask 190G, whereby the mask layer 119G is formed. The mask layer 119G remains over the conductive layer 112G. After that, the resist mask 190G is removed. Then, part of the mask film 118Gf is removed using the mask layer 119G as a mask, whereby the mask layer 118G is formed. Next, the EL film 113Gf is processed to form the EL layer 113G. For example, part of the EL film 113Gf is removed using the mask layer 119G and the mask layer 118G as a mask to form the EL layer 113G.

Accordingly, as illustrated in FIG. 25D, the stacked-layer structure of the EL layer 113G, the mask layer 118G, and the mask layer 119G remains over the conductive layer 112G. The mask layer 119R and the conductive layer 112B are exposed.

Next, hydrophobic treatment for the conductive layer 112B, for example, is preferably performed. At the time of processing the EL film 113Gf, the surface of the conductive layer 112B changes to have hydrophilic properties in some cases, for example. The hydrophobization treatment for the conductive layer 112B, for example, can increase the adhesion between the conductive layer 112B and a layer to be formed in a later step (which is the EL layer 113B here) and inhibit peeling. Note that the hydrophobization treatment is not necessarily performed.

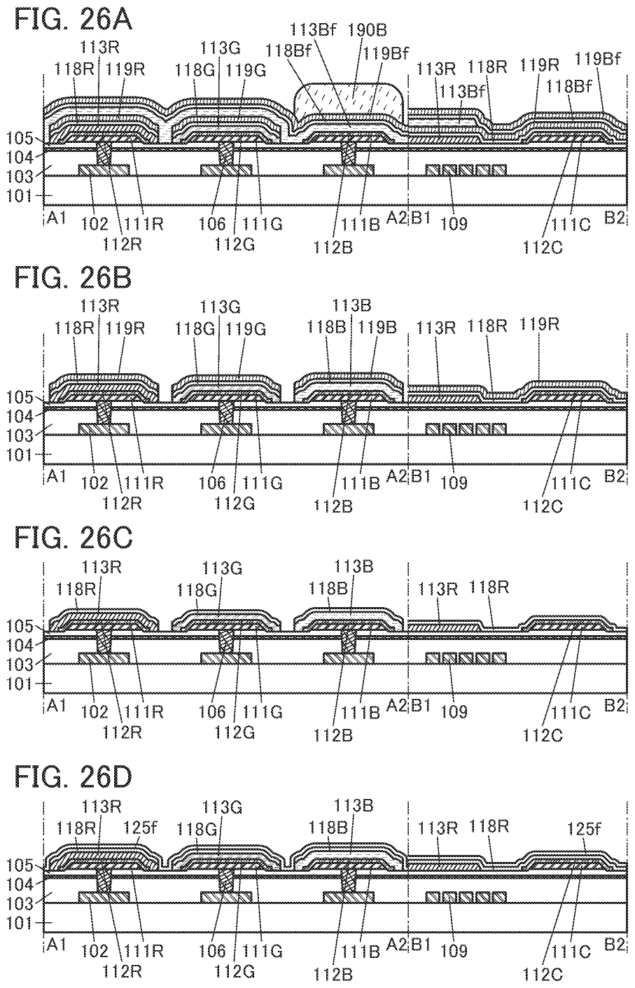

Next, as illustrated in FIG. 26A, an EL film 113Bf to be the EL layer 113B later is formed over the conductive layer 112B, over the mask layer 119R, over the mask layer 119G, and over the insulating layer 105.

The EL film 113Bf can be formed by a method similar to a method that can be employed to form the EL film 113Rf.

Then, as illustrated in FIG. 26A, a mask film 118Bf to be the mask layer 118B later and a mask film 119Bf to be a mask layer 119B later are sequentially formed over the EL film 113Bf and over the mask layer 119R. After that, a resist mask 190B is formed. The materials and the formation methods of the mask film 118Bf and the mask film 119Bf are similar to conditions applicable to the mask film 118Rf and the mask film 119Rf. The materials and the formation method of the resist mask 190B are similar to conditions applicable to the resist mask 190R.

The resist mask 190B is provided at a position overlapping with the conductive layer 112B.

Subsequently, as illustrated in FIG. 26A and FIG. 26B, part of the mask film 119Bf is removed using the resist mask 190B, whereby the mask layer 119B is formed. The mask layer 119B remains over the conductive layer 112B. After that, the resist mask 190B is removed. Then, part of the mask film 118Bf is removed using the mask layer 119B as a mask, whereby the mask layer 118B is formed. Next, the EL film 113Bf is processed to form the EL layer 113B. For example, part of the EL film 113Bf is removed using the mask layer 119B and the mask layer 118B as a mask to form the EL layer 113B.

Accordingly, as illustrated in FIG. 26B, the stacked-layer structure of the EL layer 113B, the mask layer 118B, and the mask layer 119B remains over the conductive layer 112B. The mask layer 119R and the mask layer 119G are exposed.

Note that the side surface of the EL layer 113R, the side surface of the EL layer 113G, and the side surface of the EL layer 113B are preferably perpendicular or substantially perpendicular to their formation surfaces. For example, the angle between the formation surfaces and these side surfaces is preferably greater than or equal to 60° and less than or equal to 90°.

As described above, the distance between adjacent two layers among the EL layer 113R, the EL layer 113G, and the EL layer 113B formed by a photolithography method can be shortened to less than or equal to 8 μm, less than or equal to 5 μm, less than or equal to 3 μm, less than or equal to 2 μm, or less than or equal to 1 μm. Here, the distance can be specified, for example, by a distance between opposite end portions of two adjacent layers among the EL layer 113R, the EL layer 113G, and the EL layer 113B. The distance between the island-shaped EL layers 113 is shortened in this manner, whereby a display device with high resolution and a high aperture ratio can be provided.

Next, the mask layer 119R, the mask layer 119G, and the mask layer 119B are preferably removed as illustrated in FIG. 26C. The mask layer 118R, the mask layer 118G, the mask layer 118B, the mask layer 119R, the mask layer 119G, and the mask layer 119B might remain in the display device in some cases depending on the subsequent steps. Removing the mask layer 119R, the mask layer 119G, and the mask layer 119B at this stage can inhibit the mask layer 119R, the mask layer 119G, and the mask layer 119B from remaining in the display device. In the case where a conductive material is used for the mask layer 119R, the mask layer 119G, and the mask layer 119B, removing the mask layer 119R, the mask layer 119G, and the mask layer 119B in advance can inhibit generation of leakage current, formation of a capacitor, and the like due to the mask layer 119R, the mask layer 119G, and the mask layer 119B, for example.

Although this embodiment shows an example where the mask layer 119R, the mask layer 119G, and the mask layer 119B are removed, the mask layer 119R, the mask layer 119G, and the mask layer 119B are not necessarily removed. For example, in the case where the mask layer 119R, the mask layer 119G, and the mask layer 119B contain the material having a property of blocking ultraviolet rays, the procedure preferably proceeds to the next step without removing the mask layer 119R, the mask layer 119G, and the mask layer 119B, in which case the EL layer 113 can be protected from ultraviolet rays.

The step of removing the mask layers can be performed by a method similar to that for the step of processing the mask layers. In particular, using a wet etching method can reduce damage to the EL layer 113R, the EL layer 113G, and the EL layer 113B in removing the mask layers, as compared to the case of using a dry etching method.

The mask layers may be removed by being dissolved in a solvent such as water or alcohol. Examples of alcohol include ethyl alcohol, methyl alcohol, isopropyl alcohol (IPA), and glycerin.

After the mask layers are removed, drying treatment may be performed in order to remove water contained in the EL layer 113R, the EL layer 113G, and the EL layer 113B and water adsorbed on the surface of the EL layer 113R, the surface of the EL layer 113G, and the surface of the EL layer 113B. For example, heat treatment in an inert gas atmosphere or a reduced-pressure atmosphere can be performed. The heat treatment can be performed at a substrate temperature higher than or equal to 50° C., and lower than or equal to 200° C., preferably higher than or equal to 60° C., and lower than or equal to 150° C., further preferably higher than or equal to 70° C., and lower than or equal to 120° C. Employing a reduced-pressure atmosphere is preferable, in which case drying at a lower temperature is possible.

Next, as illustrated in FIG. 26D, the insulating film 125f to be the insulating layer 125 later is formed to cover the EL layer 113R, the EL layer 113G, and the EL layer 113B and the mask layer 118R, the mask layer 118G, and the mask layer 118B.

As described later, an insulating film to be the insulating layer 127 later is formed in contact with the upper surface of the insulating film 125f. Therefore, the upper surface of the insulating film 125f preferably has high affinity for a material used for the insulating film, e.g., a photosensitive resin composition containing an acrylic resin. To improve the affinity, surface treatment is preferably performed so that the upper surface of the insulating film 125f is made hydrophobic or its hydrophobic properties are improved. For example, it is preferable to perform the treatment using a silylation agent such as HMDS. By making the upper surface of the insulating film 125f hydrophobic in this manner, the insulating film 127f can be formed with high adhesion. Note that the above-described hydrophobization treatment may be performed as the surface treatment.

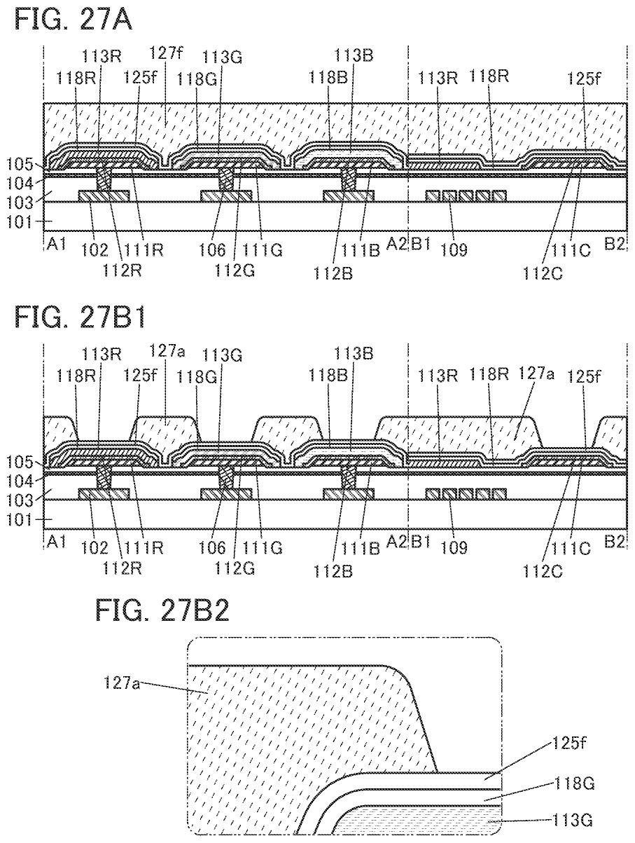

Then, as illustrated in FIG. 27A, an insulating film 127f to be the insulating layer 127 later is formed over the insulating film 125f.

The insulating film 125f and the insulating film 127f are preferably formed by a formation method that causes less damage to the EL layer 113R, the EL layer 113G, and the EL layer 113B. The insulating film 125f, which is formed in contact with the side surfaces of the EL layer 113R, the EL layer 113G, and the EL layer 113B, is particularly preferably formed by a method that is less likely to damage the EL layer 113R, the EL layer 113G, and the EL layer 113B than the method of forming the insulating film 127f.

In addition, the insulating film 125f and the insulating film 127f are each formed at a temperature lower than the upper temperature limit of the EL layer 113R, the EL layer 113G, and the EL layer 113B. When the substrate temperature at the time when the insulating film 125f is formed is increased, the formed insulating film 125f, even with a small thickness, can have a low impurity concentration and a high barrier property against at least one of water and oxygen.

The substrate temperature at the time of forming the insulating film 125f and the insulating film 127f is preferably higher than or equal to 60° C., higher than or equal to 80° C., higher than or equal to 100° C., or higher than or equal to 120° C., and lower than or equal to 200° C., lower than or equal to 180° C., lower than or equal to 160° C., lower than or equal to 150° C., or lower than or equal to 140° C.

As the insulating film 125f, an insulating film is preferably formed within the above substrate temperature range to have a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm.

The insulating film 125f is preferably formed by an ALD method, for example. The use of an ALD method is preferable, in which case damage by the deposition is reduced and a film with good coverage can be deposited. As the insulating film 125f, an aluminum oxide film is preferably formed by an ALD method, for example.

Alternatively, the insulating film 125f may be formed by a sputtering method, a CVD method, or a PECVD method, each of which has a higher deposition rate than an ALD method. In that case, a highly reliable display device can be manufactured with high productivity.

The insulating film 127f is preferably formed by the aforementioned wet film formation method. The insulating film 127f is preferably formed by spin coating using a photosensitive material, for example, and preferably formed using specifically a photosensitive resin composition containing an acrylic resin.

The insulating film 127f is preferably formed using a resin composition containing a polymer, an acid-generating agent, and a solvent, for example. The polymer is formed using one or more kinds of monomers and has a structure where one or more kinds of structural units (also referred to as building blocks) are repeated regularly or irregularly. As the acid-generating agent, one or both of a compound that generates an acid by light irradiation and a compound that generates an acid by heating can be used. The resin composition may also include one or more of a photosensitizing agent, a sensitizer, a catalyst, an adhesive aid, a surface-active agent, and an antioxidant.

Heat treatment (also referred to as prebaking) is preferably performed after the insulating film 127f is formed. The heat treatment is performed at a temperature lower than the upper temperature limit of the EL layer 113R, the EL layer 113G, and the EL layer 113B. The substrate temperature in the heat treatment is preferably higher than or equal to 50° C., and lower than or equal to 200° C., further preferably higher than or equal to 60° C., and lower than or equal to 150° C., still further preferably higher than or equal to 70° C., and lower than or equal to 120° C. Accordingly, a solvent contained in the insulating film 127f can be removed.

Then, part of the insulating film 127f is exposed to visible light or ultraviolet rays. Here, when a positive photosensitive resin composition containing an acrylic resin is used for the insulating film 127f, a region where the insulating layer 127 is not formed in a later step is irradiated with visible light or ultraviolet rays. The insulating layer 127 is formed in regions that are interposed between any two of the conductive layer 112R, the conductive layer 112G, and the conductive layer 112B and around the conductive layer 112C. Accordingly, irradiation with visible light or ultraviolet rays is performed over the conductive layer 112R, over the conductive layer 112G, over the conductive layer 112B, and over the conductive layer 112C. Note that when a negative photosensitive material is used for the insulating film 127f, the region where the insulating layer 127 is to be formed is irradiated with visible light or ultraviolet rays.

The width of the insulating layer 127 formed later can be controlled in accordance with the exposed region of the insulating film 127f. In this embodiment, processing is performed such that the insulating layer 127 includes a portion overlapping with the upper surface of the conductive layer 111.

Light used for the exposure preferably includes the i-line (wavelength: 365 nm). The light used for the exposure may include at least one of the g-line (wavelength: 436 nm) and the h-line (wavelength: 405 nm).

Here, when a barrier insulating layer against oxygen such as an aluminum oxide film, for example, is provided as one or both of the mask layer 118 and the insulating film 125f, diffusion of oxygen into the EL layer 113R, the EL layer 113G, and the EL layer 113B can be inhibited. When the EL layer is irradiated with light (visible light rays or ultraviolet rays), an organic compound contained in the EL layer is brought into an excited state and a reaction between the organic compound and oxygen in the atmosphere is promoted in some cases. Specifically, when the EL layer is irradiated with light (visible light rays or ultraviolet rays) in an atmosphere containing oxygen, oxygen might be bonded to the organic compound contained in the EL layer. By providing the mask layer 118 and the insulating film 125f over the island-shaped EL layer, bonding of oxygen in the atmosphere to the organic compound contained in the EL layer can be reduced.

Next, as illustrated in FIG. 27B1 and FIG. 27B2, development is performed to remove the exposed region of the insulating film 127f, so that an insulating layer 127a is formed. FIG. 27B2 is an enlarged view of the end portions of the EL layer 113G and the insulating layer 127a illustrated in FIG. 27B1 and their vicinity. The insulating layer 127a is formed in regions that are interposed between any two of the conductive layer 112R, the conductive layer 112G, and the conductive layer 112B and a region surrounding the conductive layer 112C. Here, when an acrylic resin is used for the insulating film 127f, a developer is preferably an alkaline solution and can be TMAH, for example.

Then, a residue (scum) due to the development may be removed. For example, the residue can be removed by ashing using oxygen plasma.

Etching may be performed so that the surface level of the insulating layer 127a is adjusted. The insulating layer 127a may be processed by ashing using oxygen plasma, for example. In the case where a non-photosensitive material is used for the insulating film 127f, the surface level of the insulating film 127f can be adjusted by the ashing, for example.

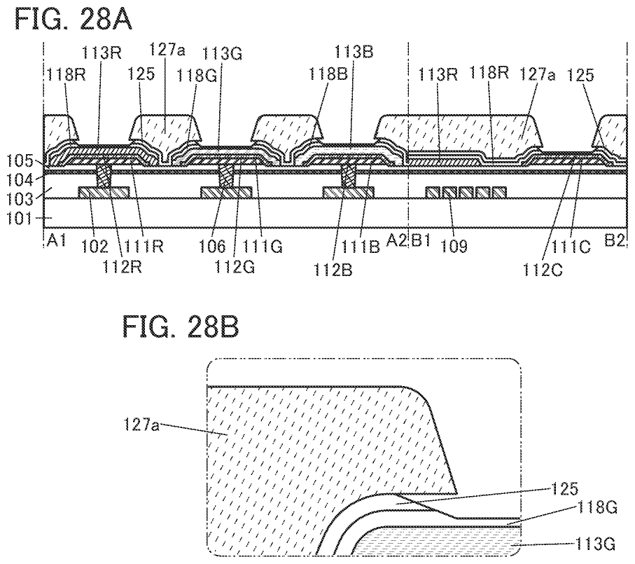

Next, as illustrated in FIG. 28A and FIG. 28B, etching treatment is performed with the insulating layer 127a as a mask to remove part of the insulating film 125f and reduce the thickness of part of the mask layer 118R, the mask layer 118G, and the mask layer 118B. Thus, the insulating layer 125 is formed under the insulating layer 127a. Moreover, the surfaces of the thin portions in the mask layer 118R, the mask layer 118G, and the mask layer 118B are exposed. FIG. 28B is an enlarged view of the end portions of the EL layer 113G and the insulating layer 127a illustrated in FIG. 28A and their vicinity. Note that the etching treatment using the insulating layer 127a as a mask may be hereinafter referred to as first etching treatment.

The first etching treatment can be performed by dry etching or wet etching. Note that the insulating film 125f is preferably formed using a material similar to that of the mask layer 118R, the mask layer 118G, and the mask layer 118B, in which case the first etching treatment can be performed collectively.

By etching using the insulating layer 127a with a tapered side surface as a mask as illustrated in FIG. 28B, the side surface of the insulating layer 125 and upper end portions of the side surfaces of the mask layer 118R, the mask layer 118G, and the mask layer 118B can be made to have a tapered shape relatively easily.

In the case of performing dry etching, a chlorine-based gas is preferably used. As the chlorine-based gas, one selected from Cl₂, BCl₃, SiCl₄, CCl₄, and the like or a mixture of two or more selected therefrom can be used. Moreover, one selected from an oxygen gas, a hydrogen gas, a helium gas, an argon gas, and the like or a mixture of two or more selected therefrom can be added to the chlorine-based gas as appropriate. By the dry etching, the thin regions of the mask layer 118R, the mask layer 118G, and the mask layer 118B can be formed with favorable in-plane uniformity.

As a dry etching apparatus, a dry etching apparatus including a high-density plasma source can be used. As the dry etching apparatus including a high-density plasma source, an inductively coupled plasma (ICP) etching apparatus can be used, for example. Alternatively, a capacitively coupled plasma (CCP) etching apparatus including parallel plate electrodes can be used. The capacitively coupled plasma etching apparatus including the parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes. Alternatively, a structure may be employed in which high-frequency voltages with different frequencies are applied to the parallel plate electrodes.

In the case of performing dry etching, a by-product or the like generated by the dry etching might be deposited on the upper surface and the side surface of the insulating layer 127a, for example. Thus, a component contained in the etching gas, a component contained in the insulating film 125f, components contained in the mask layer 118R, the mask layer 118G, and the mask layer 118B, or the like might be contained in the insulating layer 127 after the display device is completed.

The first etching treatment is preferably performed by wet etching. Using a wet etching method can reduce damage to the EL layer 113R, the EL layer 113G, and the EL layer 113B, as compared to the case of using a dry etching method. Wet etching can be performed using an alkaline solution, for example. For instance, TMAH, which is an alkaline solution, is preferably used for wet etching of an aluminum oxide film. In that case, paddle wet etching can be performed. Note that the insulating film 125f is preferably formed using a material similar to that of the mask layer 118R, the mask layer 118G, and the mask layer 118B, in which case the etching treatment can be performed collectively.

As illustrated in FIG. 28A and FIG. 28B, the mask layer 118R, the mask layer 118G, and the mask layer 118B are not removed completely by the first etching treatment, and the etching treatment is stopped when the thickness of the mask layer 118R, the mask layer 118G, and the mask layer 118B is reduced. The corresponding mask layer 118R, mask layer 118G, and mask layer 118B are left over the EL layer 113R, the EL layer 113G, and the EL layer 113B in this manner, whereby the EL layer 113R, the EL layer 113G, and the EL layer 113B can be inhibited from being damaged by processing in a later step.

Although the mask layer 118R, the mask layer 118G, and the mask layer 118B are thinned in FIG. 28A and FIG. 28B, the present invention is not limited thereto. For example, depending on the thickness of the insulating film 125f and the thicknesses of the mask layer 118R, the mask layer 118G, and the mask layer 118B, the first etching treatment may be stopped before the insulating film 125f is processed into the insulating layer 125. Specifically, the first etching treatment may be stopped only after reducing the thickness of part of the insulating film 125f. In the case where the insulating film 125f is formed with a material similar to those of the mask layer 118R, the mask layer 118G, and the mask layer 118B, the boundary between the insulating film 125f and the mask layer 118R, the mask layer 118G, and the mask layer 118B might be unclear. Consequently, whether the insulating layer 125 is formed and whether the mask layer 118R, the mask layer 118G, and the mask layer 118B are thinned cannot be determined in some cases.

Although FIG. 28A and FIG. 28B show an example in which the shape of the insulating layer 127a is not changed from that in FIG. 27B1 and FIG. 27B2, the present invention is not limited thereto. For example, the end portion of the insulating layer 127a may sag and cover the end portion of the insulating layer 125. As another example, the end portion of the insulating layer 127a may be in contact with the upper surfaces of the mask layer 118R, the mask layer 118G, and the mask layer 118B. As described above, when light exposure is not performed on the insulating layer 127a after the development, the shape of the insulating layer 127a may be likely to change.

Next, light exposure is preferably performed on the entire substrate so that the insulating layer 127a is irradiated with visible light or ultraviolet rays. The energy density for the light exposure is preferably greater than 0) mJ/cm² and less than or equal to 800 mJ/cm², further preferably greater than 0) mJ/cm² and less than or equal to 500 mJ/cm². Performing such light exposure after the development can sometimes increase the degree of transparency of the insulating layer 127a. In addition, it is sometimes possible to lower the substrate temperature required for subsequent heat treatment for changing the shape of the insulating layer 127a into a tapered shape.

Meanwhile, as described later, when light exposure is not performed on the insulating layer 127a, it sometimes becomes easy to change the shape of the insulating layer 127a or change the shape of the insulating layer 127 to a tapered shape in a later step. Thus, in some cases, it is preferable not to perform light exposure of the insulating layer 127a after the development.

For example, in the case where a light curable resin is used for the insulating layer 127a, light exposure of the insulating layer 127a can start polymerization and cure the insulating layer 127a. Note that without performing light exposure of the insulating layer 127a at this stage, at least one of after-mentioned post-baking and second etching treatment may be performed while the insulating layer 127a remains in a state where its shape is relatively easily changed. Thus, generation of unevenness in the formation surface of the common layer 114 and the common electrode 115 can be inhibited and accordingly step disconnection of the common layer 114 and the common electrode 115 can be inhibited. Note that light exposure may be performed after the development but before the first etching treatment. Meanwhile, depending on the material (e.g., a positive-type material) of the insulating layer 127a and the first etching treatment conditions, the insulating layer 127a that has been subjected to light exposure might be dissolved in a chemical solution during the first etching treatment. For this reason, light exposure is preferably performed after the first etching treatment but before post-baking. Hence, the insulating layer 127a having an intended shape can be stably formed with high reproducibility.

Here, irradiation with visible light or ultraviolet rays is preferably performed in an atmosphere containing no oxygen or an atmosphere containing a small amount of oxygen. For example, the irradiation with visible light or ultraviolet rays is preferably performed in an inert gas atmosphere such as a nitrogen atmosphere or a reduced-pressure atmosphere. If the irradiation with visible light or ultraviolet rays is performed in an atmosphere containing a large amount of oxygen, the compound contained in the EL layer 113 might be oxidized and the properties of the EL layer 113 might be changed. By contrast, by performing the irradiation with visible light or ultraviolet rays in an atmosphere containing no oxygen or an atmosphere containing a small amount of oxygen, a change of the properties of the EL layer can be inhibited: hence, a more highly reliable display device can be provided.

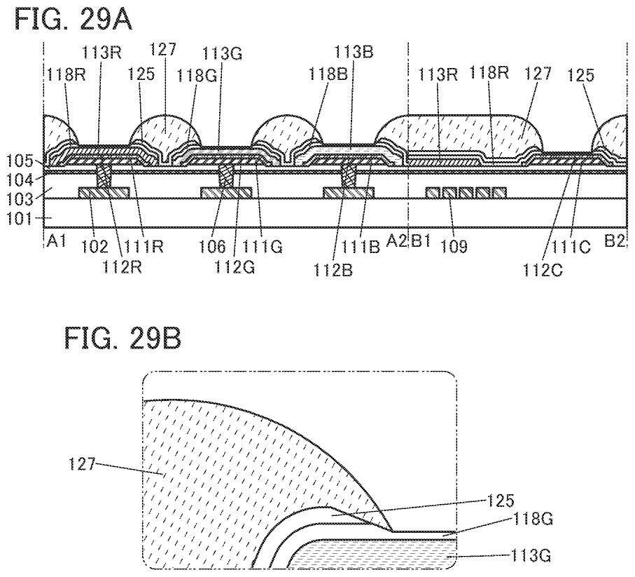

Then, as illustrated in FIG. 29A and FIG. 29B, heat treatment (also referred to as post-baking) is performed. As illustrated in FIG. 29A and FIG. 29B, the heat treatment can change the insulating layer 127a into the insulating layer 127 with a tapered side surface. As described above, in some cases, the insulating layer 127a is already changed in shape and has a tapered side surface at the time when the first etching treatment is finished. The heat treatment is performed at a temperature lower than the upper temperature limit of the EL layer 113. The heat treatment can be performed at a substrate temperature higher than or equal to 50° C., and lower than or equal to 200° C., preferably higher than or equal to 60° C., and lower than or equal to 150° C., further preferably higher than or equal to 70° C., and lower than or equal to 130° C. The heating atmosphere may be an air atmosphere or an inert gas atmosphere. Moreover, the heating atmosphere may be an atmospheric-pressure atmosphere or a reduced-pressure atmosphere. The heat treatment is preferably performed in a reduced-pressure atmosphere, in which case drying at a lower temperature is possible. The heat treatment in this step is preferably performed at a higher substrate temperature than the heat treatment (pre-baking) after the formation of the insulating film 127f. Accordingly, adhesion between the insulating layer 127 and the insulating layer 125 can be improved, and corrosion resistance of the insulating layer 127 can be increased. FIG. 29B is an enlarged view of the end portions of the layer 113G and the insulating layer 127 illustrated in FIG. 29A and their vicinities.

As described above, a material with high heat resistance is used for the light-emitting element of the display device of one embodiment of the present invention. Therefore, the temperature of the pre-baking and the temperature of the post-baking can each be higher than or equal to 100° C., higher than or equal to 120° C., or higher than or equal to 140° C. Thus, adhesion between the insulating layer 127 and the insulating layer 125 can be further improved, and the corrosion resistance of the insulating layer 127 can be further increased. Moreover, the range of choices for materials that can be used for the insulating layer 127 can be widened. By adequately removing the solvent and the like included in the insulating layer 127, for example, entry of impurities such as water and oxygen into the EL layer 113 can be inhibited.

When the mask layer 118R, the mask layer 118G, and the mask layer 118B are not completely removed by the first etching treatment and the mask layer 118R, the mask layer 118G, and the mask layer 118B with reduced thicknesses remain, the EL layer 113R, the EL layer 113G, and the EL layer 113B can be inhibited from being damaged and deteriorating in the post-baking, for example. Thus, the reliability of the light-emitting element can be increased.

As illustrated in FIG. 7A and FIG. 7B, the side surface of the insulating layer 127 might have a concave shape depending on the material of the insulating layer 127, and the temperature, time, and atmosphere of the post-baking. For example, the insulating layer 127 is more likely to be changed in shape to have a concave shape as the post-baking is performed at higher temperature or for a longer time. In addition, as described above, the insulating layer 127 is sometimes likely to be changed in shape at the time of the post-baking, in the case where light exposure is not performed on the insulating layer 127a after development.

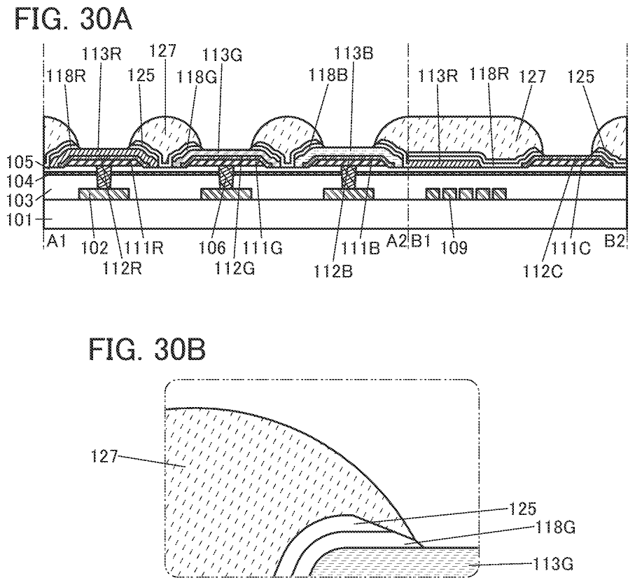

Next, as illustrated in FIG. 30A and FIG. 30B, etching treatment is performed with the insulating layer 127 as a mask to remove part of the mask layer 118R, the mask layer 118G, and the mask layer 118B. Note that part of the insulating layer 125 is also removed in some cases. Thus, openings are formed in the mask layer 118R, the mask layer 118G, and the mask layer 118B, and the upper surfaces of the EL layer 113R, the EL layer 113G, and the EL layer 113B and the conductive layer 112C are exposed. Note that FIG. 30B is an enlarged view of the end portions of the EL layer 113G and the insulating layer 127 illustrated in FIG. 30A and their vicinities. Note that the etching treatment using the insulating layer 127 as a mask may be hereinafter referred to as second etching treatment.

The end portion of the insulating layer 125 is covered with the insulating layer 127. FIG. 30A and FIG. 30B illustrate an example where part of the end portion of the mask layer 118G, specifically, a tapered portion formed by the first etching treatment, is covered with the insulating layer 127 and the tapered portion formed by the second etching treatment is exposed. That is, the structure in FIG. 30A and FIG. 30B corresponds to that in FIG. 5A and FIG. 5B.

If the first etching treatment is not performed and the insulating layer 125 and the mask layer are collectively etched after the post-baking, the insulating layer 125 and the mask layer under the end portion of the insulating layer 127 may be eliminated by side etching and a cavity may be formed. The cavity causes unevenness in the formation surface of the common layer 114 and the common electrode 115, so that disconnection is likely to occur in the common layer 114 and the common electrode 115. Even when a cavity is formed owing to side etching of the insulating layer 125 and the mask layer by the first etching treatment, the post-baking performed subsequently can make the insulating layer 127 fill the cavity. After that, the mask layer having a smaller thickness is etched by the second etching treatment: thus, the amount of side etching decreases, a cavity is less likely to be formed, and even if a cavity is formed, it can be extremely small. Therefore, the formation surface of the common layer 114 and the common electrode 115 can be flatter.

Note that as illustrated in FIG. 6A and FIG. 6B or FIG. 8A, and FIG. 8B, the insulating layer 127 may cover the entire end portion of the mask layer 118G. For example, the end portion of the insulating layer 127 sags and covers the end portion of the mask layer 118G in some cases. For another example, the end portion of the insulating layer 127 may be in contact with the upper surface of at least one of the EL layer 113R, the EL layer 113G, and the EL layer 113B. As described above, in the case where light exposure is not performed on the insulating layer 127a after development, the shape of the insulating layer 127 is likely to change in some cases.

The second etching treatment is performed by wet etching. Using a wet etching method can reduce damage to the EL layer 113R, the EL layer 113G, and the EL layer 113B, as compared to the case of using a dry etching method. The wet etching can be performed using an alkaline solution such as TMAH, for example.

Meanwhile, in the case where the second etching treatment is performed by a wet etching method and gaps due to, for example, poor adhesion between the EL layer 113 and another layer exist at the interface between the EL layer 113 and the mask layer 118, the interface between the EL layer 113 and the inorganic insulating layer 125, and the interface between the EL layer 113 and the insulating layer 105, the chemical solution used in the second etching treatment sometimes enters the gaps to come into contact with the pixel electrode. Here, when the chemical solution comes into contact with both the conductive layer 111 and the conductive layer 112, one of the conductive layer 111 and the conductive layer 112 that has a lower spontaneous potential than the other suffers from galvanic corrosion in some cases. For example, when the conductive layer 111 is formed using aluminum and the conductive layer 112 is formed using indium tin oxide, the conductive layer 112 sometimes corrodes. As a result, the yield of the display device decreases in some cases. This degrades the reliability of the display device in some cases.

In the method of manufacturing the display device of one embodiment of the present invention, the conductive layer 112 is formed to cover the upper surface and the side surface of the conductive layer 111 as described above. Thus, even when gaps exist at the interface between the EL layer 113 and the mask layer 118, the interface between the EL layer 113 and the inorganic insulating layer 125, and the interface between the EL layer 113 and the insulating layer 105, for example, the chemical solution can be prevented from coming into contact with the conductive layer 111 in the second etching treatment. Thus, corrosion of the pixel electrode, e.g., the conductive layer 112, can be inhibited. As described above, the method of manufacturing the display device of one embodiment of the present invention can achieve high yield. In addition, the method of manufacturing the display device of one embodiment of the present invention can inhibit generation of defects.

As described above, by providing the insulating layer 127, the insulating layer 125, the mask layer 118R, the mask layer 118G, and the mask layer 118B, a connection defect due to a disconnected portion and an increase in electrical resistance due to a locally thinned portion can be inhibited from occurring in the common layer 114 and the common electrode 115 between the light-emitting elements. Thus, the display device of one embodiment of the present invention can have improved display quality.

Heat treatment may be performed after part of the EL layer 113R, the EL layer 113G, and the EL layer 113B is exposed. The heat treatment can remove water contained in the EL layer 113, water adsorbed onto a surface of the EL layer 113, and the like. The shape of the insulating layer 127 may be changed by the heat treatment. Specifically, the insulating layer 127 may be extended to cover at least one of the end portion of the insulating layer 125, the end portions of the mask layer 118R, the mask layer 118G, and the mask layer 118B, and the upper surfaces of the EL layer 113R, the EL layer 113G, and the EL layer 113B. For example, the insulating layer 127 may have a shape illustrated in FIG. 6A and FIG. 6B. For example, heat treatment in an inert gas atmosphere or a reduced-pressure atmosphere can be performed. The heat treatment can be performed at a substrate temperature higher than or equal to 50° C., and lower than or equal to 200° C., preferably higher than or equal to 60° C., and lower than or equal to 150° C., further preferably higher than or equal to 70° C., and lower than or equal to 120° C. The heat treatment is preferably performed in a reduced-pressure atmosphere, in which case dehydration at a lower temperature is possible. Note that the temperature range of the heat treatment is preferably set as appropriate in consideration of the upper temperature limit of the EL layer 113. In consideration of the upper temperature limit of the EL layer 113, temperatures from 70° C. to 120° C. inclusive are particularly preferable in the above temperature range.

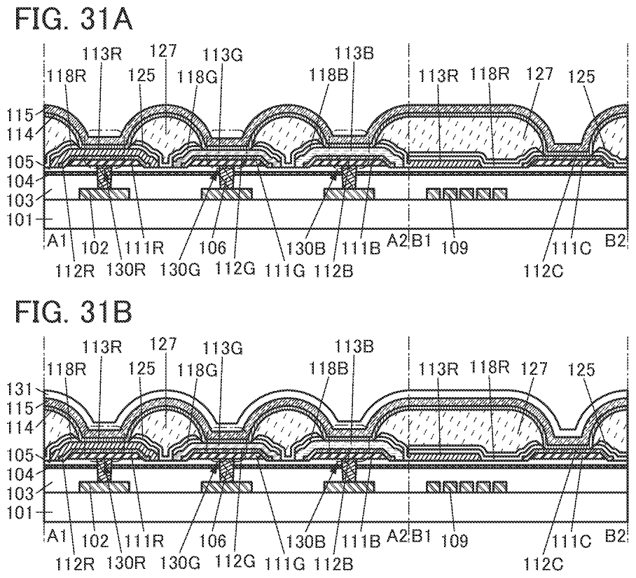

Then, as illustrated in FIG. 31A, the common layer 114 is formed over the EL layer 113R, over the EL layer 113G, over the EL layer 113B, over the conductive layer 112C, and over the insulating layer 127. The common layer 114 can be formed by a method such as an evaporation method (including a vacuum evaporation method), a transfer method, a printing method, an inkjet method, or a coating method.

Then, as illustrated in FIG. 31A, the common electrode 115 is formed over the common layer 114. The common electrode 115 can be formed by a method such as a sputtering method or a vacuum evaporation method. Alternatively, the common electrode 115 may be formed in such a manner that a film formed by an evaporation method and a film formed by a sputtering method are stacked.

The common electrode 115 can be formed successively without a process such as etching between formations of the common layer 114 and the common electrode 115. For example, after the common layer 114 is formed in a vacuum, the common electrode 115 can be formed in a vacuum without exposing the substrate to the air. In other words, the common layer 114 and the common electrode 115 can be successively formed in a vacuum. Accordingly, the lower surface of the common electrode 115 can be a clean surface, as compared to the case where the common layer 114 is not provided in the display device 100. Thus, the light-emitting element 130 can have high reliability and favorable characteristics.

Next, the protective layer 131 is formed over the common electrode 115, as illustrated in FIG. 31B. The protective layer 131 can be formed by a vacuum evaporation method, a sputtering method, a CVD method, an ALD method, or the like.

Subsequently, the substrate 120 is attached onto the protective layer 131 with the resin layer 122, whereby the display device having the structure illustrated in FIG. 2A or the structure illustrated in FIG. 18A can be manufactured. In the method of manufacturing the display device of one embodiment of the present invention, the conductive layer 112 is formed to cover the upper surface and the side surface of the conductive layer 111 as described above, which can increase the yield of the display device and inhibit generation of defects.

Here, after the insulating layer 127 is formed by the post-baking illustrated in FIG. 29A and FIG. 29B, the insulating layer 127 may be exposed to light. For example, the insulating layer 127 may be exposed to light in the case where the aforementioned light exposure is not performed on the insulating layer 127a. For example, the insulating layer 127 may be exposed to light after the second etching treatment illustrated in FIG. 30A and FIG. 30B but before the formation of the common layer 114 illustrated in FIG. 31A. Alternatively, the insulating layer 127 may be exposed to light after the formation of the common electrode 115 illustrated in FIG. 31A but before the formation of the protective layer 131 illustrated in FIG. 31B. Alternatively, the insulating layer 127 may be exposed to light after the formation of the protective layer 131 illustrated in FIG. 31B. Here, for example, the conditions similar to those for the aforementioned light exposure of the insulating layer 127a can be used as the conditions for light exposure of the insulating layer 127. Note that light exposure of the insulating layer 127a and light exposure of the insulating layer 127 may be omitted, performed only once in total, or performed two or more times in total.

For example, in the case where a photocurable resin is used for the insulating layer 127, light exposure of the insulating layer 127 can cure the insulating layer 127. Consequently, deformation of the insulating layer 127 can be inhibited. Thus, peeling of the layer over the insulating layer 127 can be inhibited, for example. Consequently, the display device of one embodiment of the present invention can be a highly reliable display device.

As described above, in the method of manufacturing a display device of one embodiment of the present invention, the island-shaped EL layer 113R, the island-shaped EL layer 113G, and the island-shaped EL layer 113B are formed not by using a fine metal mask but by processing a film formed over the entire surface: thus, the island-shaped layers can be formed to have a uniform thickness. Accordingly, a high-resolution display device or a display device with a high aperture ratio can be achieved. Furthermore, even when the resolution or the aperture ratio is high and the distance between the subpixels is extremely short, the EL layer 113R, the EL layer 113G, and the EL layer 113B can be inhibited from being in contact with each other in adjacent subpixels. As a result, generation of a leakage current between the subpixels can be inhibited. This can prevent crosstalk due to unintended light emission, so that a display device with extremely high contrast can be achieved.

The insulating layer 127 having a tapered end portion and being provided between adjacent island-shaped EL layers 113 can inhibit occurrence of disconnection and prevent formation of a locally thinned portion in the common electrode 115 at the time of forming the common electrode 115. Thus, a connection defect due to a disconnected portion and an increase in electric resistance due to a locally thinned portion can be inhibited from occurring in the common layer 114 and the common electrode 115. Hence, the display device of one embodiment of the present invention achieves both high resolution and high display quality.

### Manufacturing Method Example 2

A manufacturing method example of the display device 100 having the structure illustrated in FIG. 10 and the structure illustrated in FIG. 18C will be described below with reference to drawings. Note that steps different from those in the method described with FIG. 24A to FIG. 31B will be mainly described, and the description of the same steps as those in the method described with FIG. 24A to FIG. 31B will be omitted as appropriate.

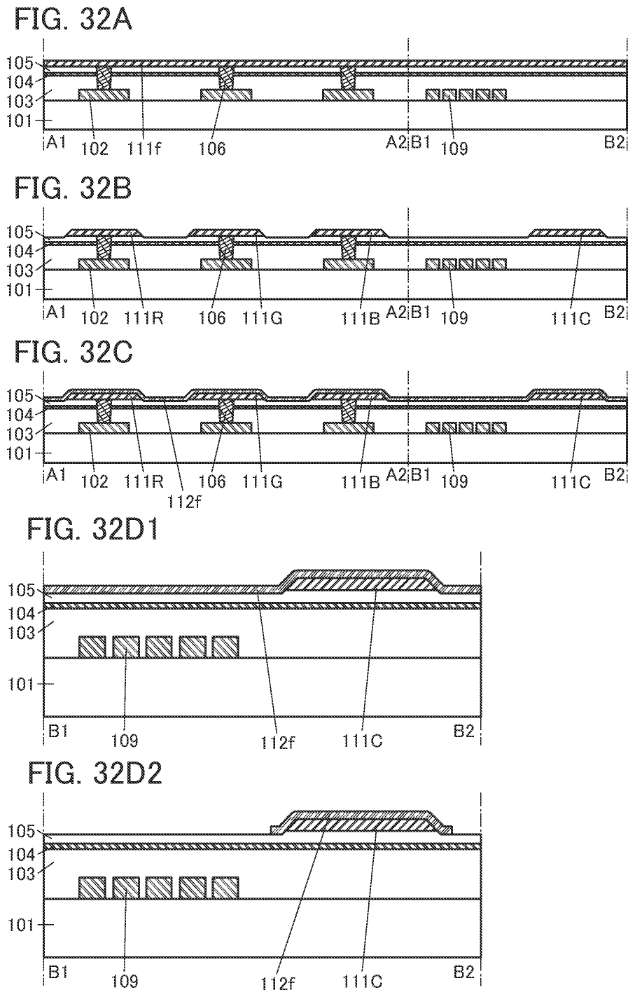

FIG. 32A to FIG. 32C illustrate steps similar to those in FIG. 24A to FIG. 24C.

FIG. 32D1 is an enlarged view of a cross section along the line B1-B2 shown in FIG. 32C. In the example illustrated in FIG. 32D1, the conductive film 112f includes a region overlapping with the conductive layer 109.

FIG. 32D2 illustrates a modification example of FIG. 32D1, and in the example, the conductive film 112f does not overlap with the conductive layer 109. For example, after the conductive film 112f is formed as illustrated in FIG. 32C, the conductive film 112f is partly removed in a region along the line B1-B2, whereby a structure illustrated in FIG. 32D2 can be fabricated. When a step illustrated in FIG. 32D2 is performed, the fabricated structure along the line B1-B2 in the display device 100 becomes the structure illustrated in FIG. 18A, for example.

For example, the conductive film 112f provided in the region overlapping with the conductive layer 109 is removed so that the conductive layer 112C formed in a later step does not overlap with the conductive layer 109. As a result, generation of parasitic capacitance can be inhibited as described above, for example. It may be assumed that the conductive layer 112C is formed by the step illustrated in FIG. 32D2. That is, in FIG. 32D2, the conductive film 112f may be replaced with the conductive layer 112C.

The manufacturing method example of the display device 100 is described below assuming that the step illustrated in FIG. 32D2 is not performed. However, the following description of the manufacturing method example can be referred to for the case where the step illustrated in FIG. 32D2 is performed.

Next, hydrophobization treatment is preferably performed on the conductive film 112f, as described above.

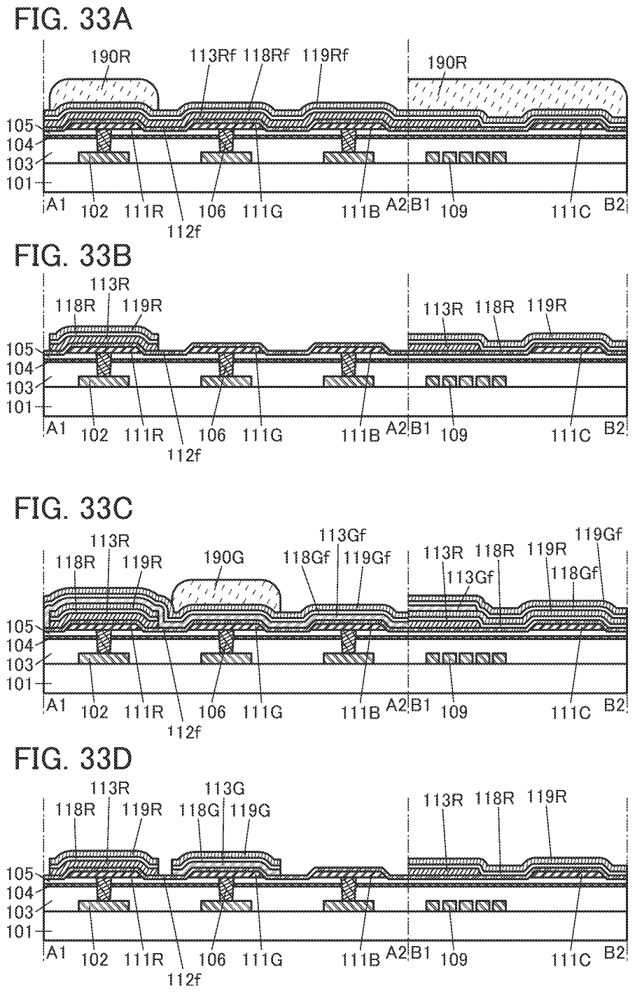

Subsequently, as illustrated in FIG. 33A, the EL film 113Rf to be the EL layer 113R later is formed over the conductive film 112f by a method similar to the method illustrated in FIG. 25A. After that, the mask film 118Rf to be the mask layer 118R later and the mask film 119Rf to be the mask layer 119R later are sequentially formed over the EL film 113Rf and over the conductive film 112f by a method similar to the method illustrated in FIG. 25A.

Next, as illustrated in FIG. 33A, the resist mask 190R is formed over the mask film 119Rf by a method similar to the method illustrated in FIG. 25A. The resist mask 190R is provided at a position overlapping with the conductive layer 111R. The resist mask 190R can also be provided at a position overlapping with the conductive layer 111C.

Subsequently, as illustrated in FIG. 33A and FIG. 33B, part of the mask film 119Rf is removed using the resist mask 190R by a method similar to the method illustrated in FIG. 25A and FIG. 25B, whereby the mask layer 119R is formed. The mask layer 119R remains over the conductive layer 111R and over the conductive layer 111C. After that, the resist mask 190R is removed by a method similar to the method illustrated in FIG. 25A and FIG. 25B. Next, by a method similar to the method illustrated in FIG. 25A and FIG. 25B, part of the mask film 118Rf is removed using the mask layer 119R as a mask, whereby the mask layer 118R is formed.

Next, as illustrated in FIG. 33A and FIG. 33B, the EL film 113Rf is processed by a method similar to the method illustrated in FIG. 25A and FIG. 25B, whereby the EL layer 113R is formed. For example, part of the EL film 113Rf is removed using the mask layer 119R and the mask layer 118R as a mask to form the EL layer 113R. Accordingly, as illustrated in FIG. 33B, the stacked-layer structure of the EL layer 113R, the mask layer 118R, and the mask layer 119R remains over the conductive film 112f to include a region overlapping with the conductive layer 111R. In a region where the mask layer 119R is not provided, the conductive film 112f is exposed.

The resist mask 190R is preferably provided to cover the area from the end portion of the EL layer 113R to the end portion of the conductive layer 111C (the end portion closer to the EL layer 113R) in the cross section B1-B2. Thus, as illustrated in FIG. 33B, the mask layers 118R and 119R are provided to cover the area from the end portion of the EL layer 113R to the end portion of the conductive layer 111C (the end portion closer to the EL layer 113R) in the cross section B1-B2. Hence, the conductive film 112f can be inhibited from being exposed in the cross section B1-B2, for example. This can inhibit the conductive film 112f, the insulating layer 105, the insulating layer 104, and the insulating layer 103 from being partly removed by etching, for example, and thus inhibit the conductive layer 109 from being exposed. Thus, unintentional electrical connection between the conductive layer 109 and another conductive layer can be inhibited. For example, a short circuit between the conductive layer 109 and the common electrode 115 formed in a later step can be inhibited.

Next, hydrophobic treatment for the conductive film 112f, for example, is preferably performed. At the time of processing the EL film 113Rf, the surface of the conductive film 112f changes to have hydrophilic properties in some cases, for example. The hydrophobization treatment for the conductive film 112f, for example, can increase the adhesion between the conductive film 112f and a layer to be formed in a later step (which is the EL layer 113G here) and inhibit peeling. Note that the hydrophobization treatment is not necessarily performed.

Subsequently, as illustrated in FIG. 33C, the EL film 113Gf to be the EL layer 113G later is formed over the conductive film 112f and over the mask layer 119R by a method similar to the method illustrated in FIG. 25C.

Then, as illustrated in FIG. 33C, the mask film 118Gf to be the mask layer 118G later and the mask film 119Gf to be the mask layer 119G later are sequentially formed over the EL film 113Gf and over the mask layer 119R by a method similar to the method illustrated in FIG. 25C. After that, a resist mask 190G is formed.

The resist mask 190G is provided at a position overlapping with the conductive layer 111G.

Subsequently, as illustrated in FIG. 33C and FIG. 33D, part of the mask film 119Gf is removed using the resist mask 190G by a method similar to the method illustrated in FIG. 25C and

FIG. 25D, whereby the mask layer 119G is formed. The mask layer 119G remains over the conductive layer 111G. After that, the resist mask 190G is removed by a method similar to the method illustrated in FIG. 25C and FIG. 25D. Next, by a method similar to the method illustrated in FIG. 25C and FIG. 25D, part of the mask film 118Gf is removed using the mask layer 119G as a mask, whereby the mask layer 118G is formed. Next, the EL film 113Gf is processed to form the EL layer 113G by a method similar to the method illustrated in FIG. 25C and FIG. 25D. For example, part of the EL film 113Gf is removed using the mask layer 119G and the mask layer 118G as a mask to form the EL layer 113G.

Accordingly, as illustrated in FIG. 33D, the stacked-layer structure of the EL layer 113G, the mask layer 118G, and the mask layer 119G remains over the conductive layer 111G. The mask layer 119R is exposed, and the conductive film 112f is exposed in regions where neither the mask layer 119R nor the mask layer 119G is provided.

Next, hydrophobic treatment for the conductive film 112f, for example, is preferably performed. At the time of processing the EL film 113Gf, the surface of the conductive film 112f changes to have hydrophilic properties in some cases, for example. The hydrophobization treatment for the conductive film 112f, for example, can increase the adhesion between the conductive film 112f and a layer to be formed in a later step (which is the EL layer 113B here) and inhibit peeling. Note that the hydrophobization treatment is not necessarily performed.

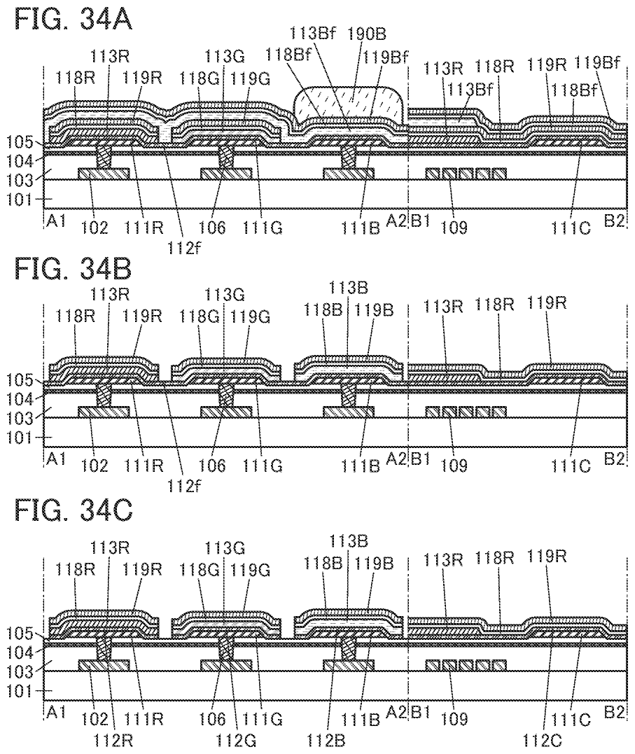

Subsequently, as illustrated in FIG. 34A, the EL film 113Bf to be the EL layer 113B later is formed over the conductive film 112f, over the mask layer 119R, and over the mask layer 119G by a method similar to the method illustrated in FIG. 26A.

Then, as illustrated in FIG. 34A, the mask film 118Bf to be the mask layer 118B later and the mask film 119Bf to be the mask layer 119B later are sequentially formed over the EL film 113Bf and over the mask layer 119R by a method similar to the method illustrated in FIG. 26A. After that, a resist mask 190B is formed.

The resist mask 190B is provided at a position overlapping with the conductive layer 111B.

Subsequently, as illustrated in FIG. 34A and FIG. 34B, part of the mask film 119Bf is removed using the resist mask 190B, whereby the mask layer 119B is formed. The mask layer 119B remains over the conductive layer 111B. After that, the resist mask 190B is removed. Then, part of the mask film 118Bf is removed using the mask layer 119B as a mask, whereby the mask layer 118B is formed. Next, the EL film 113Bf is processed to form the EL layer 113B. For example, part of the EL film 113Bf is removed using the mask layer 119B and the mask layer 118B as a mask to form the EL layer 113B.

Accordingly, as illustrated in FIG. 34B, the stacked-layer structure of the EL layer 113B, the mask layer 118B, and the mask layer 119B remains over the conductive layer 111B. The mask layer 119R and the mask layer 119G are exposed, and the conductive film 112f is exposed in regions where none of the mask layer 119R, the mask layer 119G, and the mask layer 119B is provided.

Next, as illustrated in FIG. 34B and FIG. 34C, part of the conductive film 112f is removed by an etching method using the mask layer 119R, the mask layer 119G, and the mask layer 119B as a mask, for example. Consequently, the conductive layer 112R, the conductive layer 112G, the conductive layer 112B, and the conductive layer 112C are formed. In the case where a conductive oxide is used for the conductive film 112f, the conductive film 112f can be removed by a wet etching method, for example. The conductive layer 112 is formed to cover the upper surface and the side surface of the conductive layer 111. In the case where the conductive layer 112 has the structure illustrated in FIG. 2B2, a metal material is used for the conductive layer 112a, and a conductive oxide is used for the conductive layer 112b, for example, a conductive film to be the conductive layer 112a can be partly removed by a dry etching method after a conductive film to be the conductive layer 112b is partly removed by a wet etching method.

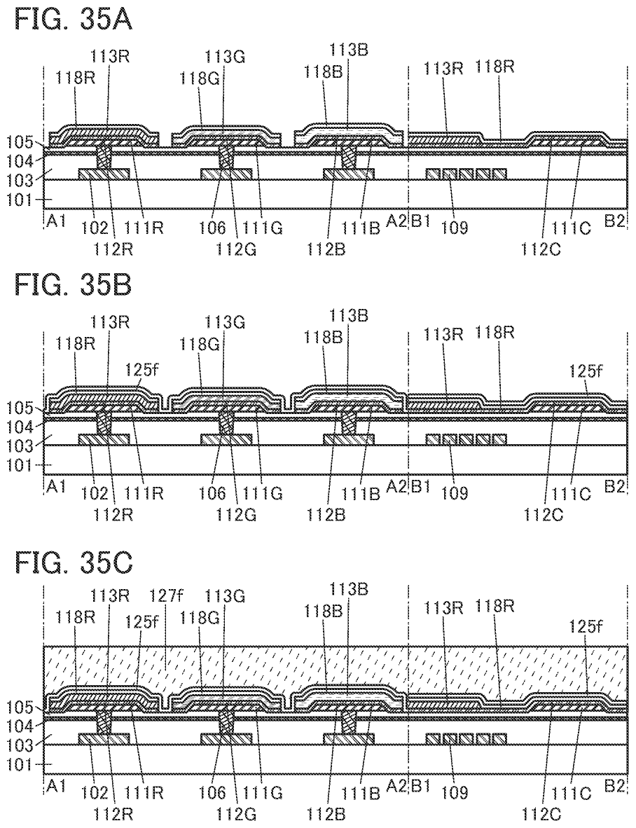

Next, d as illustrated in FIG. 35A, the mask layer 119R, the mask layer 119G, and the mask layer 119B are preferably remove, by a method similar to the method illustrated in FIG. 26C.

Next, as illustrated in FIG. 35B, the insulating film 125f to be the insulating layer 125 later is formed to cover the conductive layer 112R, the conductive layer 112G, the conductive layer 112B, EL layer 113R, EL layer 113G, EL layer 113B, the mask layer 118R, the mask layer 118G, and the mask layer 118B by a method similar to the method illustrated in FIG. 26D.

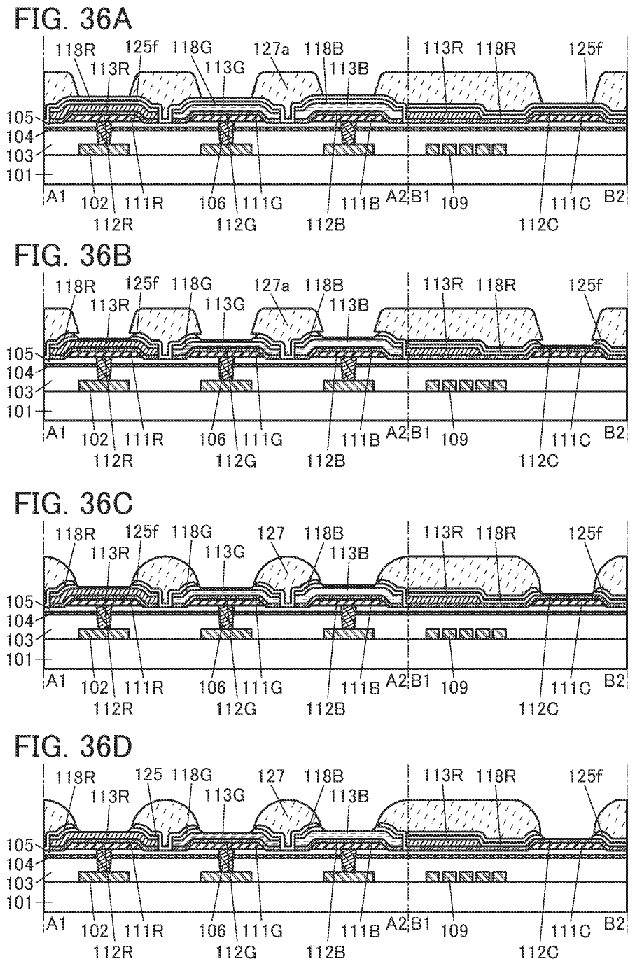

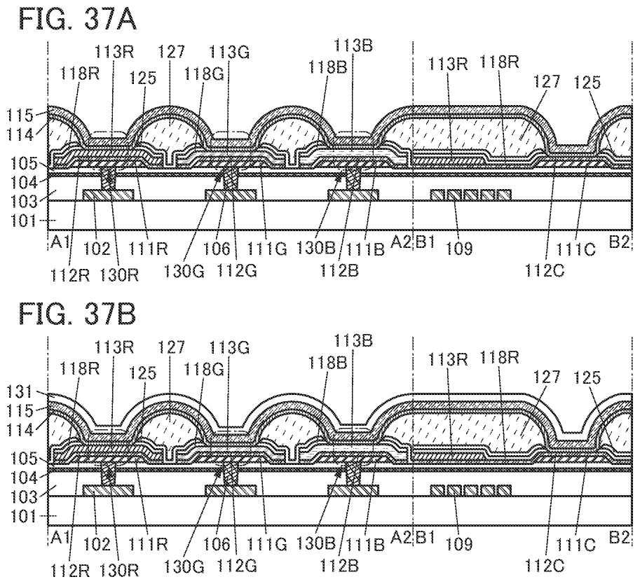

FIG. 35C, FIG. 36A to FIG. 36D, FIG. 37A, and FIG. 37B show steps similar to those in FIG. 27A, FIG. 27B1, FIG. 28A, FIG. 29A, FIG. 30A, FIG. 31A, and FIG. 31B. After the step illustrated in FIG. 37B, the substrate 120 is attached onto the protective layer 131 with the resin layer 122, whereby the display device having the structure illustrated in FIG. 10 and the structure illustrated in FIG. 18C can be manufactured.

### Manufacturing Method Example 3

A manufacturing method example of the display device 100 having the structure illustrated in FIG. 14 and the structure illustrated in FIG. 18E will be described below with reference to drawings. Note that steps different from those in the method described with FIG. 24A to FIG. 31B will be mainly described, and the description of the same steps as those in the method described with FIG. 24A to FIG. 31B will be omitted as appropriate.

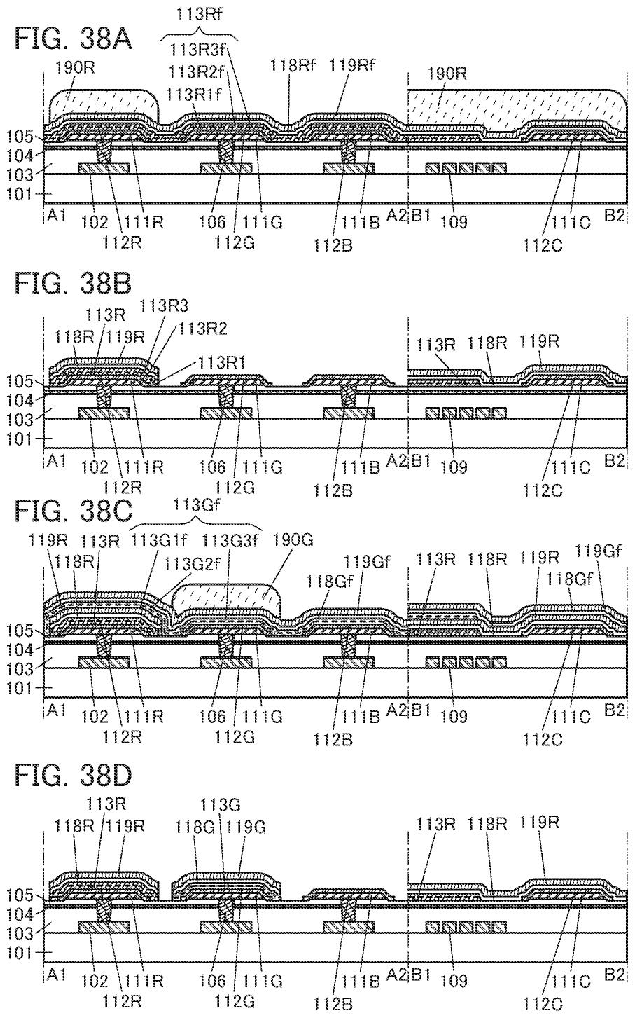

First, steps similar to the steps illustrated in FIG. 24A to FIG. 24D are performed. Next, as illustrated in FIG. 38A, an EL film 113Rf to be the EL layer 113R later is formed over conductive layer 112R, over the conductive layer 112G, over the conductive layer 112B, and over the insulating layer 105 by a method similar to the method illustrated in FIG. 25A. The EL film 113Rf includes a film 113R1f to be the light-emitting unit 113R1 later, a charge-generation film 113R2f to be the charge-generation layer 113R2 later, and a film 113R3f to be the light-emitting unit 113R3 later. In FIG. 38A, the charge-generation film 113Rf2 is indicated by a dashed line.

Next, as illustrated in FIG. 38A, the mask film 118Rf to be the mask layer 118R later and the mask film 119Rf to be the mask layer 119R later are sequentially formed over the EL film 113Rf, over the conductive layer 112C, and over the insulating layer 105 by a method similar to the method illustrated in FIG. 25A. Next, as illustrated in FIG. 38A, the resist mask 190R is formed over the mask film 119Rf by a method similar to the method illustrated in FIG. 25A.

Subsequently, as illustrated in FIG. 38A and FIG. 38B, part of the mask film 119Rf is removed using the resist mask 190R by a method similar to the method illustrated in FIG. 25A and FIG. 25B, whereby the mask layer 119R is formed. The mask layer 119R remains over the conductive layer 111R and over the conductive layer 111C. After that, the resist mask 190R is removed by a method similar to the method illustrated in FIG. 25A and FIG. 25B. Next, by a method similar to the method illustrated in FIG. 25A and FIG. 25B, part of the mask film 118Rf 20) is removed using the mask layer 119R as a mask, whereby the mask layer 118R is formed.

Next, as illustrated in FIG. 38A and FIG. 38B, the EL film 113Rf is processed by a method similar to the method illustrated in FIG. 25A and FIG. 25B, whereby the EL layer 113R is formed. For example, part of the EL film 113Rf is removed using the mask layer 119R and the mask layer 118R as a mask to form the EL layer 113R. As described above, the EL layer 113R includes the light-emitting unit 113R1, the charge-generation layer 113R2 over the light-emitting unit 113R1, and the light-emitting unit 113R3 over the charge-generation layer 113R2, for example. Note that the charge-generation layer 113R2 is indicated by the dashed line.

Next, the hydrophobization treatment for the conductive layer 112G, for example, is preferably performed because it can increase the adhesion between the conductive layer 112G and a layer to be formed in a later step (which is the EL layer 113G here) and inhibit peeling, as described above. Note that the hydrophobization treatment is not necessarily performed.

Next, as illustrated in FIG. 38C, an EL film 113Gf to be the EL layer 113G later is formed over the conductive layer 112G, over the conductive layer 112B, over the mask layer 119R, and over the insulating layer 105 by a method similar to the method illustrated in FIG. 25C. The EL film 113Gf includes a film 113G1f to be the light-emitting unit 113G1 later, a charge-generation film 113G2f to be the charge-generation layer 113G2 later, and a film 113G3f to be the light-emitting unit 113G3 later. In FIG. 38C, the charge-generation film 113Gf2 is indicated by a dashed line.

Then, as illustrated in FIG. 38C, the mask film 118Gf to be the mask layer 118G later and the mask film 119Gf to be the mask layer 119G later are sequentially formed over the EL film 113Gf and over the mask layer 119R by a method similar to the method illustrated in FIG. 25C. After that, a resist mask 190G is formed by a method similar to the method illustrated in FIG. 25C.

Subsequently, as illustrated in FIG. 38C and FIG. 38D, part of the mask film 119Gf is removed using the resist mask 190G by a method similar to the method illustrated in FIG. 25C and FIG. 25D, whereby the mask layer 119G is formed. After that, the resist mask 190G is removed by a method similar to the method illustrated in FIG. 25C and FIG. 25D. Next, by a method similar to the method illustrated in FIG. 25C and FIG. 25D, part of the mask film 118Gf is removed using the mask layer 119G as a mask, whereby the mask layer 118G is formed. Next, the EL film 113Gf is processed to form the EL layer 113G by a method similar to the method illustrated in FIG. 25C and FIG. 25D. The EL layer 113G includes the light-emitting unit 113G1, the charge-generation layer 113G2 over the light-emitting unit 113G1, and the light-emitting unit 113G3 over the charge-generation layer 113G2, for example. Note that the charge-generation layer 113G2 is indicated by the dashed line.

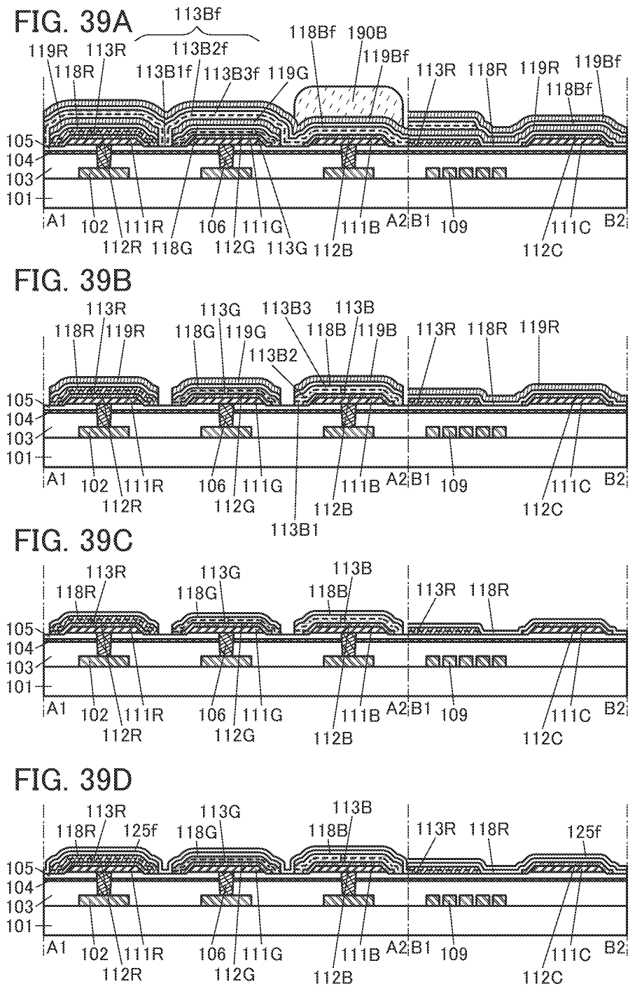

Next, as illustrated in FIG. 39A, an EL film 113Bf to be the EL layer 113B later is formed over the conductive layer 112B, over the mask layer 119R, over the mask layer 119G, and over the insulating layer 105 by a method similar to the method illustrated in FIG. 26A. The EL film 113Bf includes a film 113B1f to be the light-emitting unit 113B1 later, a charge-generation film 113B2f to be the charge-generation layer 113B2 later, and a film 113B3f to be the light-emitting unit 113B3 later. In FIG. 39A, the charge-generation film 113Bf2 is indicated by a dashed line.

Then, as illustrated in FIG. 39A, the mask film 118Bf to be the mask layer 118B later and the mask film 119Bf to be the mask layer 119B later are sequentially formed over the EL film 113Bf and over the mask layer 119R by a method similar to the method illustrated in FIG. 26A. After that, a resist mask 190B is formed by a method similar to the method illustrated in FIG. 26A.

Subsequently, as illustrated in FIG. 39A and FIG. 39B, part of the mask film 119Bf is removed using the resist mask 190B to form the mask layer 119B by a method similar to the method illustrated in FIG. 26A and FIG. 26B. After that, the resist mask 190B is removed by a method similar to the method illustrated in FIG. 26A and FIG. 26B. Next, by a method similar to the method illustrated in FIG. 26A and FIG. 26B, part of the mask film 118Bf is removed using the mask layer 119B as a mask, whereby the mask layer 118B is formed. Next, the EL film 113Bf is processed to form the EL layer 113B by a method similar to the method illustrated in FIG. 26A and FIG. 26B. As described above, the EL layer 113B includes the light-emitting unit 113B1, the charge-generation layer 113B2 over the light-emitting unit 113B1, and the light-emitting unit 113B3 over the charge-generation layer 113B2, for example. Note that the charge-generation layer 113B2 is indicated by the dashed line.

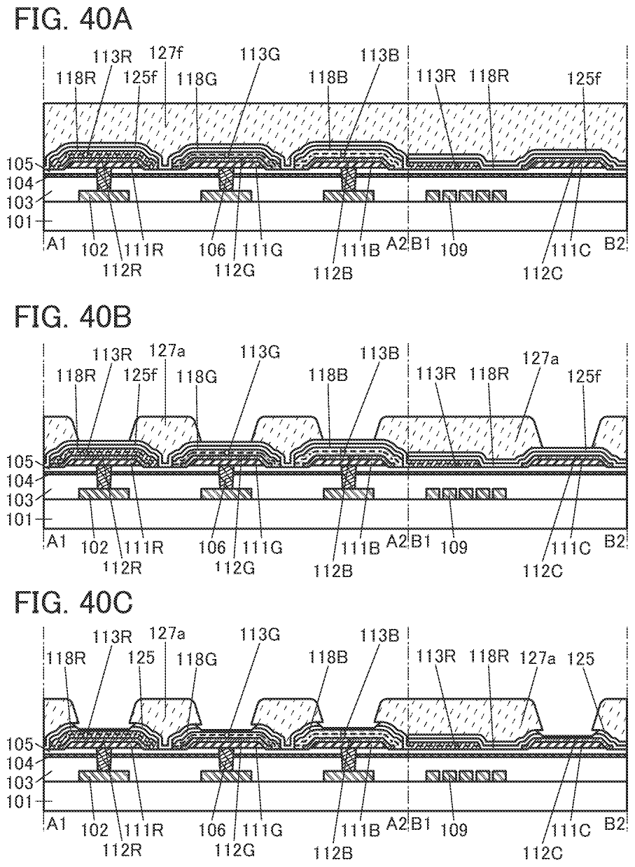

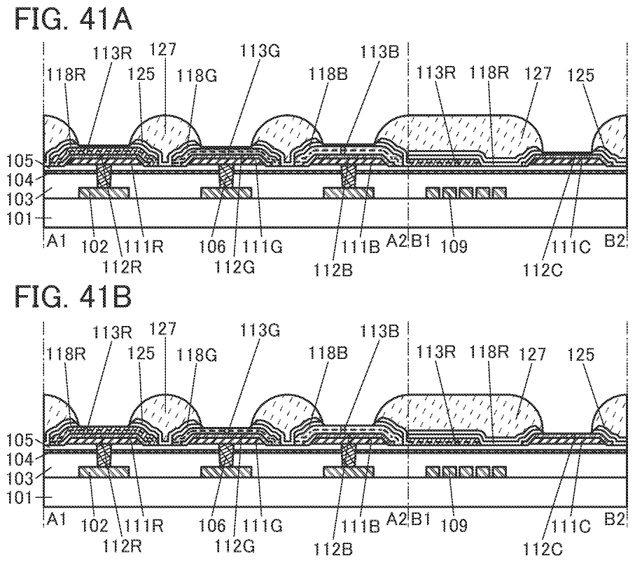

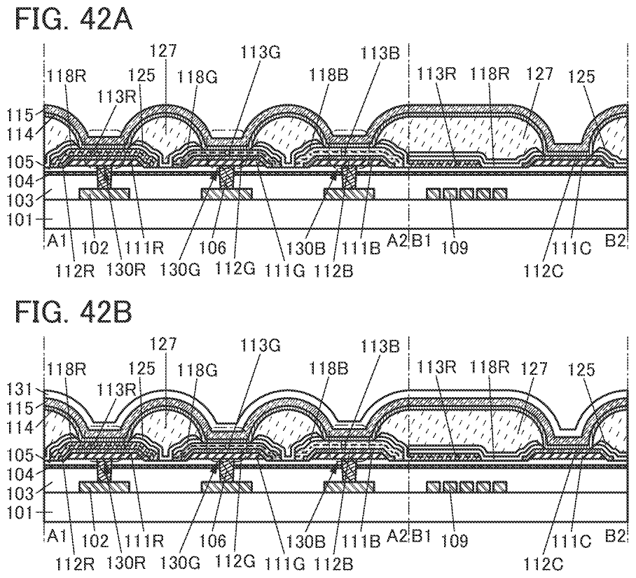

FIG. 39C, FIG. 39D, FIG. 40A to FIG. 40C, FIG. 41A, FIG. 41B, FIG. 42A, and FIG. 42B show steps similar to those in FIG. 26C, FIG. 26D, FIG. 27A, FIG. 27B1, FIG. 28A, FIG. 29A, FIG. 30A, FIG. 31A, and FIG. 31B. After the step illustrated in FIG. 42B, the substrate 120 is attached onto the protective layer 131 with the resin layer 122, whereby the display device having the structure illustrated in FIG. 14 and the structure illustrated in FIG. 18E can be manufactured.

### Manufacturing Method Example 4

A manufacturing method example of the display device 100 having the structure illustrated in FIG. 19A and the structure illustrated in FIG. 18A will be described below with reference to drawings. Note that steps different from those in the method described with FIG. 24A to FIG. 31B will be mainly described, and the description of the same steps as those in the method described with FIG. 24A to FIG. 31B will be omitted as appropriate.

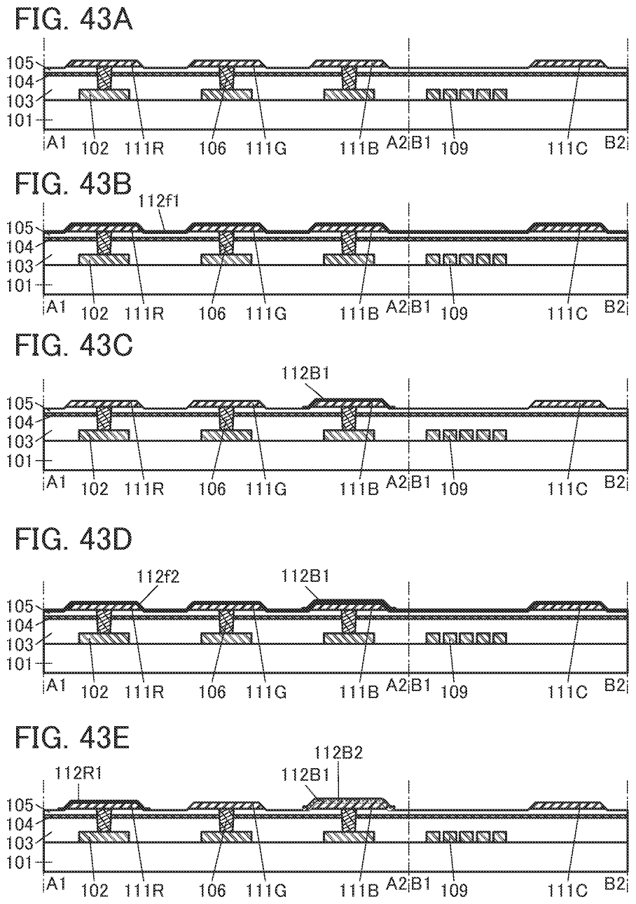

First, steps similar to the steps illustrated in FIG. 24A and FIG. 24B are performed. Thus, the conductive layer 111R, the conductive layer 111G, the conductive layer 111B, and the conductive layer 111C are formed over the plugs 106 and over the insulating layer 105, as illustrated in FIG. 43A.

Next, as illustrated in FIG. 43B, a conductive film 112f1 is formed over the conductive layer 111R, over the conductive layer 111G, over the conductive layer 111B, over the conductive layer 111C, and over the insulating layer 105. The conductive film 112f1 can be formed by a method similar to the method for the conductive film 112f illustrated in FIG. 24C, for example, and formed using a material similar to that for the conductive film 112f.

Then, as illustrated in FIG. 43B and FIG. 43C, the conductive film 112f1 is processed to form a conductive layer 112B1 that covers the upper surface and the side surface of the conductive layer 111B. The conductive film 112f1 can be processed by a method similar to the method for processing the conductive film 112f.

Next, as illustrated in FIG. 43D, a conductive film 112f2 is formed over the conductive layer 111R, over the conductive layer 111G, over the conductive layer 112B1, over the conductive layer 111C, and over the insulating layer 105. The conductive film 112f2 can be formed using a method and a material similar to those for the conductive film 112f.

Subsequently, as illustrated in FIG. 43D and FIG. 43E, the conductive film 112f2 is processed, thereby forming the conductive layer 112R1 that covers the upper surface and the side surface of the conductive layer 111R and a conductive layer 112B2 over the conductive layer 112B1. In FIG. 43E, the boundary between the conductive layer 112B1 and the conductive layer 112B2 is indicated by a dotted line.

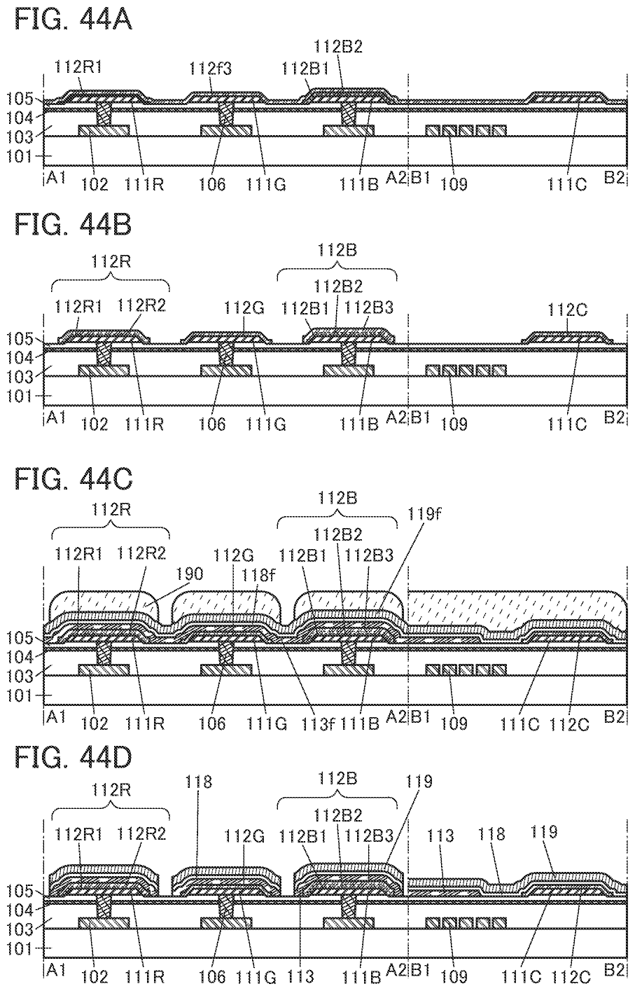

Next, as illustrated in FIG. 44A, a conductive film 112f3 is formed over the conductive layer 112R1, over the conductive layer 111G, over the conductive layer 112B2, over the conductive layer 111C, and over the insulating layer 105. The conductive film 112f3 can be formed using a method and a material similar to those for the conductive film 112f.

Then, as illustrated in FIG. 44A and FIG. 44B, the conductive film 112f3 is processed, thereby forming a conductive layer 112R2 over the conductive layer 112R1, the conductive layer 112G that covers the upper surface and the side surface of the conductive layer 111G, a conductive layer 112B3 over the conductive layer 112B2, and the conductive layer 112C that covers the upper surface and the side surface of the conductive layer 111C. The conductive layer 112R, the conductive layer 112R can form the conductive layer 112R, and the conductive layer 112B1, the conductive layer 112B2, and the conductive layer 112B3 can form the conductive layer 112B. The conductive film 112f3 can be processed by a method similar to the method for processing the conductive film 112f. In FIG. 44B, the boundary between the conductive layer 112R1 and the conductive layer 112R2, the boundary between the conductive layer 112B1 and the conductive layer 112B2, and the boundary between the conductive layer 112B2 and the conductive layer 112B3 are indicated by dotted lines. The same applies to the other diagrams.

In the above manner, the conductive layer 112R, the conductive layer 112G, and the conductive layer 112B can have different thicknesses. Note that among the conductive layer 112R, the conductive layer 112G, and the conductive layer 112B, the conductive layer 112B has the largest thickness and the conductive layer 112G has the smallest thickness: however, one embodiment of the present invention is not limited thereto, and the thicknesses of the conductive layer 112R, the conductive layer 112G, and the conductive layer 112B can be set as appropriate. For example, among the conductive layer 112R, the conductive layer 112G, and the conductive layer 112B, the conductive layer 112R may have the largest thickness, and the conductive layer 112B may have the smallest thickness.

Although the thickness of the conductive layer 112C is equal to that of the conductive layer 112G, one embodiment of the present invention is not limited thereto. For example, the thickness of the conductive layer 112C may be larger than the thickness of the conductive layer 112G. For example, not only at the time of processing the conductive film 112f3 but also at the time of processing the conductive film 112f2, the conductive film may be left to cover the upper surface and the side surface of the conductive layer 111C. In that case, the thickness of the conductive layer 112C can be equal to the thickness of the conductive layer 112R, for example. Furthermore, at the time of processing any of the conductive film 112f1, the conductive film 112f2, and the conductive film 112f3, the conductive film may be left to cover the upper surface and the side surface of the conductive layer 111C. In that case, the thickness of the conductive layer 112C can be equal to the thickness of the conductive layer 112B, for example.

Next, as illustrated in FIG. 44C, an EL film 113f to be the EL layer 113 later is formed over the conductive layer 112R, over the conductive layer 112G, over the conductive layer 112B, and over the insulating layer 105. Then, a mask film 118f to be the mask layer 118 and a mask film 119f to be a mask layer 119 are sequentially formed over the EL film 113f, over the conductive layer 112C, and over the insulating layer 105.

Next, as illustrated in FIG. 44C, the resist mask 190 is formed over the mask film 119f. The resist mask 190 is provided at a position overlapping with the conductive layer 112R, a position overlapping with the conductive layer 112G, and a position overlapping with the conductive layer 112B. The resist mask 190 is preferably provided also at a position overlapping with the conductive layer 112C. Furthermore, the resist mask 190 is preferably provided to cover the area from the end portion of the EL film 113f to the end portion of the conductive layer 112C (the end portion closer to the EL film 113f), as illustrated in the cross-sectional view along the line B1-B2 in FIG. 44C.

Subsequently, as illustrated in FIG. 44C and FIG. 44D, part of the mask film 119f is removed using the resist mask 190, whereby the mask layer 119 is formed. The mask layer 119 remains over the conductive layer 112R, over the conductive layer 112G, over the conductive layer 112B, and over the conductive layer 112C. After that, the resist mask 190 is removed. Then, part of the mask film 118f is removed using the mask layer 119 as a mask, whereby the mask layer 118 is formed.

Next, as illustrated in FIG. 44C and FIG. 44D, the EL film 113f is processed, so that the EL layer 113 is formed. For example, part of the EL film 113f is removed using the mask layer 119 and the mask layer 118 as a mask to form the EL layer 113.

Thus, as illustrated in FIG. 44D, the stacked-layer structure of the EL layer 113, the mask layer 118, and the mask layer 119 is left over the conductive layer 112R, the conductive layer 112G, and the conductive layer 112B. In addition, in the cross section B1-B2, the mask layer 118 and the mask layer 119 can be provided to cover the area from the end portion of the EL layer 113 to the end portion of the conductive layer 112C (the end portion closer to the EL layer 113).

Subsequently, steps similar to the steps illustrated in FIG. 26C to FIG. 31B are performed. Subsequently, the coloring layer 132R, the coloring layer 132G, and the coloring layer 132B are formed over the protective layer 131. Subsequently, the substrate 120 is attached to the coloring layer 132 using the resin layer 122, whereby the display device having the structure illustrated in FIG. 19A and the structure illustrated in FIG. 18A can be manufactured.

As described above, in the display device 100 having the structure illustrated in FIG. 19A, the EL film 113f, the mask film 118f, and the mask film 119f can each be completed by one formation step and one processing step, and do not need to be formed and processed separately for each color. Thus, the manufacturing process of the display device 100 can be simplified. Consequently, the manufacturing cost of the display device 100 can be reduced, whereby the display device 100 can be an inexpensive display device.

### Manufacturing Method Example 5

A manufacturing method example of the display device 100 having the structure illustrated in FIG. 21A and the structure illustrated in FIG. 18C will be described below with reference to drawings. Note that a method different from the method described using FIG. 32A to FIG. 32C and FIG. 33A to FIG. 37B is mainly described, and the same method as the already-described method is omitted as appropriate

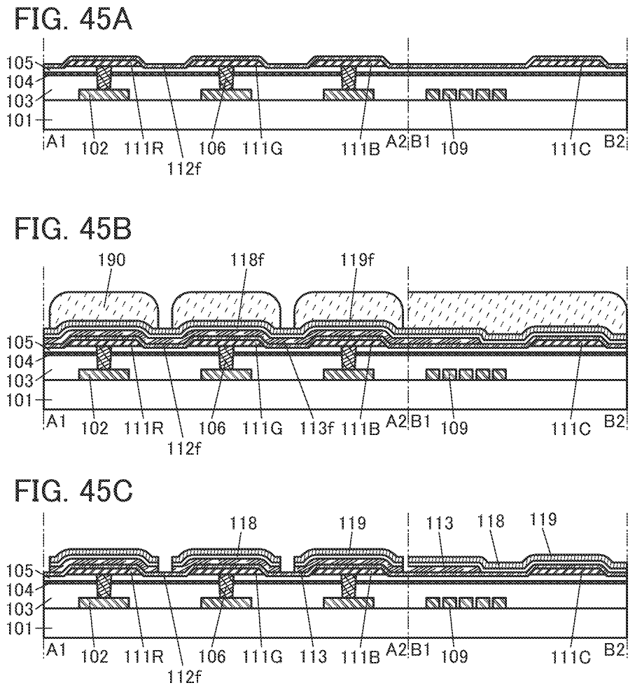

First, steps similar to those illustrated in FIG. 32A to FIG. 32C are performed. Thus, as illustrated in FIG. 45A, the conductive layer 111R, the conductive layer 111G, the conductive layer 111B, and the conductive layer 111C are formed over the plugs 106 and over the insulating layer 105. The conductive film 112f is formed over the conductive layer 111R, over the conductive layer 111G, over the conductive layer 111B, over the conductive layer 111C, and over the insulating layer 105.

Next, as illustrated in FIG. 45B, the EL film 113f to be the EL layer 113 later is formed over the conductive film 112f. Then, the mask film 118f to be the mask layer 118 later and the mask film 119f to be the mask layer 119 later are sequentially formed over the EL film 113f and over the conductive film 112f.

Next, as illustrated in FIG. 45B, the resist mask 190 is formed over the mask film 119f. The resist mask 190 is provided at a position overlapping with the conductive layer 111R, a position overlapping with the conductive layer 111G, and a position overlapping with the conductive layer 111B. The resist mask 190 is preferably provided also at a position overlapping with the conductive layer 111C. Furthermore, the resist mask 190 is preferably provided to cover the area from the end portion of the EL film 113f to the end portion of the conductive layer 111C (the end portion closer to the EL film 113f), as illustrated in the cross-sectional view along the line B1-B2 in FIG. 45B.

Subsequently, as illustrated in FIG. 45B and FIG. 45C, part of the mask film 119f is removed using the resist mask 190, whereby the mask layer 119 is formed. The mask layer 119 remains over the conductive layer 111R, over the conductive layer 111G, over the conductive layer 111B, and over the conductive layer 111C. After that, the resist mask 190 is removed. Then, part of the mask film 118f is removed using the mask layer 119 as a mask, whereby the mask layer 118 is formed.

Next, as illustrated in FIG. 45B and FIG. 45C, the EL film 113f is processed, so that the EL layer 113 is formed. For example, part of the EL film 113f is removed using the mask layer 119 and the mask layer 118 as a mask to form the EL layer 113.

Thus, as illustrated in FIG. 45C, the stacked-layer structure of the EL layer 113, the mask layer 118, and the mask layer 119 is left over the conductive layer 111R, the conductive layer 111G, and the conductive layer 111B. In addition, in the cross section B1-B2, the mask layer 118 and the mask layer 119 can be provided to cover the area from the end portion of the EL layer 113 to the end portion of the conductive layer 111C (the end portion closer to the EL layer 113).

Subsequently, steps similar to the steps illustrated in FIG. 34C to FIG. 37B are performed. Subsequently, the coloring layer 132R, the coloring layer 132G, and the coloring layer 132B are formed over the protective layer 131. Subsequently, the substrate 120 is attached to the coloring layer 132 using the resin layer 122, whereby the display device having the structure illustrated in FIG. 21A and the structure illustrated in FIG. 18C can be manufactured.

As described above, in the display device 100 having the structure illustrated in FIG. 21A, the EL film 113f, the mask film 118f, and the mask film 119f can each be completed by one formation step and one processing step, and do not need to be formed and processed separately for each color. Thus, the manufacturing process of the display device 100 can be simplified. Consequently, the manufacturing cost of the display device 100 can be reduced, whereby the display device 100 can be an inexpensive display device.

This embodiment can be combined with the other embodiments as appropriate. In the case where a plurality of structure examples are described in one embodiment in this specification and the like, the structure examples can be combined as appropriate.

### Embodiment 2

In this embodiment, a structure example of a light-emitting element that can be used for the display device of one embodiment of the present invention, specifically, a structure example of a light-emitting element having a tandem structure, will be described.

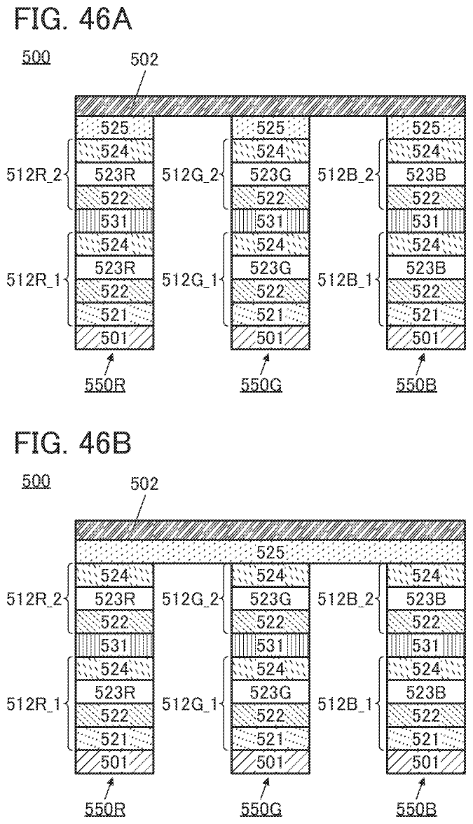

FIG. 46A is a schematic cross-sectional view of a display device 500. The display device 500 includes a light-emitting element 550R that emits red light, a light-emitting element 550G that emits green light, and a light-emitting element 550B that emits blue light.

The light-emitting element 550R has a structure in which, between a pair of electrodes (an electrode 501 and an electrode 502), two light-emitting units (a light-emitting unit 512R_1 and a light-emitting unit 512R_2) are stacked with a charge-generation layer 531 therebetween. Similarly, the light-emitting element 550G includes a light-emitting unit 512G_1, the charge-generation layer 531, and a light-emitting unit 512G_2 between the pair of electrodes, and the light-emitting element 550B includes a light-emitting unit 512B_1, the charge-generation layer 531, and a light-emitting unit 512B_2 between the pair of electrodes.

The electrode 501 functions as a pixel electrode and is provided in every light-emitting element. The electrode 502 functions as a common electrode and is shared by a plurality of light-emitting elements.

As illustrated in FIG. 46A, the light-emitting unit 512R_1 includes a layer 521, a layer 522, a light-emitting layer 523R, and a layer 524. The light-emitting unit 512R_2 includes the layer 522, the light-emitting layer 523R, and the layer 524. The light-emitting element 550R includes a layer 525 and the like between the light-emitting unit 512R_2 and the electrode 502. Note that the layer 525 can also be regarded as part of the light-emitting unit 512R_2.

In the case where the electrode 501 functions as an anode and the electrode 502 functions as a cathode, the layer 521 includes, for example, a layer containing a substance with a high hole-injection property (a hole-injection layer). The layer 522 includes one or both of a layer containing a substance with a high hole-transport property (a hole-transport layer) and a layer containing a substance with a high electron-blocking property (an electron-blocking layer), for example. The layer 524 includes one or both of a layer containing a substance with a high electron-transport property (an electron-transport layer) and a layer containing a substance with a high hole-blocking property (a hole-blocking layer), for example. The layer 525 includes, for example, a layer containing a substance with a high electron-injection property (an electron-injection layer).

In the case where the electrode 501 functions as a cathode and the electrode 502 functions as an anode, for example, the layer 521 includes an electron-injection layer, the layer 522 includes one or both of an electron-transport layer and a hole-blocking layer, the layer 524 includes one or both of a hole-transport layer and an electron-blocking layer, and the layer 525 includes a hole-injection layer.

Note that in terms of the layer 522, the light-emitting layer 523R, and the layer 524, the light-emitting unit 512R_1 and the light-emitting unit 512R_2 may have the same structure (materials, thicknesses, and the like) or different structures.

FIG. 46A illustrates the layer 521 and the layer 522 separately: however, one embodiment of the present invention is not limited thereto. For example, the layer 522 may be omitted when the layer 521 has functions of both a hole-injection layer and a hole-transport layer or the layer 521 has functions of both an electron-injection layer and an electron-transport layer.

In the case of manufacturing a light-emitting element having a tandem structure, two light-emitting units are stacked with the charge-generation layer 531 therebetween. The charge-generation layer 531 includes at least a charge-generation region. The charge-generation layer 531 has a function of injecting electrons into one of the light-emitting unit 512R_1 and the light-emitting unit 512R_2 and injecting holes into the other when voltage is applied between the electrode 501 and the electrode 502.

The light-emitting layer 523R included in the light-emitting element 550R contains a light-emitting substance that emits red light, the light-emitting layer 523G included in the light-emitting element 550G contains a light-emitting substance that emits green light, and the light-emitting layer 523B included in the light-emitting element 550B contains a light-emitting substance that emits blue light. Note that the light-emitting element 550G and the light-emitting element 550B have a structure in which the light-emitting layer 523R included in the light-emitting element 550R is replaced with the light-emitting layer 523G and the light-emitting layer 523B, respectively, and the other components are similar to those of the light-emitting element 550R.

The structure (material, thickness, and the like) of the layer 521, the layer 522, the layer 524, and the layer 525 may be the same among the light-emitting elements of two or more or all of the colors or different from each other among the light-emitting elements of all the colors.

A structure in which a plurality of light-emitting units are connected in series with the charge-generation layer 531 therebetween as in the light-emitting element 550R, the light-emitting element 550G, and the light-emitting element 550B is referred to as a tandem structure in this specification. By contrast, a structure in which one light-emitting unit is provided between a pair of electrodes is referred to as a single structure. Note that the tandem structure may be referred to as a stack structure. The tandem structure enables a light-emitting element capable of high-luminance light emission. Furthermore, the tandem structure reduces the amount of current needed for obtaining the same luminance as compared with a single structure, and thus can improve the reliability of the light-emitting elements.

It can be said that the display device 500 according to one embodiment of the present invention employs a light-emitting element having a tandem structure and the display device has an SBS structure. Thus, the display device 500 can take advantages of both the tandem structure and the SBS structure. Note that the light-emitting element in the display device 500 illustrated in FIG. 46A has a structure in which two light-emitting units are formed in series, and this structure may be referred to as a two-unit tandem structure. In the light-emitting element 550R having a two-unit tandem structure illustrated in FIG. 46A, a second light-emitting unit including a red-light-emitting layer is stacked over a first light-emitting unit including a red-light-emitting layer. Similarly, in the light-emitting element 550G having a two-unit tandem structure illustrated in FIG. 46A, a second light-emitting unit including a green-light-emitting layer is stacked over a first light-emitting unit including a green-light-emitting layer, and in the light-emitting element 550B, a second light-emitting unit including a blue-light-emitting layer is stacked over a first light-emitting unit including a blue-light-emitting layer.

FIG. 46B illustrates a modification example of the display device 500 illustrated in FIG. 46A. The display device 500 illustrated in FIG. 46B is an example in which, like the electrode 502, the layer 525 is shared by the plurality of light-emitting elements. In this case, the layer 525 can be referred to as a common layer. By providing one or more common layers for the plurality of light-emitting elements in this manner, the manufacturing step can be simplified, resulting in a reduction in manufacturing cost.

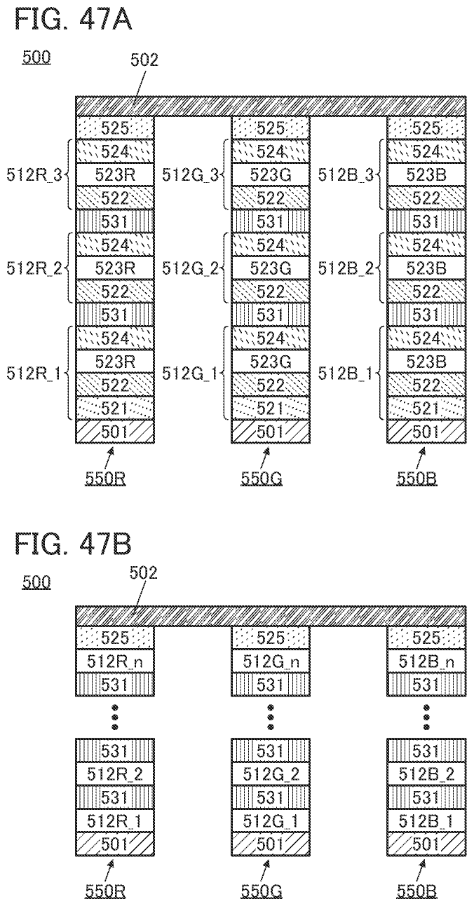

The display device 500 illustrated in FIG. 47A is an example in which three light-emitting units are stacked. In the light-emitting element 550R in FIG. 47A, a light-emitting unit 512R_3 is further stacked over the light-emitting unit 512R_2 with another charge-generation layer 531 therebetween. The light-emitting unit 512R_3 has a structure similar to that of the light-emitting unit 512R_2. The same applies to a light-emitting unit 512G_3 included in the light-emitting element 550G and a light-emitting unit 512B_3 included in the light-emitting element 550B. Note that in the case where the light-emitting element includes a plurality of charge-generation layers 531, two or more or all of the plurality of charge-generation layers 531 may have the same structure (material, thickness, and the like) or may have structures that are completely different from each other.

FIG. 47B illustrates an example in which n light-emitting units (n is an integer greater than or equal to 2) are stacked.

When the number of stacked light-emitting units is increased in the above manner, luminance obtained from the light-emitting element with the same amount of current can be increased in accordance with the number of stacked layers. Moreover, increasing the number of stacked light-emitting units can reduce current necessary for obtaining the same luminance: thus, power consumption of the light-emitting element can be reduced in accordance with the number of stacked layers.

There is no particular limitation on the light-emitting substance in the light-emitting layer in the display device 500 illustrated in each of FIG. 46A, FIG. 46B, FIG. 47A, and FIG. 47B. For example, the display device in FIG. 46A can have a structure in which the two light-emitting layers 523R included in the light-emitting element 550R each contain a phosphorescent material, the two light-emitting layers 523G included in the light-emitting element 550G each contain a fluorescent material, and the two light-emitting layers 523B included in the light-emitting element 550B each contain a fluorescent material.

Alternatively, for example, the display device in FIG. 46A can have a structure in which the two light-emitting layers 523R included in the light-emitting element 550R each contain a phosphorescent material, the two light-emitting layers 523G included in the light-emitting element 550G each contain a fluorescent material, and the two light-emitting layers 523B included in the light-emitting element 550B each contain a phosphorescent material.

For the display device of one embodiment of the present invention, a structure may be employed in which fluorescent materials are used for all the light-emitting layers included in the light-emitting element 550R, the light-emitting element 550G, and the light-emitting element 550B or a structure may be employed in which phosphorescent materials are used for all the light-emitting layers included in the light-emitting element 550R, the light-emitting element 550G, and the light-emitting element 550B.

In FIG. 46A, for example, the structure may be employed in which the light-emitting layer 523R included in the light-emitting unit 512R_1 contains a phosphorescent material and the light-emitting layer 523R included in the light-emitting unit 512R_2 contains a fluorescent material, or a structure in which the light-emitting layer 523R included in the light-emitting unit 512R_1 contains a fluorescent material and the light-emitting layer 523R included in the light-emitting unit 512R_2 contains a phosphorescent material, i.e., a structure in which a light-emitting layer in a first unit and a light-emitting layer in a second unit are formed using different light-emitting substances. Note that here, the light-emitting unit 512R_1 and the light-emitting unit 512R_2 are described, and the same structure can also be applied to the light-emitting unit 512G_1 and the light-emitting unit 512G_2, and the light-emitting unit 512B_1 and the light-emitting unit 512B_2.

This embodiment can be combined with the other embodiments as appropriate. In the case where a plurality of structure examples are described in one embodiment in this specification, the structure examples can be combined as appropriate.

### Embodiment 3

In this embodiment, display devices of embodiments of the present invention are described.

Pixel layouts different from the layout in FIG. 1 will be mainly described in this embodiment. There is no particular limitation on the arrangement of subpixels, and any of a variety of methods can be employed. Examples of the arrangement of subpixels include stripe arrangement, S-stripe arrangement, matrix arrangement, delta arrangement, Bayer arrangement, and PenTile arrangement.

The top surface shape of the subpixel illustrated in a diagram in this embodiment corresponds to the top surface shape of a light-emitting region.

Examples of the top surface shape of the subpixel include polygons such as a triangle, a tetragon (including a rectangle and a square), and a pentagon: polygons with rounded corners: an ellipse; and a circle.

The range of the circuit layout for forming the subpixels is not limited to the range of the subpixels illustrated in the drawing and may be placed outside the subpixels.

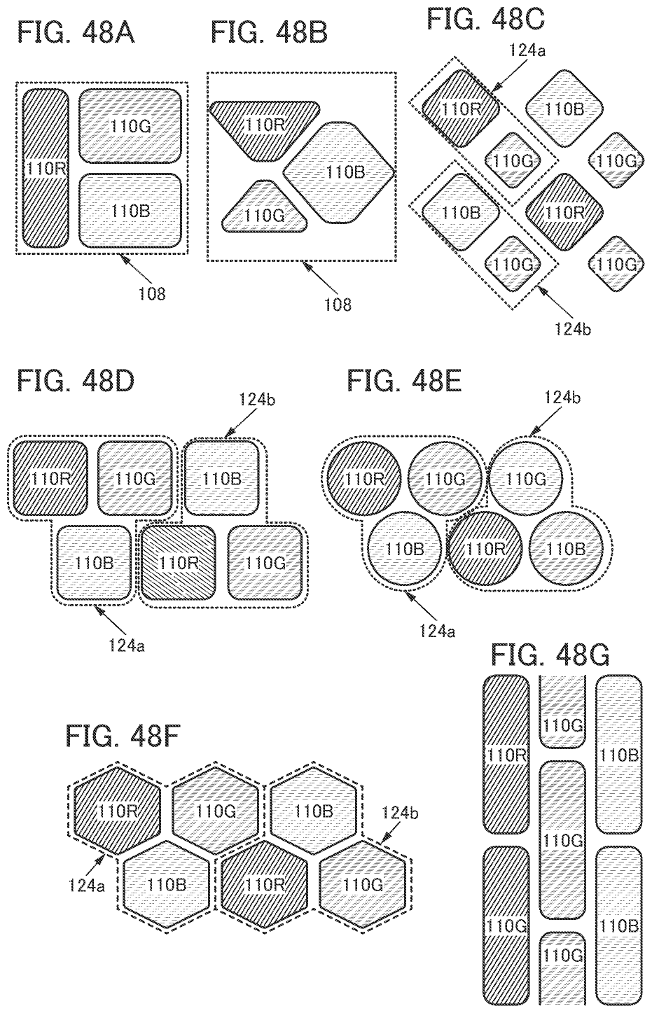

The pixel 108 illustrated in FIG. 48A employs S-stripe arrangement. The pixel 108 illustrated in FIG. 48A is composed of three subpixels: the subpixel 110R, the subpixel 110G, and the subpixel 110B.

The pixel 108 illustrated in FIG. 48B includes the subpixel 110R whose top surface has a rough trapezoidal shape with rounded corners, the subpixel 110G whose top surface has a rough triangle shape with rounded corners, and the subpixel 110B whose top surface has a rough tetragonal or rough hexagonal shape with rounded corners. The subpixel 110R has a larger light-emitting area than the subpixel 110G. In this manner, the shapes and sizes of the subpixels can be determined independently. For example, the size of a subpixel including a light-emitting element with higher reliability can be smaller.

A pixel 124a and a pixel 124b illustrated in FIG. 48C employ PenTile arrangement. FIG. 48C illustrates an example where the pixels 124a including the subpixel 110R and the subpixel 110G and the pixels 124b including the subpixel 110G and the subpixel 110B are alternately arranged.

The pixel 124a and the pixel 124b illustrated in FIG. 48D to FIG. 48F employ delta arrangement. The pixel 124a includes two subpixels (the subpixel 110R and the subpixel 110G) in the upper row (first row) and one subpixel (the subpixel 110B) in the lower row (second row). The pixel 124b includes one subpixel (the subpixel 110B) in the upper row (first row) and two subpixels (the subpixel 110R and the subpixel 110G) in the lower row (second row).

FIG. 48D illustrates an example where the upper surface of each subpixel has a rough tetragonal shape with rounded corners, FIG. 48E illustrates an example where the upper surface of each subpixel is circular, and FIG. 48F illustrates an example where the upper surface of each subpixel has a rough hexagonal shape with rounded corners.

In FIG. 48F, each subpixel is placed inside one of close-packed hexagonal regions. Focusing on one of the subpixels, the subpixel is placed so as to be surrounded by six subpixels. The subpixels are arranged such that subpixels that emit light of the same color are not adjacent to each other. For example, focusing on the subpixel 110R, the subpixel 110R is surrounded by three subpixels 110G and three subpixels 110B that are alternately arranged.

FIG. 48G illustrates an example where subpixels of different colors are arranged in a zigzag manner. Specifically, the positions of the top sides of two subpixels arranged in the column direction (e.g., the subpixel 110R and the subpixel 110G or the subpixel 110G and the subpixel 110B) are not aligned in the plan view.

For example, in each pixel illustrated in FIG. 48A to FIG. 48G, it is preferable that the subpixel 110R be a subpixel R emitting red light, the subpixel 110G be a subpixel G emitting green light, and the subpixel 110B be a subpixel B emitting blue light. Note that the structure of the subpixels is not limited to this, and the colors and arrangement order of the subpixels can be determined as appropriate. For example, the subpixel 110G may be the subpixel R emitting red light and the subpixel 110R may be the subpixel G emitting green light.

In a photolithography method, as a pattern to be processed becomes finer, the influence of light diffraction becomes more difficult to ignore: therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a subpixel may have a polygonal shape with rounded corners, an elliptical shape, a circular shape, or the like.

Furthermore, in the method of manufacturing the display device of one embodiment of the present invention, the EL layer is processed into an island shape using a resist mask. A resist film formed over the EL layer needs to be cured at a temperature lower than the upper temperature limit of the EL layer. Therefore, the resist film is insufficiently cured in some cases depending on the upper temperature limit of the material of the EL layer and the curing temperature of the resist material. An insufficiently cured resist film may have a shape different from a desired shape after being processed. As a result, the top surface of the EL layer may have a polygonal shape with rounded corners, an elliptical shape, a circular shape, or the like. For example, when a resist mask whose top surface has a square shape is intended to be formed, a resist mask whose top surface has a circular shape may be formed, and the top surface of the EL layer may have a circular shape.

Note that to obtain a desired top surface shape of the EL layer, a technique of correcting a mask pattern in advance so that a transferred pattern agrees with a design pattern (OPC (Optical Proximity Correction) technique) may be used. Specifically, with the OPC technique, a pattern for correction is added to a corner portion or the like of a figure on a mask pattern.

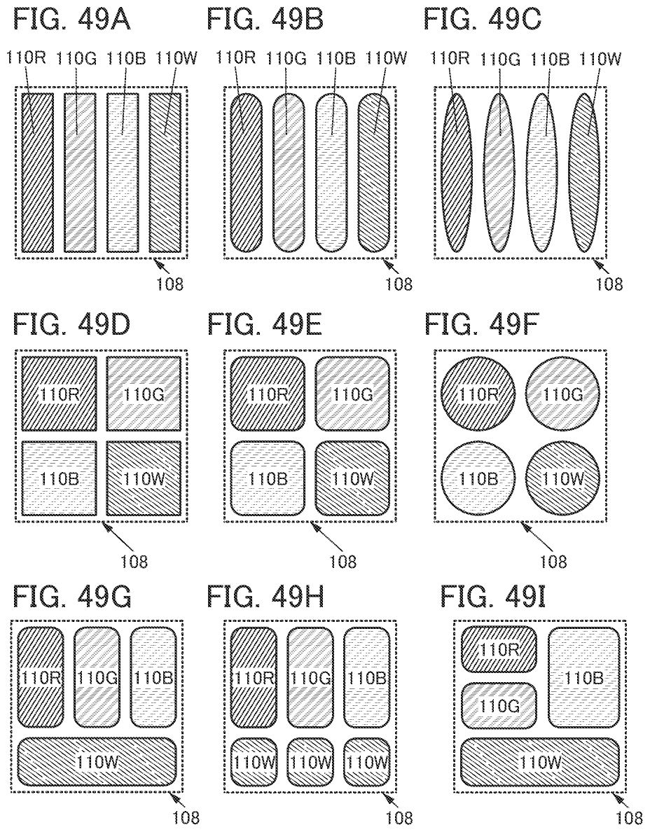

As illustrated in FIG. 49A to FIG. 49I, the pixel can include four types of subpixels.

The pixels 108 illustrated in FIG. 49A to FIG. 49C employ stripe arrangement.

FIG. 49A illustrates an example where each subpixel has a rectangular top surface shape, FIG. 49B illustrates an example where each subpixel has a top surface shape formed by combining two half circles and a rectangle, and FIG. 49C illustrates an example where each subpixel has an elliptical top surface shape.

The pixels 108 illustrated in FIG. 49D to FIG. 49F employ matrix arrangement.

FIG. 49D illustrates an example where each subpixel has a square top surface shape, FIG. 49E illustrates an example where each subpixel has a rough square top surface shape with rounded corners, and FIG. 49F illustrates an example where each subpixel has a circular top surface shape.

FIG. 49G and FIG. 49H each illustrate an example where one pixel 108 is composed of two rows and three columns.

The pixel 108 illustrated in FIG. 49G includes three subpixels (the subpixel 110R, the subpixel 110G, and the subpixel 110B) in the upper row (first row) and one subpixel (the subpixel 110W) in the lower row (second row). In other words, the pixel 108 includes the subpixel 110R in the left column (first column), the subpixel 110G in the center column (second column), the subpixel 110B in the right column (third column), and the subpixel 110W across these three columns.

The pixel 108 illustrated in FIG. 49H includes three subpixels (the subpixel 110R, the subpixel 110G, and the subpixel 110B) in the upper row (first row) and three of the subpixels 110W in the lower row (second row). In other words, the pixel 108 includes the subpixel 110R and the subpixel 110W in the left column (first column), the subpixel 110G and another subpixel 110W in the center column (second column), and the subpixel 110B and another subpixel 110W in the right column (third column). Matching the positions of the subpixels in the upper row and the lower row as illustrated in FIG. 49H enables efficient removal of dust that would be produced in the manufacturing process, for example. Thus, a display device with high display quality can be provided.

In the pixel 108 illustrated in FIG. 49G and FIG. 49H, stripe arrangement is employed as the layout of the subpixel 110R, the subpixel 110G, and the subpixel 110B, whereby the display quality can be improved.

FIG. 49I illustrates an example where one pixel 108 is composed of three rows and two columns.

The pixel 108 illustrated in FIG. 49I includes the subpixel 110R in the upper row (first row), the subpixel 110G in the center row (second row), the subpixel 110B across the first and second rows, and one subpixel (the subpixel 110W) in the lower row (third row). In other words, the pixel 108 includes the subpixel 110R and the subpixel 110G in the left column (first column), the subpixel 110B in the right column (second column), and the subpixel 110W across these two columns.

In the pixel 108 illustrated in FIG. 49I, so-called S stripe arrangement is employed as the layout of the subpixel 110R, the subpixel 110G, and the subpixel 110B, whereby the display quality can be improved.

The pixel 108 illustrated in FIG. 49A to FIG. 49I consists of four subpixels: the subpixel 110R, the subpixel 110G, the subpixel 110B, and the subpixel 110W. For example, the subpixel 110R can be a subpixel that emits red light, the subpixel 110G can be a subpixel that emits green light, the subpixel 110B can be a subpixel that emits blue light, and the subpixel 110W can be a subpixel that emits white light. Note that at least one of the subpixel 110R, the subpixel 110G, the subpixel 110B, and the subpixel 110W may be a subpixel that emits cyan light, a subpixel that emits magenta light, a subpixel that emits yellow light, or a subpixel that emits near-infrared light.

As described above, the pixel composed of the subpixels each including the light-emitting element can employ any of a variety of layouts in the display device of one embodiment of the present invention.

This embodiment can be combined with the other embodiments as appropriate. In the case where a plurality of structure examples are described in one embodiment in this specification, the structure examples can be combined as appropriate.

### Embodiment 4

In this embodiment, display devices of embodiments of the present invention are described.

The display device of this embodiment can be a high-resolution display device. Accordingly, the display device in this embodiment can be used for display portions of information terminals (wearable devices) such as watch-type and bracelet-type information terminals and display portions of wearable devices capable of being worn on a head, such as a VR device like a head-mounted display (HMD) and a glasses-type AR device.

The display device of this embodiment can be a high-definition display device or a large-sized display device. Accordingly, the display device of this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or notebook personal computer, a monitor of a computer and the like, digital signage, and a large game machine such as a pachinko machine.

### [Display Module]

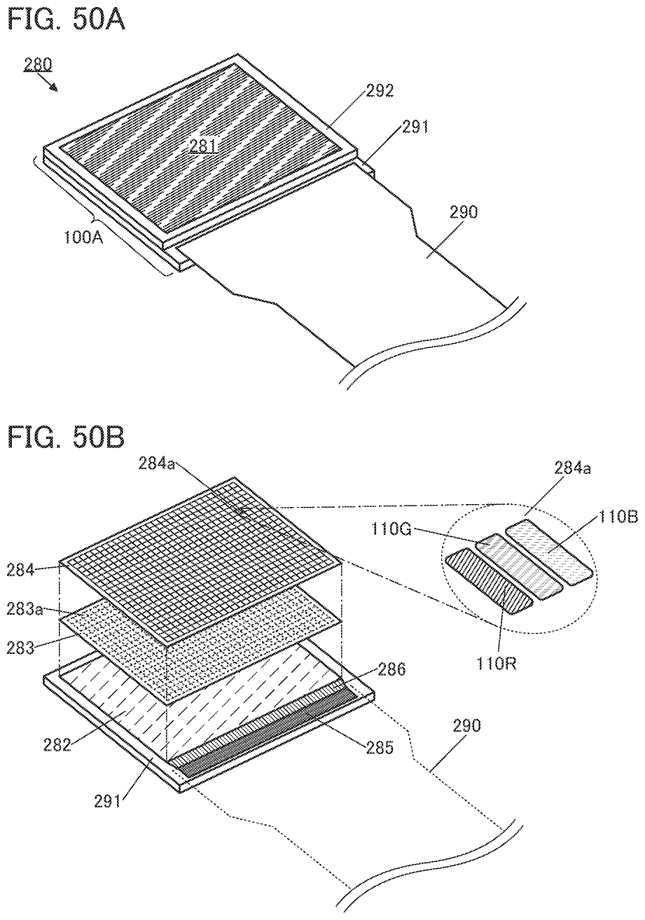

FIG. 50A is a perspective view of a display module 280. The display module 280 includes a display device 100A and an FPC 290. Note that the display device included in the display module 280 is not limited to the display device 100A and may be any of a display device 100B to a display device 100F described later.

The display module 280 includes a substrate 291 and a substrate 292. The display module 280 includes a display portion 281. The display portion 281 is a region of the display module 280 where an image is displayed, and is a region where light from pixels provided in a pixel portion 284 described later can be seen.

FIG. 50B is a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. A terminal portion 285 to be connected to the FPC 290 is provided in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side of FIG. 50B. The pixel 284a can employ any of the structures described in the above embodiments. FIG. 50B illustrates an example where the pixel 284a has a structure similar to that of the pixel 108 illustrated in FIG. 1.

The pixel circuit portion 283 includes a plurality of pixel circuits 283a arranged periodically.

One pixel circuit 283a is a circuit that controls driving of a plurality of elements included in one pixel 284a. One pixel circuit 283a can be provided with three circuits each controlling light emission of one light-emitting element. For example, the pixel circuit 283a can include at least one selection transistor, one current control transistor (driving transistor), and a capacitor for one light-emitting element. In this case, a gate signal is input to a gate of the selection transistor, and a source signal is input to a source or a drain of the selection transistor. Thus, an active-matrix display device is achieved.

The circuit portion 282 includes a circuit for driving the pixel circuits 283a in the pixel circuit portion 283. For example, one or both of a gate line driver circuit and a source line driver circuit are preferably included. In addition, at least one of an arithmetic circuit, a memory circuit, a power supply circuit, and the like may be included.

The FPC 290 functions as a wiring for supplying a video signal, a power supply potential, or the like to the circuit portion 282 from the outside. An integrated circuit (IC) may be mounted on the FPC 290.

The display module 280 can have a structure in which one or both of the pixel circuit portion 283 and the circuit portion 282 are stacked below the pixel portion 284: thus, the aperture ratio (the effective display area ratio) of the display portion 281 can be significantly high. For example, the aperture ratio of the display portion 281 can be higher than or equal to 40% and lower than 100%, preferably higher than or equal to 50% and lower than or equal to 95%, further preferably higher than or equal to 60% and lower than or equal to 95%. Furthermore, the pixels 284a can be arranged extremely densely and thus, the display portion 281 can have an extremely high resolution. For example, the pixels 284a are preferably arranged in the display portion 281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has an extremely high resolution, and thus can be suitably used for a VR device such as an HMD or a glasses-type AR device. For example, even with a structure where the display portion of the display module 280 is seen through a lens, pixels of the extremely-high-resolution display portion 281 included in the display module 280 are prevented from being seen when the display portion is enlarged by the lens, so that display providing a high sense of immersion can be performed. Without being limited thereto, the display module 280 can be suitably used for electronic devices including a relatively small display portion. For example, the display module 280 can be favorably used in a display portion of a wearable electronic device, such as a watch.

### [Display Device 100A]

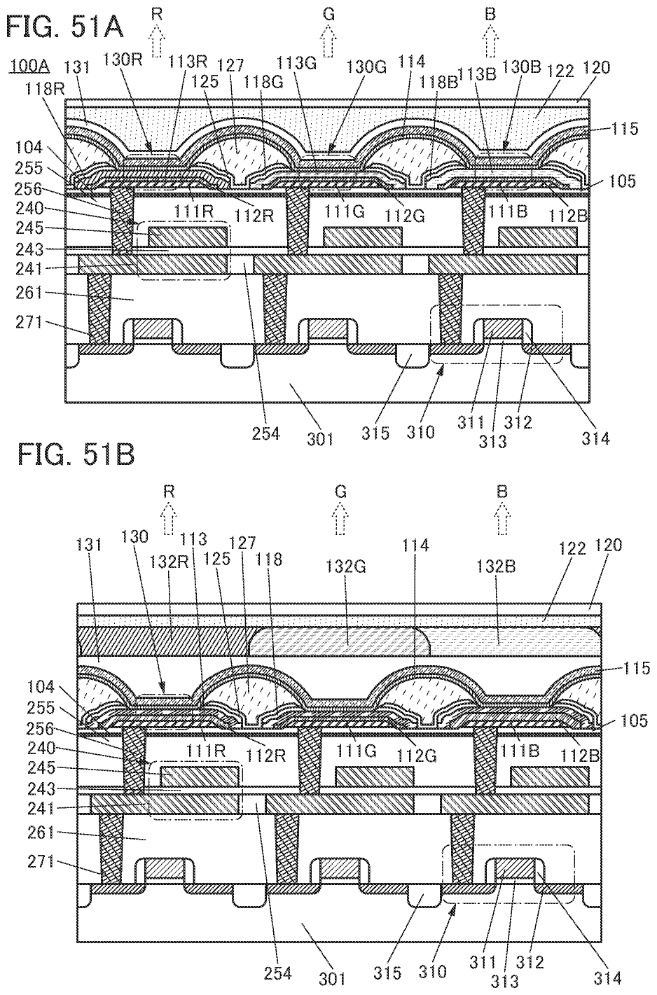

The display device 100A illustrated in FIG. 51A includes a substrate 301, a light-emitting element 130R, a light-emitting element 130G, a light-emitting element 130B, a capacitor 240, and a transistor 310.

The substrate 301 corresponds to the substrate 291 in FIG. 50A and FIG. 50B. The transistor 310 is a transistor including a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 positioned therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240, the insulating layer 104 is provided over the insulating layer 255, and the insulating layer 105 is provided over the insulating layer 104. The light-emitting element 130R, the light-emitting element 130G, and the light-emitting element 130B are provided over the insulating layer 105. FIG. 51A illustrates an example where the light-emitting element 130R, the light-emitting element 130G, and the light-emitting element 130B have a structure similar to the stacked-layer structure illustrated in FIG. 2A. An insulator is provided in a region between adjacent light-emitting elements. In FIG. 51A, for example, the insulating layer 125 and the insulating layer 127 over the insulating layer 125 are provided in this region.

The mask layer 118R is positioned over the EL layer 113R included in the light-emitting element 130R, the mask layer 118G is positioned over the EL layer 113G included in the light-emitting element 130G, and the mask layer 118B is positioned over the EL layer 113B included in the light-emitting element 130B.

A conductive layer 111R, a conductive layer 111G, and a conductive layer 111B are each electrically connected to one of the source and the drain of the transistor 310 through a plug 256 embedded in the insulating layer 243, the insulating layer 255, the insulating layer 104, and the insulating layer 105, the conductive layer 241 embedded in the insulating layer 254, and the plug 271 embedded in the insulating layer 261. The level of the upper surface of the insulating layer 105 is equal to or substantially equal to the level of the upper surface of the plug 256. A variety of conductive materials can be used for the plugs.

The protective layer 131 is provided over the light-emitting element 130R, the light-emitting element 130G, and the light-emitting element 130B. The substrate 120 is attached to the protective layer 131 with the resin layer 122. Embodiment 1 can be referred to for details of the light-emitting elements 130 and the components thereover up to the substrate 120. The substrate 120 corresponds to the substrate 292 in FIG. 50A.

FIG. 51B illustrates a modification example of the display device 100A illustrated in FIG. 51A. The display device illustrated in FIG. 51B includes the coloring layer 132R, the coloring layer 132G, and the coloring layer 132B, and each of the light-emitting elements 130 includes a region overlapping with one of the coloring layer 132R, the coloring layer 132G, and the coloring layer 132B. FIG. 19A can be referred to for the details of the light-emitting element 130 and the components thereover up to the substrate 120 in the display device illustrated in FIG. 51B. In the display device illustrated in FIG. 51B, the light-emitting element 130 can emit white light, for example. For example, the coloring layer 132R can transmit red light, the coloring layer 132G can transmit green light, and the coloring layer 132B can transmit blue light.

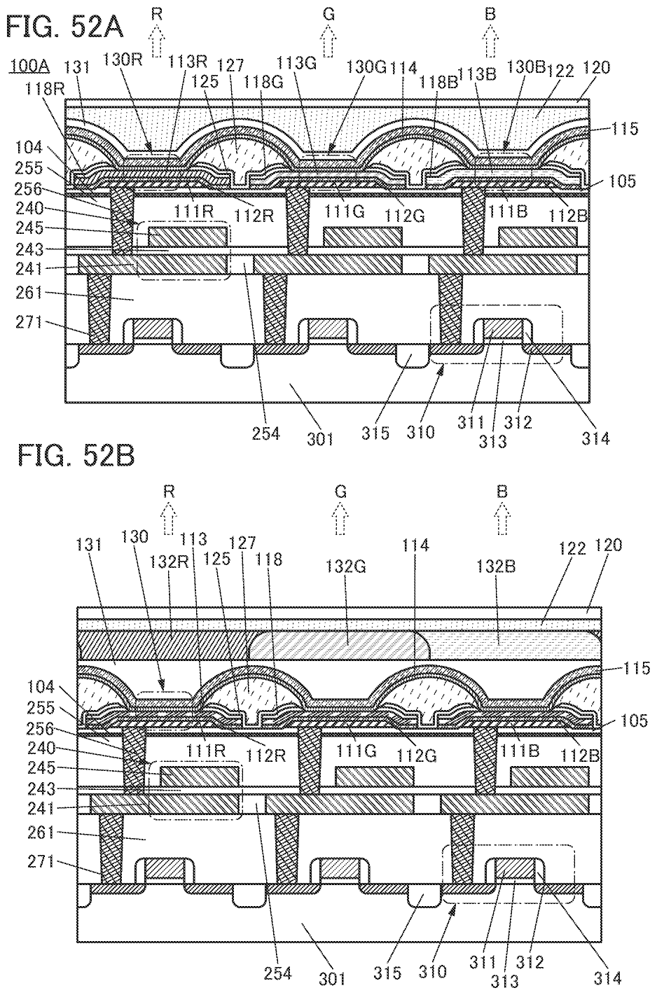

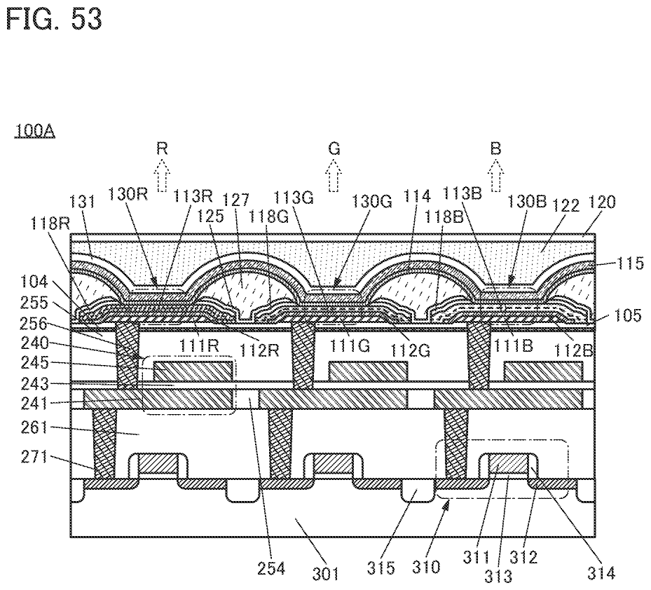

FIG. 52A illustrates a modification example of the structure illustrated in FIG. 51A, and in the example, the light-emitting element 130R, the light-emitting element 130G, and the light-emitting element 130B have the structure illustrated in FIG. 10. FIG. 52B illustrates a modification example of the structure illustrated in FIG. 51B, and in the example, the light-emitting element 130R, the light-emitting element 130G, and the light-emitting element 130B have the structure illustrated in FIG. 21A. FIG. 53 illustrates a modification example of the structure illustrated in FIG. 51A, and in the example, the light-emitting element 130R, the light-emitting element 130G, and the light-emitting element 130B have the structure illustrated in FIG. 14.

### [Display Device 100B]

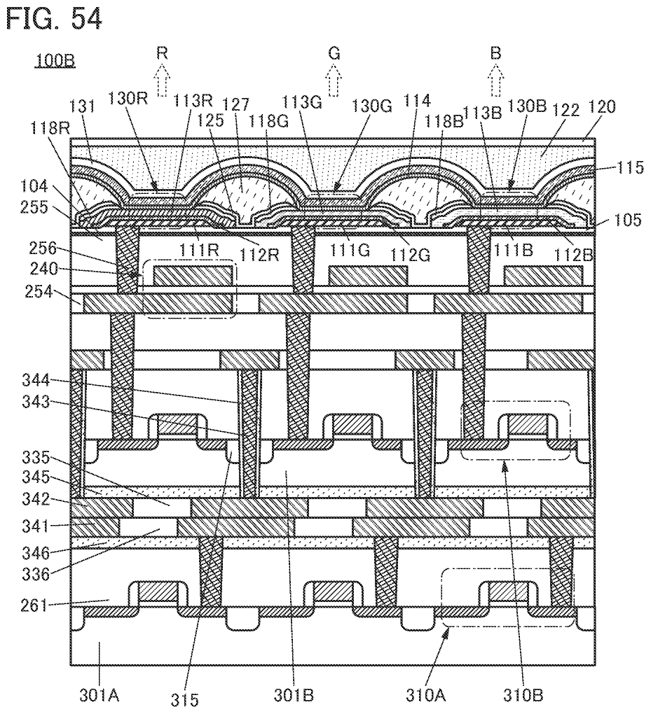

The display device 100B illustrated in FIG. 54 has a structure where a transistor 310A and a transistor 310B in each of which a channel is formed in a semiconductor substrate are stacked. Note that in the description of the display device below, portions similar to those of the above-mentioned display device are not described in some cases.

In the display device 100B, a substrate 301B provided with the transistor 310B, the capacitor 240, and the light-emitting elements is bonded to a substrate 301A provided with the transistor 310A.

Here, an insulating layer 345 is preferably provided on the lower surface of the substrate 301B. An insulating layer 346 is preferably provided over the insulating layer 261 provided over the substrate 301A. The insulating layer 345 and the insulating layer 346 are insulating layers functioning as protective layers and can inhibit diffusion of impurities into the substrate 301B and the substrate 301A. For the insulating layer 345 and the insulating layer 346, an inorganic insulating film that can be used for the protective layer 131 can be used.

The substrate 301B is provided with a plug 343 that penetrates the substrate 301B and the insulating layer 345. Here, an insulating layer 344 is preferably provided to cover the side surface of the plug 343. The insulating layer 344 functions as a protective layer and can inhibit diffusion of impurities into the substrate 301B. For the insulating layer 344, an inorganic insulating film that can be used for the protective layer 131 can be used.

A conductive layer 342 is provided under the insulating layer 345 on the rear surface of the substrate 301B (the surface of the substrate 301A). The conductive layer 342 is preferably provided to be embedded in an insulating layer 335. The bottom surfaces of the conductive layer 342 and the insulating layer 335 are preferably planarized. Here, the conductive layer 342 is electrically connected to the plug 343.

Between the substrate 301A and the substrate 301B, a conductive layer 341 is provided over the insulating layer 346. The conductive layer 341 is preferably provided to be embedded in an insulating layer 336. The upper surfaces of the conductive layer 341 and the insulating layer 336 are preferably planarized.

The conductive layer 341 and the conductive layer 342 are bonded to each other, whereby the substrate 301A and the substrate 301B are electrically connected to each other. Here, improving the planarity of a plane formed by the conductive layer 342 and the insulating layer 335 and a plane formed by the conductive layer 341 and the insulating layer 336 allows the conductive layer 341 and the conductive layer 342 to be bonded to each other favorably.

The conductive layer 341 and the conductive layer 342 are preferably formed using the same conductive material. For example, a metal film containing an element selected from Al, Cr, Cu, Ta, Ti, Mo, and W, a metal nitride film containing the above element as a component (a titanium nitride film, a molybdenum nitride film, or a tungsten nitride film), or the like can be used. Copper is particularly preferably used for the conductive layer 341 and the conductive layer 342. In that case, it is possible to employ Cu-to-Cu (copper-to-copper) direct bonding technique (a technique for achieving electrical continuity by connecting Cu (copper) pads).

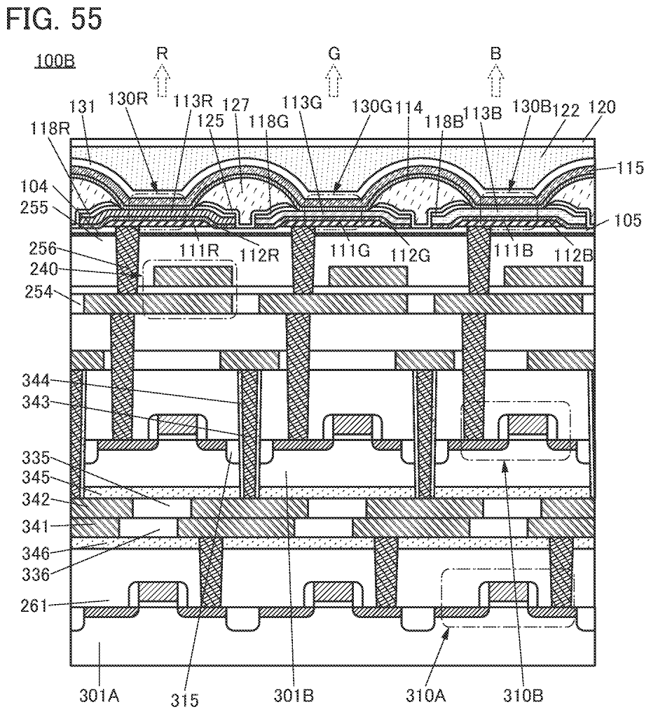

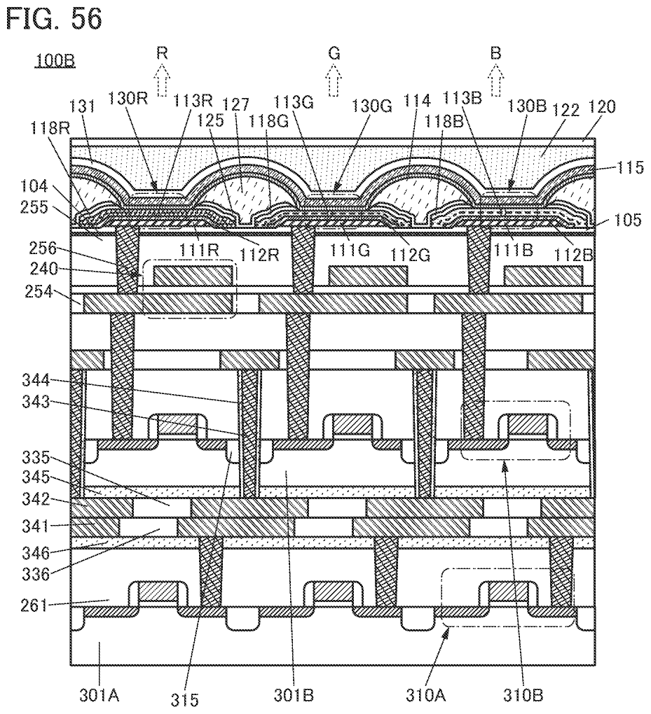

FIG. 55 illustrates a modification example of the structure illustrated in FIG. 54, and in the example, the light-emitting element 130R, the light-emitting element 130G, and the light-emitting element 130B have the structure illustrated in FIG. 10. FIG. 56 illustrates a modification example of the structure illustrated in FIG. 54, and in the example, the light-emitting element 130R, the light-emitting element 130G, and the light-emitting element 130B have the structure illustrated in FIG. 14.

### [Display Device 100C]

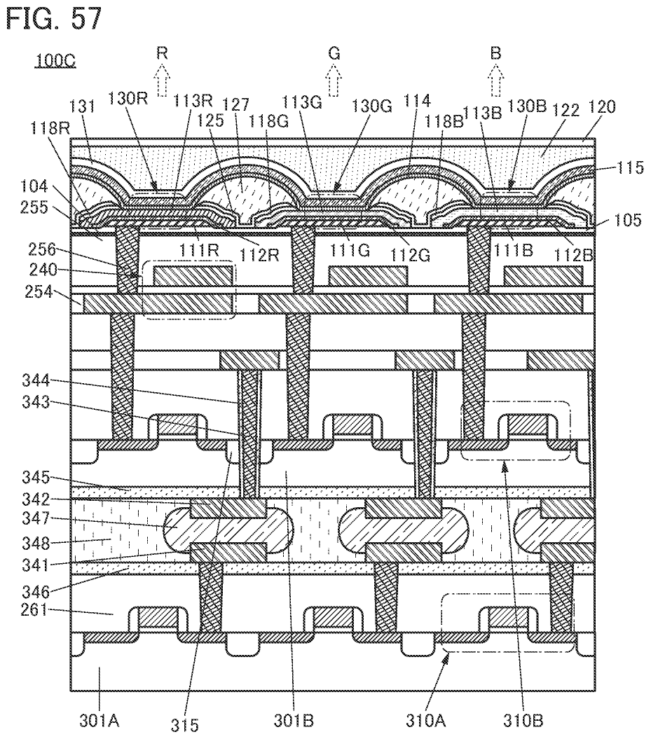

The display device 100C illustrated in FIG. 57 has a structure where the conductive layer 341 and the conductive layer 342 are bonded to each other through a bump 347.

As illustrated in FIG. 57, providing the bump 347 between the conductive layer 341 and the conductive layer 342 enables the conductive layer 341 and the conductive layer 342 to be electrically connected to each other. The bump 347 can be formed using a conductive material containing gold (Au), nickel (Ni), indium (In), tin (Sn), or the like, for example. For another example, solder may be used for the bump 347. An adhesive layer 348 may be provided between the insulating layer 345 and the insulating layer 346. In the case where the bump 347 is provided, the insulating layer 335 and the insulating layer 336 may be omitted.

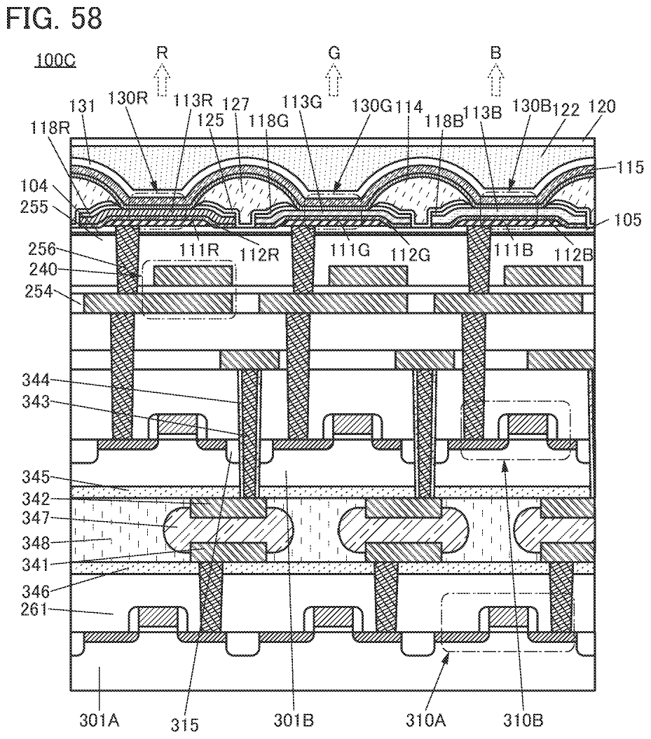

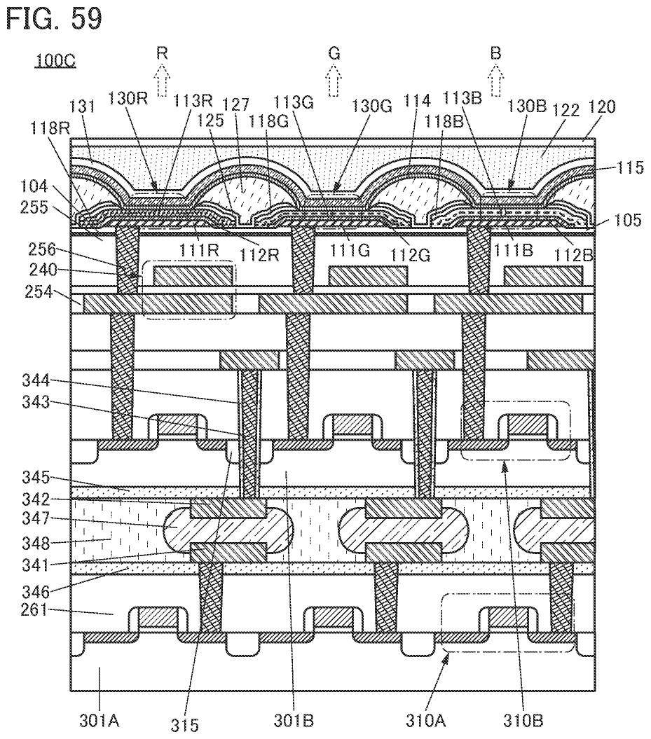

FIG. 58 illustrates a modification example of the structure illustrated in FIG. 57, and in the example, the light-emitting element 130R, the light-emitting element 130G, and the light-emitting element 130B have the structure illustrated in FIG. 10. FIG. 59 illustrates a modification example of the structure illustrated in FIG. 57, and in the example, the light-emitting element 130R, the light-emitting element 130G, and the light-emitting element 130B have the structure illustrated in FIG. 14.

### [Display Device 100D]

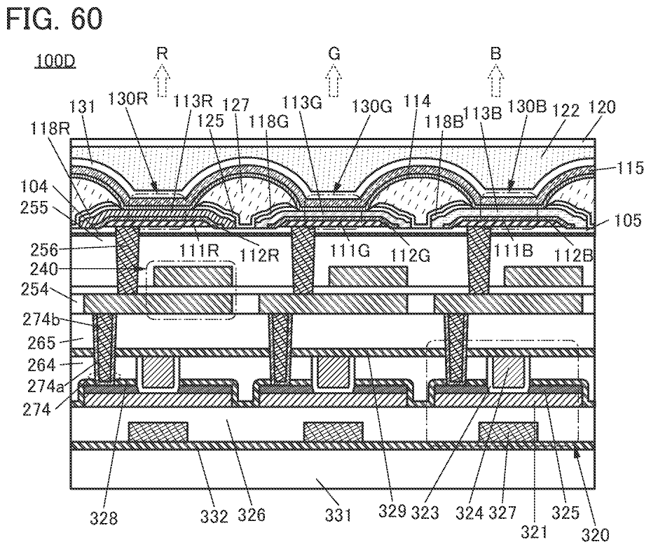

The display device 100D illustrated in FIG. 60 differs from the display device 100A mainly in a structure of a transistor.

A transistor 320 is a transistor that contains a metal oxide (also referred to as an oxide semiconductor) in a semiconductor layer where a channel is formed (hereinafter, the transistor is referred to as OS transistor).

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIG. 50A and FIG. 50B. As the substrate 331, an insulating substrate or a semiconductor substrate can be used.

The insulating layer 332 is provided over the substrate 331. The insulating layer 332 functions as a barrier layer that inhibits diffusion of impurities such as water and hydrogen from the substrate 331 into the transistor 320 and release of oxygen from the semiconductor layer 321 to the insulating layer 332 side. As the insulating layer 332, for example, a film in which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used as at least part of the insulating layer 326 that is in contact with the semiconductor layer 321. The upper surface of the insulating layer 326 is preferably planarized.

The semiconductor layer 321 is provided over the insulating layer 326. The semiconductor layer 321 preferably includes a metal oxide film having semiconductor characteristics. The pair of conductive layers 325 are provided over and in contact with the semiconductor layer 321 and function as a source electrode and a drain electrode.

An insulating layer 328 is provided to cover the upper surfaces and the side surfaces of the pair of conductive layers 325, the side surface of the semiconductor layer 321, and the like, and an insulating layer 264 is provided over the insulating layer 328. The insulating layer 328 functions as a barrier layer that inhibits diffusion of impurities such as water and hydrogen from, for example, the insulating layer 264 into the semiconductor layer 321 and release of oxygen from the semiconductor layer 321. As the insulating layer 328, an insulating film similar to the insulating layer 332 can be used.

An opening reaching the semiconductor layer 321 is provided in the insulating layer 328 and the insulating layer 264. The insulating layer 323 that is in contact with the side surfaces of the insulating layer 264, the insulating layer 328, and the conductive layer 325, and the top surface of the semiconductor layer 321, and the conductive layer 324 are embedded in the opening. The conductive layer 324 functions as a second gate electrode, and the insulating layer 323 functions as a second gate insulating layer.

The upper surface of the conductive layer 324, the upper surface of the insulating layer 323, and the upper surface of the insulating layer 264 are subjected to planarization treatment so that their levels are equal to or substantially equal to each other, and an insulating layer 329 and an insulating layer 265 are provided to cover these layers.

The insulating layer 264 and the insulating layer 265 each function as an interlayer insulating layer. The insulating layer 329 functions as a barrier layer that inhibits diffusion of impurities such as water and hydrogen from the insulating layer 265 into the transistor 320, for example. As the insulating layer 329, an insulating film similar to the insulating layer 328 and the insulating layer 332 can be used.

A plug 274 electrically connected to one of the pair of conductive layers 325 is provided so as to be embedded in the insulating layer 265, the insulating layer 329, the insulating layer 264, and the insulating layer 328. Here, the plug 274 preferably includes a conductive layer 274a that covers the side surface of an opening in the insulating layer 265, the insulating layer 329, the insulating layer 264, and the insulating layer 328 and part of upper surface of the conductive layer 325, and a conductive layer 274b in contact with the upper surface of the conductive layer 274a. In that case, a conductive material in which hydrogen and oxygen are less likely to diffuse is preferably used for the conductive layer 274a.

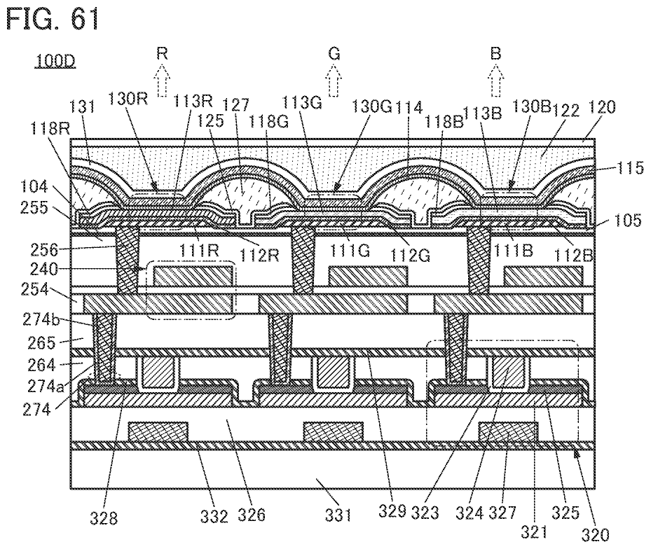

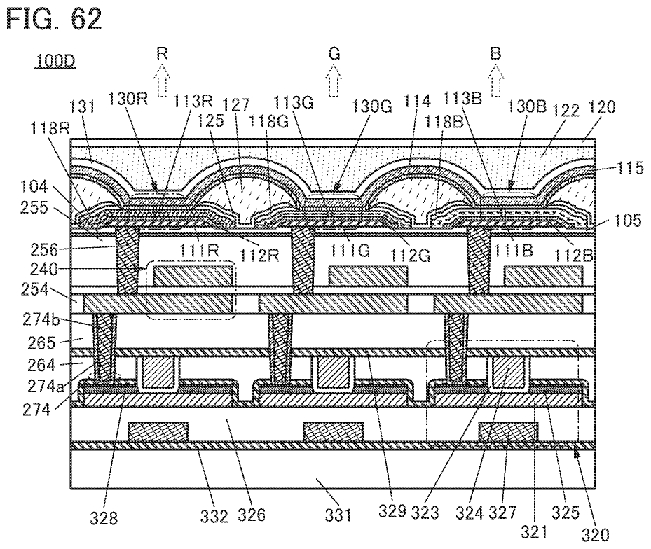

FIG. 61 illustrates a modification example of the structure illustrated in FIG. 60, and in the example, the light-emitting element 130R, the light-emitting element 130G, and the light-emitting element 130B have the structure illustrated in FIG. 10. FIG. 62 illustrates a modification example of the structure illustrated in FIG. 60, and in the example, the light-emitting element 130R, the light-emitting element 130G, and the light-emitting element 130B have the structure illustrated in FIG. 14.

### [Display Device 100E]

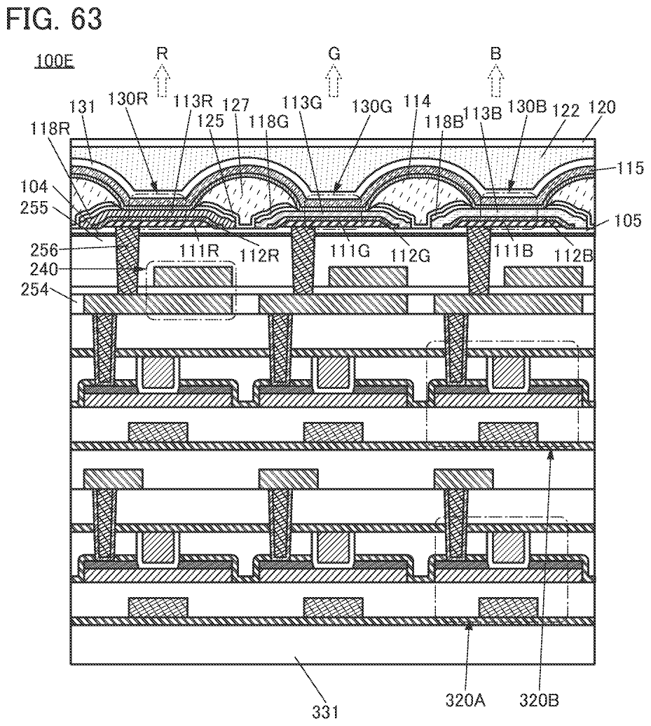

The display device 100E illustrated in FIG. 63 has a structure in which a transistor 320A and a transistor 320B each including an oxide semiconductor in a semiconductor where a channel is formed are stacked.

The description of the display device 100D can be referred to for the transistor 320A, the transistor 320B, and the components around them.

Although the structure where two transistors including an oxide semiconductor are stacked is described here, the present invention is not limited thereto. For example, three or more transistors may be stacked.

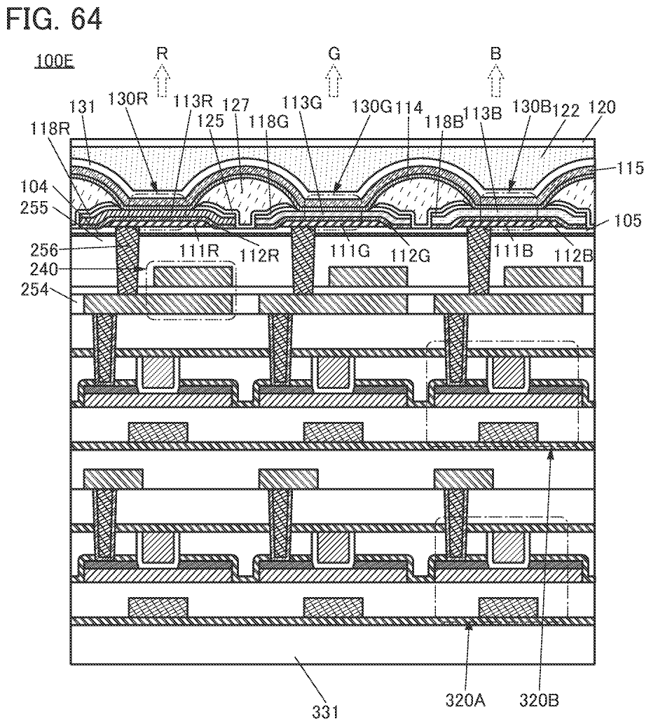

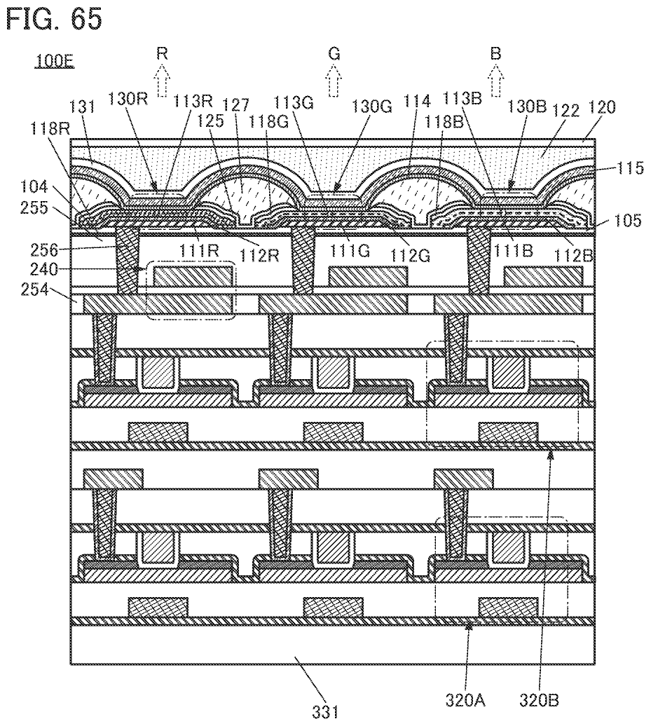

FIG. 64 illustrates a modification example of the structure illustrated in FIG. 63, and in the example, the light-emitting element 130R, the light-emitting element 130G, and the light-emitting element 130B have the structure illustrated in FIG. 10. FIG. 65 illustrates a modification example of the structure illustrated in FIG. 63, and in the example, the light-emitting element 130R, the light-emitting element 130G, and the light-emitting element 130B have the structure illustrated in FIG. 14.

### [Display Device 100F]

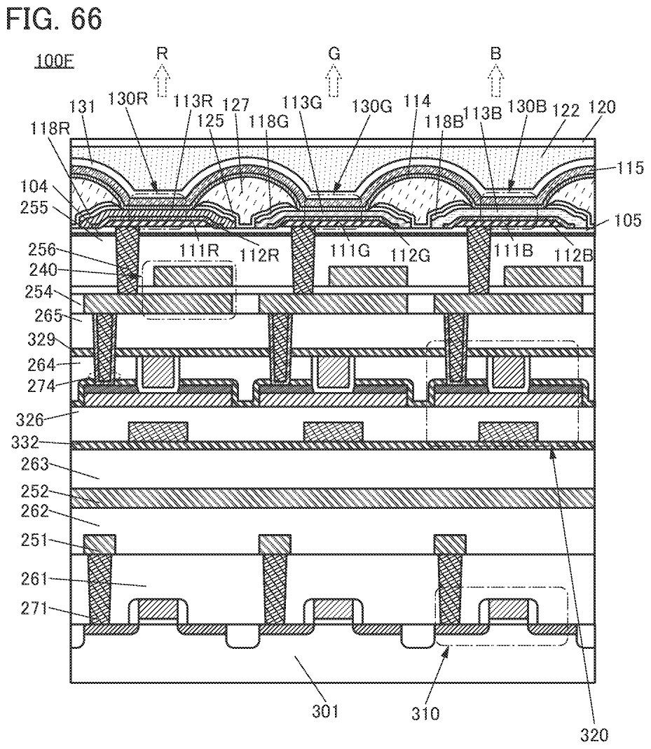

The display device 100F illustrated in FIG. 66 has a structure in which the transistor 310 whose channel is formed in the substrate 301 and the transistor 320 including a metal oxide in the semiconductor layer where the channel is formed are stacked.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. The transistor 310 can be used as a transistor included in the pixel circuit or a transistor included in a driver circuit (a gate line driver circuit or a source line driver circuit) for driving the pixel circuit. The transistor 310 and the transistor 320 can also be used as transistors included in a variety of circuits such as an arithmetic circuit and a memory circuit.

With such a structure, not only the pixel circuit but also the driver circuit, for example, can be formed directly under the light-emitting elements; thus, the display device can be downsized as compared with the case where a driver circuit is provided around a display region.

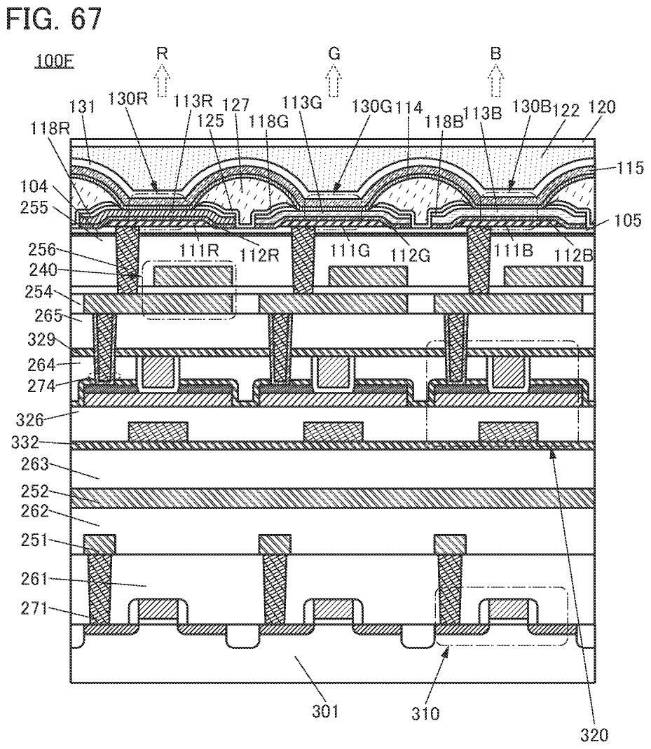

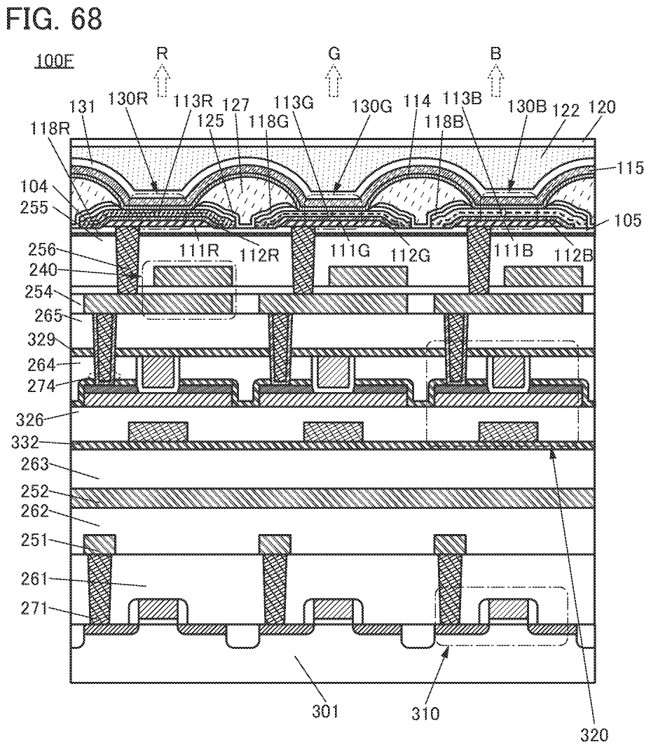

FIG. 67 illustrates a modification example of the structure illustrated in FIG. 66, and in the example, the light-emitting element 130R, the light-emitting element 130G, and the light-emitting element 130B have the structure illustrated in FIG. 10. FIG. 68 illustrates a modification example of the structure illustrated in FIG. 66, and in the example, the light-emitting element 130R, the light-emitting element 130G, and the light-emitting element 130B have the structure illustrated in FIG. 14.

### [Display Device 100G]

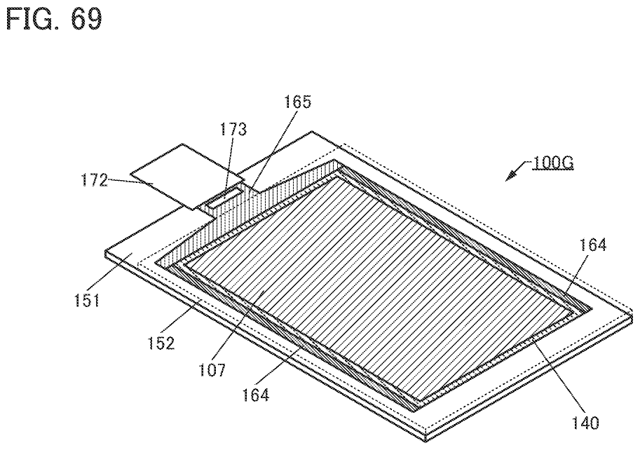

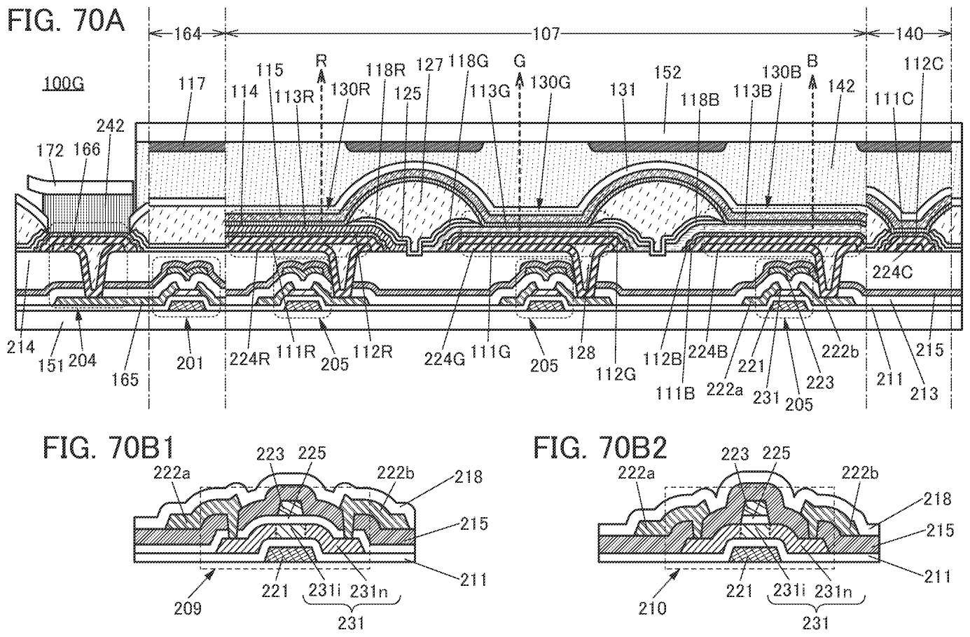

FIG. 69 is a perspective view of a display device 100G, and FIG. 70A is a cross-sectional view of the display device 100G.

In the display device 100G, a substrate 152 and a substrate 151 are bonded to each other. In FIG. 69, the substrate 152 is clearly denoted by a dashed line.

The display device 100G includes the pixel portion 107, the connection portion 140, a circuit 164, a wiring 165, and the like. FIG. 69 illustrates an example where an IC 173 and an FPC 172 are mounted on the display device 100G. Thus, the structure illustrated in FIG. 69 can be regarded as a display module including the display device 100G, the IC, and the FPC. Here, a display device in which a substrate is equipped with a connector such as an FPC or mounted with an IC is referred to as a display module.

The connection portion 140 is provided outside the pixel portion 107. The connection portion 140 can be provided along one or more sides of the pixel portion 107. The number of connection portions 140 can be one or more. FIG. 69 illustrates an example where the connection portion 140 is provided to surround the four sides of the display portion. A common electrode of a light-emitting element is electrically connected to a conductive layer in the connection portion 140, so that a potential can be supplied to the common electrode.

As the circuit 164, a scan line driver circuit can be used, for example.

The wiring 165 has a function of supplying a signal and power to the pixel portion 107 and the circuit 164. The signal and power are input to the wiring 165 from the outside through the FPC 172 or from the IC 173.

FIG. 69 illustrates an example where the IC 173 is provided over the substrate 151 by a COG (Chip On Glass) method, a COF (Chip On Film) method, or the like. An IC including a scan line driver circuit, a signal line driver circuit, or the like can be used as the IC 173, for example. Note that the display device 100G and the display module are not necessarily provided with an IC. The IC may be mounted on the FPC by a COF method, for example.

FIG. 70A illustrates example cross sections of part of a region including the FPC 172, part of the circuit 164, part of the pixel portion 107, part of the connection portion 140, and part of a region including an end portion of the display device 100G.

The display device 100G illustrated in FIG. 70A includes a transistor 201, a transistor 205, the light-emitting element 130R that emits red light, the light-emitting element 130G that emits green light, the light-emitting element 130B that emits blue light, and the like between the substrate 151 and the substrate 152.

The light-emitting element 130R, the light-emitting element 130G, and the light-emitting element 130B each have the same structure as the stacked-layer structure illustrated in FIG. 2A except the structure of the pixel electrode. For details of the light-emitting element, Embodiment 1 can be referred to.

The light-emitting element 130R includes a conductive layer 224R, the conductive layer 111R over the conductive layer 224R, and the conductive layer 112R over the conductive layer 111R. All of the conductive layer 224R, the conductive layer 111R, and the conductive layer 112R can be referred to as a pixel electrode, or the conductive layer 111R and the conductive layer 112R can be referred to as a pixel electrode.

The light-emitting element 130G includes a conductive layer 224G, the conductive layer 111G over the conductive layer 224G, and the conductive layer 112G over the conductive layer 111G.

The light-emitting element 130B includes a conductive layer 224B, the conductive layer 111B over the conductive layer 224B, and the conductive layer 112B over the conductive layer 111B.

The conductive layer 224R is connected to a conductive layer 222b included in the transistor 205 through an opening provided in an insulating layer 214, an insulating layer 215, and an insulating layer 213. An end portion of the conductive layer 111R is positioned on the outer side of an end portion of the conductive layer 224R. As described above, the conductive layer 112R is provided to cover the upper surface and the side surface of the conductive layer 111R.

Detailed description of the conductive layer 224G, the conductive layer 111G, and the conductive layer 112G of the light-emitting element 130G and the conductive layer 224B, the conductive layer 111B, and the conductive layer 112B of the light-emitting element 130B is omitted because these conductive layers are similar to the conductive layer 224R, the conductive layer 111R, and the conductive layer 112R of the light-emitting element 130R.

The conductive layer 224R, the conductive layer 224G, and the conductive layer 224B are formed to cover the openings provided in the insulating layer 214. A layer 128 is embedded in each of the depressed portions.

The layer 128 has a planarization function for the depressed portions of the conductive layer 224R, the conductive layer 224G, and the conductive layer 224B. Over the conductive layer 224R, the conductive layer 224G, the conductive layer 224B, and the layer 128, the conductive layer 111R, the conductive layer 111G, and the conductive layer 111B that are respectively electrically connected to the conductive layer 224R, the conductive layer 224G, and the conductive layer 224B are provided. Thus, regions overlapping with the depressed portions of the conductive layer 224R, the conductive layer 224G, and the conductive layer 224B can also be used as the light-emitting regions, increasing the aperture ratio of the pixels.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is further preferably formed using an organic insulating material. For the layer 128, an organic insulating material that can be used for the insulating layer 127 can be used, for example.

The protective layer 131 is provided over the light-emitting element 130R, the light-emitting element 130G, and the light-emitting element 130B. The protective layer 131 and the substrate 152 are bonded to each other with an adhesive layer 142. The substrate 152 is provided with a light-blocking layer 117. A solid sealing structure, a hollow sealing structure, or the like can be employed to seal the light-emitting elements 130. In FIG. 70A, a solid sealing structure is employed in which a space between the substrate 152 and the substrate 151 is filled with the adhesive layer 142. Alternatively, a hollow sealing structure in which the space is filled with an inert gas (e.g., nitrogen or argon) may be employed. Here, the adhesive layer 142 may be provided not to overlap with the light-emitting elements. The space may be filled with a resin different from that of the frame-shaped adhesive layer 142.

FIG. 70A illustrates an example in which the connection portion 140 includes a conductive layer 224C obtained by processing the same conductive film as the conductive layer 224R, the conductive layer 224G, and the conductive layer 224B, the conductive layer 111C obtained by processing the same conductive film as the conductive layer 111R, the conductive layer 111G, and the conductive layer 111B, and the conductive layer 112C obtained by processing the same conductive film as the conductive layer 112R, the conductive layer 112G, and the conductive layer 112B.

The display device 100G has a top-emission structure. Light emitted by the light-emitting element is emitted toward the substrate 152 side. For the substrate 152, a material having a high visible-light-transmitting property is preferably used. The pixel electrode contains a material that reflects visible light, and a counter electrode (the common electrode 115) contains a material that transmits visible light.

The transistor 201 and the transistor 205 are formed over the substrate 151. These transistors can be fabricated using the same material in the same process.

An insulating layer 211, an insulating layer 213, an insulating layer 215, and the insulating layer 214 are provided in this order over the substrate 151. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or two or more.

A material in which impurities such as water and hydrogen do not easily diffuse is preferably used for at least one of the insulating layers covering the transistors. In that case, the insulating layer can function as a barrier layer. Such a structure can effectively inhibit diffusion of impurities into the transistors from the outside and increase the reliability of the display device.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

An organic insulating layer is suitable as the insulating layer 214 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. The insulating layer 214 may have a stacked-layer structure of an organic insulating layer and an inorganic insulating layer. The uppermost layer of the insulating layer 214 preferably has a function of an etching protective layer. In that case, a depressed portion can be inhibited from being formed in the insulating layer 214 at the time of processing the conductive layer 224R, the conductive layer 111R, the conductive layer 112R, or the like. Alternatively, a depressed portion may be formed in the insulating layer 214 at the time of processing the conductive layer 224R, the conductive layer 111R, the conductive layer 112R, or the like.

Each of the transistor 201 and the transistor 205 includes a conductive layer 221 functioning as a gate, the insulating layer 211 functioning as a gate insulating layer, a conductive layer 222a and the conductive layer 222b functioning as a source and a drain, a semiconductor layer 231, the insulating layer 213 functioning as a gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display device of this embodiment. For example, a planar transistor, a staggered transistor, an inverted staggered transistor, or the like can be used. A top-gate transistor structure or a bottom-gate transistor structure may be employed. Alternatively, gates may be provided above and below the semiconductor layer where a channel is formed.

The structure where the semiconductor layer where a channel is formed is held between two gates is used for the transistor 201 and the transistor 205. The two gates may be connected to each other and supplied with the same signal to drive the transistor. Alternatively, a potential for controlling the threshold voltage may be supplied to one of the two gates and a potential for driving may be supplied to the other to control the threshold voltage of the transistor.

There is no particular limitation on the crystallinity of a semiconductor material used for the transistors, and any of an amorphous semiconductor and a semiconductor having crystallinity (a microcrystalline semiconductor, a polycrystalline semiconductor, a single crystal semiconductor, or a semiconductor partly including crystal regions) may be used. It is preferable to use a semiconductor having crystallinity, in which case deterioration of the transistor characteristics can be inhibited.

The semiconductor layer of the transistor preferably includes a metal oxide. That is, a transistor including a metal oxide in its channel formation region is preferably used for the display device of this embodiment.

As examples of the oxide semiconductor having crystallinity, a CAAC (c-axis aligned crystalline)-OS, an nc (nanocrystalline)-OS, and the like can be given.

Alternatively, a transistor containing silicon in its channel formation region (a Si transistor) may be used. As examples of silicon, single crystal silicon, polycrystalline silicon, amorphous silicon, and the like can be given. In particular, a transistor containing low-temperature polysilicon (LTPS) in its semiconductor layer (hereinafter also referred to as an LTPS transistor) can be used. The LTPS transistor has high field-effect mobility and favorable frequency characteristics.

With the use of Si transistors such as LTPS transistors, a circuit required to be driven at a high frequency (e.g., a source driver circuit) can be formed on the same substrate as a display portion. Thus, external circuits mounted on the display device can be simplified, and parts costs and mounting costs can be reduced.

An OS transistor has much higher field-effect mobility than a transistor containing amorphous silicon. In addition, the OS transistor has an extremely low leakage current between a source and a drain in an off state (hereinafter, also referred to as off-state current), and electric charge accumulated in a capacitor that is connected in series to the transistor can be retained for a long period. Furthermore, power consumption of the display device can be reduced with the use of an OS transistor.

To increase the emission luminance of the light-emitting element included in the pixel circuit, the amount of current fed through the light-emitting element needs to be increased. For this, it is necessary to increase the source-drain voltage of a driving transistor included in the pixel circuit. Since an OS transistor has a higher breakdown voltage between the source and the drain than a Si transistor, a high voltage can be applied between the source and the drain of the OS transistor. Accordingly, when an OS transistor is used as the driving transistor included in the pixel circuit, the amount of current flowing through the light-emitting element can be increased, so that the emission luminance of the light-emitting element can be increased.

When transistors operate in a saturation region, a change in source-drain current with respect to a change in gate-source voltage can be smaller in an OS transistor than in a Si transistor. Accordingly, when an OS transistor is used as the driving transistor in the pixel circuit, the amount of current flowing between the source and the drain can be set minutely by a change in gate-source voltage: hence, the amount of current flowing through the light-emitting element can be controlled. Accordingly, the number of gray levels in the pixel circuit can be increased.

Regarding saturation characteristics of current flowing when transistors operate in a saturation region, even in the case where the source-drain voltage of an OS transistor increases gradually, a more stable current (saturation current) can be fed through the OS transistor than through a Si transistor. Thus, by using an OS transistor as the driving transistor, a stable current can be fed through light-emitting elements even when the current-voltage characteristics of the organic EL devices vary, for example. In other words, when the OS transistor operates in the saturation region, the source-drain current hardly changes with an increase in the source-drain voltage: hence, the emission luminance of the light-emitting element can be stable.

As described above, with the use of an OS transistor as a driving transistor included in the pixel circuit, it is possible to achieve “inhibition of black-level degradation,” “increase in emission luminance,” “increase in gray level,” “inhibition of variation in light-emitting elements,” and the like.

The semiconductor layer preferably contains indium, M (M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more selected from aluminum, gallium, yttrium, and tin.

It is particularly preferable that an oxide containing indium (In), gallium (Ga), and zinc (Zn) (also referred to as IGZO) be used for the semiconductor layer. Alternatively, it is preferable to use an oxide containing indium, tin, and zinc. Further alternatively, it is preferable to use an oxide containing indium, gallium, tin, and zinc. Alternatively, an oxide containing indium (In), aluminum (Al), and zinc (Zn) (also referred to as IAZO) is preferably used for the semiconductor layer. Alternatively, an oxide containing indium (In), aluminum (Al), gallium (Ga), and zinc (Zn) (also referred to as IAGZO) is preferably used for the semiconductor layer.

When the semiconductor layer is an In-M-Zn oxide, the atomic ratio of In is preferably higher than or equal to the atomic ratio of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of +30% of an intended atomic ratio.

For example, when the atomic ratio is described as In:Ga:Zn=4:2:3 or a composition in the neighborhood thereof, the case is included where the atomic proportion of Ga is greater than or equal to 1 and less than or equal to 3 and the atomic proportion of Zn is greater than or equal to 2 and less than or equal to 4 with the atomic proportion of In being 4. When the atomic ratio is described as In:Ga:Zn=5:1:6 or a composition in the neighborhood thereof, the case is included where the atomic proportion of Ga is greater than 0.1 and less than or equal to 2 and the atomic proportion of Zn is greater than or equal to 5 and less than or equal to 7 with the atomic proportion of In being 5. When the atomic ratio is described as In:Ga:Zn=1:1:1 or a composition in the neighborhood thereof, the case is included where the atomic proportion of Ga is greater than 0.1 and less than or equal to 2 and the atomic proportion of Zn is greater than 0.1 and less than or equal to 2 with the atomic proportion of In being 1.

The transistor included in the circuit 164 and the transistor included in the pixel portion 107 may have the same structure or different structures. One structure or two or more types of structures may be employed for a plurality of transistors included in the circuit 164. Similarly, one structure or two or more types of structures may be employed for a plurality of transistors included in the pixel portion 107.

All of the transistors included in the pixel portion 107 may be OS transistors or all of the transistors included in the pixel portion 107 may be Si transistors: alternatively, some of the transistors included in the pixel portion 107 may be OS transistors and the others may be Si transistors.

For example, when both an LTPS transistor and an OS transistor are used in the pixel portion 107, the display device can have low power consumption and high driving capability. A structure where an LTPS transistor and an OS transistor are used in combination is referred to as LTPO in some cases. For example, preferably, an OS transistor is used as a transistor functioning as a switch for controlling conduction and non-conduction between wirings and an LTPS transistor is used as a transistor for controlling current.

For example, one of the transistors included in the pixel portion 107 functions as a transistor for controlling current flowing through the light-emitting element and can be referred to as a driving transistor. One of a source and a drain of the driving transistor is electrically connected to the pixel electrode of the light-emitting element. An LTPS transistor is preferably used as the driving transistor. In that case, the amount of current flowing through the light-emitting element can be increased in the pixel circuit.

Another transistor included in the pixel portion 107 functions as a switch for controlling selection and non-selection of the pixel and can be referred to as a selection transistor. A gate of the selection transistor is electrically connected to a gate line, and one of a source and a drain thereof is electrically connected to a signal line. An OS transistor is preferably used as the selection transistor. In that case, the gray level of the pixel can be maintained even with an extremely low frame frequency (e.g., lower than or equal to 1 fps); thus, power consumption can be reduced by stopping the driver in displaying a still image.

As described above, the display device of one embodiment of the present invention can have all of a high aperture ratio, high resolution, high display quality, and low power consumption.

Note that the display device of one embodiment of the present invention has a structure including the OS transistor and the light-emitting element having an MML (metal maskless) structure. With this structure, the leakage current that might flow through the transistor and the lateral leakage current that might flow between adjacent light-emitting elements can be extremely low: With the structure, a viewer can notice any one or more of the image crispness, the image sharpness, a high chroma, and a high contrast ratio in an image displayed on the display device. When the leakage current that would flow through the transistor and the lateral leakage current between the light-emitting elements are extremely low; light leakage that might occur in black display (what is called black-level degradation) or the like can be minimized.

In particular, in the case where a light-emitting element having the MML structure employs the above-described SBS structure, a layer provided between light-emitting elements is disconnected: accordingly, lateral leakage current can be prevented or be made extremely low. FIG. 70B1 and FIG. 70B2 illustrate other structure examples of transistors.

A transistor 209 and a transistor 210 each include the conductive layer 221 functioning as a gate, the insulating layer 211 functioning as a gate insulating layer, the semiconductor layer 231 including a channel formation region 231i and a pair of low-resistance regions 231n, the conductive layer 222a connected to one of the pair of low-resistance regions 231n, the conductive layer 222b connected to the other of the pair of low-resistance regions 231n, an insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned at least between the conductive layer 223 and the channel formation region 231i. Furthermore, an insulating layer 218 covering the transistor may be provided.

FIG. 70B1 illustrates an example of the transistor 209 in which the insulating layer 225 covers the upper surface and the side surface of the semiconductor layer 231. The conductive layer 222a and the conductive layer 222b are connected to the low-resistance regions 231n through openings provided in the insulating layer 225 and the insulating layer 215. One of the conductive layer 222a and the conductive layer 222b functions as a source, and the other functions as a drain.

Meanwhile, in the transistor 210 illustrated in FIG. 70B2C, the insulating layer 225 overlaps with the channel formation region 231i of the semiconductor layer 231 and does not overlap with the low-resistance regions 231n. The structure illustrated in FIG. 70B2 can be formed by processing the insulating layer 225 with the conductive layer 223 as a mask, for example. In FIG. 70B2, the insulating layer 215 is provided to cover the insulating layer 225 and the conductive layer 223, and the conductive layer 222a and the conductive layer 222b are connected to the low-resistance regions 231n through the openings in the insulating layer 215.

A connection portion 204 is provided in a region of the substrate 151 where the substrate 152 does not overlap. In the connection portion 204, the wiring 165 is electrically connected to the FPC 172 through a conductive layer 166 and a connection layer 242. An example is described in which the conductive layer 166 has a stacked-layer structure of a conductive film obtained by processing the same conductive film as the conductive layer 224R, the conductive layer 224G, and the conductive layer 224B, a conductive film obtained by processing the same conductive film as the conductive layer 111R, the conductive layer 111G, and the conductive layer 111B, and a conductive film obtained by processing the same conductive film as the conductive layer 112R, the conductive layer 112G, and the conductive layer 112B. The conductive layer 166 is exposed on the upper surface of the connection portion 204. Thus, the connection portion 204 and the FPC 172 can be electrically connected to each other through the connection layer 242.

A light-blocking layer 117 is preferably provided on the surface of the substrate 152 that faces the substrate 151. The light-blocking layer 117 can be provided between adjacent light-emitting elements, in the connection portion 140, and in the circuit 164, for example. A variety of optical members can be provided on the outer surface of the substrate 152.

The material that can be used for the substrate 120 can be used for each of the substrate 151 and the substrate 152.

The material that can be used for the resin layer 122 can be used for the adhesive layer 142.

As the connection layer 242, an anisotropic conductive film (ACF), an anisotropic conductive paste (ACP), or the like can be used.

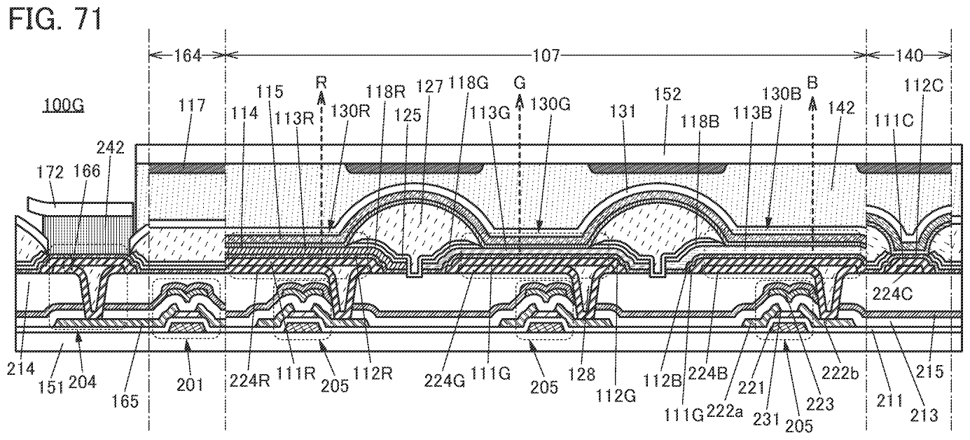

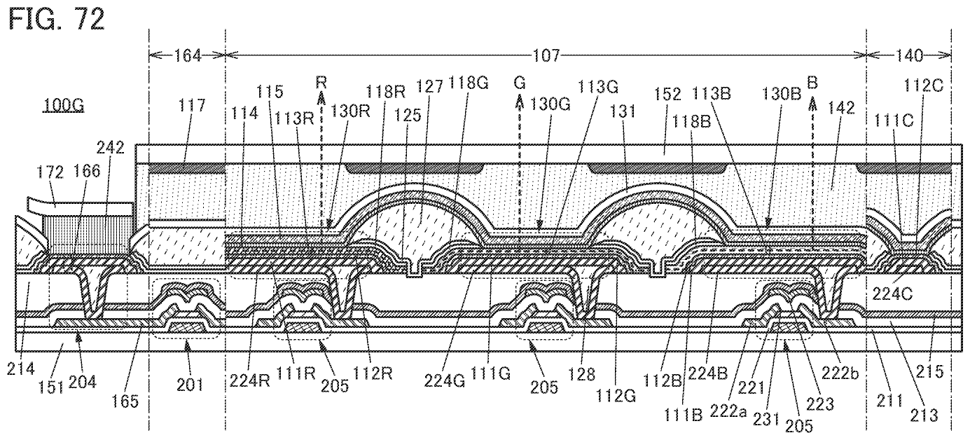

FIG. 71 illustrates a modification example of the structure illustrated in FIG. 70A, and in the example, the light-emitting element 130R, the light-emitting element 130G, and the light-emitting element 130B have the structure illustrated in FIG. 10. FIG. 72 illustrates a modification example of the structure illustrated in FIG. 70A, and in the example, the light-emitting element 130R, the light-emitting element 130G, and the light-emitting element 130B have the structure illustrated in FIG. 14.

### [Display Device 100H]

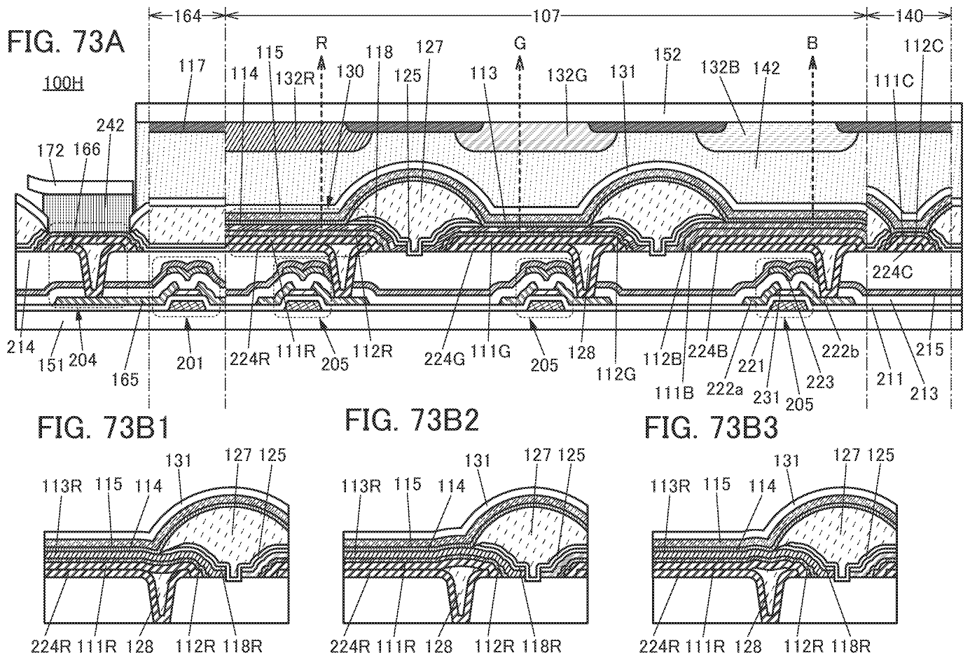

The display device 100H illustrated in FIG. 73A is a modification example of the display device 100G illustrated in FIG. 70A and differs from the display device 100G mainly in including the coloring layer 132R, the coloring layer 132G, and the coloring layer 132B.

In the display device 100H, the light-emitting element 130 includes a region overlapping with one of the coloring layer 132R, the coloring layer 132G, and the coloring layer 132B. The coloring layer 132R, the coloring layer 132G, and the coloring layer 132B can be provided on a surface of the substrate 152 on the substrate 151 side. The end portion of the coloring layer 132R, the end portion of the coloring layer 132G, and the end portion of the coloring layer 132B can overlap with the light-blocking layer 117. Regarding the display device 100H, FIG. 19A can be referred to for the details of the structure of the light-emitting element 130, for example.

In the display device 100H, the light-emitting element 130 can emit white light, for example. For example, the coloring layer 132R transmits red light, the coloring layer 132G transmits green light, and the coloring layer 132B transmits blue light. Note that in the display device 100H the coloring layer 132R, the coloring layer 132G, and the coloring layer 132B may be provided between the protective layer 131 and the adhesive layer 142. In that case, the protective layer 131 is preferably planarized as illustrated in FIG. 19A.

Although FIG. 70A, FIG. 73A, and the like illustrate an example where the upper surface of the layer 128 includes a flat portion, the shape of the layer 128 is not particularly limited. FIG. 73B1 to FIG. 73B3 illustrate variation examples of the layer 128.

As illustrated in FIG. 73B1 to FIG. 73B3, the upper surface of the layer 128 can have a shape such that its center and the vicinity thereof are depressed, i.e., a shape including a concave surface, in a cross-sectional view.

As illustrated in FIG. 73B2, the upper surface of the layer 128 can have a shape such that its center and the vicinity thereof bulge, i.e., a shape including a convex surface, in a cross-sectional view.

The upper surface of the layer 128 may include one or both of a convex surface and a concave surface. The number of convex surfaces and the number of concave surfaces included in the upper surface of the layer 128 are not limited and can each be one or more.

The level of the upper surface of the layer 128 and the level of the upper surface of the conductive layer 224R may be equal to or substantially equal to each other, or may be different from each other. For example, the level of the upper surface of the layer 128 may be either lower or higher than the level of the upper surface of the conductive layer 224R.

FIG. 73B1 can be regarded as illustrating an example where the layer 128 fits in the depressed portion formed in the conductive layer 224R. By contrast, as illustrated in FIG. 73B3, the layer 128 may exist also outside the depressed portion formed in the conductive layer 224R, that is, the layer 128 may be formed to have an upper surface wider than the depressed portion.

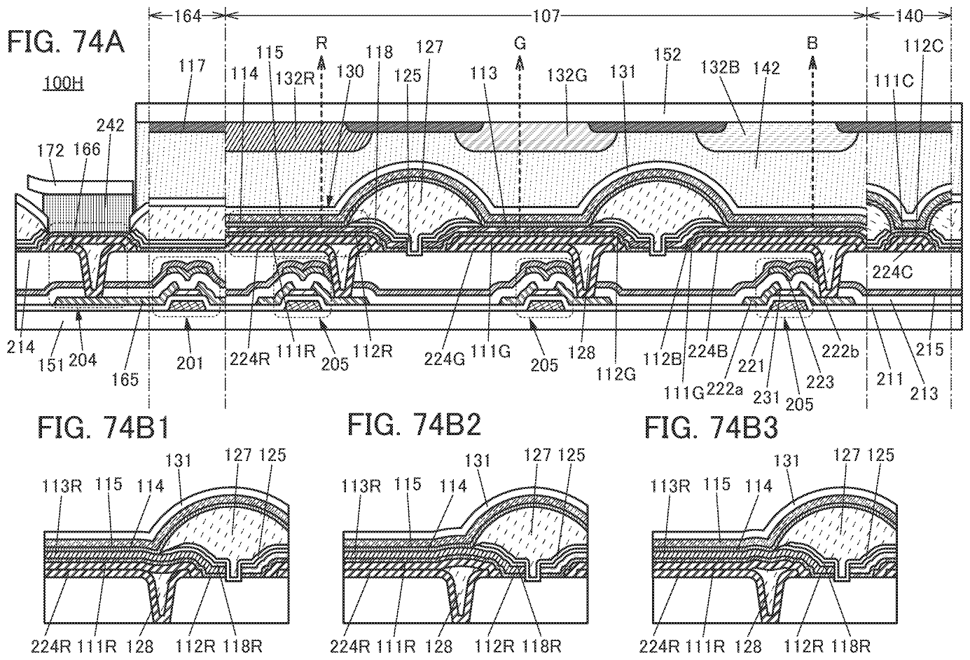

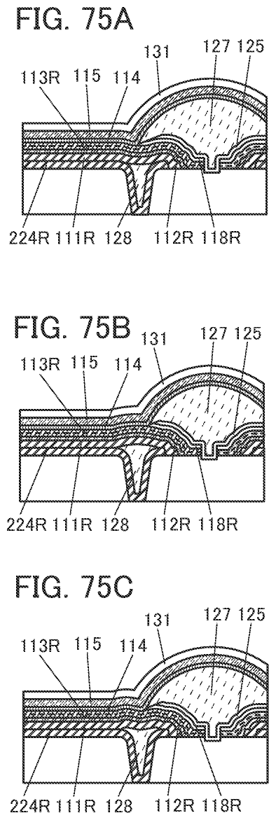

FIG. 74A, FIG. 74B1, FIG. 74B2, and FIG. 74B3 are modification examples of the structures illustrated in FIG. 73A, FIG. 73B1, FIG. 73B2, and FIG. 73B3, respectively, and in each example, the light-emitting element 130R, the light-emitting element 130G, and the light-emitting element 130B have the structure illustrated in FIG. 10. FIG. 75A to FIG. 75C illustrate modification examples of the structures illustrated in FIG. 73B1 to FIG. 73B3, respectively, and in each example, the EL layer 113R has the structure illustrated in FIG. 14.

This embodiment can be combined with any of the other embodiments as appropriate. In this specification, in the case where a plurality of structure examples are described in one embodiment, the structure examples can be combined as appropriate.

### Embodiment 5

In this embodiment, light-emitting elements that can be used for the display device of one embodiment of the present invention will be described.

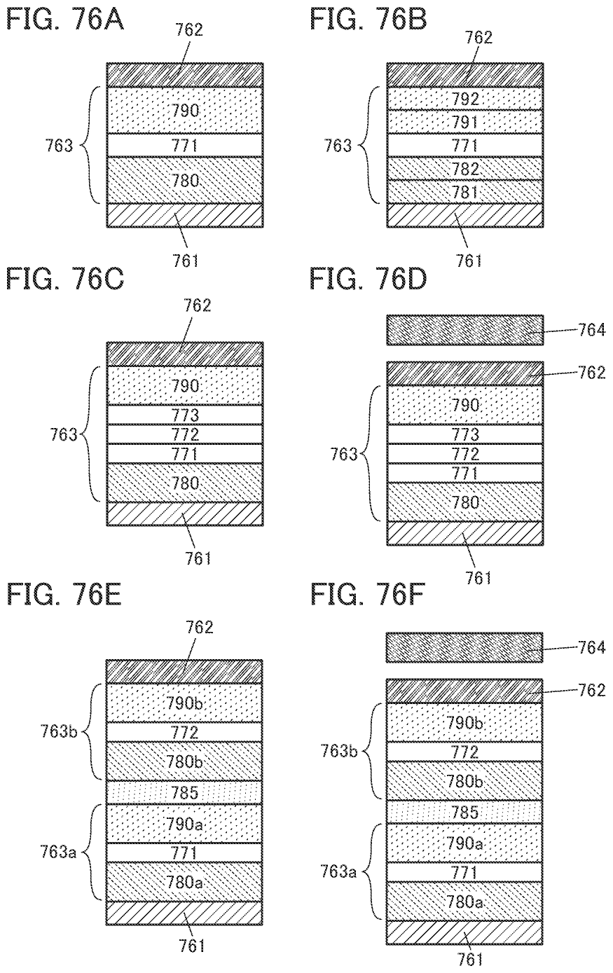

As illustrated in FIG. 76A, the light-emitting element includes an EL layer 763 between a pair of electrodes (a lower electrode 761 and an upper electrode 762). The EL layer 763 can be formed of a plurality of layers such as a layer 780, a light-emitting layer 771, and a layer 790.

The light-emitting layer 771 contains at least a light-emitting substance.

In the case where the lower electrode 761 is an anode and the upper electrode 762 is a cathode, the layer 780 includes one or more of a layer containing a substance with a high hole-injection property (a hole-injection layer), a layer containing a substance with a high hole-transport property (a hole-transport layer), and a layer containing a substance with a high electron-blocking property (an electron-blocking layer). Furthermore, the layer 790 includes one or more of a layer containing a substance with a high electron-injection property (an electron-injection layer), a layer containing a substance with a high electron-transport property (an electron-transport layer), and a layer containing a substance with a high hole-blocking property (a hole-blocking layer). In the case where the lower electrode 761 is a cathode and the upper electrode 762 is an anode, the above structures of the layer 780 and the layer 790 are replaced with each other.

The structure including the layer 780, the light-emitting layer 771, and the layer 790, which is provided between a pair of electrodes, can function as a single light-emitting unit, and the structure in FIG. 76A is referred to as a single structure in this specification.

FIG. 76B is a variation example of the EL layer 763 included in the light-emitting element illustrated in FIG. 76A. Specifically, the light-emitting element illustrated in FIG. 76B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layer structure, carriers can be efficiently injected to the light-emitting layer 771, and the efficiency of the recombination of carriers in the light-emitting layer 771 can be increased.

Note that structures in which a plurality of light-emitting layers (light-emitting layers 771, 772, and 773) are provided between the layer 780 and the layer 790 as illustrated in FIG. 76C and FIG. 76D are variations of the single structure. Although FIG. 76C and FIG. 76D illustrate the examples where three light-emitting layers are included, the light-emitting element having a single structure may include two or four or more light-emitting layers. In addition, the light-emitting element having a single structure may include a buffer layer between two light-emitting layers. The buffer layer can be formed using a material that can be used for the hole-transport layer or the electron-transport layer, for example.

A structure where a plurality of light-emitting units (a light-emitting unit 763a and a light-emitting unit 763b) are connected in series with a charge-generation layer 785 (also referred to as an intermediate layer) therebetween as illustrated in FIG. 76E and FIG. 76F is referred to as a tandem structure in this specification. Note that the tandem structure may be referred to as a stack structure. The tandem structure enables a light-emitting element capable of high-luminance light emission. Furthermore, the tandem structure reduces the amount of current needed for obtaining the same luminance as compared with a single structure, and thus can improve the reliability.

Note that FIG. 76D and FIG. 76F illustrate examples where the display device includes a layer 764 overlapping with the light-emitting element. FIG. 76D illustrates an example in which the layer 764 overlaps with the light-emitting element illustrated in FIG. 76C, and FIG. 76F illustrates an example in which the layer 764 overlaps with the light-emitting element illustrated in FIG. 76E. In FIG. 76D and FIG. 76F, a conductive film transmitting visible light is used for the upper electrode 762 to extract light to the upper electrode 762 side.

One or both of a color conversion layer and a color filter (coloring layer) can be used as the layer 764.

In FIG. 76C and FIG. 76D, light-emitting substances that emit light of the same color, or moreover, the same light-emitting substance may be used for the light-emitting layer 771, the light-emitting layer 772, and the light-emitting layer 773. For example, a light-emitting substance emitting blue light may be used for the light-emitting layer 771, the light-emitting layer 772, and the light-emitting layer 773. In a subpixel that emits blue light, blue light emitted from the light-emitting element can be extracted. In a subpixel that emits red light and a subpixel that emits green light, by providing a color conversion layer as the layer 764 illustrated in FIG. 76D, blue light emitted from the light-emitting element can be converted into light with a longer wavelength, and red light or green light can be extracted. As the layer 764, both a color conversion layer and a coloring layer are preferably used. In some cases, part of light emitted from the light-emitting element is transmitted through the color conversion layer without being converted. When light transmitted through the color conversion layer is extracted through the coloring layer, light other than light of the intended color can be absorbed by the coloring layer, and color purity of light exhibited by a subpixel can be improved.

Alternatively, light-emitting substances emitting light of different colors may be used for the light-emitting layer 771, the light-emitting layer 772, and the light-emitting layer 773. White light emission can be obtained when the light-emitting layer 771, the light-emitting layer 772, and the light-emitting layer 773 emit light of complementary colors. The light-emitting element having a single structure preferably includes a light-emitting layer containing a light-emitting substance emitting blue light and a light-emitting layer containing a light-emitting substance emitting visible light with a longer wavelength than blue light, for example.

In the case where the light-emitting element having a single structure includes three light-emitting layers, for example, a light-emitting layer containing a light-emitting substance emitting red (R) light, a light-emitting layer containing a light-emitting substance emitting green (G) light, and a light-emitting layer containing a light-emitting substance emitting blue (B) light are preferably included. The stacking order of the light-emitting layers can be RGB or RBG from an anode side, for example. In that case, a buffer layer may be provided between R and G or between R and B.

For example, in the case where the light-emitting element having a single structure includes two light-emitting layers, the light-emitting element preferably includes a light-emitting layer containing a light-emitting substance that emits blue (B) light and a light-emitting layer containing a light-emitting substance that emits yellow (Y) light. Such a structure may be referred to as a BY single structure.

A coloring layer may be provided as the layer 764 illustrated in FIG. 76D. When white light passes through the coloring layer, light of a desired color can be obtained.

The light-emitting element emitting white light preferably contains two or more light-emitting layers. For example, when white light emission is obtained using two light-emitting layers, two or more light-emitting layers are selected such that their emission colors are complementary. For example, when an emission color of a first light-emitting layer and an emission color of a second light-emitting layer are complementary colors, the light-emitting element can be configured to emit white light as a whole. To obtain white light emission by using three or more light-emitting layers, the light-emitting element is configured to emit white light as a whole by combining emission colors of the three or more light-emitting layers.

In FIG. 76E and FIG. 76F, light-emitting substances that emit light of the same color, or moreover, the same light-emitting substance may be used for the light-emitting layer 771 and the light-emitting layer 772.

For example, in light-emitting elements included in subpixels emitting light of different colors, a light-emitting substance that emits blue light can be used for each of the light-emitting layer 771 and the light-emitting layer 772. In a subpixel that emits blue light, blue light emitted from the light-emitting element can be extracted. In the subpixel that emits red light and the subpixel that emits green light, by providing a color conversion layer as the layer 764 illustrated in FIG. 76F, blue light emitted from the light-emitting element can be converted into light with a longer wavelength, and red light or green light can be extracted. As the layer 764, both a color conversion layer and a coloring layer are preferably used.

In the case where the light-emitting element having the structure illustrated in FIG. 76E or FIG. 76F is used for the subpixels emitting different colors, the subpixels may use different light-emitting substances. Specifically, in the light-emitting element included in the subpixel emitting red light, a light-emitting substance that emits red light can be used for each of the light-emitting layer 771 and the light-emitting layer 772. Similarly, in the light-emitting element included in the subpixel emitting green light, a light-emitting substance that emits green light can be used for each of the light-emitting layer 771 and the light-emitting layer 772. In the light-emitting element included in the subpixel emitting blue light, a light-emitting substance that emits blue light can be used for each of the light-emitting layer 771 and the light-emitting layer 772. In light-emitting elements included in subpixels emitting light of different colors, a light-emitting substance that emits blue light can be used for each of the light-emitting layer 771 and the light-emitting layer 772. A display device having such a structure can be regarded as employing a light-emitting element with the tandem structure and the SBS structure. Thus, advantages of both the tandem structure and the SBS structure can be achieved. Accordingly, a light-emitting element being capable of high-luminance light emission and having high reliability can be obtained.

In FIG. 76E and FIG. 76F, light-emitting substances emitting light of different colors may be used for the light-emitting layer 771 and the light-emitting layer 772. White light emission can be obtained when the light-emitting layer 771 and the light-emitting layer 772 emit light of complementary colors. A coloring layer may be provided as the layer 764 illustrated in FIG. 76F. When white light passes through the coloring layer, light of a desired color can be obtained.

Although FIG. 76E and FIG. 76F illustrate examples where the light-emitting unit 763a includes one light-emitting layer 771 and the light-emitting unit 763b includes one the light-emitting layer 772, one embodiment of the present invention is not limited thereto. Each of the light-emitting unit 763a and the light-emitting unit 763b may include two or more light-emitting layers.

In addition, although FIG. 76E and FIG. 76F illustrate the light-emitting element including two light-emitting units, one embodiment of the present invention is not limited thereto. The light-emitting element may include three or more light-emitting units.

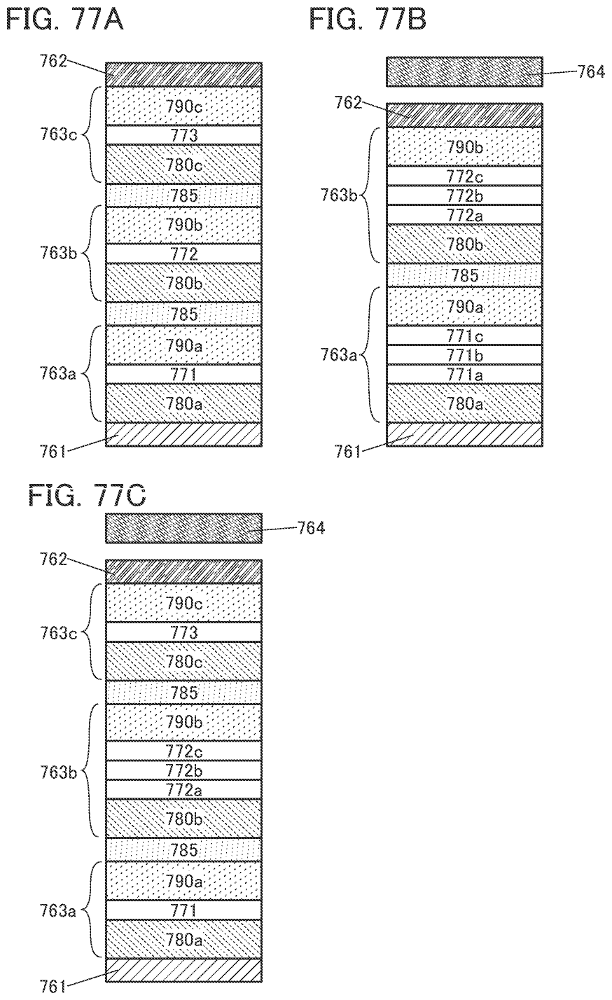

Specifically, structures of the light-emitting element illustrated in FIG. 77A to FIG. 77C can be given.

FIG. 77A illustrates a structure including three light-emitting units. Note that a structure including two light-emitting units and a structure including three light-emitting units may be referred to as a two-unit tandem structure and a three-unit tandem structure, respectively.

As illustrated in FIG. 77A, a plurality of light-emitting units (the light-emitting unit 763a, the light-emitting unit 763b, and the light-emitting unit 763c) are connected in series through the charge-generation layers 785. The light-emitting unit 763a includes a layer 780a, the light-emitting layer 771, and a layer 790a. The light-emitting unit 763b includes a layer 780b, the light-emitting layer 772, and a layer 790b. The light-emitting unit 763c includes a layer 780c, the light-emitting layer 773, and a layer 790c. Note that the layer 780c can have a structure applicable to the layer 780a and the layer 780b, and the layer 790c can have a structure applicable to the layer 790a and the layer 790b.

In FIG. 77A, the light-emitting layer 771, the light-emitting layer 772, and the light-emitting layer preferably contain light-emitting substances that emit light of the same color. Specifically, the light-emitting layer 771, the light-emitting layer 772, and the light-emitting layer 773 can each contain a light-emitting substance that emits red (R) light (a so-called R\R\R three-unit tandem structure): the light-emitting layer 771, the light-emitting layer 772, and the light-emitting layer 773 can each contain a light-emitting substance that emits green (G) light (a so-called a G\G\G three-unit tandem structure): or the light-emitting layer 771, the light-emitting layer 772, and the light-emitting layer 773 can each contain a light-emitting substance that emits blue (B) light (a so-called B\B\B three-unit tandem structure). Note that “a\b” means that a light-emitting unit containing a light-emitting substance that emits light of b is provided over a light-emitting unit containing a light-emitting substance that emits light of a with a charge-generation layer therebetween, where a and b represent colors.

In FIG. 77A, light-emitting substances that emit light of different colors may be used for some or all of the light-emitting layer 771, the light-emitting layer 772, and the light-emitting layer 773. Examples of a combination of emission colors for the light-emitting layer 771, the light-emitting layer 772, and the light-emitting layer 773 include blue (B) for two of them and yellow (Y) for the other; and red (R) for one of them, green (G) for another, and blue (B) for the other.

Note that the structure containing the light-emitting substances that emit light of the same color is not limited to the above structure. For example, a light-emitting element with a tandem structure may be employed in which light-emitting units each including a plurality of light-emitting layers are stacked as illustrated in FIG. 77B. FIG. 77B illustrates a structure in which two light-emitting units the light-emitting unit 763a and the light-emitting unit 763b) are connected in series with the charge-generation layer 785 therebetween. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In FIG. 77B, the light-emitting unit 763a is configured to emit white (W) light by selecting light-emitting substances for the light-emitting layer 771a, the light-emitting layer 771b, and the light-emitting layer 771c so that their emission colors are complementary colors. Furthermore, the light-emitting unit 763b is configured to emit white (W) light by selecting light-emitting substances for the light-emitting layer 772a, the light-emitting layer 772b, and the light-emitting layer 772c are selected so that their emission colors are complementary colors. That is, the structure illustrated in FIG. 77B is a two-unit tandem structure of WWW. Note that there is no particular limitation on the stacking order of the light-emitting substances having complementary emission colors. The practitioner can select the optimal stacking order as appropriate. Although not illustrated, a three-unit tandem structure of WWW or a tandem structure with four or more units may be employed.

The following structure can be given: a BY or Y\B two-unit tandem structure including a light-emitting unit that emits yellow (Y) light and a light-emitting unit that emits blue (B) light; an R·G\B or B\R·G two-unit tandem structure including a light-emitting unit that emits red (R) light and green (G) light and a light-emitting unit that emits blue (B) light: a B\Y\B three-unit tandem structure including a light-emitting unit that emits blue (B) light, a light-emitting unit that emits yellow (Y) light, and a light-emitting unit that emits blue (B) light in this order: a B\YG\B three-unit tandem structure including a light-emitting unit that emits blue (B) light, a light-emitting unit that emits yellow green (YG) light, and a light-emitting unit that emits blue (B) light in this order; and a B\G\B three-unit tandem structure including a light-emitting unit that emits blue (B) light, a light-emitting unit that emits green (G) light, and a light-emitting unit that emits blue (B) light in this order. Note that “a\b” means that one light-emitting unit contains a light-emitting substance that emits light of a and a light-emitting substance that emits light of b.

As illustrated in FIG. 77C, a light-emitting unit including one light-emitting layer and a light-emitting unit including a plurality of light-emitting layers may be used in combination.

Specifically, in the structure illustrated in FIG. 77C, a plurality of light-emitting units (the light-emitting unit 763a, the light-emitting unit 763b, and the light-emitting unit 763c) are connected in series through the charge-generation layers 785. The light-emitting unit 763a includes the layer 780a, the light-emitting layer 771, and the layer 790a. The light-emitting unit 763b includes a layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

As the structure illustrated in FIG. 77C, for example, a three-unit tandem structure of B\R·G·YG\B in which the light-emitting unit 763a is a light-emitting unit that emits blue (B) light, the light-emitting unit 763b is a light-emitting unit that emits red (R), green (G), and yellow-green (YG) light, and the light-emitting unit 763c is a light-emitting unit that emits blue (B) light can be employed.

Examples of the number of stacked light-emitting units and the order of colors from the anode side include a two-unit structure of B and Y, a two-unit structure of B and a light-emitting unit X, a three-unit structure of B, Y, and B, and a three-unit structure of B, X, and B. Examples of the number of light-emitting layers stacked in the light-emitting unit X and the order of colors from an anode side include a two-layer structure of R and Y, a two-layer structure of R and G, a two-layer structure of G and R, a three-layer structure of G, R, and G, and a three-layer structure of R. G, and R. Another layer may be provided between two light-emitting layers.

Also in FIG. 76C and FIG. 76D, the layer 780 and the layer 790 may each independently have a stacked-layer structure of two or more layers as illustrated in FIG. 76B.

In FIG. 76E and FIG. 76F, the light-emitting unit 763a includes the layer 780a, the light-emitting layer 771, and the layer 790a, and the light-emitting unit 763b includes the layer 780b, the light-emitting layer 772, and the layer 790b.

In the case where the lower electrode 761 is an anode and the upper electrode 762 is a cathode, the layer 780a and the layer 780b each include one or more of a hole-injection layer, a hole-transport layer, and an electron-blocking layer. The layer 790a and the layer 790b each include one or more of an electron-injection layer, an electron-transport layer, and a hole-blocking layer. In the case where the lower electrode 761 is a cathode and the upper electrode 762 is an anode, the structures of the layer 780a and the layer 790a are replaced with each other, and the structures of the layer 780b and the layer 790b are also replaced with each other.

In the case where the lower electrode 761 is an anode and the upper electrode 762 is a cathode, for example, the layer 780a includes a hole-injection layer and a hole-transport layer over the hole-injection layer, and may further include an electron-blocking layer over the hole-transport layer. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 771 and the electron-transport layer. In the case where the lower electrode 761 is a cathode and the upper electrode 762 is an anode, for example, the layer 780a includes an electron-injection layer and an electron-transport layer over the electron-injection layer, and may further include a hole-blocking layer over the electron-transport layer. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 771 and the hole-transport layer.

In the case of fabricating a light-emitting element having a tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes into the other when voltage is applied between the pair of electrodes.

Next, materials that can be used for the light-emitting element will be described.

A conductive film transmitting visible light is used as the electrode through which light is extracted, which is either the lower electrode 761 or the upper electrode 762. A conductive film reflecting visible light is preferably used as the electrode through which light is not extracted. In the case where a display device includes a light-emitting element emitting infrared light, a conductive film transmitting visible light and infrared light is used as the electrode through which light is extracted, and a conductive film reflecting visible light and infrared light is preferably used as the electrode through which light is not extracted.

A conductive film transmitting visible light may be used as the electrode through which light is not extracted. In that case, the electrode is preferably placed between a reflective layer and the EL layer 763. In other words, light emitted from the EL layer 763 may be reflected by the reflective layer to be extracted from the display device.

As a material that forms the pair of electrodes of the light-emitting element, a metal, an alloy, an electrically conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include In—Sn oxide, In—Si—Sn oxide (also referred to as ITSO), In—Zn oxide, and In—W—Zn oxide. Examples of the material include an aluminum alloy, an alloy of silver and magnesium, and an alloy containing silver, such as APC. Other example of the material include elements belonging to Group 1 or Group 2 of the periodic table, which are not exemplified above (e.g., lithium, cesium, calcium, and strontium), rare earth metals such as europium and ytterbium, an alloy containing any of these metals in appropriate combination, and graphene.

In addition, the light-emitting element preferably also employs a microcavity structure. Therefore, one of the pair of electrodes of the light-emitting element is preferably an electrode having properties of transmitting and reflecting visible light (a transflective electrode), and the other is preferably an electrode having a property of reflecting visible light (a reflective electrode). When the light-emitting element has a microcavity structure, light obtained from the light-emitting layer can be resonated between the electrodes, whereby light emitted from the light-emitting element can be intensified.

Note that the transflective electrode can have a stacked-layer structure of a conductive layer that can be used as a reflective electrode and a conductive layer having a visible-light-transmitting property (also referred to as a transparent electrode).

The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity less than or equal to 1×10⁻² Ωcm.

The light-emitting element includes at least the light-emitting layer. The light-emitting element may further include, as a layer other than the light-emitting layer, a layer containing a substance with a high hole-injection property, a substance with a high hole-transport property, a hole-blocking material, a substance with a high electron-transport property, an electron-blocking material, a substance with a high electron-injection property, a substance with a bipolar property (a substance with a high electron-transport property and a high hole-transport property), or the like. For example, the light-emitting element can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used in the light-emitting element, and an inorganic compound may be included. Each layer included in the light-emitting element can be formed by any of the following methods: an evaporation method (including a vacuum evaporation method), a transfer method, a printing method, an ink-jet method, a coating method, and the like.

The light-emitting layer contains one or more kinds of light-emitting substances. As the light-emitting substance, a substance exhibiting an emission color of blue, violet, bluish violet, green, yellowish green, yellow, orange, red, or the like is used as appropriate. Alternatively, as the light-emitting substance, a substance emitting near-infrared light can be used.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton: an organometallic complex (particularly an iridium complex) having a phenylpyridine derivative including an electron-withdrawing group as a ligand: a platinum complex; and a rare earth metal complex.

The light-emitting layer may contain one or more kinds of organic compounds (e.g., a host material and an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the hole-transport material, it is possible to use a material having a high hole-transport property which can be used for the hole-transport layer and will be described later. As the electron-transport material, it is possible to use a material having a high electron-transport property which can be used for the electron-transport layer and will be described later. Alternatively, as one or more kinds of organic compounds, a bipolar material or a TADF material may be used.

The light-emitting layer preferably contains a phosphorescent material and a combination of a hole-transport material and an electron-transport material that easily forms an exciplex, for example. Such a structure makes it possible to efficiently obtain light emission using ExTET (Exciplex-Triplet Energy Transfer), which is energy transfer from an exciplex to a light-emitting substance (a phosphorescent material). When a combination is selected to form an exciplex that exhibits light emission whose wavelength overlaps with the wavelength of the lowest-energy-side absorption band of the light-emitting substance, energy can be transferred smoothly and light emission can be obtained efficiently. With this structure, high efficiency, low-voltage driving, and a long lifetime of the light-emitting element can be achieved at the same time.

The hole-injection layer injects holes from the anode to the hole-transport layer and contains a material with a high hole-injection property. Examples of a material with a high hole-injection property include an aromatic amine compound and a composite material containing a hole-transport material and an acceptor material (electron-accepting material).

As the hole-transport material, it is possible to use a material having a high hole-transport property which can be used for the hole-transport layer and will be described later.

As the acceptor material, an oxide of a metal belonging to Group 4 to Group 8 of the periodic table can be used, for example. Specific examples include molybdenum oxide, vanadium oxide, niobium oxide, tantalum oxide, chromium oxide, tungsten oxide, manganese oxide, and rhenium oxide. Among these, molybdenum oxide is particularly preferable since it is stable in the air, has a low hygroscopic property, and is easy to handle. An organic acceptor material containing fluorine can be used. An organic acceptor material such as a quinodimethane derivative, a chloranil derivative, or a hexaazatriphenylene derivative can be used.

For example, a hole-transport material and a material containing an oxide of a metal belonging to Group 4 to Group 8 of the periodic table (typically, molybdenum oxide) may be used as the material having a high hole-injection property.

The hole-transport layer transports holes injected from the anode by the hole-injection layer, to the light-emitting layer. The hole-transport layer contains a hole-transport material. As the hole-transport material, a substance having a hole mobility higher than or equal to 1×10⁻⁶ cm²/Vs is preferable. Note that other substances can also be used as long as the substances have a hole-transport property higher than an electron-transport property. As the hole-transport material, a material with a high hole-transport property, such as π-electron rich heteroaromatic compound (e.g., a carbazole derivative, a thiophene derivative, or a furan derivative) or an aromatic amine (a compound having an aromatic amine skeleton), is preferable.

The electron-blocking layer is provided in contact with the light-emitting layer. The electron-blocking layer has a hole-transport property and contains a material capable of blocking electrons. Any of the materials having an electron-blocking property among the above hole-transport materials can be used for the electron-blocking layer.

The electron-blocking layer has a hole-transport property, and thus can also be referred to as a hole-transport layer. A layer having an electron-blocking property among the hole-transport layers can also be referred to as an electron-blocking layer.

The electron-transport layer transports electrons injected from the cathode by the electron-injection layer, to the light-emitting layer. The electron-transport layer contains an electron-transport material. As the electron-transport material, a substance having an electron mobility higher than or equal to 1×10⁻⁶ cm²/Vs is preferable. Note that other substances can also be used as long as the substances have an electron-transport property higher than a hole-transport property: As the electron-transport material, any of the following materials with a high electron-transport property can be used, for example: a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a π-electron deficient heteroaromatic compound such as a nitrogen-containing heteroaromatic compound.

The hole-blocking layer is provided in contact with the light-emitting layer. The hole-blocking layer has an electron-transport property and contains a material capable of blocking holes. Any of the materials having a hole-blocking property among the above electron-transport materials can be used for the hole-blocking layer.

The hole-blocking layer has an electron-transport property, and thus can also be referred to as an electron-transport layer. A layer having a hole-blocking property among the electron-transport layers can also be referred to as a hole-blocking layer.

The electron-injection layer injects electrons from the cathode to the electron-transport layer and contains a material with a high electron-injection property. As the material with a high electron-injection property, an alkali metal, an alkaline earth metal, or a compound thereof can be used. As the material with a high electron-injection property, a composite material containing an electron-transport material and a donor material (electron-donating material) can also be used.

The difference between the LUMO level of the substance with a high electron-injection property and the work function value of the material used for the cathode is preferably small (specifically, smaller than or equal to 0.5 eV).

The electron-injection layer can be formed using, for example, an alkali metal, an alkaline earth metal, or a compound thereof, such as lithium, cesium, ytterbium, lithium fluoride (LiF), cesium fluoride (CsF), calcium fluoride (CaFₓ, where X is a given number), 8-(quinolinolato) lithium (abbreviation: Liq), 2-(2-pyridyl) phenolatolithium (abbreviation: LiPP), 2-(2-pyridyl)-3-pyridinolatolithium (abbreviation: LiPPy), 4-phenyl-2-(2-pyridyl) phenolatolithium (abbreviation: LiPPP), lithium oxide (LiOₓ), or cesium carbonate. The electron-injection layer may have a stacked-layer structure of two or more layers. The stacked-layer structure can be, for example, a structure where lithium fluoride is used for the first layer and ytterbium is used for the second layer.

The electron-injection layer may contain an electron-transport material. For example, a compound having an unshared electron pair and an electron deficient heteroaromatic ring can be used as the electron-transport material. Specifically, a compound having at least one of a pyridine ring, a diazine ring (a pyrimidine ring, a pyrazine ring, or a pyridazine ring), and a triazine ring can be used.

Note that the lowest unoccupied molecular orbital (LUMO) level of the organic compound having an unshared electron pair is preferably higher than or equal to −3.6 eV and lower than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-α: 2′, 3′-c]phenazine (abbreviation: HATNA), 2,4,6-tris[3′-(pyridin-3-yl) biphenyl-3-yl]-1,3,5-triazine (abbreviation: TmPPPyTz), or the like can be used for the organic compound having an unshared electron pair. Note that NBPhen has a higher glass transition point (Tg) than BPhen and thus has high heat resistance.

As described above, the charge-generation layer includes at least a charge-generation region. The charge-generation region preferably contains an acceptor material, and for example, preferably contains a hole-transport material and an acceptor material which can be used for the hole-injection layer.

The charge-generation layer preferably includes a layer containing a material having a high electron-injection property. The layer can also be referred to as an electron-injection buffer layer. The electron-injection buffer layer is preferably provided between the charge-generation region and the electron-transport layer. By provision of the electron-injection buffer layer, an injection barrier between the charge-generation region and the electron-transport layer can be lowered: thus, electrons generated in the charge-generation region can be easily injected into the electron-transport layer.

The electron-injection buffer layer preferably contains an alkali metal or an alkaline earth metal, and for example, can contain an alkali metal compound or an alkaline earth metal compound. Specifically, the electron-injection buffer layer preferably contains an inorganic compound containing an alkali metal and oxygen or an inorganic compound containing an alkaline earth metal and oxygen, further preferably contains an inorganic compound containing lithium and oxygen (lithium oxide (Li₂O) or the like). Alternatively, a material that can be used for the electron-injection layer can be suitably used for the electron-injection buffer layer.

The charge-generation layer preferably includes a layer containing a material having a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of inhibiting interaction between the charge-generation region and the electron-injection buffer layer (or the electron-transport layer) and smoothly transferring electrons.

A phthalocyanine-based material such as copper (II) phthalocyanine (abbreviation: CuPc) or a metal complex having a metal-oxygen bond and an aromatic ligand is preferably used for the electron-relay layer.

Note that the charge-generation region, the electron-injection buffer layer, and the electron-relay layer cannot be clearly distinguished from each other in some cases on the basis of the cross-sectional shapes, the characteristics, or the like.

Note that the charge-generation layer may contain a donor material instead of an acceptor material. For example, the charge-generation layer may include a layer containing an electron-transport material and a donor material, which can be used for the electron-injection layer.

When the light-emitting units are stacked, provision of a charge-generation layer between two light-emitting units can inhibit an increase in driving voltage.

This embodiment can be combined with the other embodiments as appropriate. In the case where a plurality of structure examples are described in one embodiment in this specification, the structure examples can be combined as appropriate.

### Embodiment 6

In this embodiment, electronic devices of one embodiment of the present invention will be described.

Electronic devices of this embodiment each include the display device of one embodiment of the present invention in a display portion. The display device of one embodiment of the present invention is highly reliable and can be easily increased in resolution and definition. Thus, the display device of one embodiment of the present invention can be used for a display portion of a variety of electronic devices.

Examples of the electronic devices include electronic devices with a relatively large screen, such as a television device, a desktop or notebook personal computer, a monitor of a computer or the like, digital signage, and a large game machine such as a pachinko machine: a digital camera: a digital video camera: a digital photo frame: a mobile phone: a portable game console: a portable information terminal; and an audio reproducing device.

In particular, the display device of one embodiment of the present invention can have a high resolution, and thus can be suitably used for an electronic device having a relatively small display portion. Examples of such an electronic device include a watch-type or a bracelet-type information terminal device (wearable device), and a wearable device worn on a head, such as a device for VR such as a head-mounted display, a glasses-type device for AR, and a device for MR.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K. 8K, or higher is preferable. The definition (resolution) of the display device of one embodiment of the present invention is preferably higher than or equal to 100 ppi, further preferably higher than or equal to 300 ppi, still further preferably higher than or equal to 500 ppi, yet still further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. With the use of such a display device having one or both of high definition and high resolution, the electronic device can provide higher realistic sensation, sense of depth, and the like in personal use such as portable use and home use. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

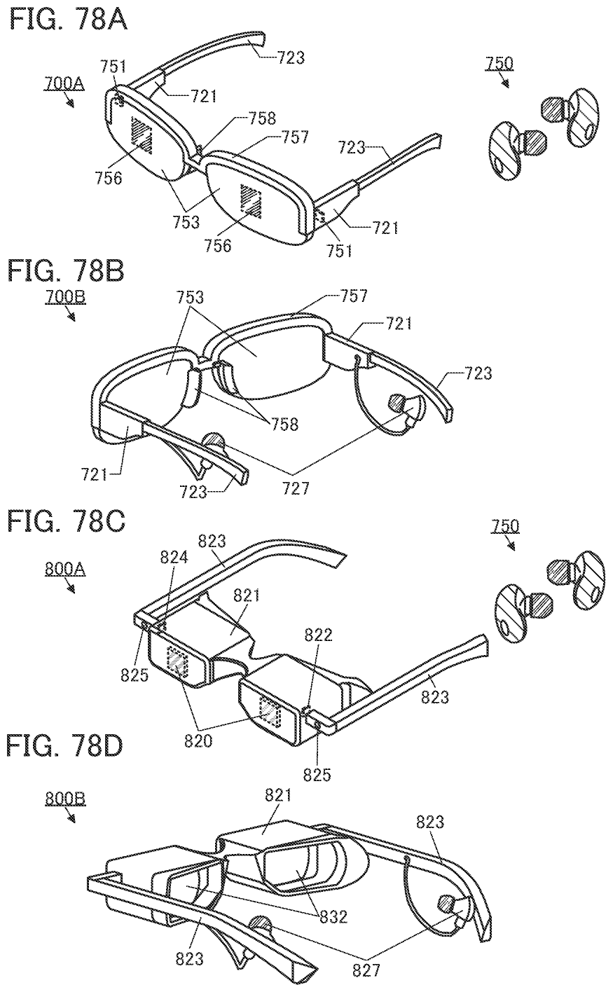

Examples of a wearable device that can be worn on a head are described with reference to FIG. 78A to FIG. 78D. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher sense of immersion.

An electronic device 700A illustrated in FIG. 78A and an electronic device 700B illustrated in FIG. 78B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panel 751. Thus, a highly reliable electronic appliance is obtained.

The electronic device 700A and the electronic device 700B can each project images displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are provided with an acceleration sensor such as a gyroscope sensor, the orientation of the user's head can be sensed and an image corresponding to the orientation can be displayed on the display regions 756.

The communication portion includes a wireless communication device, and a picture signal, for example, can be supplied by the wireless communication device. Instead of or in addition to the wireless communication device, a connector that can be connected to a cable for supplying a video signal and a power supply potential may be provided.

The electronic device 700A and the electronic device 700B are provided with a battery so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables executing various types of processing. For example, processing such as a pause or a restart of a moving image can be executed by a tap operation, and processing such as fast forward and fast rewind can be executed by a slide operation. When the touch sensor module is provided in each of the two housings 721, the range of the operation can be increased.

Any of various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion device (also referred to as a photoelectric conversion element) can be used as a light-receiving element. One or both of an inorganic semiconductor and an organic semiconductor can be used for an active layer of the photoelectric conversion device.

An electronic device 800A illustrated in FIG. 78C and an electronic device 800B illustrated in FIG. 78D each include a pair of display portions 820, a housing 821, a communication portion 822, a pair of wearing portions 823, a control portion 824, a pair of image capturing portions 825, and a pair of lenses 832.

A display device of one embodiment of the present invention can be used in the display portions 820. Thus, a highly reliable electronic appliance is obtained.

The display portions 820 are positioned inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B preferably include a mechanism for adjusting focus by changing the distance between the lenses 832 and the display portions 820.

The electronic device 800A or the electronic device 800B can be mounted on the user's head with the wearing portions 823. Note that FIG. 78C illustrates an example in which the wearing portion 823 has a shape like a temple (also referred to as a joint or the like) of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example where the image capturing portions 825 are provided is described here, a range sensor capable of measuring a distance from an object (hereinafter also referred to as a sensing portion) just needs to be provided. In other words, the image capturing portion 825 is one embodiment of the sensing portion. As the sensing portion, an image sensor or a distance image sensor such as LIDAR (Light Detection and Ranging) can be used, for example. By using images obtained by the camera and images obtained by the range image sensor, more information can be obtained and a gesture operation with higher accuracy is possible.

The electronic device 800A may include a vibration mechanism that functions as bone-conduction earphones. For example, any one or more of the display portion 820, the housing 821, and the wearing portion 823 can employ a structure including the vibration mechanism. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying, for example, a video signal from a video output device, power for charging a battery provided in the electronic device, and the like can be 0 connected.

The electronic device of one embodiment of the present invention may have a function of performing wireless communication with earphones 750. The earphones 750 include a communication portion (not illustrated) and has a wireless communication function. The earphones 750 can receive information (e.g., audio data) from the electronic device with the wireless communication function. For example, the electronic device 700A in FIG. 78A has a function of transmitting information to the earphones 750 with the wireless communication function. For another example, the electronic device 800A illustrated in FIG. 78C has a function of transmitting information to the earphones 750 with the wireless communication function.

The electronic device may include an earphone portion. The electronic device 700B in FIG. 78B includes earphone portions 727. For example, the earphone portion 727 and the control portion can be connected to each other by wire. Part of a wiring that connects the earphone portion 727 and the control portion may be positioned inside the housing 721 or the wearing portion 723.

Similarly, the electronic device 800B illustrated in FIG. 78D includes earphone portions 827. For example, the earphone portion 827 and the control portion 824 can be connected to each other by wire. Part of a wiring that connects the earphone portion 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

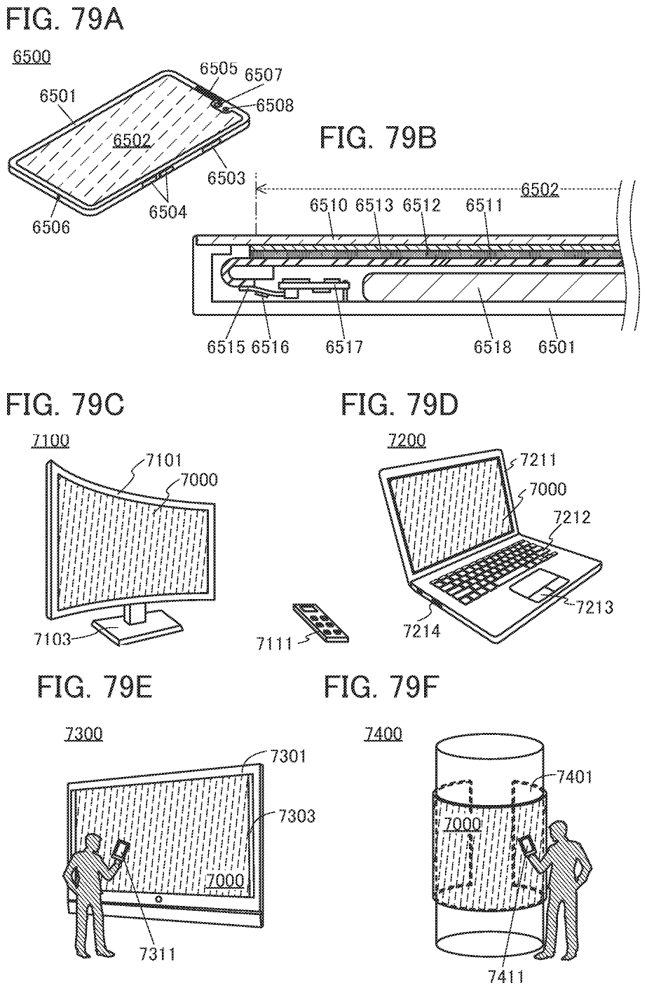

An electronic device 6500 illustrated in FIG. 79A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502. Thus, a highly reliable electronic appliance is obtained.

FIG. 79B is a schematic cross-sectional view including an end portion of the housing 6501 on the microphone 6506 side.

A protection member 6510 having a light-transmitting property is provided on a display surface side of the housing 6501, and a display device 6511, an optical member 6512, a touch sensor panel 6513, a printed circuit board 6517, a battery 6518, and the like are provided in a space surrounded by the housing 6501 and the protection member 6510.

The display device 6511, the optical member 6512, and the touch sensor panel 6513 are fixed to the protection member 6510 with an adhesive layer (not illustrated).

Part of the display device 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display device 6511. Thus, an extremely lightweight electronic device can be achieved. Since the display device 6511 is extremely thin, the battery 6518 with high capacity can be mounted without an increase in the thickness of the electronic device. Moreover, part of the display device 6511 is folded back so that a connection portion with the FPC 6515 is provided on the back side of a pixel portion, whereby an electronic device with a narrow bezel can be achieved.

FIG. 79C illustrates an example of a television device. In a television device 7100, a display portion 7000 is incorporated in a housing 7101. Here, the housing 7101 is supported by a stand 7103.

The display device of one embodiment of the present invention can be used for the display portion 7000. Thus, a highly reliable electronic appliance is obtained.

Operation of the television device 7100 illustrated in FIG. 79C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may be provided with a display portion for displaying information output from the remote control 7111. With operation keys or a touch panel provided in the remote control 7111, channels and volume can be controlled and videos displayed on the display portion 7000 can be operated.

Note that the television device 7100 has a structure in which a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 79D illustrates an example of a notebook personal computer. A notebook personal computer 7200 includes a housing 7211, a keyboard 7212, a pointing device 7213, an external connection port 7214, and the like. In the housing 7211, the display portion 7000 is incorporated.

The display device of one embodiment of the present invention can be used for the display portion 7000. Thus, a highly reliable electronic appliance is obtained.

FIG. 79E and FIG. 79F illustrate examples of digital signage.

Digital signage 7300 illustrated in FIG. 79E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 79F is digital signage 7400 attached to a cylindrical pillar 7401. The digital signage 7400 includes the display portion 7000 provided along a curved surface of the pillar 7401.

The display device of one embodiment of the present invention can be used for the display portion 7000 illustrated in each of FIG. 79E and FIG. 79F. Thus, a highly reliable electronic appliance is obtained.

A larger area of the display portion 7000 can increase the amount of information that can be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 79E and FIG. 79F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

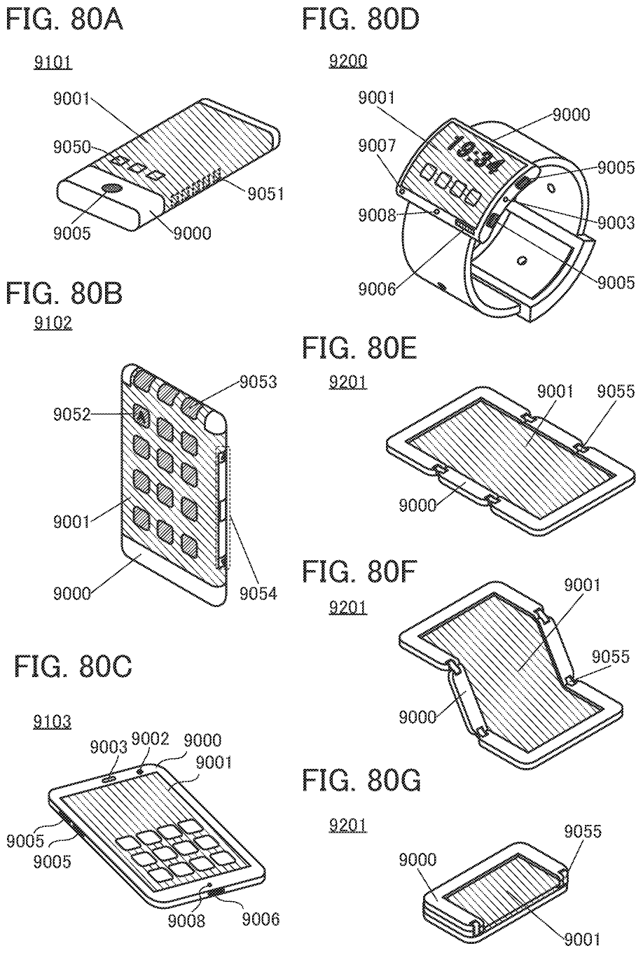

Electronic devices illustrated in FIG. 80A to FIG. 80G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared ray's), a microphone 9008, and the like.

The electronic devices illustrated in FIG. 80A to FIG. 80G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. In addition, the electronic devices may each include a camera, for example, and have a function of taking a still image or a moving image and storing the taken image in a recording medium (an external recording medium or a recording medium incorporated in the camera), a function of displaying the taken image on the display portion, or the like.

The details of the electronic devices illustrated in FIG. 80A to FIG. 80G are described below:

FIG. 80A is a perspective view illustrating a portable information terminal 9101. The portable information terminal 9101 can be used as a smartphone, for example. Note that the portable information terminal 9101 may include the speaker 9003, the connection terminal 9006, the sensor 9007, or the like. The portable information terminal 9101 can display characters and image information on its plurality of surfaces. FIG. 80A illustrates an example where three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050 or the like may be displayed at the position where the information 9051 is displayed.

FIG. 80B is a perspective view illustrating a portable information terminal 9102. The portable information terminal 9102 has a function of displaying information on three or more surfaces of the display portion 9001. Here, an example is illustrated in which information 9052, information 9053, and information 9054 are displayed on different surfaces. For example, a user can check the information 9053 displayed in a position that can be observed from above the portable information terminal 9102, with the portable information terminal 9102 put in a breast pocket of his/her clothes. The user can see the display without taking out the portable information terminal 9102 from the pocket and decide whether to answer the call, for example.

FIG. 80C is a perspective view illustrating a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, the camera 9002, the microphone 9008, and the speaker 9003 on the front surface of the housing 9000: the operation keys 9005 as buttons for operation on the left side surface of the housing 9000; and the connection terminal 9006 on the bottom surface of the housing 9000.

FIG. 80D is a perspective view illustrating a watch-type portable information terminal 9200. For example, the portable information terminal 9200 can be used as a Smartwatch (registered trademark). The display surface of the display portion 9001 is curved, and display can be performed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIG. 80E to FIG. 80G are perspective views illustrating a foldable portable information terminal 9201. FIG. 80E is a perspective view of an opened state of the portable information terminal 9201, FIG. 80G is a perspective view of a folded state thereof, and FIG. 80F is a perspective view of a state in the middle of change from one of FIG. 80E and FIG. 80G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with the other embodiments as appropriate. In the case where a plurality of structure examples are described in one embodiment in this specification, the structure examples can be combined as appropriate.

### REFERENCE NUMERALS

100A: display device, 100B: display device, 100C: display device, 100D: display device, 100E: display device, 100F: display device, 100G: display device, 100H: display device, 100: display device, 101: insulating layer, 102: conductive layer, 103: insulating layer, 104: insulating layer, 105: insulating layer, 106: plug, 107: pixel portion, 108: pixel, 109: conductive layer, 110B: subpixel, 110G: subpixel, 110R: subpixel, 110W: subpixel, 110: subpixel, 111a: conductive layer, 111B: conductive layer, 111b: conductive layer, 111C: conductive layer, 111c: conductive layer, 111f: conductive film, 111G: conductive layer, 111R: conductive layer, 111: conductive layer, 112a: conductive layer, 112B: conductive layer, 112b: conductive layer, 112C: conductive layer, 112c: conductive layer, 112f: conductive film, 112G: conductive layer, 112R: conductive layer, 112: conductive layer, 113B: EL layer, 113Bf: EL film, 113d: charge-generation layer, 113e: light-emitting unit, 113f: EL film, 113G: EL layer, 113Gf: EL film, 113R: EL layer, 113Rf: EL film, 113: EL layer, 114: common layer, 115: common electrode, 117: light-blocking layer, 118B: mask layer, 118Bf: mask film, 118f: mask film, 118G: mask layer, 118Gf: mask film, 118R: mask layer, 118Rf: mask film, 118: mask layer, 119B: mask layer, 119Bf: mask film, 119f: mask film, 119G: mask layer, 119Gf: mask film, 119R: mask layer, 119Rf: mask film, 119: mask layer, 120: substrate, 122: resin layer, 124a: pixel, 124b: pixel, 125f: insulating film, 125: insulating layer, 127a: insulating layer, 127b: insulating layer, 127f: insulating film, 127: insulating layer, 128: layer, 130B: light-emitting element, 130G: light-emitting element, 130R: light-emitting element, 130: light-emitting element, 131: protective layer, 132B: coloring layer, 132G: coloring layer, 132R: coloring layer. 132: coloring layer. 140: connection portion. 141: region. 142: adhesive layer. 151: substrate. 152: substrate. 164: circuit. 165: wiring. 166: conductive layer. 172: FPC. 173: IC. 180: region. 182: region. 184: region. 186: region. 190B: resist mask. 190G: resist mask. 190R: resist mask. 190: resist mask. 201: transistor. 204: connection portion. 205: transistor, 209: transistor. 210: transistor. 211: insulating layer. 213: insulating layer. 214: insulating layer. 215: insulating layer. 218: insulating layer. 221: conductive layer. 222a: conductive layer. 222b: conductive layer. 223: conductive layer. 224B: conductive layer. 224C: conductive layer. 224G: conductive layer. 224R: conductive layer. 225: insulating layer. 231i: channel formation region. 231n: low-resistance region. 231: semiconductor layer. 240: capacitor. 241: conductive layer. 242: connection layer. 243: insulating layer. 245: conductive layer. 251: conductive layer. 252: conductive layer. 254: insulating layer. 255: insulating layer. 256: plug. 261: insulating layer. 262: insulating layer. 263: insulating layer. 264: insulating layer. 265: insulating layer. 271: plug. 274a: conductive layer. 274b: conductive layer. 274: plug. 280: display module. 281: display portion. 282: circuit portion. 283a: pixel circuit. 283: pixel circuit portion. 284a: pixel. 284: pixel portion. 285: terminal portion. 286: wiring portion. 290: FPC. 291: substrate. 292: substrate. 301A: substrate. 301B: substrate. 301: substrate. 310A: transistor. 310B: transistor. 310: transistor, 311: conductive layer. 312: low-resistance region. 313: insulating layer. 314: insulating layer. 315: element isolation layer, 320A: transistor. 320B: transistor. 320D: transistor. 321: semiconductor layer. 323: insulating layer. 324: conductive layer. 325: conductive layer. 326: insulating layer. 327: conductive layer. 328: insulating layer. 329: insulating layer. 331: substrate. 332: insulating layer. 335: insulating layer. 336: insulating layer. 341: conductive layer. 342: conductive layer. 343: plug. 344: insulating layer. 345: insulating layer. 346: insulating layer. 347: bump. 348: adhesive layer. 500: display device. 501: electrode. 502: electrode. 512B_1: light-emitting unit. 512B_2: light-emitting unit. 512B_3: light-emitting unit. 512G_1: light-emitting unit. 512G_2: light-emitting unit. 512G_3: light-emitting unit. 512R_1: light-emitting unit. 512R_2: light-emitting unit. 512R_3: light-emitting unit. 521: layer. 522: layer. 523B: light-emitting layer. 523G: light-emitting layer. 523R: light-emitting layer. 524: layer. 525: layer. 531: charge-generation layer. 550B: light-emitting element. 550G: light-emitting element. 550R: light-emitting element. 700A: electronic device. 700B: electronic device. 721: housing. 723: wearing portion. 727: earphone portion. 750: earphones. 751: display panel. 753: optical member. 756: display region. 757: frame. 758: nose pad. 761: lower electrode. 762: upper electrode. 763a: light-emitting unit. 763b: light-emitting unit. 763c: light-emitting unit. 763: EL layer. 764: layer. 771a: light-emitting layer. 771b: light-emitting layer. 771c: light-emitting layer. 771: light-emitting layer. 772a: light-emitting layer. 772b: light-emitting layer. 772c: light-emitting layer. 772: light-emitting layer. 773: light-emitting layer. 780a: layer. 780b: layer. 780c: layer. 780: layer. 781: layer. 782: layer. 785: charge-generation layer. 790a: layer. 790b: layer, 790c: layer, 790: layer, 791: layer, 792: layer, 800A: electronic device, 800B: electronic device, 820: display portion, 821: housing, 822: communication portion, 823: wearing portion, 824: control portion, 825: imaging portion, 827: earphone portion, 832: lens, 6500: electronic device, 6501: housing, 6502: display portion, 6503: power button, 6504: button, 6505: speaker, 6506: microphone, 6507: camera, 6508: light source, 6510: protective member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote controller, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A display device comprising:
a first light-emitting element;
a second light-emitting element adjacent to the first light-emitting element;
a first insulating layer between the first light-emitting element and the second light-emitting element; and
a second insulating layer over the first insulating layer,
wherein the first light-emitting element comprises a first conductive layer, a second conductive layer covering an upper surface and a side surface of the first conductive layer, a first EL layer over the second conductive layer, and a common electrode over the first EL layer,
wherein the second light-emitting element comprises a third conductive layer, a fourth conductive layer covering an upper surface and a side surface of the third conductive layer, a second EL layer over the fourth conductive layer, and the common electrode over the second EL layer,
wherein the common electrode is over the second insulating layer,
wherein visible light reflectance of the first conductive layer is higher than visible light reflectance of the second conductive layer, and
wherein visible light reflectance of the third conductive layer is higher than visible light reflectance of the fourth conductive layer.

2. The display device according to claim 1,
wherein the first EL layer comprises a first functional layer comprising a region in contact with the second conductive layer and a first light-emitting layer over the first functional layer, and
wherein the second EL layer comprises a second functional layer comprising a region in contact with the fourth conductive layer and a second light-emitting layer over the second functional layer.

3. The display device according to claim 2,
wherein the first functional layer and the second functional layer each comprise at least one of a hole-injection layer and a hole-transport layer,
wherein a work function of the second conductive layer is higher than a work function of the first conductive layer, and
wherein a work function of the fourth conductive layer is higher than a work function of the third conductive layer.

4. The display device according to claim 3,
wherein the first light-emitting element further comprises a common layer between the first EL layer and the common electrode,
wherein the second light-emitting element further comprises the common layer between the second EL layer and the common electrode,
wherein the common layer is between the second insulating layer and the common electrode, and
wherein the common layer comprises at least one of an electron-injection layer and an electron-transport layer.

5. the display device according to claim 2,
wherein the first functional layer and the second functional layer each comprise at least one of an electron-injection layer and an electron-transport layer,
wherein a work function of the second conductive layer is lower than a work function of the first conductive layer, and
wherein a work function of the fourth conductive layer is lower than a work function of the third conductive layer.

6. The display device according to claim 5,
wherein the first light-emitting element further comprises a common layer between the first EL layer and the common electrode,
wherein the second light-emitting element further comprises the common layer between the second EL layer and the common electrode,
wherein the common layer is between the second insulating layer and the common electrode, and
wherein the common layer comprises at least one of a hole-injection layer and a hole-transport layer.

7. The display device according to claim 1,
wherein the second conductive layer and the fourth conductive layer each comprise any one or more selected from indium, tin, zinc, gallium, titanium, aluminum, and silicon.

8. The display device according to claim 1,
wherein the first insulating layer comprises a region in contact with a side surface of the first EL layer and a side surface of the second EL layer and covers part of an upper surface of the first EL layer and part of an upper surface of the second EL layer,
wherein an end portion of the second insulating layer has a tapered shape with a taper angle less than 90° in a cross-sectional view, and
wherein the second insulating layer covers at least part of a side surface of the first insulating layer.

9. The display device according to claim 1,
wherein an end portion of the first insulating layer has a tapered shape with a taper angle less than 90° in a cross-sectional view.

10. The display device according to claim 1,
wherein the first insulating layer is an inorganic insulating layer, and
wherein the second insulating layer is an organic insulating layer.

11. The display device according to claim 1,
wherein the first insulating layer comprises aluminum oxide, and
wherein the second insulating layer comprises an acrylic resin.

12. A display module comprising:
the display device according to claim 1; and
at least one of a connector and an integrated circuit.

13. An electronic device comprising:
the display module according to claim 12; and
at least one of a housing, a battery, a camera, a speaker, and a microphone.

14. A method of manufacturing a display device, comprising the steps of:
forming a first conductive layer;
forming a second conductive layer that covers an upper surface and a side surface of the first conductive layer and has lower visible light reflectance than the first conductive layer;
forming an EL film over the second conductive layer;
forming a mask film over the EL film; and
forming an EL layer over the second conductive layer and a mask layer over the EL layer by processing the EL film and the mask film.

15. The method of manufacturing a display device, according to claim 14,
wherein hydrophobization treatment for the second conductive layer is performed between the step of forming the second conductive layer and the step of forming the EL film.

16. The method of manufacturing a display device, according to claim 15,
wherein the hydrophobization treatment is performed by fluorination of the second conductive layer.

17. A method of manufacturing a display device, comprising the steps of:
forming a first conductive layer and a second conductive layer;
forming a third conductive layer that covers an upper surface and a side surface of the first conductive layer and has lower visible light reflectance than the first conductive layer and a fourth conductive layer that covers an upper surface and a side surface of the second conductive layer and has lower visible light reflectance than the second conductive layer;
forming a first EL film over the third conductive layer and the fourth conductive layer;
forming a first mask film over the first EL film;
forming a first EL layer over the third conductive layer and a first mask layer over the first EL layer and exposing the fourth conductive layer by processing the first EL film and the first mask film;
forming a second EL film over the first mask layer and the fourth conductive layer;
forming a second mask film over the second EL film;
forming a second EL layer over the fourth conductive layer and a second mask layer over the second EL layer and exposing the first mask layer by processing the second EL film and the second mask film,
forming an insulating film using a photosensitive material over the first mask layer and over the second mask layer;
forming an insulating layer between the first EL layer and the second EL layer by processing the insulating film;
exposing an upper surface of the first EL layer and an upper surface of the second EL layer by etching treatment using the insulating layer as a mask; and
forming a common electrode over the first EL layer, the second EL layer, and the insulating layer.

18. The method of manufacturing a display device, according to claim 17,
wherein hydrophobization treatment for the third conductive layer and the fourth conductive layer is performed between the step of forming the third conductive layer and the fourth conductive layer and the step of forming the first EL film.

19. The method of manufacturing a display device, according to claim 18,
wherein the hydrophobization treatment is performed by fluorination of the third conductive layer and the fourth conductive layer.

20. The method of manufacturing a display device, according to claim 17,
wherein the etching treatment is performed by wet etching.
